(19) United States
(12) Patent Application Publication
(10) Pub. No.: US 2025/0224485 A1
(43) Pub. Date: Jul. 10, 2025

(54) TERAHERTZ SENSORS AND RELATED SYSTEMS AND METHODS

(71) Applicant: TeraDar, Inc., Cambridge, MA (US)

(72) Inventors: Nicholas Saiz, San Jose, CA (US); Gregory L. Charvat, Guilford, CT (US); Matthew Carey, Watertown, MA (US); Edward Zhong, San Leandro, CA (US); Graham Peyton, New Haven, CT (US)

(73) Assignee: TeraDar, Inc., Cambridge, MA (US)

(21) Appl. No.: 19/004,134

(22) Filed: Dec. 27, 2024

Related U.S. Application Data
(60) Provisional application No. 63/618,784, filed on Jan. 8, 2024.
(60) Provisional application No. 63/616,483, filed on Dec. 29, 2023.

(51) Int. Cl. G01S 7/03; G01S 13/86; G01S 13/931; H01L 23/66; H01Q 21/06

(52) U.S. Cl. CPC G01S 7/036; G01S 7/032; G01S 13/865; G01S 13/931; H01L 23/66; H01Q 21/065

(57) ABSTRACT

In some embodiments, a device may comprise a substrate having signal generation circuitry, a transmitter, a receiver, and interface circuitry each mounted thereon. The transmitter may comprise a transmit semiconductor die having integrated thereon transmit circuitry configured to generate, based on a reference RF signal generated by the signal generation circuitry, first RF signals having an RF center frequency between 300-320 GHz and a transmit antenna array comprising a plurality of RF antennas configured to transmit the first RF signals. The receiver may comprise a receive semiconductor die having integrated thereon a receive antenna array comprising a plurality of RF antennas configured to receive second RF signals having the RF center frequency and receive circuitry configured to generate third RF signals based on the reference RF signal and mix the second RF signals with the third RF signals to obtain fourth RF signals. The interface circuitry may comprise ADC circuitry.

### CROSS-REFERENCE TO RELATED APPLICATIONS

This application claims the benefit of priority under 35 U.S.C. § 119 (c) of U.S. Provisional Patent Application Ser. No. 63/618,784, entitled TERAHERTZ SENSORS AND RELATED SYSTEMS AND METHODS,” filed on Jan. 8, 2024, under Attorney Docket No. F0869.70004US01, which is incorporated by reference herein in its entirety.

This application claims the benefit of priority under 35 U.S.C. § 119 (c) of U.S. Provisional Patent Application Ser. No. 63/616,483, entitled “TERAHERTZ SENSORS AND RELATED SYSTEMS AND METHODS,” filed on Dec. 29, 2023, under Attorney Docket No. F0869.70004US00, which is incorporated by reference herein in its entirety.

### BACKGROUND

Most vehicles available today are equipped with sensors capable of sensing the surrounding environment, which helps drivers operate vehicles more safely in difficult driving situations, contributing significantly to the reduction of vehicle-related accidents such as collisions. It is expected that the use of advanced sensing technologies will accelerate across all segments of the vehicle market, which will help significantly reduce vehicle-related accidents, resulting in fewer injuries and fatalities. It is also expected that the use of advanced sensing technologies at all levels of automation within the vehicle market will make mass implementation of automated vehicles safer. The development and deployment of advanced vehicle-based sensing require significant advances in technology.

### SUMMARY

Some embodiments provide for a device, comprising: a substrate defining a plane extending in first and second directions substantially orthogonal to one another; signal generation circuitry mounted on the substrate and configured to generate a reference RF signal; a transmitter mounted on the substrate, the transmitter comprising: a first transmit semiconductor die coupled to the signal generation circuitry and having integrated thereon: first transmit circuitry configured to generate, based on the reference RF signal, first RF signals having an RF center frequency between 300-320 GHz, and a first transmit antenna array comprising a first plurality of RF antennas configured to transmit the first RF signals; and a receiver mounted on the substrate, the receiver comprising: a first receive semiconductor die coupled to the signal generation circuitry and having integrated thereon: a first receive antenna array comprising a second plurality of RF antennas configured to receive second RF signals having the RF center frequency; and first receive circuitry configured to: generate third RF signals based on the reference RF signal; and mix the second RF signals with the third RF signals to obtain fourth RF signals and provide the fourth RF signals to the interface circuitry; and interface circuitry mounted on the substrate and coupled to the first receive circuitry, the interface circuitry comprising analog-to-digital conversion (ADC) circuitry configured to digitize the fourth RF signals.

Some embodiments provide for a device, comprising: a substrate defining a plane extending in first and second directions substantially orthogonal to one another; signal generation circuitry mounted on the substrate and configured to generate a reference RF signal; a transmitter mounted on the substrate, the transmitter comprising: a first transmit semiconductor die coupled to the signal generation circuitry and having integrated thereon: first transmit circuitry configured to generate, based on the reference RF signal, first RF signals having an RF center frequency in a particular frequency range within a range of 150 GHz to 1.5 THz, and a first transmit antenna array comprising a first plurality of RF antennas configured to transmit the first RF signals; and a receiver mounted on the substrate, the receiver comprising:
a first receive semiconductor die coupled to the signal generation circuitry and having integrated thereon: a first receive antenna array comprising a second plurality of RF antennas configured to receive second RF signals having the RF center frequency; and first receive circuitry configured to:
generate third RF signals based on the reference RF signal; and mix the second RF signals with the third RF signals to obtain fourth RF signals and provide the fourth RF signals to the interface circuitry; and interface circuitry mounted on the substrate and coupled to the first receive circuitry, the interface circuitry comprising analog-to-digital conversion (ADC) circuitry configured to digitize the fourth RF signals.

Some embodiments provide for a device, comprising: a substrate; and a receiver mounted on the substrate, the receiver comprising: a first receive semiconductor die having integrated thereon: a first receive antenna array configured to receive RF signals, the first receive antenna array comprising a first RF antenna; and first receive circuitry comprising: a plurality of mixers coupled to respective RF antennas in the first receive antenna array, the plurality of mixers comprising a first mixer coupled to the first RF antenna and configured to mix an RF signal obtained using the first RF antenna with a reference RF signal to output a first mixed signal;

a first amplifier coupled to the first mixer and configured to amplify the first mixed signal output by the first mixer; and a first reflector coupled between the first mixer and the first amplifier and configured to reflect at least some RF energy generated by the first mixer back into the first mixer.

Some embodiments provide for a device, comprising: a substrate; and a receiver mounted on the substrate, the receiver comprising: a first receive semiconductor die having integrated thereon: a first RF antenna configured to receive RF signals; and first receive circuitry comprising: a first mixer coupled to the first RF antenna and configured to mix an RF signal obtained using the first RF antenna with a reference RF signal to output a first mixed signal;
a first amplifier coupled to the first mixer and configured to amplify the first mixed signal output by the first mixer; and a first reflector coupled between the first mixer and the first amplifier.

Some embodiments provide for a device, comprising: a substrate; and a receiver mounted on the substrate, the receiver comprising: a first receive semiconductor die having integrated thereon: a first receive antenna array comprising a plurality of RF antennas, each of the plurality of RF antennas comprising two or more patches serially coupled to one another; and first receive circuitry coupled to the plurality of RF antennas, wherein, for each particular one of the plurality of RF antennas, the first receive circuitry is coupled to one of the two or more patches of the particular RF antenna.

Some embodiments provide for a device, comprising: a substrate defining a plane extending in first and second directions substantially orthogonal to one another; a transmitter mounted on the substrate, the transmitter comprising: a first transmit semiconductor die having integrated thereon:
first transmit circuitry configured to generate first RF signals based on a reference RF signal; and a first transmit antenna array comprising a plurality of RF antennas configured to transmit the first RF signals and having a first aperture with a first length extending in the first direction and a first width extending in the second direction, the first length being larger than the first width, wherein the plurality of RF antennas is arranged in a two-dimensional grid and has mirror symmetry across a line extending in the first direction; and
a receiver mounted on the substrate, the receiver comprising a first receive semiconductor die having integrated thereon: a first receive antenna array comprising a plurality of RF antennas configured to receive second RF signals and having a second aperture with a second length extending in the first direction and a second width extending in the second direction, the second length being smaller than the second width; and first receive circuitry configured to obtain the second RF signals via the plurality of RF antennas of the first receive antenna array.

Some embodiments provide for a device, comprising: a substrate; a receiver mounted on the substrate, the receiver comprising: a first semiconductor die having integrated thereon a first plurality of RF antennas configured to receive first RF signals having a first RF center frequency, the first plurality of RF antennas including a first RF antenna; and a second semiconductor die having integrated thereon a second plurality of RF antennas configured to receive second RF signals having the first RF center frequency, the second plurality of RF antennas including a second RF antenna, wherein the first semiconductor die and the second semiconductor die are arranged in the receiver such that a center-to-center distance between the first RF antenna and the second RF antenna is less than or equal to (e.g., within 10% of) one half of a free-space wavelength at the first RF center frequency.

Some embodiments provide for a device, comprising: a semiconductor die having integrated thereon: a first plurality of RF antennas configured to receive RF signals having a first RF center frequency, the first plurality of RF antennas including a first RF antenna, wherein the first RF antenna is integrated on the semiconductor die such that a center of the first RF antenna is located at a distance from an outer edge of the semiconductor die that is less than one quarter of a free-space wavelength at the first RF center frequency.

Some embodiments provide for a method of manufacturing a semiconductor dies having RF antenna arrays integrated thereon for use in a transmitter and/or receiver, the method comprising: obtaining a semiconductor wafer comprising a plurality of RF antenna arrays; and dicing the semiconductor wafer into a plurality of semiconductor dies each having integrated thereon a respective one of the plurality of RF antenna arrays such that, on each of the plurality of semiconductor dies, a distance between an outer edge of the semiconductor die and an outer edge of at least one RF antenna of the RF antenna array integrated on the semiconductor die is between 10 and 50 microns.

Some embodiments provide for a device, comprising: a substrate; a transmitter mounted on the substrate, the transmitter comprising: a transmit semiconductor die having integrated thereon: a transmit antenna array comprising a first plurality of transmit RF antennas configured to transmit first RF signals; and transmit circuitry configured to feed the plurality of RF antennas in the transmit antenna array; a receiver mounted on the substrate, the receiver comprising:
a receive semiconductor die having integrated thereon: a receive antenna array comprising a second plurality of RF antennas configured to receive second RF signals; receive circuitry configured to process the RF signals received by the plurality of RF antennas to obtain processed RF signals; analog-to-digital conversion (ADC) circuitry mounted on the substrate, the ADC circuitry coupled to the receive circuitry and configured to digitize the processed RF signals to obtain digitized RF signals; and processing circuitry configured to operate at least one of the transmit circuitry, receive circuitry, and the ADC circuitry in: a first operating state in a plurality of time intervals, each of the plurality of time intervals including time when the first plurality of RF antennas are being operated to transmit the first RF signals and/or time when the second plurality of RF antennas are being operated to receive the second RF signals; and
a second operating state outside of the plurality of time intervals, wherein the at least one of the transmit circuitry, the receive circuitry, and the ADC circuitry is operated using less power in the second operating state than is used to operate it in the first operating state.

Some embodiments provide for a device, comprising: a substrate; a transmitter mounted on the substrate, the transmitter comprising: a transmit semiconductor die having integrated thereon:
transmit circuitry configured to generate, based on a reference RF signal, first RF signals having an RF center frequency between 300 GHz and 3 THz; and a transmit antenna array comprising a first plurality of RF antennas configured to transmit the first RF signals;
a receiver mounted on the substrate, the receiver comprising: a receive semiconductor die having integrated thereon: a receive antenna array comprising a second plurality of RF antennas configured to receive second RF signals having the RF center frequency, the second RF signals being generated at least in part by first RF signals being reflected by a target object; and
receive circuitry configured to: generate third RF signals based on the reference RF signal; and
mix the second RF signals with the third RF signals to obtain fourth RF signals; interface circuitry mounted on the substrate and comprising analog-to-digital conversion (ADC) circuitry, the ADC circuitry coupled to the receive circuitry and configured to digitize the fourth RF signals to obtain digitized RF signals; and processing circuitry configured to identify a material of the target object using one or more of the digitized RF signals, wherein the material is any material having a dielectric constant greater than 1.

Some embodiments provide for a device, comprising: a substrate; a transmitter mounted on the substrate, the transmitter comprising: transmit circuitry configured to generate first RF signals having an RF center frequency between 300 GHz and 3 THz; and a transmit antenna array comprising a plurality of RF antennas configured to transmit the first RF signals; a receiver mounted on the substrate, the receiver comprising: a receive antenna array configured to receive second RF signals having the RF center frequency, the second RF signals being generated at least in part by first RF signals being reflected by a target object; and receive circuitry configured to process the received second RF signals to obtain processed RF signals; ADC circuitry coupled to the receive circuitry and configured to digitize the processed RF signals to obtain digitized RF signals; and processing circuitry configured to identify a material of the target object using one or more of the digitized RF signals, wherein the material is any material having a dielectric constant greater than 1.

Some embodiments provide for a method for use with a device comprising a substrate having a transmitter, a receiver, and analog-to-digital conversion (ADC) circuitry mounted thereon, the transmitter comprising a transmit antenna array, the receiver comprising a receive antenna array and receive circuitry, the method comprising: transmitting, using the transmit antenna array, first RF signals having an RF center frequency between 300 GHz and 3 THz;
receiving, using the receive antenna array, second RF signals having the RF center frequency, the second RF signals being generated at least in part by first RF signals being reflected by a target object; processing, using the receive circuitry, the second RF signals to obtain processed RF signals; digitizing, using the ADC circuitry, the processed RF signals output by the receive circuitry to obtain digitized RF signals; and identifying, using processing circuitry, a material of the target object using one or more of the digitized RF signals, wherein the material is any material having a dielectric constant greater than 1.

Some embodiments provide for a device, comprising: a substrate; a transmitter mounted on the substrate, the transmitter comprising: a transmit semiconductor die having integrated thereon:
transmit circuitry configured to generate, based on a reference RF signal, first RF signals having an RF center frequency between 300 GHz and 3 THz; and a transmit antenna array comprising a first plurality of RF antennas configured to transmit the first RF signals;
a receiver mounted on the substrate, the receiver comprising: a receive semiconductor die having integrated thereon: a receive antenna array comprising a second plurality of RF antennas configured to receive second RF signals having the RF center frequency, the second RF signals being generated at least in part by first RF signals being reflected by a target object; and
receive circuitry configured to: generate third RF signals based on the reference RF signal; and
mix the second RF signals with the third RF signals to obtain fourth RF signals; and
interface circuitry mounted on the substrate and comprising analog-to-digital conversion (ADC) circuitry, the ADC circuitry coupled to the receive circuitry and configured to digitize the fourth RF signals to obtain digitized RF signals; processing circuitry configured to detect a material disposed on the target object using one or more of the digitized RF signals.

Some embodiments provide for a device, comprising: a substrate; a transmitter mounted on the substrate, the transmitter comprising: transmit circuitry configured to generate first RF signals having an RF center frequency between 300 GHz and 3 THz; and a transmit antenna array comprising a first plurality of RF antennas configured to transmit the first RF signals; a receiver mounted on the substrate, the receiver comprising: a receive antenna array comprising a second plurality of RF antennas configured to receive second RF signals having the RF center frequency, the second RF signals being generated at least in part by first RF signals being reflected by a target object; and receive circuitry configured to process the received second RF signals to obtain processed RF signals; ADC circuitry coupled to the receive circuitry and configured to digitize the processed RF signals to obtain digitized RF signals; and processing circuitry configured to detect a material disposed on the target object using one or more of the digitized RF signals.

Some embodiments provide for a method for use with a device comprising a substrate having a transmitter, a receiver, and analog-to-digital conversion (ADC) circuitry mounted thereon, the transmitter comprising a transmit antenna array, the receiver comprising a receive antenna array and receive circuitry, the method comprising: transmitting, using the transmit antenna array, first RF signals having an RF center frequency between 300 GHz and 3 THz;
receiving, using the receive antenna array, second RF signals having the RF center frequency, the second RF signals being generated at least in part by first RF signals being reflected by a target object; processing, using the receive circuitry, the second RF signals to obtain processed RF signals; digitizing, using the ADC circuitry, the processed RF signals output by the receive circuitry to obtain digitized RF signals; and detecting, using processing circuitry, a material disposed on the target object using one or more of the digitized RF signals.

Some embodiments provide for a device, comprising: a transmitter mounted on the substrate, the transmitter comprising: a transmit semiconductor die having integrated thereon:
transmit circuitry configured to generate, based on a reference RF signal, first RF signals having an RF center frequency between 300 GHz and 3 THz; and a transmit antenna array comprising a first plurality of RF antennas configured to transmit the first RF signals; a receiver mounted on the substrate, the receiver comprising: a receive semiconductor die having integrated thereon:
a receive antenna array comprising a second plurality of RF antennas configured to receive second RF signals generated as a result of the first RF signals being reflected by a target object; and receive circuitry configured to: generate third RF signals based on the reference RF signal; and mix the second RF signals with the third RF signals to obtain fourth RF signals; interface circuitry mounted on the substrate and comprising analog-to-digital conversion (ADC) circuitry, the ADC circuitry coupled to the receive circuitry and configured to digitize the fourth RF signals to obtain digitized RF signals; and processing circuitry configured to: determine a first velocity of at least a part of the target object using one or more of the digitized RF signals;
predict movement of the target object using the first velocity.

Some embodiments provide for a device, comprising: a substrate; a transmitter mounted on the substrate, the transmitter comprising: transmit circuitry configured to generate first RF signals having an RF center frequency between 300 GHz and 3 THz; and a transmit antenna array comprising a first plurality of RF antennas configured to transmit the first RF signals; a receiver mounted on the substrate, the receiver comprising: a receive antenna array comprising a second plurality of RF antennas configured to receive second RF signals generated as a result of the first RF signals being reflected by a target object; and receive circuitry configured to process the received second RF signals to obtain processed RF signals; ADC circuitry coupled to the receive circuitry and configured to digitize the processed RF signals to obtain digitized RF signals; and processing circuitry configured to: determine a first velocity of at least a part of the target object using one or more of the digitized RF signals; predict movement of the target object using the first velocity.

Some embodiments provide for a method for use with a device comprising a substrate having a transmitter, a receiver, and analog-to-digital conversion (ADC) circuitry mounted thereon, the transmitter comprising a transmit antenna array, the receiver comprising a receive antenna array and receive circuitry, the method comprising: transmitting, using the transmit antenna array, first RF signals having an RF center frequency between 300 GHz and 3 THz;
receiving, using the receive antenna array, second RF signals having the RF center frequency, the second RF signals being generated at least in part by first RF signals being reflected by a target object; processing, using the receive circuitry, the second RF signals to obtain processed RF signals; digitizing, using the ADC circuitry, the processed RF signals output by the receive circuitry to obtain digitized RF signals; and determining, using the processing circuitry, a first velocity of at least a part of the target object using one or more of the digitized RF signals;
predicting, using the processing circuitry, movement of the target object using the first velocity.

Some embodiments provide for a device, comprising: a substrate; a transmitter mounted on the substrate, the transmitter comprising: a transmit semiconductor die having integrated thereon:
transmit circuitry configured to generate, based on a reference RF signal, first RF signals having an RF center frequency between 300 GHz and 3 THz; and a transmit antenna array comprising a plurality of RF antennas configured to transmit the first RF signals; a receiver mounted on the substrate, the receiver comprising: a receive semiconductor die having integrated thereon: a receive antenna array configured to receive second RF signals generated as a result of the first RF signals being reflected by one or more target objects in a scene; and receive circuitry configured to: generate third RF signals based on the reference RF signal; and mix the second RF signals with the third RF signals to obtain fourth RF signals; interface circuitry mounted on the substrate and comprising analog-to-digital conversion (ADC) circuitry, the ADC circuitry coupled to the receive circuitry and configured to digitize the fourth RF signals to obtain digitized RF signals; and processing circuitry configured to perform: obtaining sensor data about the scene from a sensor separate from the device; and associating the sensor data obtained from the sensor with data derived from one or more of the digitized RF signals.

Some embodiments provide for a device, comprising: a substrate; a transmitter mounted on the substrate, the transmitter comprising: transmit circuitry configured to generate first RF signals having an RF center frequency between 300 GHz and 3 THz; and a transmit antenna array comprising a plurality of RF antennas configured to transmit the first RF signals;
a receiver mounted on the substrate, the receiver comprising: a receive antenna array configured to receive second RF signals generated as a result of the first RF signals being reflected by one or more target objects in a scene; and receive circuitry configured to process the received second RF signals to obtain processed RF signals; ADC circuitry coupled to the receive circuitry and configured to digitize the processed RF signals to obtain digitized RF signals; and
processing circuitry configured to perform: obtaining sensor data about the scene from a sensor separate from the device; and associating the sensor data obtained from the sensor with data derived from one or more of the digitized RF signals.

Some embodiments provide for a method for use with a device comprising a substrate having a transmitter, a receiver, and analog-to-digital conversion (ADC) circuitry mounted thereon, the transmitter comprising a transmit antenna array, the receiver comprising a receive antenna array and receive circuitry, the method comprising: transmitting, using the transmit antenna array, first RF signals having an RF center frequency between 300 GHz and 3 THz;
receiving, using the receive antenna array, second RF signals having the RF center frequency, the second RF signals being generated at least in part by first RF signals being reflected by a target object; processing, using the receive circuitry, the second RF signals to obtain processed RF signals;
digitizing, using the ADC circuitry, the processed RF signals output by the receive circuitry;
obtaining, using the processing circuitry, sensor data about the scene from a sensor separate from the device; and associating, using the processing circuitry, the sensor data obtained from the sensor with data derived from one or more of the digitized RF signals.

Some embodiments provide for a device, comprising: a substrate; signal generation circuitry mounted on the substrate and configured to generate a reference RF signal, the reference RF signal being a linear frequency modulated (LFM) chirp signal; a transmitter mounted on the substrate, the transmitter comprising: a first transmit semiconductor die coupled to the signal generation circuitry and having integrated thereon: first transmit circuitry configured to generate, based on the reference RF signal, first RF signals having an RF center frequency between 300-320 GHz, and a first transmit antenna array comprising a first plurality of RF antennas configured to transmit the first RF signals; and a receiver mounted on the substrate, the receiver comprising: a first receive semiconductor die coupled to the signal generation circuitry and having integrated thereon: a first receive antenna array comprising a second plurality of RF antennas configured to receive second RF signals having the RF center frequency, the second RF signals being generated at least in part by first RF signals being reflected by a target object; and first receive circuitry configured to process the second RF signals, using the reference RF signal, to output processed RF signals; analog-to-digital conversion (ADC) circuitry configured to digitize the processed RF signals to obtain digitized RF signals; and processing circuitry coupled to the ADC circuitry and configured to generate a range cross-range image of the target object using the digitized RF signals.

Some embodiments provide for a method of imaging a target object using a device comprising a substrate having a transmitter, a receiver, and analog-to-digital conversion (ADC) circuitry, mounted thereon, the transmitter comprising a transmit antenna array, the receiver comprising a receive antenna array and receive circuitry, the method comprising: A) transmitting, using the transmit antenna array, first RF signals having an RF center frequency between 300 GHz and 320 GHz, wherein each of the first RF signals is a linear frequency modulated (LFM) chirp signal; B) receiving, using the receive antenna array, second RF signals having the RF center frequency, the second RF signals being generated at least in part by first RF signals being reflected by the target object; C) processing, using the receive circuitry, the second RF signals to obtain processed RF signals; D) digitizing, using the ADC circuitry, the processed RF signals output by the receive circuitry to obtain digitized RF signals; and E) generating, using processing circuitry coupled to the ADC circuitry and digitized RF signals, a range cross-range image of the target object.

Some embodiments provide for a device, comprising a substrate; and a receiver mounted on the substrate, the receiver comprising: a first receive semiconductor die having integrated thereon: a first receive antenna array comprising a plurality of RF antennas, each of the plurality of RF antennas comprising: a first patch; and a second patch serially coupled to the first patch and having a different geometry from the first patch; and first receive circuitry coupled to the plurality of RF antennas.

Some embodiments provide for a device, comprising a substrate defining a plane extending in first and second directions substantially orthogonal to one another; signal generation circuitry mounted on the substrate and configured to generate a reference RF signal; a transmitter mounted on the substrate, the transmitter comprising: a first transmit semiconductor die coupled to the signal generation circuitry and having integrated thereon: first transmit circuitry configured to generate, based on the reference RF signal, first RF signals having an RF center frequency in a particular frequency range within a range of 150 GHz to 1.5 THz; and a first transmit antenna array comprising a first plurality of RF antennas configured to transmit the first RF signals; a receiver mounted on the substrate, the receiver comprising: a first receive semiconductor die coupled to the signal generation circuitry and having integrated thereon: a first receive antenna array comprising a second plurality of RF antennas configured to receive second RF signals having the RF center frequency, each of the second plurality of RF antennas comprising: a first patch; and a second patch serially coupled to the first patch and having a different geometry from the first patch; and first receive circuitry configured to: generate third RF signals based on the reference RF signal; and mix the second RF signals with the third RF signals to obtain fourth RF signals; and interface circuitry mounted on the substrate and coupled to the first receive circuitry, the interface circuitry comprising analog-to-digital conversion (ADC) circuitry configured to digitize the fourth RF signals.

Some embodiments provide for a device, comprising a substrate; a receiver mounted on the substrate, the receiver comprising: a receive antenna array comprising a first plurality of receive RF antennas, the first plurality of receive RF antennas comprising: a first receive RF antenna configured to receive a first receive RF signal; and a second receive RF antenna configured to receive a second receive RF signal; and receive circuitry comprising a first plurality of receive channels, the first plurality of receive channels comprising: a first receive channel coupled to the first receive RF antenna and configured to process the first receive RF signal to obtain a first processed RF signal; and a second receive channel coupled to the second receive RF antenna and configured to process the second receive RF signal to obtain a second processed RF signal; and interface circuitry mounted on the substrate, the interface circuitry comprising: time-division multiplexing circuitry coupled to the receive circuitry, the time-division multiplexing circuitry comprising a first time-division multiplexer coupled to the first receive channel and to the second receive channel and configured to combine the first processed RF signal and the second processed RF signal into a first single time-division multiplexed signal; and analog-to-digital conversion (ADC) circuitry comprising a first ADC circuit coupled to the first time-division multiplexer and configured to digitize the first single time-division multiplexed signal into a first single digitized time-division multiplexed signal.

Some embodiments provide for a method for use with a device comprising a substrate having a receiver and interface circuitry mounted thereon, the receiver comprising a receive antenna array comprising a first plurality of receive antennas comprising a first receive RF antenna and a second receive RF antenna, the receiver further comprising receive circuitry comprising a first plurality of receive channels comprising a first receive channel coupled to the first receive RF antenna and a second receive channel coupled to the second receive RF antenna, the interface circuitry comprising time-division multiplexing circuitry coupled to the receive circuitry and comprising a first time-division multiplexer coupled to the first receive channel and the second receive channel, and the interface circuitry further comprising analog-to-digital conversion (ADC) circuitry comprising a first ADC circuit coupled to the first time-division multiplexer, the method comprising: receiving, using the first receive RF antenna, a first receive RF signal; receiving, using the second receive RF antenna, a second receive RF signal; processing, using the first receive channel, the first receive RF signal to obtain a first processed RF signal; processing, using the second receive channel, the second receive RF signal to obtain a second processed RF signal; combining, using the first time-division multiplexer, the first processed RF signal and the second processed RF signal into a first single time-division multiplexed signal; and digitizing, using the first ADC circuit, the first single time-division multiplexed signal into a first single digitized time-division multiplexed signal.

Some embodiments provide for a device, comprising: a substrate; a receiver mounted on the substrate, the receiver comprising: a first receive semiconductor die having integrated thereon: a first receive antenna array comprising a first plurality of receive RF antennas configured to receive first receive RF signals; and first receive circuitry comprising a first plurality of receive channels coupled to the first plurality of receive RF antennas and configured to process the first receive RF signals to obtain first processed RF signals; and interface circuitry mounted on the substrate, the interface circuitry comprising: first time-division multiplexing circuitry coupled to the first receive circuitry, the first time-division multiplexing circuitry comprising a first plurality of time-division multiplexers configured to combine the first processed RF signals into first time-division multiplexed signals; and first analog-to-digital conversion (ADC) circuitry coupled to the first time-division multiplexing circuitry and comprising a first plurality of ADC circuits configured to digitize the first time-division multiplexed signals into first digitized time-division multiplexed signals.

Some embodiments provide for a device, comprising: a substrate; a receiver mounted on the substrate, the receiver comprising: a receive antenna array comprising: a first plurality of receive RF antennas, the first plurality of receive RF antennas configured to receive first receive RF signals; and a second plurality of receive RF antennas, the second plurality of receive RF antennas configured to receive second receive RF signals; and receive circuitry comprising: a first plurality of receive channels coupled to the first plurality of receive RF antennas and configured to process the first receive RF signals to obtain first processed RF signals; and a second plurality of receive channels coupled to the second plurality of receive RF antennas and configured to process the second receive RF signals to obtain second processed RF signals; interface circuitry mounted on the substrate, the interface circuitry comprising: first serial communication circuitry configured to serialize the first processed RF signals to obtain and transmit a first serialized processed RF signal; and second serial communication circuitry configured to serialize the second processed RF signals to obtain and transmit a second serialized processed RF signal; and processing circuitry mounted on the substrate, communicatively coupled to the interface circuitry, and configured to synchronize serialization of the first processed RF signals by the first serial communication circuitry with serialization of the second processed RF signals by the second serial communication circuitry.

Some embodiments provide for a method for use with a device comprising a substrate having a receiver, interface circuitry, and processing circuitry mounted thereon, the receiver comprising a receive antenna array comprising a first plurality of receive RF antennas and a second plurality of receive RF antennas, the receiver further comprising receive circuitry comprising a first plurality of receive channels coupled to the first plurality of receive RF antennas and a second plurality of receive channels coupled to the second plurality of receive RF antennas, the interface circuitry comprising first serial communication circuitry and second serial communication circuitry, and the processing circuitry being communicatively coupled to the interface circuitry, the method comprising: receiving, using the first plurality of receive RF antennas, first receive RF signals; receiving, using the second plurality of receive RF antennas, second receive RF signals; processing, using the first plurality of receive channels, the first receive RF signals to obtain first processed RF signals; processing, using the second plurality of receive channels, the second receive RF signals to obtain second processed RF signals; serializing, using the first serial communication circuitry, the first processed RF signals to obtain and transmit a first serialized processed RF signal; serializing, using the second serial communication circuitry, the second processed RF signals to obtain and transmit a second serialized processed RF signal; and synchronizing, using the processing circuitry, serialization of the first processed RF signals by the first serial communication circuitry with serialization of the second processed RF signals by the second serial communication circuitry.

Some embodiments provide for a device, comprising: a substrate; a receiver mounted on the substrate, the receiver comprising: a receive antenna array comprising: a first plurality of receive RF antennas, the first plurality of receive RF antennas configured to receive first receive RF signals; and a second plurality of receive RF antennas, the second plurality of receive RF antennas configured to receive second receive RF signals; and receive circuitry comprising: a first plurality of receive channels coupled to the first plurality of receive RF antennas and configured to process the first receive RF signals to obtain first processed RF signals; and a second plurality of receive channels coupled to the second plurality of receive RF antennas and configured to process the second receive RF signals to obtain second processed RF signals; interface circuitry mounted on the substrate, the interface circuitry comprising: first serial communication circuitry configured to serialize the first processed RF signals to obtain and transmit a first serialized processed RF signal; and second serial communication circuitry configured to serialize the second processed RF signals to obtain and transmit a second serialized processed RF signal; and processing circuitry mounted on the substrate, communicatively coupled to the interface circuitry, and configured to transmit a trigger signal and a clock signal to the first serial communication circuitry and the second serial communication circuitry.

Some embodiments provide for a method of manufacturing a device comprising a substrate defining a plane extending in a first direction and a second direction that are substantially orthogonal to one another, the device further comprising a first plurality of semiconductor dies and a second plurality of semiconductor dies, the method comprising: mounting the first plurality of semiconductor dies on the substrate; after mounting the first plurality of semiconductor dies on the substrate, mechanically coupling a fixture to the substrate; and after mechanically coupling the fixture to the substrate, mounting the second plurality of semiconductor dies on the substrate.

Some embodiments provide for a method of manufacturing a device comprising a substrate defining a plane extending in a first direction and a second direction that are substantially orthogonal to one another, a transmitter comprising a plurality of transmit semiconductor dies each comprising transmit circuitry and a transmit antenna array coupled to the transmit circuitry, a receiver comprising a plurality of receive semiconductor dies each comprising a receive circuitry and a receive antenna array coupled to the receive circuitry, and a fixture, the method comprising:

mounting the plurality of receive semiconductor dies on the substrate at least in part by tiling a first row of receive semiconductor dies of the plurality of receive semiconductor dies on the substrate in the second direction; after mounting the plurality of receive semiconductor dies on the substrate, mechanically coupling the fixture to the substrate at least in part by: fastening a first edge of the substrate to the fixture at a first point within a threshold distance of the first edge; and fastening a second edge of the substrate to the fixture at a second point within the threshold distance of the second edge, wherein the second edge is opposite the first edge in the second direction; and after mechanically coupling the fixture to the substrate, mounting the plurality of transmit semiconductor dies on the substrate at least in part by tiling a first column of transmit semiconductor dies of the plurality of transmit semiconductor dies on the substrate in the first direction.

Some embodiments provide for a device, comprising: a substrate defining a plane extending in a first direction and a second direction that are substantially orthogonal to one another, the substrate comprising a first point and a second point that are configured for mechanically coupling to a fixture during manufacture of the device; a plurality of semiconductor dies mounted on the substrate and each having integrated thereon: a first antenna array comprising a first plurality of antennas; and first circuitry coupled to the first plurality of antennas; and a heat spreader mechanically coupled to the substrate at the first point and at the second point.

### BRIEF DESCRIPTION OF DRAWINGS

Various aspects and embodiments will be described with reference to the following figures. It should be appreciated that that the figures are not necessarily drawn to scale.

FIG. 1A illustrates a vehicle equipped with an example system for Terahertz-based active sensing, in accordance with some embodiments of the technology described herein.

FIG. 1B is a perspective view of an example device that may be included in the system of FIG. 1A, in accordance with some embodiments of the technology described herein.

FIG. 2 is an exploded view of an example device that may be included in the system of FIG. 1A, in accordance with some embodiments of the technology described herein.

FIG. 3 is an exploded view of an example device that may be included in the system of FIG. 1A, in accordance with some embodiments of the technology described herein.

FIG. 4A is a schematic view of an example substrate that may be included in the example system of FIG. 1A, in accordance with some embodiments of the technology described herein.

FIG. 4B is a schematic view of the transmitter of the device of FIG. 4A, in accordance with some embodiments of the technology described herein.

FIG. 5 is a schematic view of an alternative example substrate that may be included in a device in the system of FIG. 1A, in accordance with some embodiments of the technology described herein.

FIG. 6A is a plot illustrating RF atmospheric attenuation as a function of the carrier frequency.

FIG. 6B is a plot illustrating Terahertz sub-bands suitable to perform ranging, in accordance with some embodiments of the technology described herein.

FIG. 6C is a plot illustrating the frequency of an example linear frequency modulated (LFM) signal having a first linear ramp as a function of time, in accordance with some embodiments of the technology described herein.

FIG. 6D is a plot illustrating the frequency of an example LFM signal having first and second linear ramps as a function of time, in accordance with some embodiments of the technology described herein.

FIG. 7A is a side view of an example interposer having a receiver mounted thereon, which may be included in a device in the system of FIG. 1A, in accordance with some embodiments of the technology described herein.

FIG. 7B is a top view of the interposer of FIG. 7A, in accordance with some embodiments of the technology described herein.

FIG. 8A is a side view of an example device including a substrate having the receiver and interposer of FIG. 7A mounted thereon, in accordance with some embodiments of the technology described herein.

FIG. 8B is a top view of the device of FIG. 8A, in accordance with some embodiments of the technology described herein.

FIG. 9A is a top view of an alternative example device having a substrate with a receiver and interposer mounted thereon, which may be included in the system of FIG. 1A, in accordance with some embodiments of the technology described herein.

FIG. 9B is a top view of the device of FIG. 9A further illustrating processing circuitry of the device, in accordance with some embodiments of the technology described herein.

FIG. 10A is a side view of a cross-section of an example device having a substrate with a receiver mounted thereon and a fixture used for assembling the device, which may be included in the system of FIG. 1A, in accordance with some embodiments of the technology described herein.

FIG. 10B is a top view of the device of FIG. 10A mechanically coupled to the fixture further illustrating the transmitter, in accordance with some embodiments of the technology described herein.

FIG. 10C is a top view of the device of FIG. 10A with the fixture removed and replaced by a heat spreader, in accordance with some embodiments of the technology described herein.

FIG. 10D is a bottom view of the device of FIG. 10A further illustrating the interface circuitry, in accordance with some embodiments of the technology described herein.

FIG. 11A is a top view of an example substrate having a transmitter that may be included in a device in the system of FIG. 1A, in accordance with some embodiments of the technology described herein.

FIG. 11B is a circuit diagram of transmit circuitry of the transmitter of FIG. 11A, in accordance with some embodiments of the technology described herein.

FIG. 12A is a schematic view of an example transmit semiconductor die that may be included in the transmitter of FIG. 11A in accordance with some embodiments of the technology described herein.

FIG. 12B is a magnified view of transmit circuitry of a pair of transmit elements of the transmit semiconductor die of FIG. 12A, in accordance with some embodiments of the technology described herein.

FIG. 13 is a top view of an example transmitter that may be included in a device in the system of FIG. 1A, in accordance with some embodiments of the technology described herein.

FIG. 14A is a schematic view of an example substrate having a receiver, interface circuitry, and processing circuitry that may be included in a device in the system of FIG. 1A, in accordance with some embodiments of the technology described herein.

FIG. 14B is a circuit diagram of a receive element of the receiver of FIG. 14A, in accordance with some embodiments of the technology described herein.

FIG. 15A is a circuit diagram of an example common mode receive element having a reflector, in accordance with some embodiments of the technology described herein.

FIG. 15B is a circuit diagram of an example differential mode receive element having a reflector, in accordance with some embodiments of the technology described herein.

FIG. 15C is a circuit diagram of an example common mode receive element having a differential mixer and a reflector, in accordance with some embodiments of the technology described herein.

FIG. 15D is a circuit diagram of an example differential mode receive element having a differential mixer and a reflector, in accordance with some embodiments of the technology described herein.

FIG. 16 is a circuit diagram of an example differential mode receive element having a differential mixer and a current reflector, in accordance with some embodiments of the technology described herein.

FIG. 17 is a top view of an example receive semiconductor die that may be included in the receiver of FIG. 14A, in accordance with some embodiments of the technology described herein.

FIG. 18A is a top view of a receive element of the receive semiconductor die of FIG. 17, in accordance with some embodiments of the technology described herein.

FIG. 18B is a magnified top view of a portion of the receive element of FIG. 18A, in accordance with some embodiments of the technology described herein.

FIG. 19 is a top view of an alternative example antenna array that may be included in the receive semiconductor die of FIG. 17, in accordance with some embodiments of the technology described herein.

FIG. 20 is a top view of a further alternative example antenna array that may be included in the receive semiconductor die of FIG. 17, in accordance with some embodiments of the technology described herein.

FIG. 21 is a top view of yet another alternative example antenna array that may be included in the receive semiconductor die of FIG. 17, in accordance with some embodiments of the technology described herein.

FIG. 22 is a schematic view of an example receiver mounted on an interposer, which may be included in a device in the system of FIG. 1A, in accordance with some embodiments of the technology described herein.

FIG. 23 is a top view of an example receive semiconductor die that may be included in the receiver of FIG. 14A, in accordance with some embodiments of the technology described herein.

FIG. 24 is a top view of another example receiver mounted on an interposer, which may be included in a device in the system of FIG. 1A, in accordance with some embodiments of the technology described herein.

FIG. 25 is a top view of a portion of an example receive semiconductor die that may be included in the receiver of FIG. 22, in accordance with some embodiments of the technology described herein.

FIG. 26A is a schematic view of an example semiconductor wafer having a plurality of antenna arrays integrated thereon, in accordance with some embodiments of the technology described herein.

FIG. 26B is a magnified schematic view of a portion of the semiconductor wafer of FIG. 26A illustrating a location of a saw blade cut to dice semiconductor dies from the semiconductor wafer, in accordance with some embodiments of the technology described herein.

FIG. 26C is a magnified schematic view of the portion of the semiconductor wafer of FIG. 26A illustrating another location of a saw blade cut to dice semiconductor dies from the semiconductor wafer, in accordance with some embodiments of the technology described herein.

FIG. 27 is a schematic view of a semiconductor die diced from the semiconductor wafer of FIG. 26A, in accordance with some embodiments of the technology described herein.

FIG. 28 is a diagram illustrating an example spatially undersampled antenna array that may be included in the receiver of FIG. 4A, in accordance with some embodiments of the technology described herein.

FIG. 29A is an example scene in which to perform a range-cross range measurement using the device of FIG. 4A, in accordance with some embodiments of the technology described herein.

FIG. 29B is an example range-cross range measurement of the scene of FIG. 29A performed using a spatially Nyquist-sampled antenna array, in accordance with some embodiments of the technology described herein.

FIG. 29C is an example range-cross range measurement of the scene of FIG. 29A performed using a spatially undersampled antenna array, in accordance with some embodiments of the technology described herein.

FIG. 29D is an example range-cross range measurement of the scene of FIG. 29A performed using a spatially undersampled antenna array and spatial anti-aliasing processing techniques, in accordance with some embodiments of the technology described herein.

FIG. 30 is a timing diagram illustrating example states in which components of the device of FIG. 4 may be operated, in accordance with some embodiments of the technology described herein.

FIG. 31 is a timing diagram illustrating alternative example states in which components of the device of FIG. 4A may be operated over multiple frames, in accordance with some embodiments of the technology described herein.

FIG. 32A is a timing diagram illustrating example states in which components of the device of FIG. 4A may be operated within a frame of FIG. 31, in accordance with some embodiments of the technology described herein.

FIG. 32B is an example range-cross range image that may be obtained using a device in the system of FIG. 1A, in accordance with some embodiments of the technology described herein.

FIG. 32C is a diagram illustrating example operation of a transmitter according to a first transmit beamforming pattern, in accordance with some embodiments of the technology described herein.

FIG. 32D is a diagram illustrating example operation of the transmitter of FIG. 32C according to a second transmit beamforming pattern, in accordance with some embodiments of the technology described herein.

FIG. 32E is a diagram illustrating example operation of the transmitter of FIG. 32C according to a third transmit beamforming pattern, in accordance with some embodiments of the technology described herein.

FIG. 32F is a diagram illustrating angular directions of transmission focus in elevation for the transmit beamforming patterns of FIGS. 32C-32E, in accordance with some embodiments of the technology described herein.

FIG. 33 is a block diagram of an example transmit element that may be included in the device of FIG. 4A, in accordance with some embodiments of the technology described herein.

FIG. 34 is a block diagram of an example receive element that may be included in the device of FIG. 4A, in accordance with some embodiments of the technology described herein.

FIG. 35 is a schematic diagram of an example substrate having a receiver and interface circuitry mounted thereon that may be included in a device in the system of FIG. 1A, in accordance with some embodiments of the technology described herein.

FIG. 36 is a schematic diagram of another example substrate having a receiver and interface circuitry mounted thereon that may be included in a device in the system of FIG. 1A, in accordance with some embodiments of the technology described herein.

FIG. 37 is a schematic diagram of an example substrate having a receiver, interface circuitry including multiplexing circuitry, and processing circuitry mounted thereon that may be included in a device in the system of FIG. 1A, in accordance with some embodiments of the technology described herein.

FIG. 38A is a block diagram of example interface circuitry including multiplexers, which may be included on the substrate of FIG. 4A, in accordance with some embodiments of the technology described herein.

FIG. 38B is a block diagram of example interface circuitry including multiplexers integrated on receive semiconductor dies, which may be included on the substrate of FIG. 4A, in accordance with some embodiments of the technology described herein.

FIG. 38C is a block diagram of example interface circuitry including multiplexers integrated on one of a pair of interconnected receive semiconductor dies, which may be included on the substrate of FIG. 4A, in accordance with some embodiments of the technology described herein.

FIG. 38D is a block diagram of example interface circuitry including analog-to-digital conversion (ADC) circuitry directly coupled to receive semiconductor dies, which may be included on the substrate of FIG. 4A, in accordance with some embodiments of the technology described herein.

FIG. 38E is a block diagram of example interface circuitry including ADC circuitry integrated on receive semiconductor dies, which may be included on the substrate of FIG. 4A, in accordance with some embodiments of the technology described herein.

FIG. 39A is a block diagram of example interface circuitry including multiple ADC units integrated on a receive semiconductor die, which may be included on the substrate of FIG. 4A, in accordance with some embodiments of the technology described herein.

FIG. 39B is a block diagram of example interface circuitry including a single ADC unit integrated on a receive semiconductor die, which may be included on the substrate of FIG. 4A, in accordance with some embodiments of the technology described herein.

FIG. 40 is a schematic diagram of an example substrate having a receiver, interface circuitry including serial communication circuitry, and processing circuitry mounted thereon that may be included in a device in the system of FIG. 1A, in accordance with some embodiments of the technology described herein.

FIG. 41 is a schematic diagram of an example substrate having a receiver, interface circuitry including digital serial communication circuitry, and processing circuitry mounted thereon that may be included in a device in the system of FIG. 1A, in accordance with some embodiments of the technology described herein.

FIG. 42 is a schematic diagram of an example interface integrated circuit that may be included in a device in the system of FIG. 1A, in accordance with some embodiments of the technology described herein.

FIG. 43 is a schematic diagram of an alternative example interface integrated circuit that may be included in a device in the system of FIG. 1A, in accordance with some embodiments of the technology described herein.

FIG. 44 is a schematic diagram of a portion of an example interface integrated circuit that may be included in a device in the system of FIG. 1A, in accordance with some embodiments of the technology described herein.

FIG. 45 is a schematic diagram of an example digital serializer that may be included in a device in the system of FIG. 1A, in accordance with some embodiments of the technology described herein.

FIG. 46 is another example scene in which to detect and/or identify a target object, the scene including a target object and a layer disposed on the target object, in accordance with some embodiments of the technology described herein.

FIG. 47A is yet another example scene in which to detect and/or identify a target object, the scene including a vehicle and a bicycle, in accordance with some embodiments of the technology described herein.

FIG. 47B is an example range-cross-range measurement of the scene of FIG. 47A, in accordance with some embodiments of the technology described herein.

FIG. 48 is a diagram illustrating example segmentation of a THz band into multiple sub-bands, in accordance with some embodiments of the technology described herein.

FIG. 49A is an example scene in which to detect and/or identify a target object, the scene including a vehicle, a bicycle, and a dummy, in accordance with some embodiments of the technology described herein.

FIG. 49B is a plot illustrating an example range-cross range measurement of the scene of FIG. 49A performed in a first sub-band, in accordance with some embodiments of the technology described herein.

FIG. 49C is a plot illustrating an example range-cross range measurement of the scene of FIG. 49A performed in a second sub-band, in accordance with some embodiments of the technology described herein.

FIG. 49D is a plot illustrating an example range-cross range measurement of the scene of FIG. 49A performed in a third sub-band, in accordance with some embodiments of the technology described herein.

FIG. 49E is a plot illustrating an example range-cross range measurement of the scene of FIG. 49A obtained by combining the measurements of FIGS. 49B-49D, in accordance with some embodiments of the technology described herein.

FIG. 50 is a block diagram of an example system including a device for active THz sensing and a camera, in accordance with some embodiments of the technology described herein.

FIG. 51 is a block diagram of an example computer system that may be configured to perform at least some processing operations in the system of FIG. 1A or 50, in accordance with some embodiments of the technology described herein.

### DETAILED DESCRIPTION

### Terahertz-Based Active Sensing

The inventors have developed an active radio-frequency (RF) sensing technology, operating in the Terahertz band, for determining the relative and/or absolute state (e.g., position, velocity, and/or acceleration) of a target object (e.g., a static target object such as a lamp post, a utility pole, a building, or a dynamic target object such as a person, a vehicle, a car, a truck, etc.). The terms “radio-frequency” and “RF” are used herein to refer to electromagnetic signals having frequency content in the 0-3 THz band. The term “Terahertz” is used herein to refer to radio-frequency signals having frequency content in the 300 GHz-3 THz band (including the end points).

The RF technology developed by the inventors includes novel RF sensors, signal processing architectures, algorithms, and software. The RF technology developed by the inventors and described herein may be used in a variety of applications. For example, the RF technology may be used in the context of autonomous vehicles, such as autonomous cars, for determining the relative and/or absolute state of one or more target objects in the surrounding environment of the autonomous vehicle (e.g., the relative and/or absolute state of one or more cars, people, or other objects within a threshold distance of the autonomous vehicle). However, the technology described herein may be used in connection with any type of vehicle, including for example land-based vehicles (e.g., cars, trucks, bicycles, motor bicycles and other wheel-based vehicles, and trains and other rail-based vehicles), air-based vehicles (e.g., airplanes, helicopters, drones, etc.), space-based vehicles (e.g., satellites, space vessels, etc.), water-based vehicles (ships, boats, barges, etc.) and any other types of vessels configured to carry a load (e.g., people, animals, plants, equipment, materials, etc.).

Building reliable sensing capabilities for vehicles has been a major challenge for decades. Unfortunately, engineers have not identified a single type of sensor capable of effectively monitoring the surrounding environment in all conditions (e.g., rain, snow, fog, night, dense environments, etc.). As a result, the conventional approach is to equip vehicles with multiple types of sensors rather than relying on a single type of sensor. For example, a vehicle may be equipped with optical sensors (e.g., video cameras, infrared cameras), radio-frequency sensors (e.g., RADAR sensors), and LIDAR sensors. This approach is based on the idea that having a diverse set of sensors provides better coverage than what any sensor can provide individually, as each sensor has advantages and disadvantages.

Optical sensors, for example, allow vehicles to maintain a 360° view of the external environment. Significant progress has been made in recent years in camera-related technologies, with ever-increasing resolutions being available at lower prices than previously possible. With the aid of sophisticated post-processing techniques, often involving machine learning, optical sensors can detect and identify objects in the vicinity of a vehicle. The ability of an optical sensor to distinguish colors improves the camera's ability to distinguish dangerous situations from less risky circumstances. For example, a camera can easily identify other vehicles, pedestrians, cyclists, traffic signs and signals, guardrails, etc. Unfortunately, optical sensors are still far from being perfect. First, poor weather conditions (e.g., darkness, rain, snow, fog) significantly reduce image quality, which significantly degrades the optical sensor's ability to detect target objects in the roadway. Image quality is also degraded when there is low contrast among objects or when objects blend in with the background (e.g., during particularly sunny days). Second, cameras generate inherently two-dimensional data, with depth or distance information not being measured directly. Instead, depth or distance information can be obtained only after further signal processing is performed on the collected image and/or video data, which can be computationally demanding.

RADAR (radio detection and ranging) sensors are active detection sensors that use radio frequency signals to determine the relative and/or absolute state (e.g., position, velocity, and/or acceleration) of a target object. A RADAR sensor has at least one transmitter that emits RF signals toward one or more objects and at least one receiver that detects any RF signals reflected by the object(s). The detected RF signals are processed to determine absolute and/or relative (e.g., to the RADAR sensor) position, velocity, acceleration of the object(s). Unlike optical sensors, RADAR sensors are less susceptible to poor weather conditions and directly detect depth or distance information.

Conventional RADAR sensors used in autonomous vehicles operate in the millimeter wave band (i.e., 30 GHz-300 GHz), or at even lower frequencies. For example, one conventional RADAR sensor operates in the 76 GHz-81 GHz frequency band. Because of the (relatively long) wavelengths implied by operating in this frequency range, conventional RADAR sensors have limited spatial (e.g., range and angular) resolution. Indeed, conventional RADAR sensors used in the automotive context have range resolutions on the order of several centimeters and horizontal angular resolutions of about 10° to 20°. As a result, while conventional RADAR sensors can identify the presence of some target object, they cannot reliably identify the nature or shape of the target object. For example, such a conventional RADAR sensor may be unable to distinguish a pedestrian from a vehicle or a road signal. An angular resolution of about 1° or less may be necessary to distinguish the types of target objects typically encountered on roads.

LIDAR (light detection and ranging) sensors operate similarly to RADAR sensors, but at optical frequencies (e.g., in the infrared or visible portions of the electromagnetic spectrum) rather than radio frequencies. The location of an object is determined by transmitting a laser beam and by measuring the time taken for the reflected beam to hit the receiver. Because light has wavelengths that are substantially shorter than the wavelengths at which conventional automotive RADAR sensors operate, LIDAR sensors have finer spatial resolutions.

However, LIDAR sensors also have a number of drawbacks. First, they are significantly more susceptible to rain than RADAR sensors. This is because the size of rain droplets is comparable to the wavelength at which LIDAR sensors operate. In heavy rain, light emitted from the transmitter is scattered by rain droplets, which leads to unwanted echoes. Second, LIDAR sensors are susceptible to sunlight, which leads to detector saturation that, in turn, reduces a LIDAR sensor's ability to detect objects. Thus, LIDAR sensors work better at night.

Accordingly, the inventors have developed a new sensing technology for automotive and other autonomous vehicle applications that addresses the above-described shortcomings of conventional sensors and sensor fusion techniques. In particular, the inventors have developed novel RADAR sensors operating in the Terahertz band, which allows the sensors to combine some of the advantages of RADAR and LIDAR sensors (because THz radiation behaves in part similarly to millimeter wave RF signals and in part similarly to infrared light) while avoiding the need to employ computationally expensive fusion algorithms, which would be required if millimeter RADAR and LIDAR sensors were used together instead of THz RADAR. The sensing technology developed by the inventors can be deployed on vehicles (e.g., cars, whether or not autonomous) to aid with safety and operation and, in some embodiments, may replace conventional RADAR and the LIDAR sensors altogether. It should be noted, however, that, in some embodiments, the sensing technology developed by the inventors may be used in conjunction with one or more conventional sensors (e.g., cameras, RADAR, LIDAR, etc.), as aspects of the technology described herein are not limited in this respect.

Moreover, the sensing technology developed by the inventors improves upon conventional RADAR and LIDAR sensors. For example, because the sensing technology developed by the inventors operates in the Terahertz band, it achieves a spatial resolution that is significantly better than what is possible with conventional RADAR sensors. For example, the sensing technology developed by the inventors achieves range resolutions on the order of 5 mm to 15 mm, and angular resolutions on the order of 0.1° to 5° (e.g., elevation resolution of approximately 0.2°-0.9°). As described herein, conventional RADAR sensors can only achieve range resolutions on the order of several centimeters and angular resolutions of about 10° to 20°, which is insufficient for automotive and other applications.

As yet another example, Terahertz-based active sensing systems are less susceptible than LIDAR sensors to sunlight. The vast majority of the solar energy is concentrated in the visible and infrared regions, from about 300 nm to about 2000 nm. This is why LIDAR sensors that operate in this region are particularly susceptible to sunlight. By contrast, Terahertz signals, having wavelengths between 100 μm and 1 mm, are virtually immune to sunlight.

The Terahertz-based active sensing systems described herein may be used in human-operated vehicles (e.g., cars, trucks), autonomous vehicles, as well as in other contexts.

Despite the advantages described herein, the inventors have recognized that developing Terahertz-based active sensing systems presents its own challenges, as described below.

### Terahertz Active Sensing RADAR System

As described herein, operating RADAR at Terahertz frequencies (300 GHz-3 THz) is advantageous because the wide bandwidth available for signals in these frequency ranges provides for high range resolution, which is important for some automotive applications. At higher frequencies more bandwidth is available for transmission, which in turn increases the range resolution of the resulting RADAR system.

On the other hand, atmospheric attenuation at higher frequencies in the THz spectrum (e.g., at 850 GHz) and this limits the ability of a RADAR system to detect targets at longer distances applications (e.g., at a distance of 300 meters) at a given link budget (e.g., less than 20 Watts), which may be relevant in certain applications such as some automotive applications.

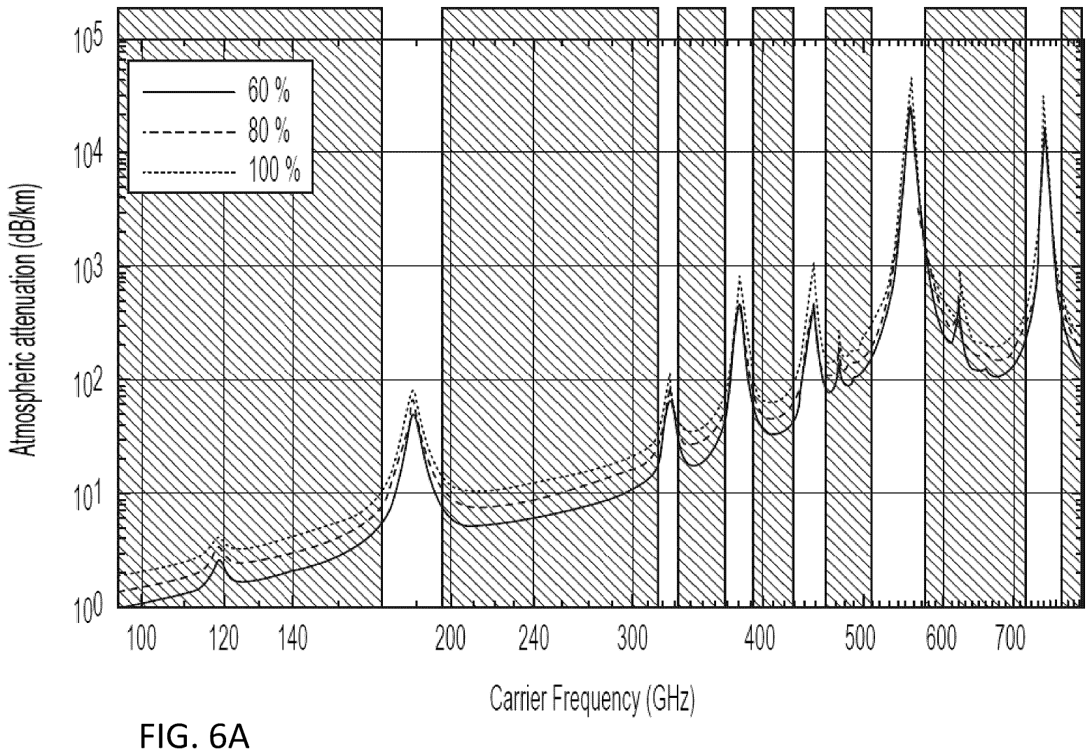

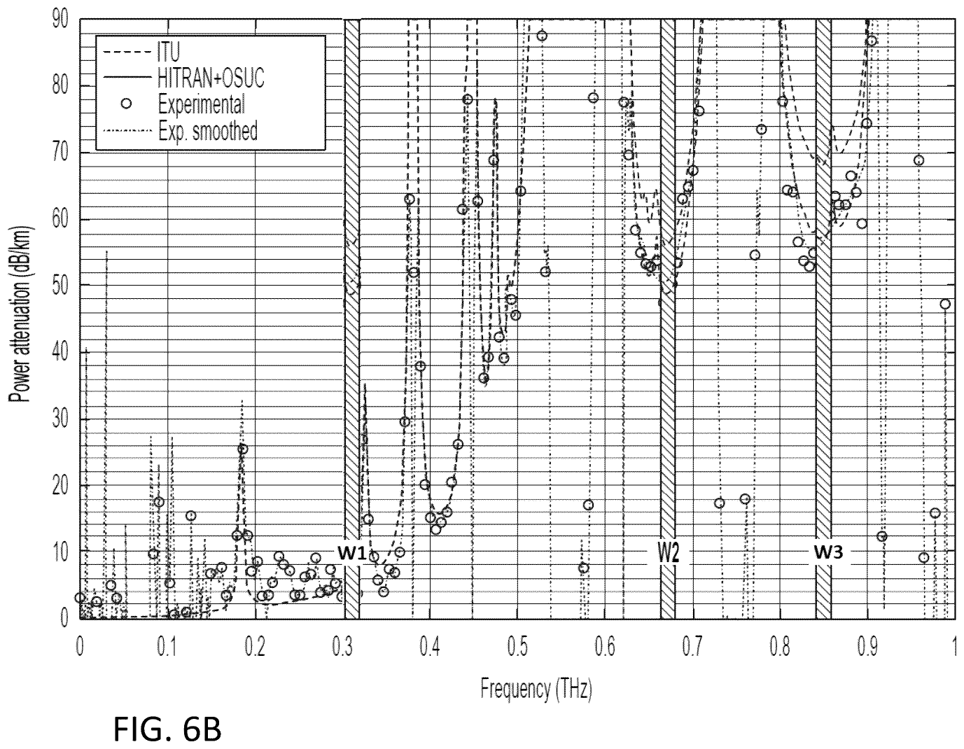

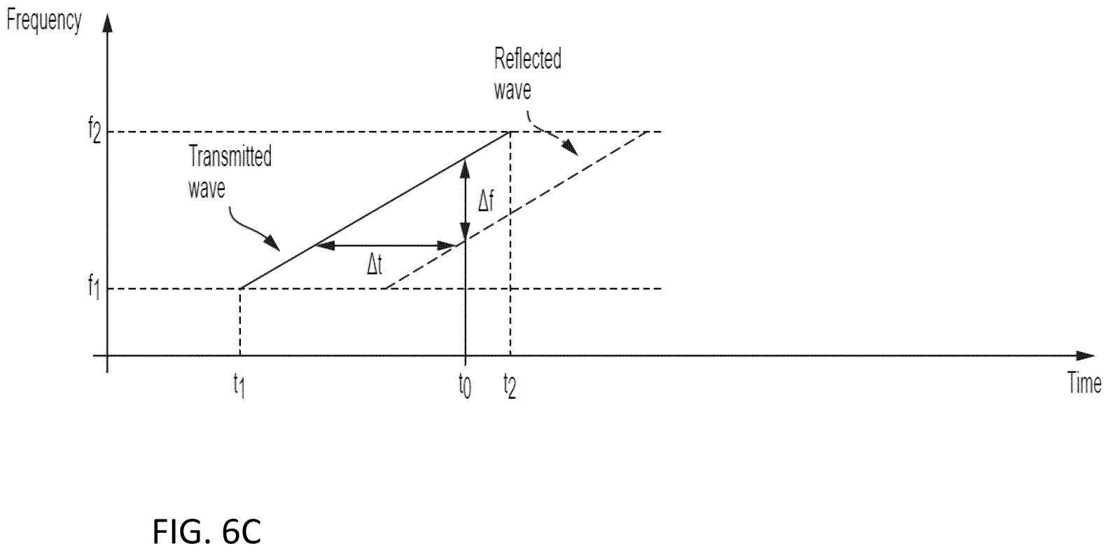

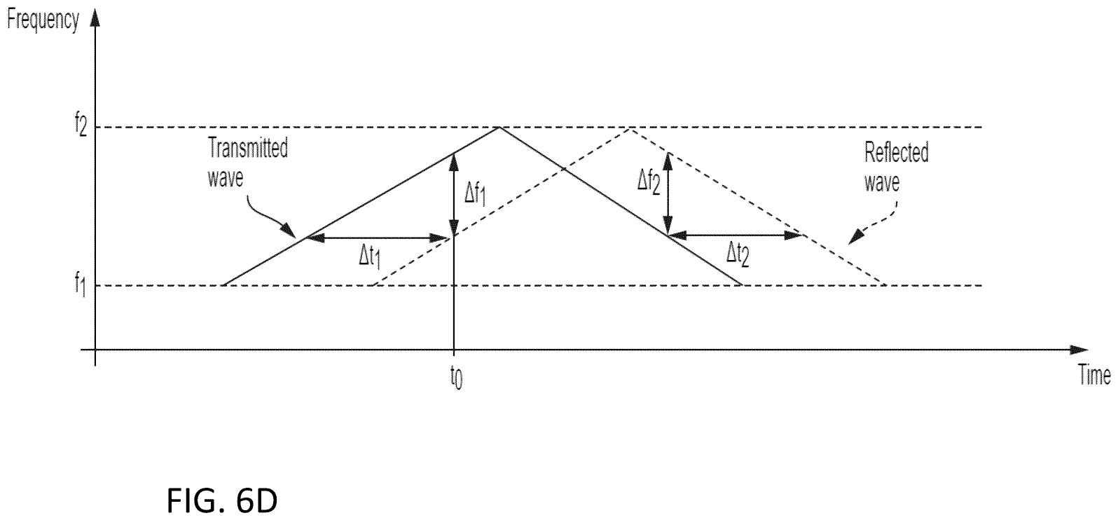

Indeed, Terahertz signals are more susceptible to atmospheric attenuation than millimeter waves or infrared light. Terahertz signals undergo absorption by water vapor and oxygen molecules in the atmosphere. For this reason, atmospheric attenuation degrades with increasing humidity. FIG. 6A is a plot illustrating how atmospheric attenuation varies as a function of frequency at a humidity of 60%, 80% and 100%, respectively. At 100 GHz, the atmospheric attenuation is well below 3 dB/km, regardless of the humidity. At 300 GHz, the atmospheric attenuation is between 10 dB/km and 40 dB/km. At 700 GHz, the atmospheric attenuation is above 100 dB/km.

Atmospheric attenuation poses a major challenge. By the time an RF signal travels from a transmitter to a target object, and upon reflection, from the target object to the receiver, the power level of the RF signal is attenuated near or below the receiver's noise floor. Therefore, the receiver's ability distinguish RF signals from noise is significantly impaired.

The inventors have identified several solutions to mitigate the effects of atmospheric attenuation. The solutions described herein may be used individually or in combination. One solution stems from the inventors' appreciation that the atmospheric attenuation exhibits local attenuation minima. FIG. 6B is another plot illustrating the atmospheric attenuation as a function of frequency. Again, attenuation can be quite severe, as high as 1000 dB/km in some bands. Notwithstanding, some frequency bands exhibit local minima. For example, the atmospheric attenuation drops substantially in the frequency bands near 310 GHz, 425 GHz, 475 GHz, 670 GHz, and 850 GHz. Recognizing this behavior, active sensing systems according to some embodiments are designed to operate in one or more of these frequency bands in which the atmospheric attenuation exhibits local minima.

The inventors have therefore recognized that there are frequency ranges in the THz band which provide a practical compromise between making available large bandwidths (for increased range resolution), while keeping atmospheric attenuation to manageable levels such that at these frequency ranges a RADAR system can range to objects at distances needed for various applications (e.g., up to 300 meters in some automotive applications) at a fixed link budget (e.g., less than 10 or 20 Watts). These ranges include, for example, 300 to 320 GHz, 390 to 450 GHz, 440 to 480 GHz, 455 to 495 GHz, and 820 to 880 GHz. In addition, millimeter wave frequency bands could be considered such as, for example, bands in the range of 190 to 300 GHz, because these bands nevertheless involve operating at higher frequencies than conventional millimeter wave RADAR systems (which operate at lower center frequencies still, e.g., under 100 GHz, which limits their available bandwidth) and therefore provide for improved range resolution, while even further mitigating the impact of atmospheric attenuation.

Accordingly, some embodiments provide for a RADAR device configured to operate at an RF center frequency between 300 and 320 GHz. Though it should be appreciated that, in other embodiments, a RADAR device configured to operate at one or more other frequency ranges (e.g., 190-300 GHz, 390 to 450 GHz, 440 to 480 GHz, 455 to 495 GHz, and 820 to 880 GHz) can be manufactured with a similar architecture.

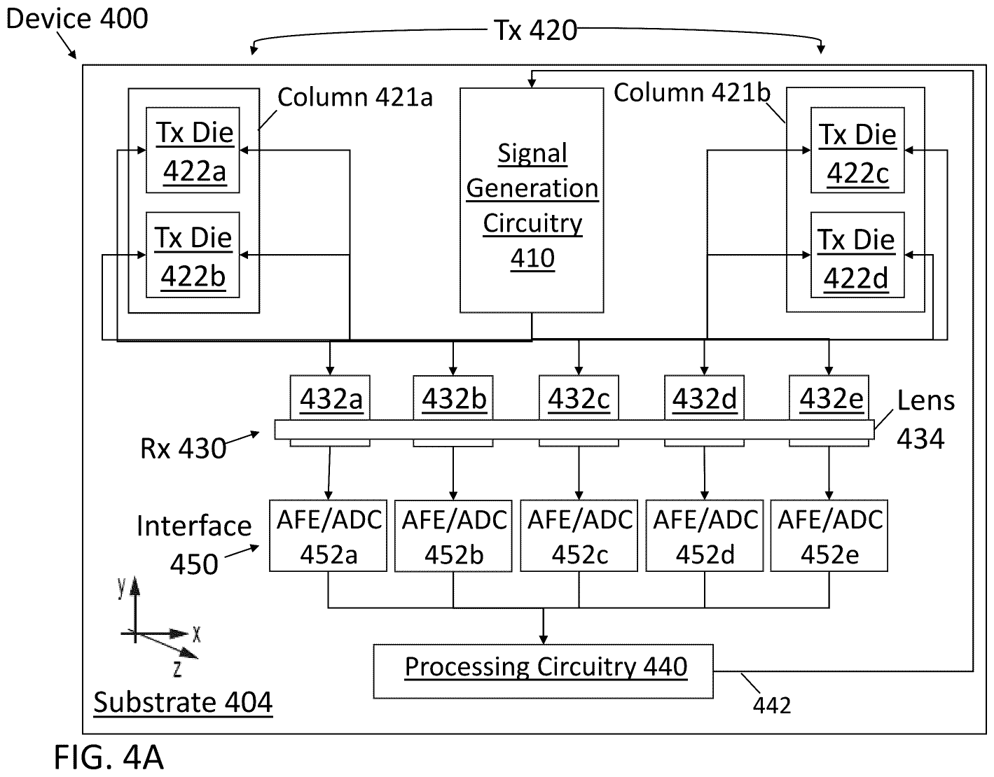

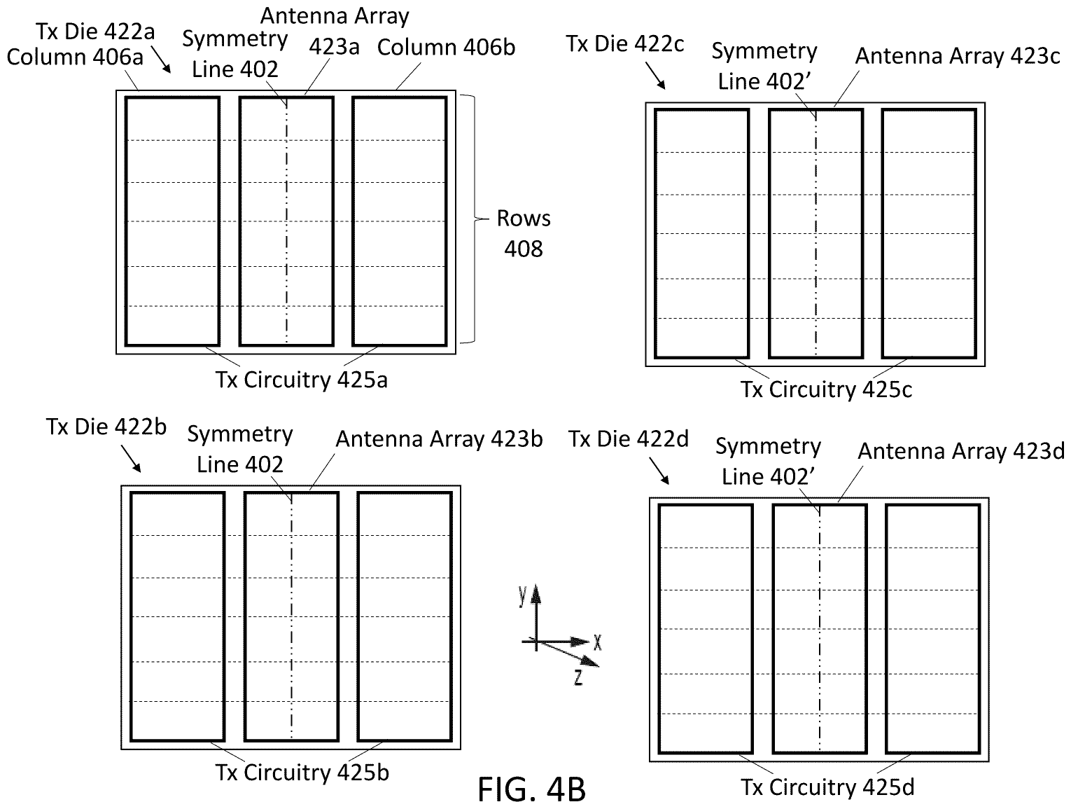

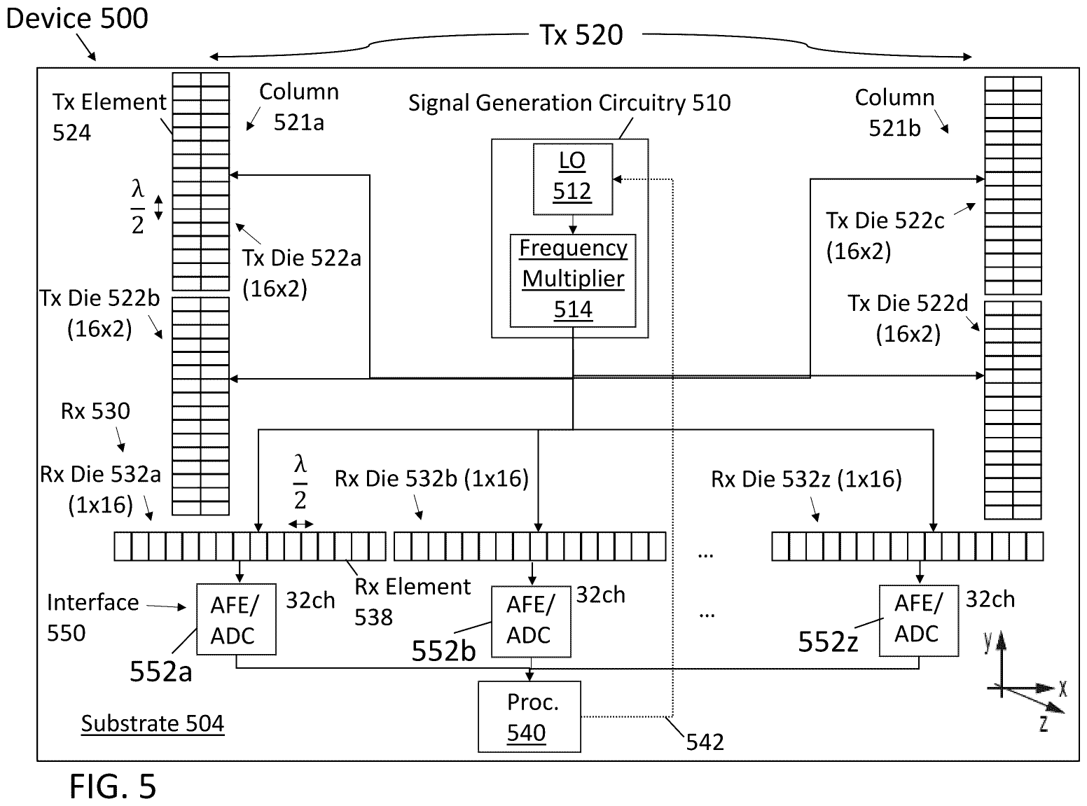

In some embodiments, the RADAR device (e.g., devices 400 and 500 described herein including with reference to FIGS. 4 and 5, respectively) comprises: (A) a substrate (e.g., 404), which may be a PCB for example, defining a plane extending in first and second directions substantially orthogonal to one another (e.g., x and y in FIG. 4A); (B) signal generation circuitry (e.g., 410) mounted on the substrate and configured to generate a reference RF signal (e.g., a linear frequency modulated chirp, for example, having a 1 millisecond (ms) duration and a center frequency between 16 and 20 GHz); (C) a transmitter (e.g., 420) mounted on the substrate, the transmitter comprising: a first transmit semiconductor die (e.g., 422a) coupled to the signal generation circuitry and having integrated thereon: first transmit circuitry (e.g., 1160) configured to generate, based on the reference RF signal, first RF signals having an RF center frequency between 300-320 GHz (e.g., at 310 GHz), and a first transmit antenna array (e.g., 1132) (e.g., comprising a first plurality of RF antennas (e.g., 1170) configured to transmit the first RF signals; (D) a receiver (e.g., 430) mounted on the substrate, the receiver comprising: a first receive semiconductor die (e.g., 432a) coupled to the signal generation circuitry and having integrated thereon: a first receive antenna array comprising a second plurality of RF antennas (e.g., 1486) configured to receive second RF signals having the RF center frequency; and first receive circuitry (e.g., 1480) configured to: generate third RF signals (e.g., having a center frequency between 150 and 160 GHz, for example, 155 GHz) based on the reference RF signal; and mix the second RF signals with the third RF signals (e.g., using a sub-harmonic mixer) to obtain fourth RF signals and provide the fourth RF signals to the interface circuitry (e.g., 450); and (E) interface circuitry (e.g., 450) mounted on the substrate and coupled to the first receive circuitry, the interface circuitry comprising analog-to-digital conversion (ADC) circuitry (e.g., 452a-452e) configured to digitize the fourth RF signals.

In some embodiments, the transmitter (e.g., 420 or 520) may include a column (e.g., 421a) of transmit semiconductor dies (e.g., 422a and 422b and, optionally, another column, e.g., 421b, of dies including dies 422c and 422d) to increase the elevation resolution of the RADAR device. Accordingly, in some embodiments, wherein the transmitter comprises a first column of transmit semiconductor dies (e.g., 2, 4, 8, or 16 dies) tiled in the first direction, the column of transmit semiconductor dies including the first transmit semiconductor die (e.g., 422a) and a second transmit semiconductor die (e.g., 422b) spaced at a distance from the first transmit semiconductor die in the first direction, and wherein the second transmit semiconductor die is coupled to the signal generation circuitry and has integrated thereon: a second transmit antenna array; and second transmit circuitry (e.g., 1160) configured to generate RF signals based on the reference RF signal and feed the generated RF signals to RF antennas in the second transmit antenna array.

In some embodiments, each transmit semiconductor die may include 8, 16, 32, 64, or 128 RF antenna elements (e.g., 1170) integrated thereon. For example, in one embodiment, the transmitter may include a column of 8 transmit semiconductor dies each having a two-dimensional grid of 16×2 RF antennas. In this example embodiment, the transmitter column may be used to achieve an elevation resolution of about 0.780 degrees.

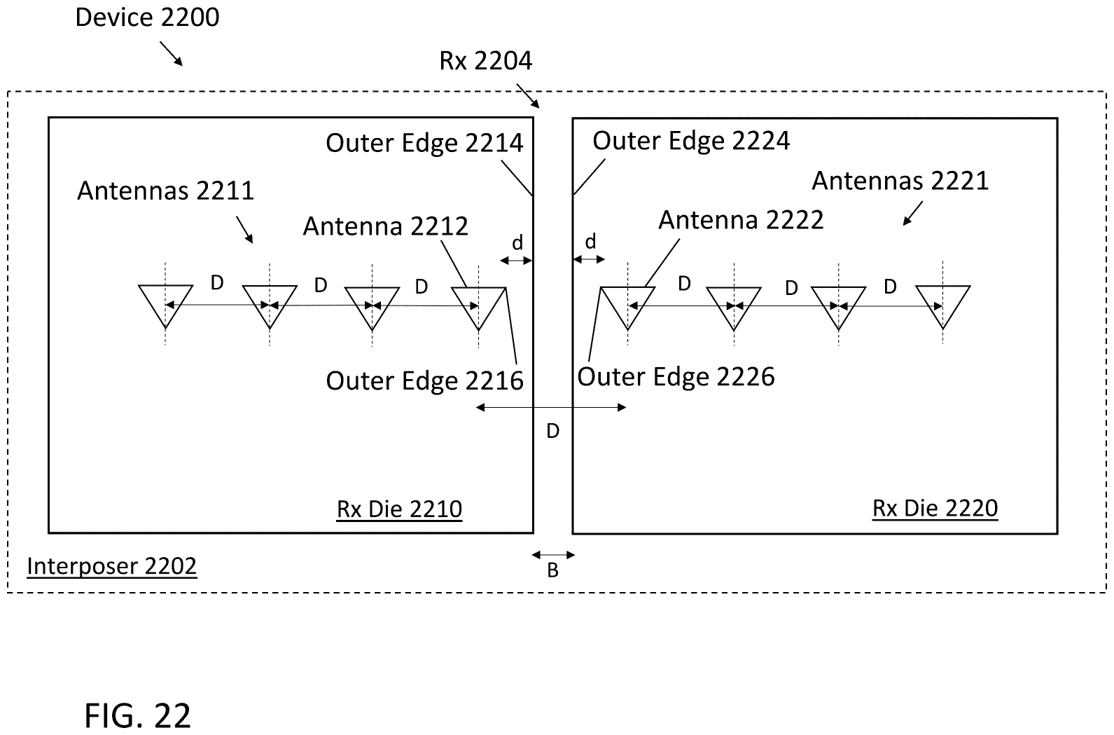

In some embodiments, the transmit semiconductor dies within a column (e.g., 421a) are spaced next to one another to preserve half-wavelength spacing between antennas located on different transmit semiconductor dies in the column (e.g., FIG. 22). This facilitates eliminating aliasing effects, such as lobes. For example, in some embodiments, the first transmit semiconductor die (e.g., 2210) has a first transmit RF antenna (e.g., 2212) integrated thereon (e.g., in the last row of antennas on the first die), the second transmit semiconductor die (e.g., 2220) has a second transmit RF antenna (e.g., 2222) integrated thereon (e.g., in the first row of RF antennas on the second die), and the first transmit semiconductor die and the second transmit semiconductor die are arranged in the transmitter such that the center-to-center distance (e.g., D in FIG. 22) between the first transmit RF antenna and the second transmit RF antenna is less than or equal to (e.g., equal to) one half of a free-space wavelength at the first RF center frequency.

In some embodiments, the transmitter (e.g., 420) has multiple columns (e.g., 421a, 421b) of semiconductor dies, which may be used to improve azimuthal resolution of the RADAR device. For example, the transmitter may include two transmit antenna arrays (e.g., 422a and 422b as one and 422c and 422d as another) each consisting of a column (e.g., 421a, 421b) of transmit semiconductor dies having RF antennas integrated thereon. The columns (e.g., 421a and 421b) may be positioned on opposite sides of the substrate. In this way, the separation between the transmit antenna arrays may be increased (or maximized) without increasing the size of the substrate. Increasing the separation between the transmit antenna arrays leads to an increase, relative to a single column implementation, in the system's spatial (specifically azimuthal) resolution, when the data obtained using the first transmit array (in the first column) is combined with the data obtained using the second transmit array.

Accordingly, in some embodiments, the transmitter comprises a second column (e.g., 421b) of transmit semiconductor dies (e.g., 422c and 422d) tiled in the first direction, wherein the second column of transmit semiconductor dies is spaced at a distance from the first column (e.g., 421a) of transmit semiconductor dies (e.g., 422a and 422b) in the second direction, wherein the second column of transmit semiconductor dies includes third and fourth transmit semiconductor dies each having integrated thereon respective transmit circuitry (e.g., 1160) and transmit antenna array (e.g., 1132) and each being coupled to the signal generation circuitry.

Any suitable type of RF antenna may be used as part of the transmitter. For example, each of the plurality of RF antennas in the transmitter may include a patch (e.g., 1270). As another example, each of the plurality of RF antennas in the transmitter may include a dipole (e.g., 1802).

In some embodiments, RF antennas integrated on a single transmit semiconductor die (e.g., 422a, 522a, 1122, 1222) may not be arranged as a single column and, instead, may be arranged in a two-dimensional grid having two columns of RF antennas. In this layout (see e.g., FIGS. 4B, 11A-11B and 12A), the RF antennas (e.g., 1170) and the on-chip transmit circuitry (e.g., 1160) that feeds the RF antennas are mirrored across a line of symmetry (e.g., 1102, 1202) (in the first direction, e.g., y in FIG. 5) along which the column of transmit semiconductor dies (e.g., 521a) is elongated. Although arranging RF antennas on each transmit semiconductor die in a two-dimensional array (rather than a one-dimensional array) results in loss of elevation resolution, it confers a number of important benefits. First, this simplifies chip layout because it makes it easier to distribute the reference RF signal from the signal generation circuitry to the transmit chips. For example, as a result of arranging 32 RF antennas in two columns and 16 rows on a single transmit semiconductor die, instead of splitting the reference RF signal into 32 parts from one edge of the chip, the reference RF signal can enter two opposite edges of the die and only needs to be split into 16 parts on each side of the die, which is easier than splitting one signal into 32 parts. Second, mirroring is helpful for the link budget. A 16×2 array transmit the same amount of power as a 32×1 array, but the aperture of the 16×2 array, which increases overall transmitter gain and results in greater range from the transmitter for the same link budget.

Accordingly, in some embodiments, the first plurality of RF antennas (e.g., 423a) integrated on a first transmit semiconductor die (e.g., 422a) may be arranged in a two-dimensional grid having two columns and multiple rows, and wherein the first plurality of RF antennas has mirror symmetry across a line (e.g., 402) extending in the first direction. For example, the first plurality of RF antennas consists of 32 RF antennas arranged into a grid having 2 columns and 16 rows.

Turning to the receiver part of the RADAR device, in some embodiments, the receiver (e.g., 430, 530) comprises a row of receive semiconductor dies (e.g., 432, 532) (e.g., 26 dies) tiled in the second direction (e.g., the x direction in FIG. 4A), the row of receive semiconductor dies including the first receive semiconductor die and a plurality of other receive semiconductor dies, each of which is coupled to the signal generation circuitry and has integrated thereon a respective receive antenna array (e.g., each having a row of 16 RF antennas integrated thereon) and respective receive circuitry (e.g., 1480) configured to process, using the reference RF signal, RF signals received by the respective receive antenna array.

As described above with reference to the spacing between transmit semiconductor dies (e.g., in FIG. 22), the spacing between receive semiconductor dies may be controlled to eliminate aliasing effects, such as grating lobes. Accordingly, in some embodiments, the receive semiconductor dies may be arranged so as to preserve half-wavelength spacing between antennas located on neighboring receive semiconductor dies in the row of receive semiconductor dies.

For example, in some embodiments, the plurality of other receive semiconductor dies includes a second receive semiconductor die, the first receive semiconductor die (e.g., 2210) has a first receive RF antenna (e.g., 2212) integrated thereon (e.g., the last RF antenna in the row of RF antennas integrated on the first receive semiconductor die), the second receive semiconductor die (e.g., 2220) has a second receive RF antenna (e.g., 2222) integrated thereon (e.g., the first RF antenna in the row of RF antennas integrated on the second receive semiconductor die), and the first receive semiconductor die and the second receive semiconductor die are arranged next to one another in the receiver such that the center-to-center distance (e.g., D in FIG. 22) between the first receive RF antenna and the second receive RF antenna is less than or equal to (e.g., within 10% of) one half of a free-space wavelength at the first RF center frequency.

Any suitable type of RF antenna may be used as part of the receiver. For example, each of the plurality of RF antennas in the receiver may include a patch (e.g., 1902). As another example, each of the plurality of RF antennas in the receiver may include a dipole (e.g., 1802).

In some embodiments, to facilitate manufacturing of the receiver and enable positioning adjacent receive semiconductor dies with a desired spacing, the receive semiconductor dies may be mounted on an interposer (e.g., 706) which, in turn, is mounted on the substrate (e.g., 804).

In some embodiments, the receiver (e.g., 700) may further include a focusing element (e.g., lens 704) mounted on the interposer and at least partially covering receive semiconductor dies (e.g., 702) in the row of receive semiconductor dies. The focusing element may increase the amount of RF energy collected by the receiver, which increases the efficiency of the RADAR device. The focusing lens may be made of a material that is transparent in the THz band, such as silicon, or a polymer. In some embodiments, the focusing element may be implemented as a cylindrical or partially cylindrical lens. The primary axis of the cylindrical lens may extend across the second direction (e.g., the x direction in FIG. 4A). In this way, the lens focuses waves offset from one another along the first direction without focusing waves offset from one another along the second direction.

Other types of focusing elements are also possible, including spherical or elliptical lenses. Spherical or elliptical lenses may be used in some embodiments to achieve viewpoint diversification. In these embodiments, waves incident on the spherical or elliptical lens from different angles may be focused on different areas of the receive antenna array. Viewpoint diversification may be achieved by interpreting different areas of the receive antenna array as being associated with different angles.

As described herein, the mixers (e.g., 1484) of the receiver (e.g., 1430) may be sub-harmonic mixers. Accordingly, in some embodiments, the third RF signals (e.g., having a center frequency between 150-160 GHz, for example 155 GHz) have a second harmonic at the RF center frequency (e.g., between 300 and 320 GHz, for example 310 GHz) and the first receive circuitry is configured to mix the second RF signals with the second harmonic of the third RF signals to obtain the fourth RF signals.

In some embodiments, the first RF signals (being transmitted by the transmitter) are LFM signals having a bandwidth of at least at least 3 GHz or at least 6 GHz (e.g., and a center frequency of 310 GHz). The signal generation circuitry may generate a reference RF signal which may be provided to the transmit circuitry (part of the transmitter) and the transmit circuitry may process the reference RF signal (e.g., by upconverting and power dividing the reference RF signal using one or more frequency multipliers and power dividers) to obtain the first RF signals and feed them to the transmit RF antennas. For example, the first transmit circuitry may comprise frequency multiplication circuitry (e.g., 1152a) configured to multiply a center frequency of the reference RF signal to the RF center frequency. The first transmit circuitry may further comprise power divider circuitry (e.g., 1154a) configured to divide the reference RF signal into reference RF signals, and the first RF signals are based on the reference RF signals, respectively.

Similarly to the transmitter, the receiver may receive the reference RF signal generated by the signal generation circuitry and process (by upconverting and power dividing) the reference RF signal to generate the third RF signals (which are then mixed using a sub-harmonic mixer with the received RF signals received by the RF antennas part of the receiver). For example, the first receive circuitry may comprise frequency multiplication circuitry (e.g., 1462) (e.g., multiple frequency multipliers) configured to multiply a center frequency of the reference RF signal to generate the third RF signals. The first receive circuitry may further comprise power divider circuitry (e.g., 1464) configured to divide the reference RF signal into reference RF signals and the third RF signals are based on the reference RF signals, respectively.

Turning to the interface circuitry, in some embodiments, the ADC circuitry (e.g., 752) may include multiple ADCs mounted on the substrate (e.g., 804). In some embodiments, the ADC circuitry may include an ADC for each respective set of one or multiple receive semiconductor dies (e.g., 702) in the row of receive semiconductor dies, which ADC is configured to digitize signals output by the respective set of one or more receive semiconductor dies. In some embodiments, the ADC circuitry may include a single ADC (e.g., 2532) for each pair of (e.g., adjacent) receive semiconductor dies (e.g., 2332) in the row receive semiconductor dies, which ADC is configured to digitize signals output by the pair of receive semiconductor dies.

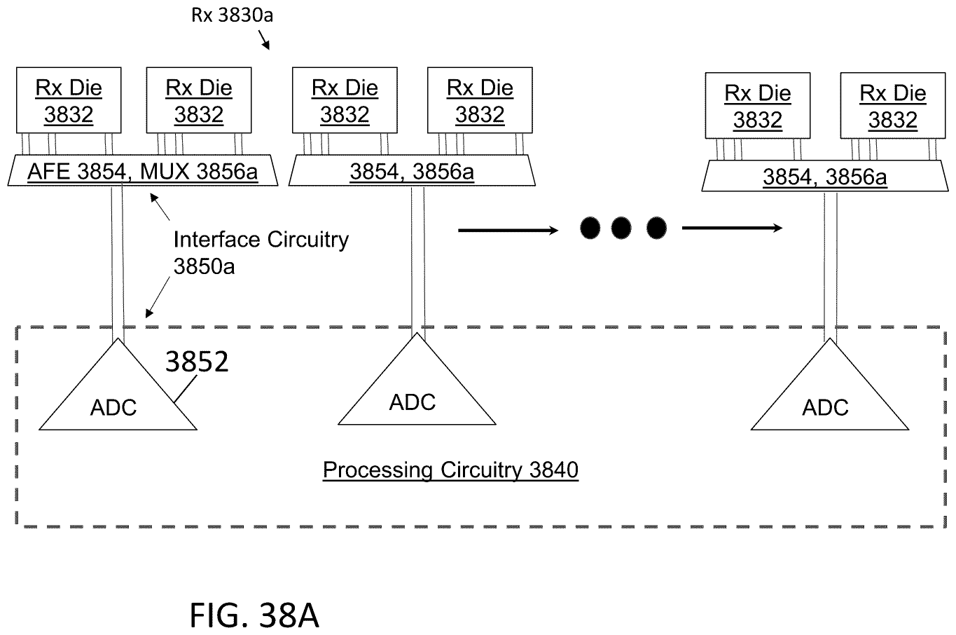

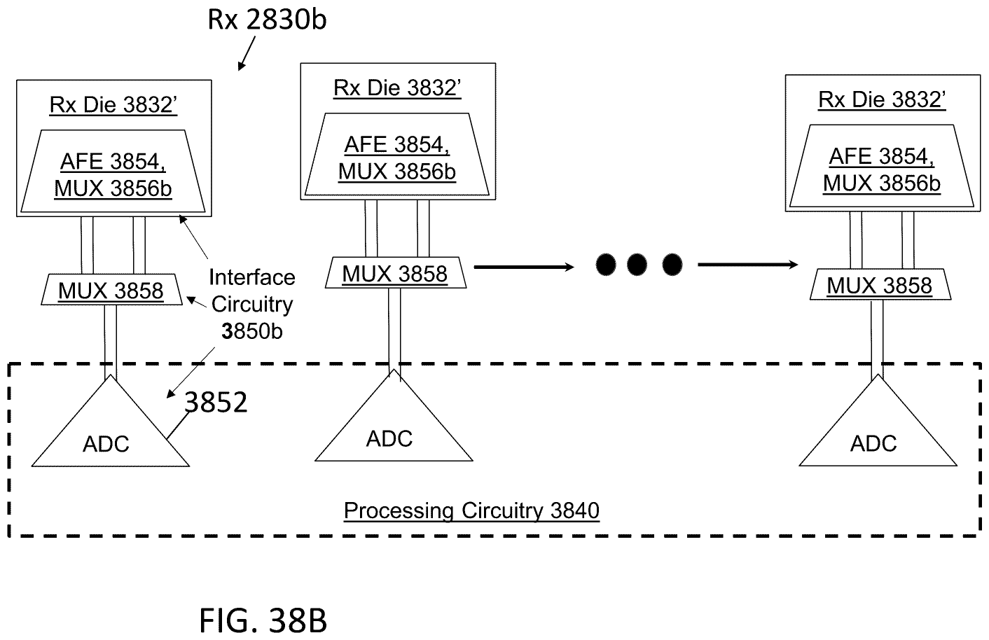

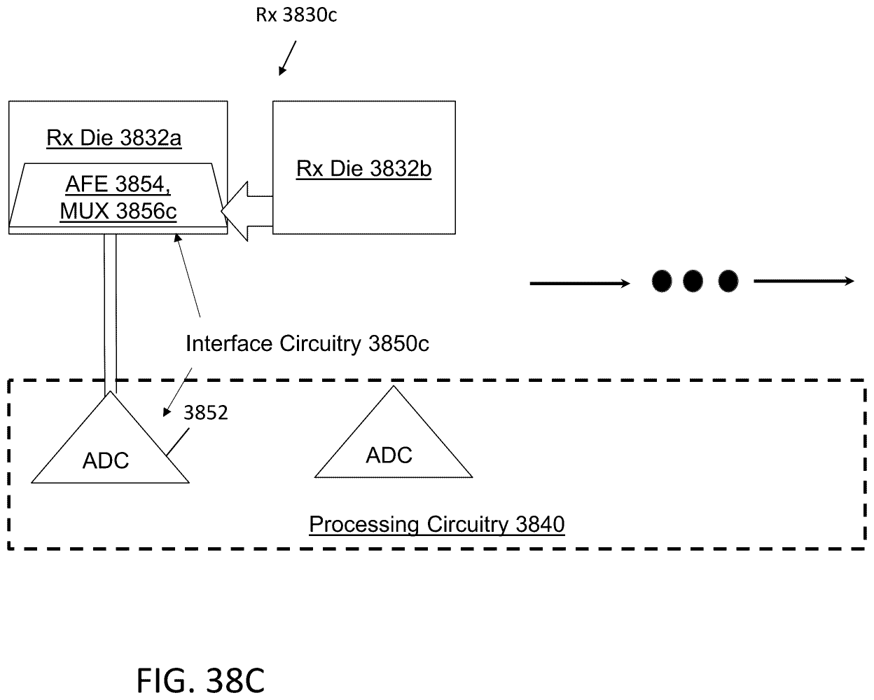

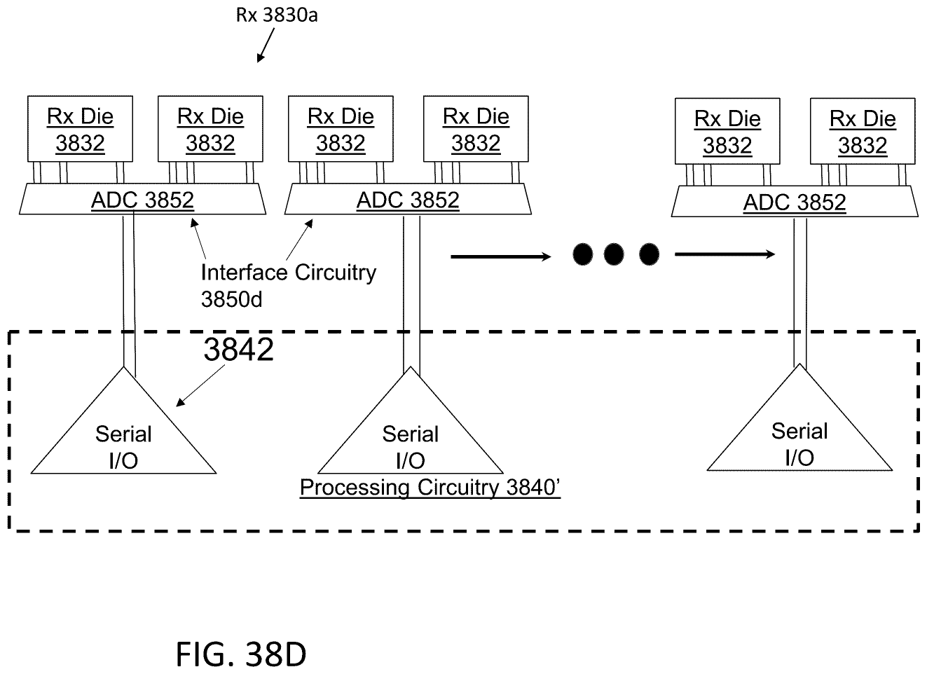

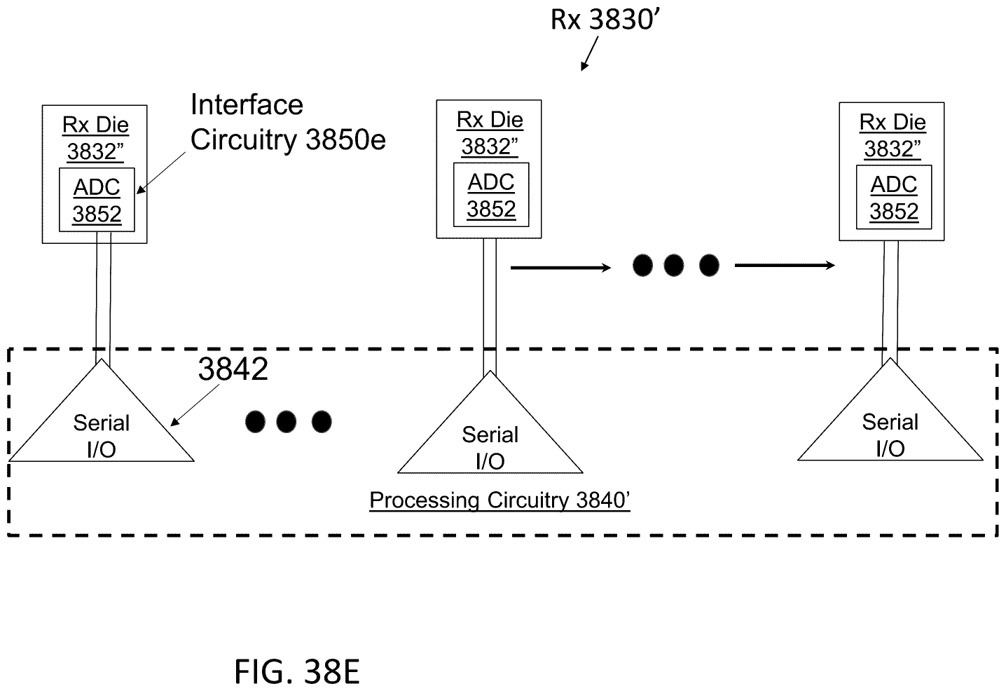

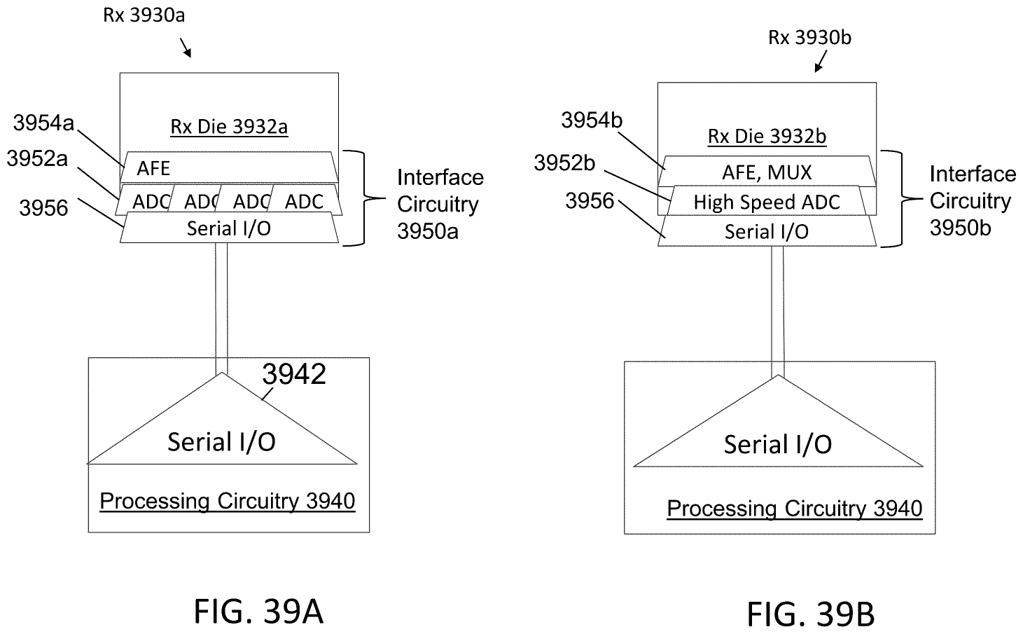

In some embodiments, the ADCs may be mounted on the substrate. In other embodiments, the ADCs may be mounted on the receive semiconductor dies (e.g., FIGS. 38E, 39A-39B). In some embodiments, one or more of the ADCs may be mounted on the substrate and one or more of the ADCs may be mounted on one or more of the receive semiconductor dies.

In some embodiments, the interface circuitry (e.g., 3550) comprises time-division multiplexing circuitry (e.g., 3556) comprising a plurality of time-division multiplexers (e.g., 3656a-3656b) configured to combine the fourth RF signals into time-division multiplexed signals. For example, the first receive circuitry (e.g., 3630) may comprise a first plurality of receive channels (e.g., 3638a-3638d) coupled to the second plurality of RF antennas (e.g., 3686a-3686d) and configured to mix the second RF signals with the third RF signals to obtain the fourth RF signals. In some embodiments, the ADC circuitry (e.g., 3552) is configured to digitize the fourth RF signals at least in part by digitizing the time-division multiplexed signals into digitized time-division multiplexed signals.

In some embodiments, the interface circuitry (e.g., 4050) comprises first serial communication circuitry (e.g., 4060a) configured to serialize a first subset of the fourth RF signals to obtain and transmit a first serialized processed RF signal and the interface circuitry further comprises second serial communication circuitry (e.g., 4060b) configured to serialize a second subset of the fourth RF signals to obtain and transmit a second serialized processed RF signal. For example, the first subset of the fourth RF signals may be obtained from a first plurality of receive channels (e.g., 4038a) coupled to a first subset of the second plurality of RF antennas (e.g., 4086a) and the second subset of the fourth RF signals may be obtained from a second plurality of receive channels (e.g., 4038b) coupled to a second subset of the second plurality of RF antennas (e.g., 4086b). In some embodiments, the device further comprises processing circuitry (e.g., 4040) configured to synchronize serialization of the first subset of the fourth RF signals by the first serial communication circuitry with serialization of the second subset of the fourth RF signals by the second serial communication circuitry.

In some embodiments, the device further comprises processing circuitry (e.g., 440) (e.g., one or more FPGAs, one or more processors, etc.) configured to process digitized signals output by the ADCs, part of the interface circuitry (e.g., 450). The digitized signals from the ADCs may be provided to the processing circuitry via a serial interface (e.g., 2342), for example via a JESD interface protocol (e.g., an interface in accordance with the JESD204 and the JESD204B revision data converter serial interface standard).

In some embodiments, the processing circuitry is mounted on the substrate (e.g., 404). In some embodiments, the processing circuitry is not mounted to the substrate but is communicatively coupled to the interface circuitry mounted on the substrate. In some embodiments, a portion of the processing circuitry is mounted on the substrate and another portion of the processing circuitry is not mounted on the substrate.

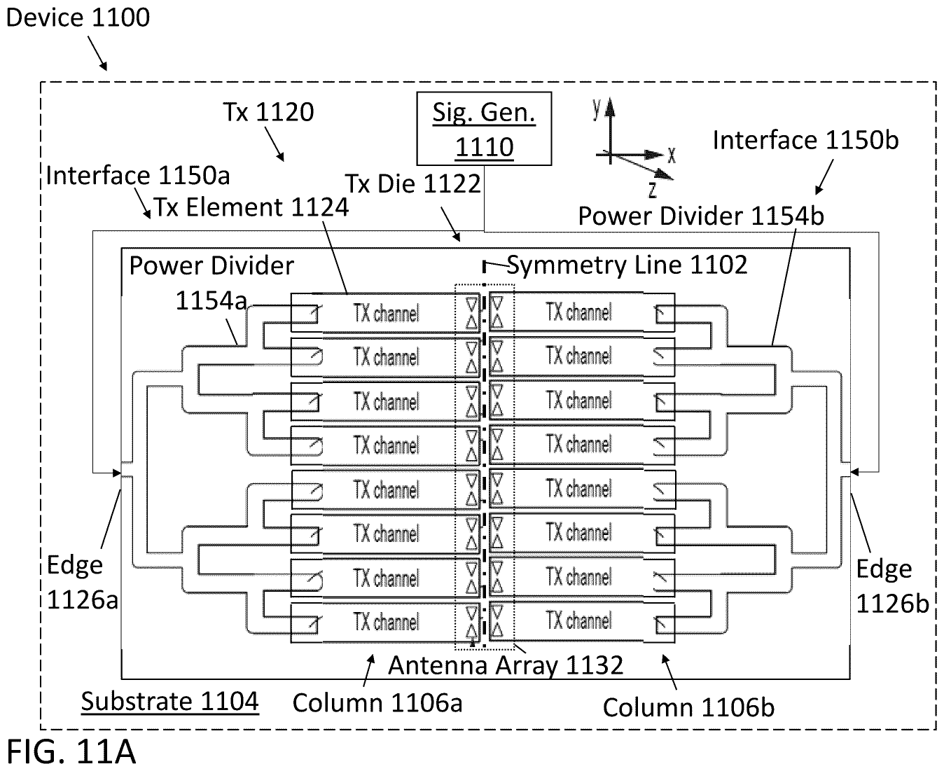

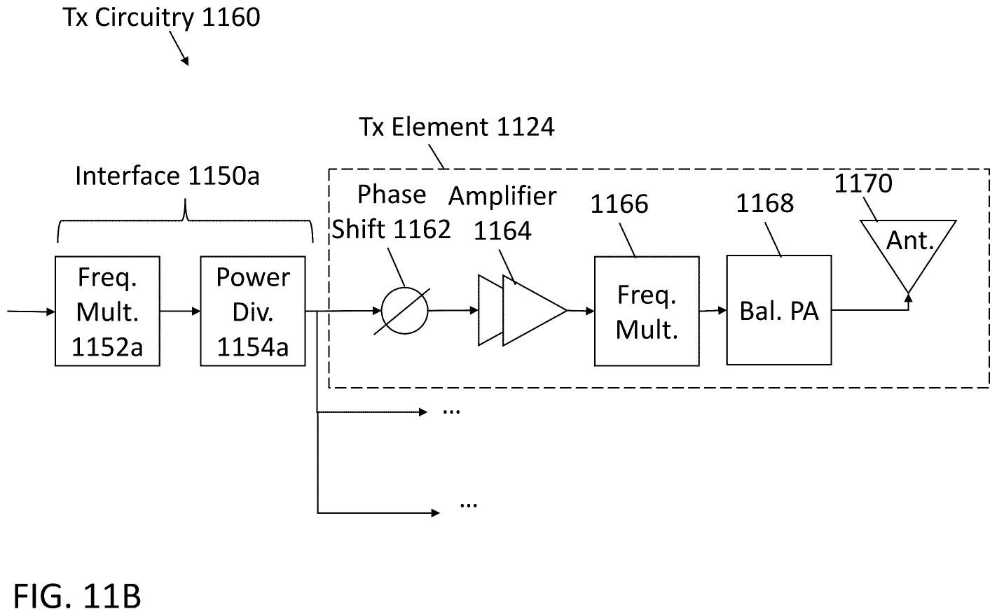

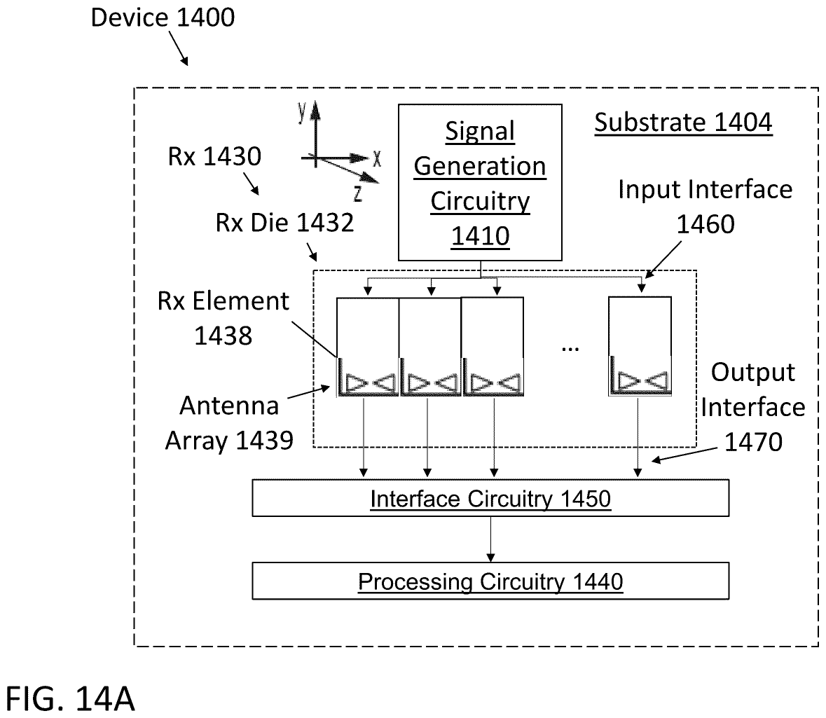

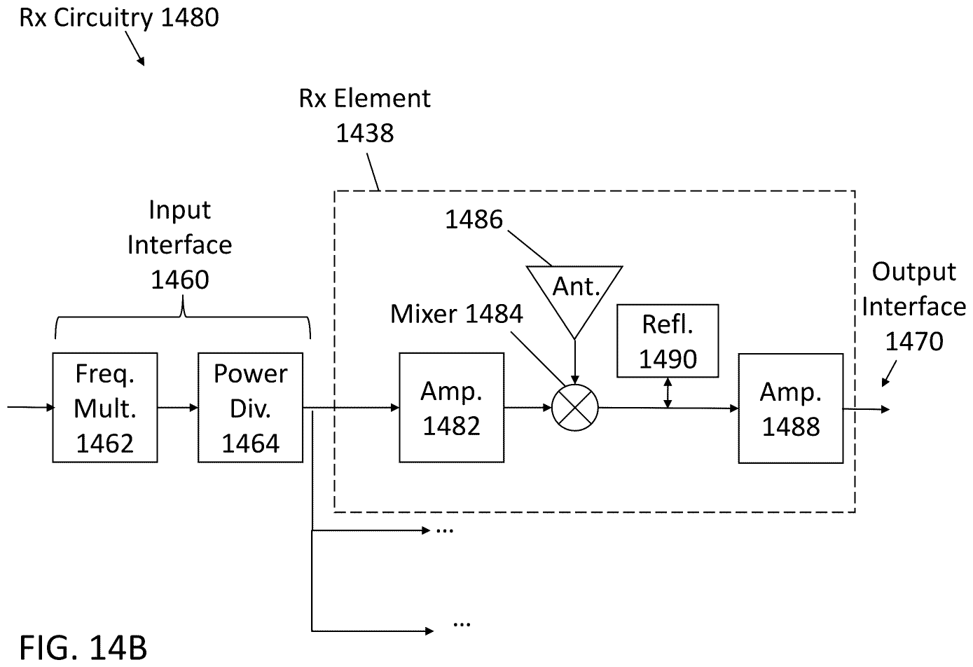

In some embodiments, a RADAR device described herein may be configured to generate range-cross range images of target objects with few or even a single transmit pulse signal. In some embodiments, a device (e.g., 400) comprises a substrate (e.g., 404), signal generation circuitry (e.g., 410) mounted on the substrate and configured to generate a reference RF signal, the reference RF signal being a linear frequency modulated (LFM) chirp signal (e.g., FIGS. 6C-6D); a transmitter (e.g., 420) mounted on the substrate, the transmitter comprising: a first transmit semiconductor die (e.g., 922 in FIG. 11A) coupled to the signal generation circuitry and having integrated thereon first transmit circuitry (e.g., 1160 in FIG. 11B) configured to generate, based on the reference RF signal, first RF signals having an RF center frequency between 300-320 GHz, and a first transmit antenna array (e.g., 1132 in FIG. 11A) comprising a first plurality of RF antennas (e.g., 1170 in FIG. 11B) configured to transmit the first RF signals; and a receiver (e.g., 430) mounted on the substrate, the receiver comprising: a first receive semiconductor die (e.g., 1432 in FIG. 14A) coupled to the signal generation circuitry and having integrated thereon a first receive antenna array (e.g., 1439) comprising a second plurality of RF antennas (e.g., 1486 in FIG. 14B) configured to receive second RF signals having the RF center frequency, the second RF signals being generated at least in part by first RF signals being reflected by a target object; and first receive circuitry (e.g., 1480 in FIG. 14B) configured to process the second RF signals, using the reference RF signal, to output processed RF signals; analog-to-digital conversion (ADC) circuitry (e.g., 452) configured to digitize the processed RF signals to obtain digitized RF signals; and processing circuitry (e.g., 440) coupled to the ADC circuitry and configured to generate a range cross-range image of the target object using the digitized RF signals.

In some embodiments, a duration (e.g., t₂-t₁ in FIG. 6C) of the reference RF signal is between 500 ms and 1.5 seconds. In some embodiments, the duration of the reference RF signal is between 750 ms and 1.25 seconds. In some embodiments, the duration of the reference RF signal is Ims. In some embodiments, the processing circuitry is configured to generate the range cross-range image only from the digitized RF signals.

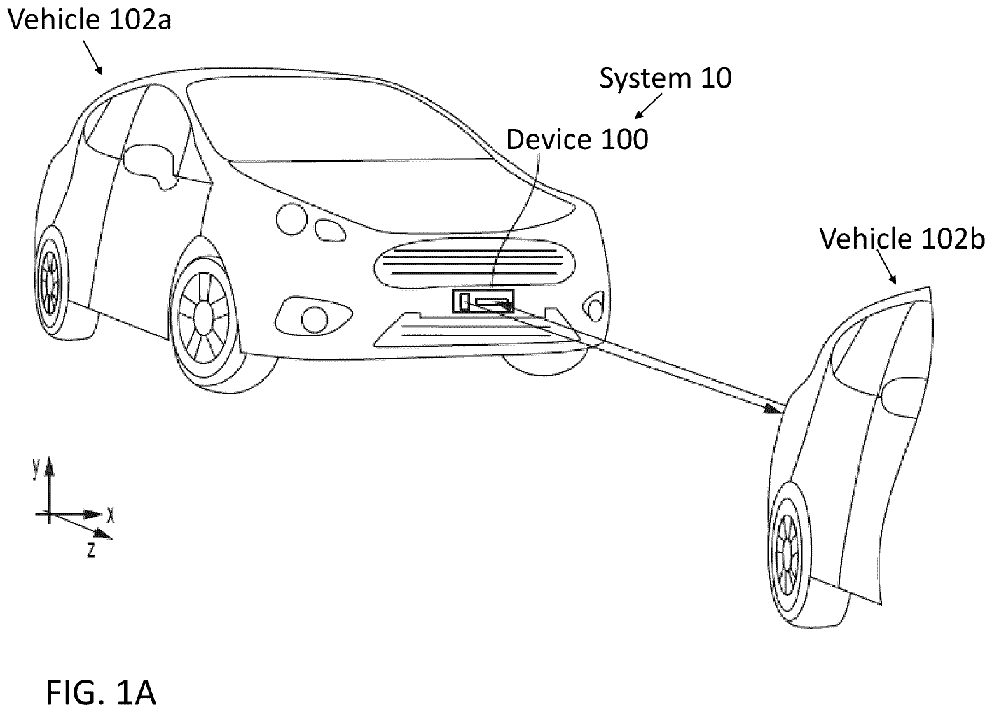

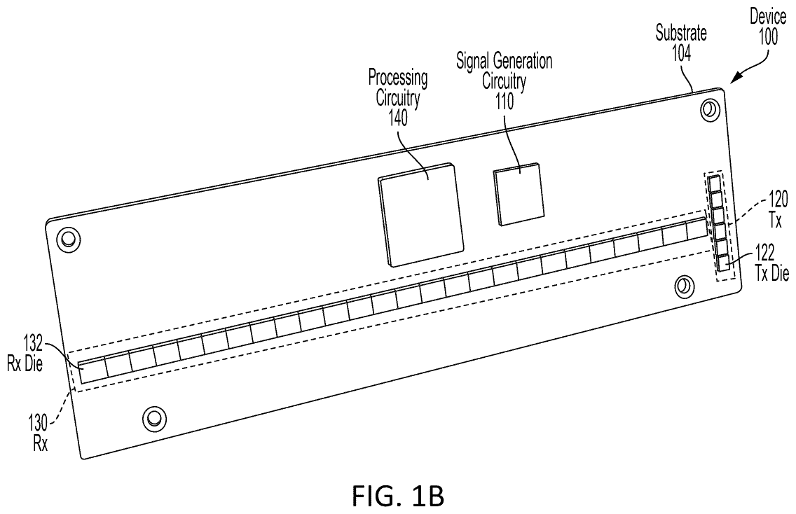

FIG. 1A illustrates a vehicle 102a equipped with an example system 10 for Terahertz-based active sensing including a Terahertz-based active sensing device 100, in accordance with some embodiments of the technology described herein.

In some embodiments, system 10 may include one or more of device 100. Although THz active sensing system 10 is shown with device 100 attached to the front bumper of the vehicle 102a, embodiments of the present technology are not limited to any particular location. Further, vehicles may be equipped with more than one THz active sensing system 10. For example, device 100 may be attached to the front side of the vehicle, and another device 100 may be attached to the rear side. In some embodiments, system 10 may include other sensing devices using other sensing technologies, including for example optical sensors (e.g., video cameras and infrared cameras), millimeter-wave RADAR sensors and/or LIDAR sensors. In other embodiments, only one or more devices 100 may be included in system 10.

FIG. 1B is a perspective view of device 100, in accordance with some embodiments of the technology described herein.

In some embodiments, device 100 may be configured for determining the relative and/or absolute state (e.g., position, velocity, and/or acceleration) of a target object using signals having frequency content in the frequency band of 300 GHz-3 THz. Device 100 includes a transmitter (Tx) 120, a receiver (Rx) 130 and processing circuitry (140) (e.g., analog and/or digital circuitry such as a field programmable gate array (FPGA) and/or application specific integrated circuit (ASIC)).

In some embodiments, substrate 104 may include a printed circuit board (PCB). In FIG. 1B, substrate 404 has a top surface (e.g., parallel to the xy-plane in FIG. 1A) configured to hold and interconnect electronic components. In some embodiments, device 400 may have a sufficiently small form factor to fit in any suitable part of a vehicle. In FIG. 1B, substrate 404 has a width (e.g., extending along the x-axis in FIG. 1A) and a length (e.g., extending along the y-axis in FIG. 1A). In some embodiments, the width may be between 5 cm and 15 cm, between 9 cm and 13 or between 7 cm and 11 cm. In some embodiments, the length may be between 1 cm and 18 cm, between 3 cm and 7 cm or between 4 cm and 6 cm. Other ranges are also possible. In some embodiments, the substrate has an area between 10 cm² and 60 cm².

In some embodiments, transmitter 120 may be configured to transmit signals in directions where target objects are likely to be present. For example, signals may be transmitted along the road in front of a vehicle. In some embodiments, transmitter 120 may have a transmit RF antenna array configured to provide a large aperture in elevation (e.g., along the y-axis in FIG. 1A), such that RF energy is focused in front of the vehicle (e.g., along the z-axis in FIG. 1A) as compared to above and/or below the vehicle. In some embodiments, transmitter 120 may be configured with a larger aperture in elevation (e.g., along the y-axis) than in azimuth (e.g., along the x-axis in FIG. 1A), such that RF energy is spread more uniformly in azimuth than in elevation. For example, a small transmit aperture in elevation may be configured to cover a wide range of directions in front of the vehicle (e.g., in the x-z plane in FIG. 1A).

Transmitter 120 is shown in FIG. 1B including multiple transmit semiconductor dies 122, each of which may include a transmit RF antenna array and transmit circuitry configured to feed the transmit RF antenna array. In some embodiments, the transmit RF antenna arrays of at least some transmit semiconductor dies 122 (e.g., the dies stacked in a column in FIG. 1B) may be configured to operate together as a larger RF antenna array (e.g., to collectively provide a large aperture in elevation), such as by having RF antennas on transmit semiconductor dies 122 spaced at a half-wavelength or less from the RF antennas on the other (e.g., next in the column) transmit semiconductor dies 122.

It should be appreciated that, in some embodiments, it may be advantageous to focus at least some transmitted RF energy, in elevation, on the ground below the vehicle. For instance, focusing RF energy on the ground may be useful for detecting and/or identifying snow, ice, and/or water on the road, and/or road and/or lane boundaries, using techniques described further below.

In some embodiments, receiver 130 may be configured to receive signals resulting from the reflection of the transmitted signals from a target object. For example, signals may be received from along the road in front of a vehicle. As shown in FIG. 1A, the transmitted signals are reflected from the rear side of another vehicle 102b. In some embodiments, receiver 130 may have a receive RF antenna array configured to provide a large aperture in azimuth (e.g., along the x-axis in FIG. 1A), such that RF energy received from different directions in front of the vehicle (e.g., in the x-z plane in FIG. 1A) may be discriminated at high resolution, as compared to RF energy received from above and/or below the vehicle. For example, receiver 130 may be configured with a larger aperture in azimuth (e.g., along the x-axis) than in elevation (e.g., along the y-axis in FIG. 1A).

Receiver 130 is shown in FIG. 1B including multiple receive semiconductor dies 132, each of which may include a receive RF antenna array and receive circuitry configured to feed (e.g., obtain RF signals via) the receive RF antenna array. In some embodiments, the receive RF antenna arrays of at least some receive semiconductor dies 132 (e.g., the dies stacked in a row in FIG. 1B) may be configured to operate together as a larger RF antenna array (e.g., to collectively provide a large aperture in azimuth), such as by having RF antennas on receive semiconductor dies 132 spaced at a half-wavelength or less from the RF antennas on the other (e.g., next in the row) receive semiconductor dies 132.

As further shown in FIG. 1B, signal generation circuitry 110 may be provided on substrate 104 with transmitter 120 and receiver 130 to provide a reference RF signal. For example, transmitter 120 may be configured to transmit RF signals based on the reference RF signal, and/or receiver 130 may be configured to generate RF signals, based on the reference RF signal, to mix with received RF signals.

In some embodiments, processing circuitry 140 may be configured to use signals obtained (e.g., mixed and digitized) from the received RF signals to determine the relative and/or absolute state of the target object. In some embodiments, the position of a target object may be determined based on a measurement of distance relative to the known location of device 100. In some embodiments, the velocity of a target object may be determined based on multiple measurements of distance, whether obtained from a single device 100 or from multiple devices 100 of system 10. Alternatively or additionally, the velocity may be determined based on a single measurement using doppler processing. Similarly, the acceleration of a target object may be determined based on multiple velocity data points. A computer may use the information obtained using device 100 to provide information to a driver of vehicle 102a (e.g., a warning or indication of location and/or proximity to a target object), and/or automatically control the vehicle 102a in some respect (e.g., to self-drive the vehicle without human intervention or with some degree of human intervention) or to perform other automated operations.

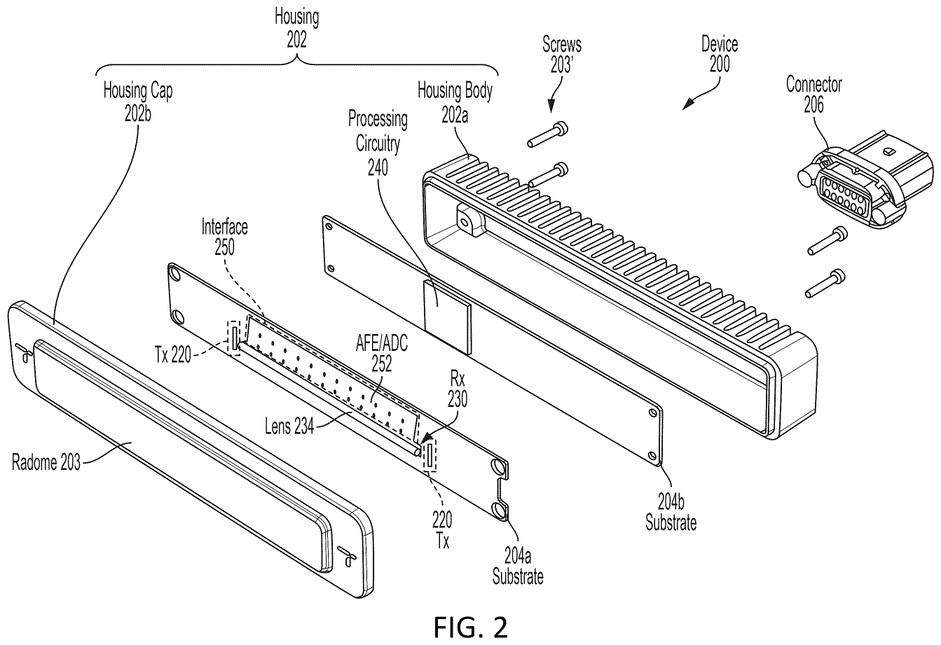

FIG. 2 is an exploded view of a device 200 that may be included in system 10, in accordance with some embodiments of the technology described herein.

In some embodiments, device 200 may be configured as described herein for device 100, including a transmitter 220 and receiver 230 on a substrate 204a. Moreover, as shown in FIG. 2, device 200 further includes interface (Int.) circuitry 250 on substrate 204a, and processing circuitry 240 is provided on another substrate 204b.

In some embodiments, one or more focusing elements may be used to perform viewpoint diversification. For example, in FIG. 2, receiver 230 is shown including a lens 234. In other embodiments, lens 234 may be omitted.

In some embodiments, interface circuitry 250 may be configured to offload signals from receiver 230 and provide the offloaded signals to processing circuitry 240. For example, interface circuitry 250 may include analog-to-digital conversion (ADC) circuitry, such as units 252 shown on substrate 204a in FIG. 2, which may include analog front end (AFE) circuitry and ADC circuitry (e.g., with the AFE circuitry coupled between receiver 230 and the ADC circuitry). For example, each AFE/ADC unit 252 shown in FIG. 2 may be a mixed-signal ASIC having AFE circuitry and ADC circuitry therein. Alternatively or additionally, in some embodiments, the AFE circuitry and/or ADC circuitry may be included on the receive semiconductor dies (e.g., and separate ADC units 252 may be omitted). Further alternatively or additionally, ADC circuitry may be located in a same integrated circuit package (e.g., on the same die(s)) as processing circuitry 240. For instance, processing circuitry 240 may include an FPGA and/or ASIC having ADC circuitry therein.

In some embodiments, device 200 may be packaged for use in a vehicle (e.g., subject to harsh weather conditions). For example, in FIG. 2, device 200 further includes a housing 202 having a housing body 202a and a cap 202b. In some embodiments, housing body 202a may be configured to hold substrates 204a and 204b in place, such as shown in FIG. 2 using screws 203′. In some embodiments, cap 202b may be configured to protect electronics of device 200 from external elements while permitting transmitter 220 and receiver 230 to exchange signals with the exterior of housing 202. For example, in FIG. 2, cap 202b is shown including a radome 203 positioned in front (e.g., along in the z-axis in FIG. 1A) of transmitter 220 and receiver 230. In some embodiments, device 200 may be configured to communicate with another part of a system, such as another vehicle sensor or vehicle computer system, via a connector 206.

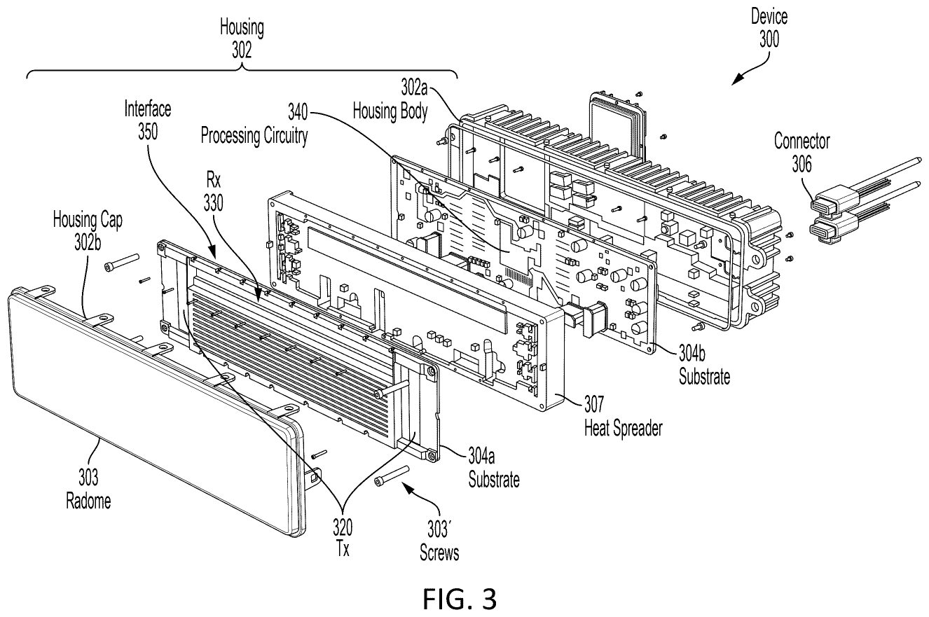

FIG. 3 is an exploded view of an example device 300 that may be included in system 10, in accordance with some embodiments of the technology described herein.

In some embodiments, device 300 may be configured as described herein for device 200 including in connection with FIG. 2, including a housing 302 having housing body 302a and housing cap 302b, radome 303, substrates 304a and 304b, transmitter 320, receiver 330, processing circuitry 340, and interface circuitry 350. In the illustrated embodiment, receiver 330 is covered by a heatsink 311, which may be configured to transfer heat from receiver 330 towards radome 303 (e.g., which may be substantially transparent at infrared wavelengths for efficient heat dissipation). Moreover, as shown in FIG. 3, device 300 is shown including a heat spreader 307, which may be thermally coupled to substrate 304a. In some embodiments, heat spreader 307 may be mechanically coupled to substrate 304a, such as shown in FIG. 3 fastened to substrate 304a using screws 303′, though other types of fasteners may be used instead of or in addition to screws 303′. Also as shown in FIG. 3, device 300 may be configured to communicate with another part of a system via connector 306.

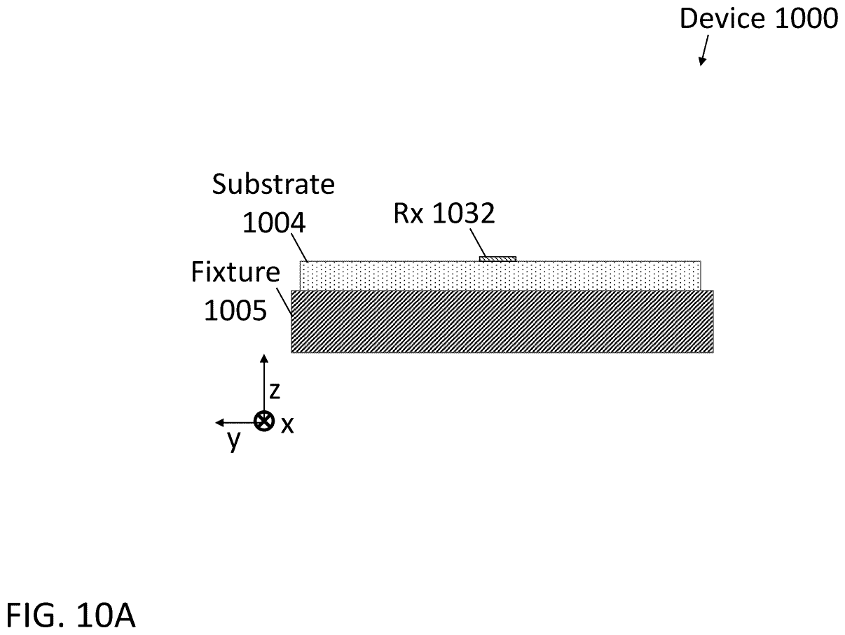

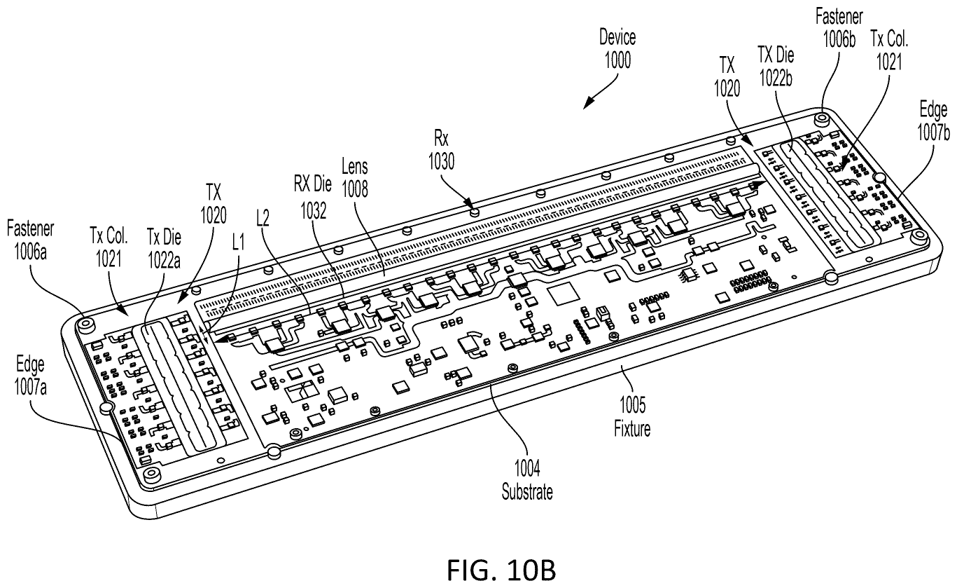

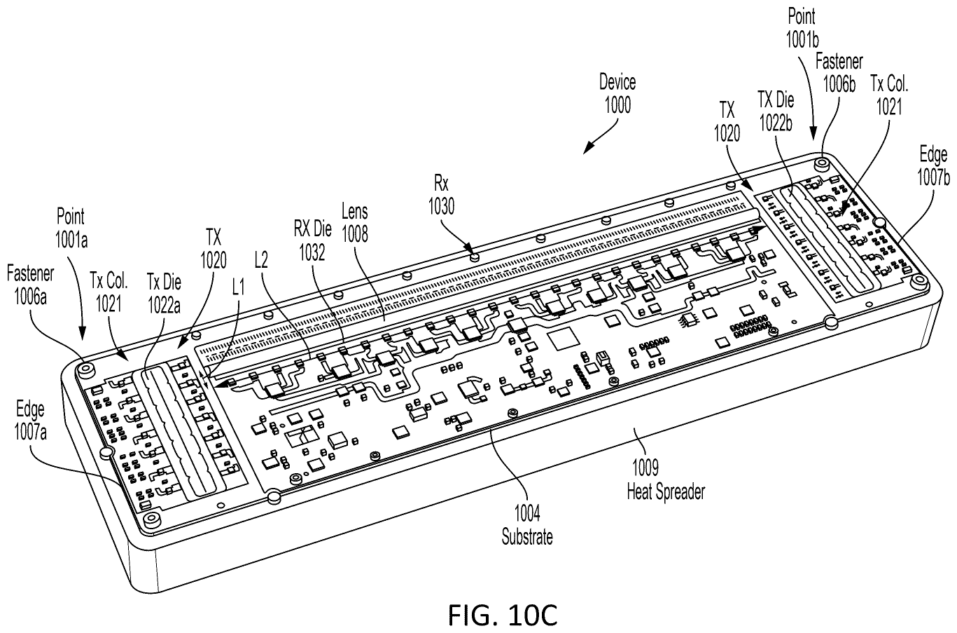

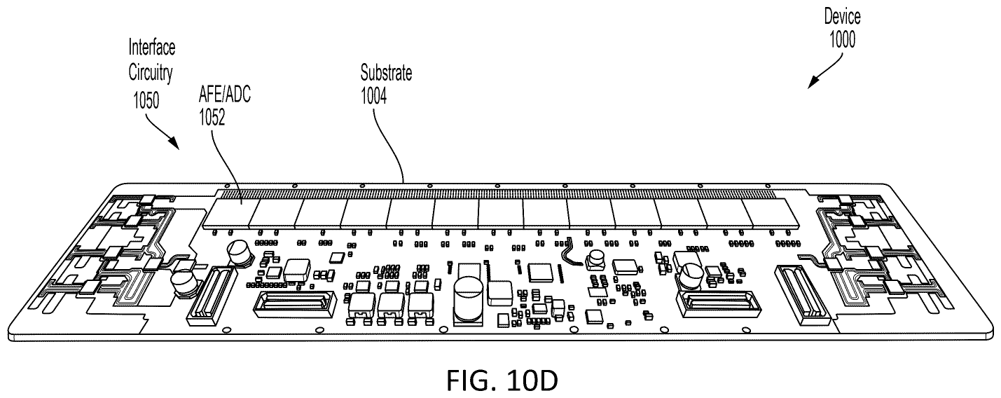

In the illustrated example, interface circuitry 350 is indicated to be on a side of substrate 304a that is hidden from view (e.g., backside), as is further described herein including in connection with FIG. 10D.

FIG. 4A is a schematic view of a substrate 404 of an example device 400 that may be included in system 10, in accordance with some embodiments of the technology described herein. In FIG. 4A, the x-axis will be referred to as the horizontal axis or azimuth axis, the y-axis as the vertical axis or elevation axis, and the z-axis as the longitudinal axis or range axis.

In some embodiments, device 400 may be configured as described herein for devices 100 and 200. For example, as shown in FIG. 4A, device 400 includes a substrate 404, a transmitter 420 and a receiver 430.

Transmitter 420 has multiple transmit semiconductor dies 422a, 422b, 422c, and 422d. Each transmit semiconductor die may have a transmit antenna array sized to emit signals having frequency content in the frequency band of 300 GHz and 3 THz or any frequency band within the 300 GHz-3 THz band (e.g., 190-300 GHz, 300-320 GHz, 307-313 GHz, 390-450 GHz, 440-480 GHz, 455-495 GHz, or 820-880 GHz). For example, transmitter 420 may have transmit antenna arrays sized to emit signals having frequency content in the frequency band of 300-320 GHz or 307-313 GHz. In some embodiments, transmit antenna arrays described herein may have a frequency bandwidth (e.g., 3 dB bandwidth) of 1 GHz-4 GHz, 1.5 GHz, 3 GHz, 4 GHz-134 GHz, 4 GHz-100 GHz, 4 GHz-60 GHz, 10 GHz-100 GHz, 10 GHz-60 GHz, 10 GHz-30 GHz, 15 GHz-60 GHz, 10 GHz-30 GHz or 15 GHz-25 GHz. Similarly, receiver 430 may have a receive antenna array sized to receive signals having frequency content in a frequency band of 300 GHz-3 THz or any sub-band of this frequency band. For example, in some embodiments, the receive antenna array may be sized to receive signals having frequency content in a frequency band of 300-320 GHz or 307-313 GHz. In some embodiments, receiver 430 has a frequency bandwidth of 10 GHz-60 GHz, 10 GHz-30 GHz, 15 GHz-60 GHz, 10 GHz-30 GHz or 15 GHz-25 GHz.

In some embodiments, transmitter 420 and receiver 430 may be disposed on substrate 404. For example, transmitter 420 and receiver 430 may be mounted directly on substrate 404. In some embodiments, transmitter 420 and receiver 430 may have components on one or more semiconductor dies that are mounted on substrate 404. For example, in FIG. 4A, transmitter 420 has a plurality of transmit semiconductor dies 422a, 422b, 422c, and 422d mounted on substrate 404, and receiver 430 has a plurality of receive semiconductor dies 432a-432c mounted on substrate 404.

In some embodiments, semiconductor dies of transmitter 420 and/or receiver 430 may be mounted directly on substrate 404, and/or may be mounted one or more interposers, with the interposer(s) mounted directly on substrate 404.

In some embodiments, transmitter 420 may transmit signals outside the plane defined by the top surface of substrate 404 (e.g., parallel to the z-axis or at any angle relative to the z-axis other than 90 deg.). For example, transmitter 420 may be shaped to have a main lobe extending away from the plane defined by the top surface of substrate 404. Similarly, receiver 430 may receive the transmitted signals upon reflection from a target object. For example, receiver 430 may be shaped to have a main lobe extending away from the plane defined by the top surface of substrate 404.

In some embodiments, transmitter 420 may have a transmit aperture (e.g., provided by its transmit antenna array(s)) having a transmit aperture width extending along the x-axis and a transmit aperture length extending along the y-axis. In some embodiments, the transmit aperture length is greater than the transmit aperture width. For example, the length of the transmit aperture length may be more than four times greater than the transmit aperture width, more than ten times greater than the transmit aperture width, more than twenty times greater than the transmit aperture width, or more than thirty times greater than the transmit aperture width. In accordance with various embodiments, the transmit aperture length may be between 10 mm and 3 cm, between 10 mm and 5 cm, between 10 mm and 7 cm, between 50 mm and 3 cm, between 50 mm and 5 cm, or between 50 mm and 7 cm. In accordance with various embodiments, the transmit aperture width may be between 0.1 mm and 3 mm, between 0.1 mm and 5 mm, or 0.1 mm and 10 mm.

In some embodiments, the transmit aperture may be elongated along the y-axis to produce a large horizontal field of view and a small vertical field of view. The transmitter 420 may be designed to have such an elongated aperture because, from the viewpoint of the front side of a vehicle, target objects are more likely to span in the horizontal direction than in the vertical direction. Therefore, computer-assisted driving algorithms tend to benefit more from data points at different azimuths than from data points at different elevations. In one example, the angular field of view in the horizontal direction may be between 200 and 900 (e.g., in the 650 GHz-690 GHz band) and the angular field of view in the vertical direction may be between 50 and 150 (e.g., in the 650 GHz-690 GHz band).

In some embodiments, transmitter 420 may have multiple columns of transmit semiconductor dies extending in one direction and spaced from one another in an orthogonal direction. For example, as shown in FIG. 4A, transmit semiconductor dies 422a and 422b are arranged in a first column 421a extending along the y direction and transmit semiconductor dies 422c and 422d are arranged in a second column 421b extending along the y direction and spaced from first column 421a along the x direction.

In some embodiments, receiver 430 may have a receive aperture (e.g., provided by its receive antenna array(s)) having a receive aperture width extending along the x-axis and a receive aperture length extending along the y-axis. In some embodiments, the receive aperture width is greater than the receive aperture length. For example, the receive aperture width may be more than five times greater than the receive aperture length, more than ten times greater than the receive aperture length, more than twenty times greater than the receive aperture length, or more than thirty times greater than the receive aperture length. For example, the receive aperture width may be between 5 mm and 10 cm, between 3 cm and 10 cm or between 5 cm and 10 cm. According to various embodiments, the receive aperture length may be between 0.1 mm and 3 mm, between 0.1 mm and 5 mm or between 0.1 mm and 1 cm. In some embodiments, the receive aperture may be elongated along the y-axis to increase the content sensed by the receiver 430 in the horizontal direction. As explained above, from the viewpoint of the front side of a vehicle, target objects tend to span the horizontal axis more than they span the vertical axis.

In some embodiments, one or more focusing elements may be used to perform viewpoint diversification. For example, in FIG. 4A, receiver 430 is shown including a lens 434. In other embodiments, lens 434 may be omitted.

In some embodiments, interface circuitry 450 may be configured to offload signals from receiver 430 and provide the offloaded signals to processing circuitry 440. For example, in FIG. 4A, interface circuitry 450 includes AFE and ADC circuitry units 452a, 452b, 452c, 452d, and 452c respectively coupled to receive semiconductor dies 432a-432c. In some embodiments, AFE and ADC circuitry units 452a-452e may be implemented using mixed-signal ASICs (e.g., having AFE components coupled to receiver 430 and ADC components coupled to processing circuitry 440). In some embodiments, AFE and ADC circuitry units 452a-452e may be mounted on substrate 404, cither directly, or on an interposer. For instance, receive semiconductor dies 432a-432c and AFE and ADC circuitry units 452a-452e may be mounted on an interposer, and the interposer may be mounted on substrate 404. In some embodiments, at least some AFE circuitry and/or ADC circuitry may be included on receive semiconductor dies 432a-432c. Further alternatively or additionally, at least some AFE and/or ADC circuitry may be located in a same integrated circuit package (e.g., on the same die(s)) as processing circuitry 440. For instance, processing circuitry 440 may include an FPGA and/or ASIC having ADC circuitry therein. While an AFE/ADC unit is shown in FIG. 4A for each receive semiconductor die, it should be appreciated that fewer units may be provided than receive semiconductor dies (e.g., as shown in FIGS. 38A, 38C, and 38D).

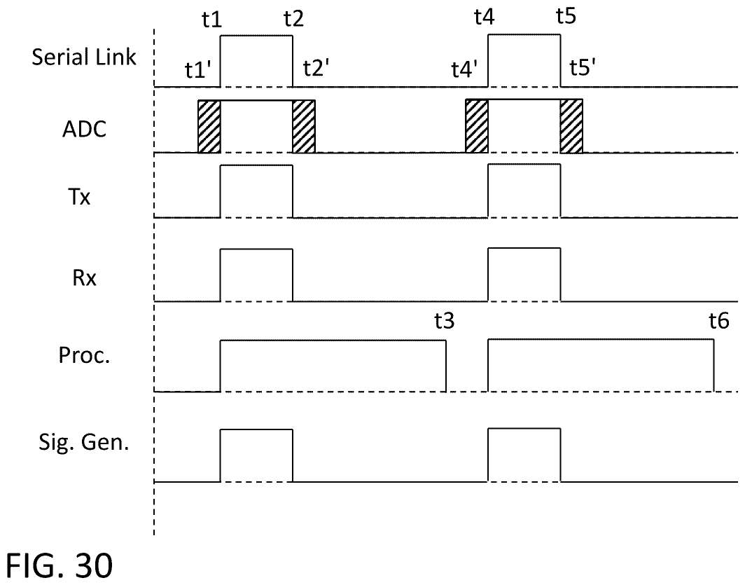

In some embodiments, processing circuitry 440 may include digital circuits and/or analog circuits configured to determine the relative and/or absolute state of a target object based on the reflected signals received from the receiver 430. Processing circuitry 440 may be mounted on substrate 404, such as shown in FIG. 4A (e.g., on another die such as an FPGA, ASIC, and/or processor), and/or processing circuitry 440 may be integrated on a receiver semiconductor die (e.g., 432a), or, at least in part, on another substrate (e.g., as shown in FIG. 4A). In some embodiments, processing circuitry 440 may be configured to control operation of device 400. For example, as shown in FIG. 4A, processing circuitry 440 may be configured to provide a control signal 442 to signal generation circuitry 410 that controls signal generation circuitry 410 to generate a reference RF signal for transmission and/or reception using transmitter 420 and/or receiver 430. In some embodiments, processing circuitry 440 may be further configured to operate various components of device 400 (e.g., transmitter 420, receiver 430, interface circuitry 450) in multiple operating states, such as described further herein including in connection with FIGS. 30-34.

FIG. 4B is a schematic view of transmitter 420, in accordance with some embodiments of the technology described herein.

In some embodiments, transmitter 420 may have a transmit semiconductor die having integrated thereon transmit circuitry configured to generate RF signals based on a reference RF signal and a transmit antenna array having RF antennas configured to transmit the RF signals. For example, as shown in FIG. 4B, transmit semiconductor die 422a has transmit circuitry 425a and transmit antenna array 423a. For instance, portions of transmit circuitry 425a may be configured to feed respective transmit antennas of transmit antenna array 423a.

In some embodiments, transmit semiconductor die 422a may have an RF transmit antenna array arranged in a two-dimensional grid. For example, as shown in FIG. 4B, transmit antenna array 423a is arranged in first and second columns 406a and 406b extending in the first direction (e.g., y-direction), with each column having multiple rows 408 extending in the second direction (e.g., x-direction). In some embodiments, the RF transmit circuitry onboard transmit semiconductor die 422a may be further arranged in the two-dimensional grid. For example, as shown in FIG. 4B, transmit circuitry 425a is shown arranged in columns 406a and 406b and rows 408. For instance, transmit circuitry 425a may be arranged in a first transmit circuitry portion in first column 406a and configured to feed the antennas in first column 406a and a second transmit circuitry portion in second column 406b configured to feed the antennas in second column 406b.

In some embodiments, transmit semiconductor die 422a may have components with mirror symmetry across a line extending in the first direction. For example, in FIG. 4B, first and second columns 406a and 406b of transmit antenna array 423a mirror one another across a symmetry line 402 that separates first and second columns 406a and 406b. For instance, antennas of transmit antenna array 423a in first column 406a may have mirror symmetry with corresponding antennas of transmit antenna array 423a in second column 406b. In some embodiments, transmit circuitry 425a may be further mirrored across symmetry line 402 separating first and second columns 406a and 406b. For example, a first transmit circuitry portion, including transmit circuitry in first column 406a configured to feed antennas of first column 406a, may have mirror symmetry with a second transmit circuitry portion across symmetry line 402, the second transmit circuitry portion including transmit circuitry in second column 406b configured to feed antennas of second column 406b.

In some embodiments, device 400 may have multiple transmit semiconductor dies having mirror symmetry across the same line. For example, as shown in FIG. 4B, transmit semiconductor die 422b has an antenna array 423b and transmit circuitry 425b arranged in a two-dimensional array with columns separated by line 402. For instance, antenna array 423b and/or transmit circuitry 425b may have mirror symmetry across symmetry line 402.

In some embodiments, device 400 may have multiple transmit semiconductor dies having mirror symmetry across respective lines. For example, as shown in FIG. 4B, transmit semiconductor die 422c has an antenna array 423c and transmit circuitry 425c arranged in a two-dimensional array with columns separated by another line 402′ extending in the same direction (y-direction) as line 402. In some embodiments, antenna array 423c and/or transmit circuitry 425c may have mirror symmetry across line 402′. Also shown in FIG. 4B, transmit semiconductor die 422d has an antenna array 423d and transmit circuitry 425d, which may have mirror symmetry across line 402′.

FIG. 5 is a schematic view of an alternative substrate 504 of an example device 500 that may be included in system 10, in accordance with some embodiments of the technology described herein. As shown in FIG. 5, substrate 504 has mounted thereon signal generation circuitry 510, a transmitter 520, a receiver 530, processing circuitry 540, and interface circuitry 550.

In some embodiments, signal generation circuitry 510 may include components configured to generate a reference RF signal for providing to the transmitter 520 and/or receiver 530. In FIG. 5, signal generation circuitry 510 has a local oscillator (LO) 512 and frequency multiplication circuitry 514. In some embodiments, LO 512 may be configured to generate an LFM signal (e.g., chirp), such as using a phase locked loop (PLL). In some embodiments, frequency multiplication circuitry may be configured to up-convert the LFM signal to generate a reference RF signal based on the LFM signal. For example, the reference RF signal may have content from the LFM signal and may have a higher center frequency than the LFM signal. In some embodiments, the reference RF signal may have a center frequency between 1 GHz and 20 GHz. In some embodiments, the reference RF signal may have a center frequency of 17.22 GHz (e.g., 310 GHz divided by 18).

In some embodiments, transmitter 520 may be configured as described herein for transmitter 420 including in connection with FIG. 4A. As shown in FIG. 5, transmitter 520 has two columns 521a and 521b of transmit semiconductor dies, and columns 521a and 521b are spaced from one another along the x-axis. As shown in FIG. 5, first column 521a has two transmit semiconductor dies 522a and 522b, and second column 521b has two transmit semiconductor dies 522c and 522d. In FIG. 5, each transmit semiconductor die 522a, 522b, 522c, 522d has 32 transmit elements 524. For example, each transmit semiconductor die may include a transmit RF antenna array and transmit circuitry configured to feed the transmit RF antenna array, and each transmit element 524 may include a transmit RF antenna of the array and transmit circuitry configured to feed the transmit RF antenna. As shown in FIG. 5, the transmit elements 524 of each semiconductor die 522, 522b, 522c, 522d are arranged in a two-dimensional (16×2) grid, with each transmit element 524 spaced center-to-center from other transmit elements 524 by a half free-space wavelength at the center frequency of RF signals transmitted by the transmit element 524 (e.g., 310 GHz). For instance, each transmit element 524 may have a transmit RF antenna spaced center-to-center from transmit RF antennas of other transmit elements 524 by a half free-space wavelength at the center frequency of RF signals transmitted by the transmit RF antennas. Alternatively or additionally, the center-to-center spacing may be within 10% and/or within 7% of a half free-space wavelength at the center frequency.

In some embodiments, receiver 530 may be configured as described herein for receiver 430 including in connection with FIG. 4A. As shown in FIG. 5, receiver 530 has a single row of 26 receive semiconductor dies 532a-532z. For example, each receive semiconductor die may include a receive RF antenna array and receive circuitry configured to feed (e.g., obtain received RF signals via) the receive RF antenna array. As shown in FIG. 5, each receive semiconductor die has 16 receive elements 538 arranged in a one-dimensional (1×16) linear array, with each receive element 538 spaced center-to-center from other receive elements 538 by a half free space wavelength at the center frequency (e.g., 310 GHz). For instance, each receive element 538 may have a receive RF antenna spaced center-to-center from receive RF antennas of other receive elements 538 by a half free-space wavelength at the center frequency of RF signals received by the receive RF antennas. Alternatively or additionally, the center-to-center spacing may be within 10%, within 9%, within 8%, and/or within 7%, within 6%, within 5%, within 4%, within 3%, within 2% and/or within 1% of a half free-space wavelength at the center frequency.

In some embodiments, interface circuitry 550 may be configured as described herein for interface circuitry 450 including in connection with FIG. 4A. As shown in FIG. 5, interface circuitry 550 has 26 combination AFE/ADC units 552a, 552b, through 5522, each coupled to a respective one of the receive semiconductor dies 532a-532z. In some embodiments, each AFE/ADC unit 552a-552z may include analog conditioning circuitry (e.g., an amplifier) and a 32-channel ADC. For example, the ADC may have 2 channels per receive element 538, for the 16 receive elements 538 of the receive semiconductor die to which the ADC is coupled. For instance, each pair of channels may be configured to carry a differential pair output signal from the receive element 538. In some embodiments, each AFE/ADC unit 552a-552z may be a mixed-signal ASIC.

In some embodiments, processing circuitry 540 may be configured as described herein for processing circuitry 440, including in connection with FIG. 4A. As shown in FIG. 5, processing circuitry 540 is mounted on substrate 404, though processing circuitry 540 may be at least partially located elsewhere, or entirely located elsewhere (e.g., mounted on another substrate). In some embodiments, processing circuitry 540 may be configured to communicate with interface circuitry 550 using a serial interface such as JESD. According to various embodiments, processing circuitry 540 may be an ASIC, FPGA, and/or processor. In some embodiments, processing circuitry 540 may be configured to control operation of device 500, such as described herein for processing circuitry 440. For example, as shown in FIG. 5, processing circuitry 540 may be configured to provide a control signal 542 to LO 512 that controls LO 512 to generate a reference RF signal for transmission and/or reception using transmitter 520 and/or receiver 530.

FIG. 6C is a plot illustrating how the frequencies of an example RF signal and the corresponding reflection may vary over time, in accordance with some embodiments. In the example illustrated in FIG. 6C, the transmitted and received RF signals have frequencies that vary according to a linear ramp. For instance, the transmitted RF signal may be generated based on a reference RF signal from signal generation circuitry 410 and/or 510, such as a chirp signal. In FIG. 6C, the solid line represents the transmitted RF signal, and the dashed line represents the reflected RF signal at the receiver. The frequency of the transmitted RF signal varies from frequency f₁ at time t₁ to frequency f₂ at time t₂. Thus, the bandwidth of the transmitted RF signal is f₂-f₁. In some embodiments, f₁ may be 190 GHz, 300 GHz, 307 GHz, 390 GHz, 440 GHz, 455 GHz, 650 GHz, 655 GHz, 660 GHz, 665 GHz, or 820 GHz, for example. In some embodiments, f₂ may be 300 GHz, 313 GHz, 320 GHz, 450 GHz, 480 GHz, 495 GHz, 690 GHz, 685 GHz, 680 GHz, 675 GHz, or 880 GHz, for example. Also shown in FIG. 6C, the transmitted RF signal has a duration of t₂-t₁. According to various embodiments, t₂-t₁ may be between 500 ms and 1.5 seconds, between 750 ms and 1.25 seconds, or 1 ms.

As shown in FIG. 6C, the frequency of the reflected RF signal mirrors the frequency of the transmitted RF signal with a delay Δt. The delay is equal to the time it takes the transmitted RF signal to do a round trip upon hitting a target object. Thus, delay Δt quantifies the distance to the target object. Delay Δt can be obtained by determining the difference between the frequencies (Δf) of the transmitted and received RF signals, respectively, at a certain time to. Because the illustrated chirp signal is linear, delay Δt is given by frequency difference Δf divided by the slope of the linear ramp. In some embodiments, Δf may be 1.5 GHz, 3 GHz, 6 GHz, 10 GHz, 20 GHz, 30 GHz, 40 GHz, 50 GHz, 60 GHz, 80 GHz, 100 GHz, 120 GHz, or 134 GHz, for example.

FIG. 6D is a plot illustrating an alternative example RF signal including two linear ramps, in accordance with some embodiments. In this example, the first linear ramp is sloped in the direction of increasing frequency (thus forming an up-ramp) and the second linear ramp is sloped in the direction of decreasing frequency (thus forming a down-ramp). The illustrated chirped signal allows a RADAR device to take two distinct measurements, one frequency difference (Δf₁, Δf₂) for each ramp. The first measurement (Δt₁) quantifies the initial distance to the target object using the first frequency difference (Δf₁), the second measurement (Δt₂) quantifies the final distance to the target object using the second frequency difference (Δf₂). In some embodiments, the two measurements can be used to quantify the velocity of the target object. In some embodiments, one side of a one- or two-ramp signal may be used to quantify the velocity of a target object using doppler phase shift processing. While no duration is labeled in FIG. 6D, in some embodiments, the duration of a two-ramp signal may be twice that of a single linear ramp, though in other embodiments, the duration may be the same as that of a single linear ramp (e.g., having a pair of ramps that are each half as long in time as in the single ramp signal).

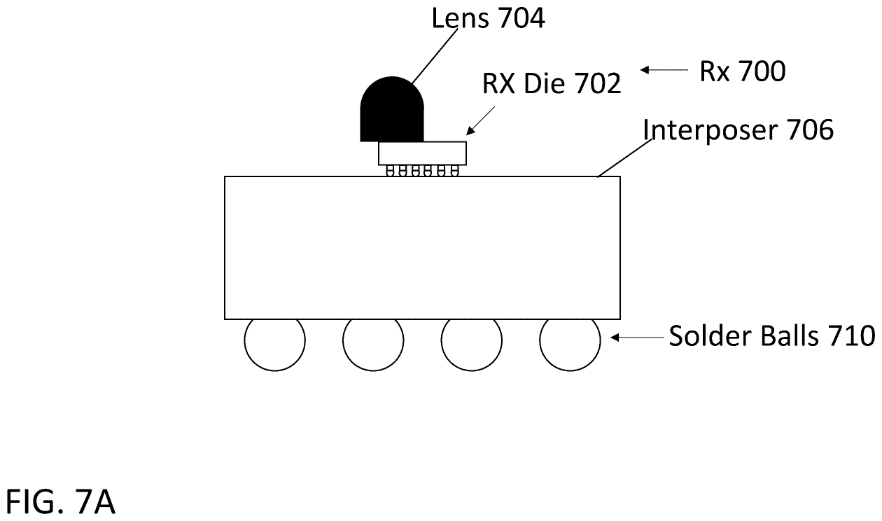

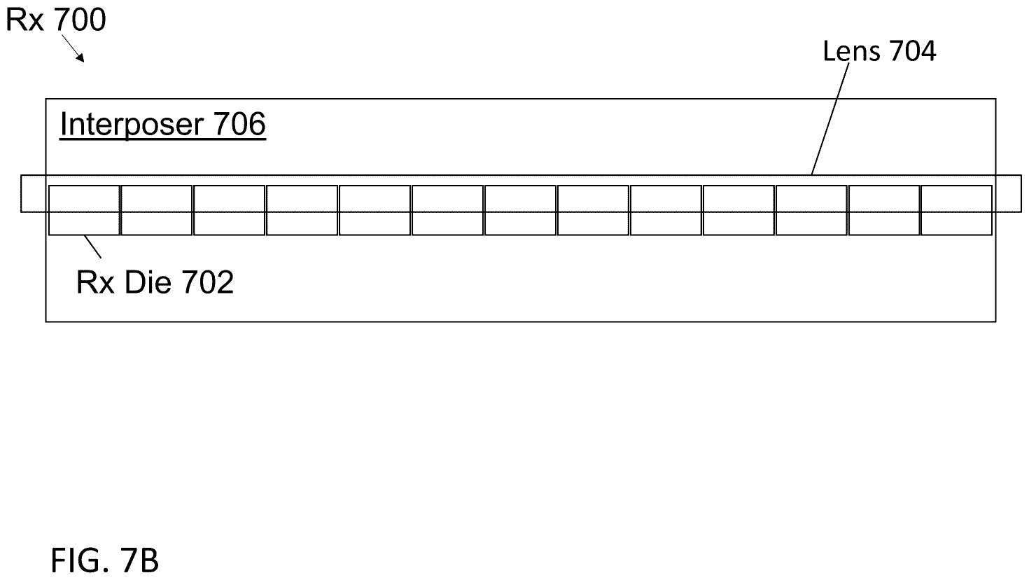

FIG. 7A is a side view of an interposer 706 having a receiver 700 mounted thereon, which may be included in a device in system 10, in accordance with some embodiments of the technology described herein. FIG. 7B is a top view of interposer 706, in accordance with some embodiments of the technology described herein.

In some embodiments, receiver 700 may be configured as described herein for receiver 430 or 530, including in connection with FIGS. 4-5. As shown in FIGS. 7A-7B, receiver 700 includes a single row of receive semiconductor dies 702 and a lens 704 disposed over at least a portion of each receive semiconductor die 702. For instance, lens 704 may be disposed over receive RF antennas of receive semiconductor dies 702 but may leave other parts of receive semiconductor dies 702 uncovered.

The inventors have recognized that an interposer may be advantageous, in some embodiments, to enable precise positioning of receive elements in a receive array. For instance, in the example of FIG. 5, receiver 530 has an array of 26 receive semiconductor dies, though an interposer may be useful in embodiments with fewer or more dics. As shown in FIGS. 7A-7B, the receive semiconductor dies 702 are mounted on interposer 706. In some embodiments, the receive semiconductor dies 702 may be packaged with leads exposed for soldering to conductive pads on interposer 706. In some embodiments, it may be easier to precisely position the receive semiconductor dies 702 in an array (e.g., preserving half wavelength spacing between receive RF antennas in separate dies) on interposer 706 than if receive semiconductor dies 702 were mounted directly on a substrate. For example, while some available PCB mounting techniques are useful for producing large substrates with many components mounted thereon at low cost and with high robustness, such techniques afford low precision with which to mount the components. In some embodiments, using an interposer may leverage higher precision mounting techniques over a relatively small area (e.g., compared to the substrate on which the interposer is mounted), such that RF antennas are precisely positioned on the interposer while the overall cost of the device remains low. Alternatively or additionally, in some embodiments, interposer 706 may provide mechanical support for a long receive array to limit bending or warping due to the weight and size (e.g., row length) of the receive array. It should be appreciated that, in some embodiments, at least some semiconductor dies may be alternatively or additionally mounted directly on a substrate.

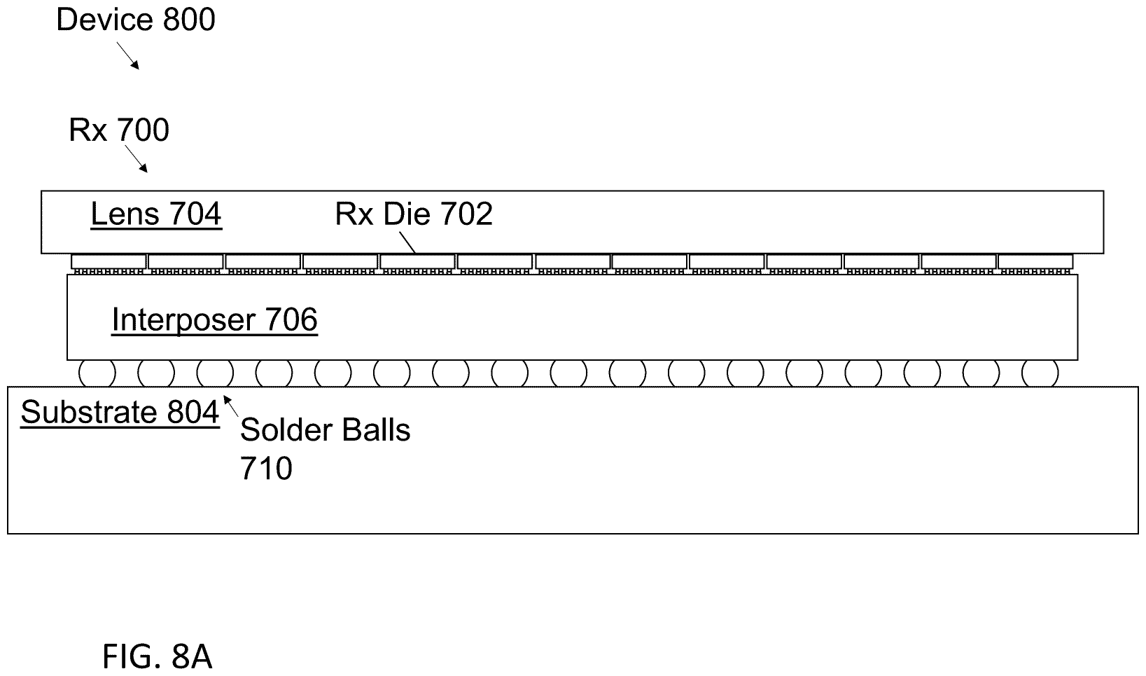

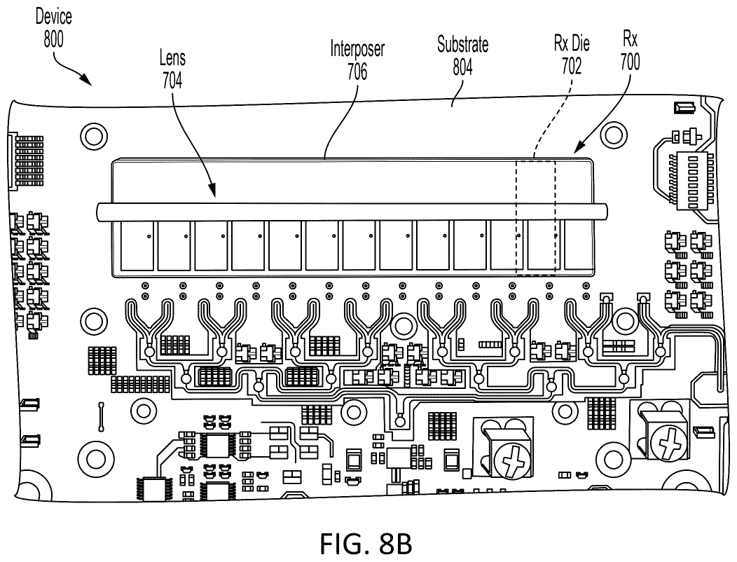

FIG. 8A is a side view of an example device 800 including a substrate 804 having receiver 700 and interposer 706 mounted thereon, in accordance with some embodiments of the technology described herein. FIG. 8B is a top view of device 800, in accordance with some embodiments of the technology described herein.

In some embodiments, device 800 may be configured as described herein for device 400 and/or 500, including in connection with FIGS. 4-5. For example, as shown in FIGS. 8A-8B, device 800 includes substrate 804 with interposer 706 of FIGS. 8A-8B mounted on substrate 804 using solder balls 710. In some embodiments, device 800 may include interface circuitry (not shown) mounted on substrate 804 and/or onboard receive semiconductor dies 702, such as including AFE and ADC circuitry configured to digitize offloaded data from receiver 700 and provide the digitized data to processing circuitry.

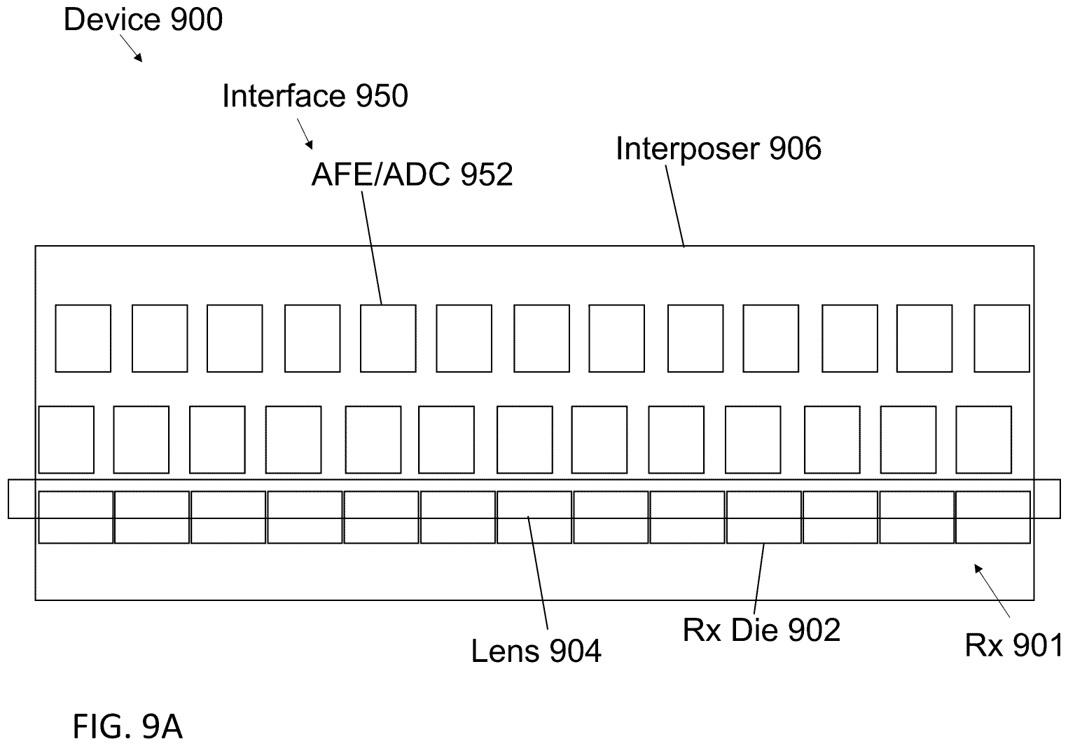

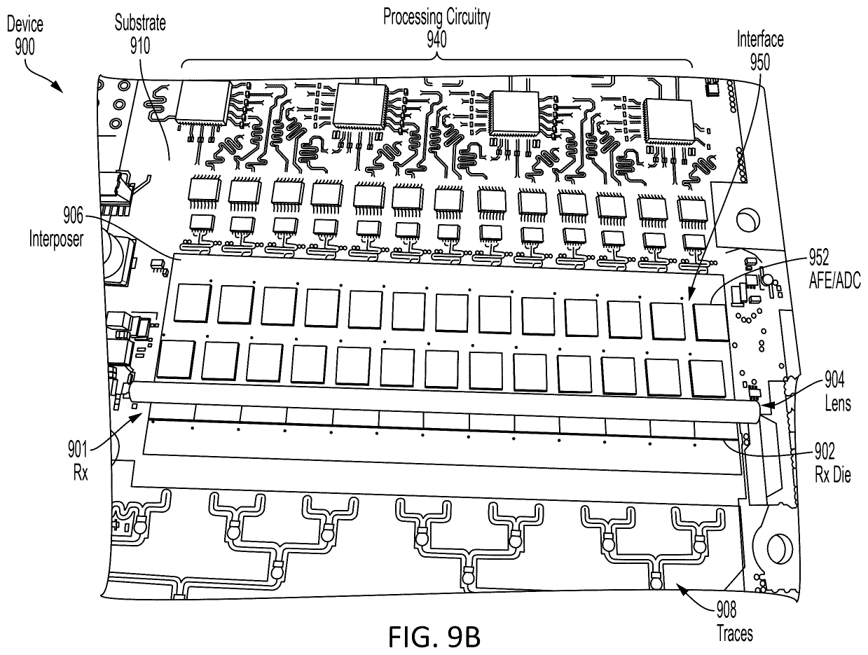

FIG. 9A is a top view of an example device 900 with receiver 700 and an alternative interposer 906 mounted thereon, which may be included in system 10, in accordance with some embodiments of the technology described herein.

In some embodiments, device 900 may be configured as described herein for device 800. For example, as shown in FIG. 9A, device 900 includes interposer 906 having a receiver 901 mounted thereon, which may be configured as described herein for receiver 700, such as including receive semiconductor dies 902 and lens 904. In addition, in FIG. 9A, interposer 906 further includes interface circuitry 950 mounted thereon. For instance, in FIG. 9A, interface circuitry 950 includes AFE/ADC units 952 mounted on interposer 906. In some embodiments, AFE/ADC units 952 may be configured as described herein for AFE/ADC units 552a-552z including in connection with FIG. 5.

FIG. 9B is a top view of device 900 further illustrating substrate 910 and processing circuitry 940, in accordance with some embodiments of the technology described herein.

As shown in FIG. 9B, processing circuitry 940 may be mounted on substrate 910. For example, AFE/ADC units 952 may be configured to offload digitized data from receiver 901 to processing circuitry 940 via solder balls (e.g., 710) to substrate 910 and then via traces on substrate 910. For instance, as further shown in FIG. 9B, traces 908 on substrate 910 may be configured to provide a reference RF signal (e.g., from signal generation circuitry) to receiver 901 via solder balls (e.g., 710), such as described herein for devices 400 and 500.

### Substrate Fixation Techniques

As described above, the inventors have recognized that developing Terahertz-based active sensing systems presents challenges. One such challenge is that components of Terahertz-based active sensing systems may be challenging to assemble reliably.

The inventors have recognized that assembling a Terahertz-based active sensing system may include mounting semiconductor dies (e.g., having antenna arrays integrated thereon) to a substrate, which typically involves heating the substrate to very high temperatures (e.g., 220° C. to 300° C.). Thermal expansion of a substrate under high heat (and/or compression thereafter) may skew positioning of, or even damage the semiconductor dies. For instance, thermal expansion of the substrate may cause antenna arrays integrated on the semiconductor dies to curve (e.g., away from a plane defined by the substrate), thereby deteriorating transmission or reception by the antenna array, or rendering the antenna array inoperable in cases of extreme warping. Some embodiments that include a lens (e.g., 1008 in FIG. 10B) may be susceptible to undesired electromagnetic dissipation due to uneven spacing with respect to the lens along the array (e.g., dissipation in an adhesive under the lens), though lens-less embodiments may similarly exhibit deteriorated performance.

Accordingly, in some embodiments, a fixture may be used while manufacturing a radar device to limit thermal expansion of a substrate of the RADAR device at least during mounting of some semiconductor dies to the substrate. For example, a RADAR device (e.g., 1000) including a substrate (e.g., 1004) defining a plane extending in a first direction and a second direction that are substantially orthogonal to one another, a first plurality of semiconductor dies (e.g., 1032), and a second plurality of semiconductor dies (e.g., 1022a) may be manufactured using a fixture (e.g., 1005). For example, manufacturing the RADAR device may include, after mounting the first plurality of semiconductor dies on the substrate, mechanically coupling the fixture to the substrate, and then, after mechanically coupling the fixture to the substrate, mounting the second plurality of semiconductor dies on the substrate. For instance the fixture may limit thermal expansion of the substrate while mechanically coupled to the substrate, thereby mitigating (e.g., reducing or eliminating) the impact of the thermal expansion (and/or thermal compression thereafter) on the first plurality of semiconductor dies that are mounted on the substrate, such that the first plurality of semiconductor dies are not damaged or substantially curved during manufacture. According to various embodiments, warpage of the substrate during manufacturing may be reduced from about 900 microns without using the fixture to less than 100 microns when using the fixture, such as less than 50 microns, less than 25 microns, less than 15 microns, between 5 microns and 50 microns, between 5 microns and 25 microns, and/or between 5 microns and 15 microns.

Accordingly, some embodiments provide for a method of manufacturing a device (e.g., 1000) comprising a substrate (e.g., 1004) defining a plane extending in a first direction (e.g., the y-direction in FIG. 10B) and a second direction (e.g., the x-direction in FIG. 10B) that are substantially orthogonal to one another, the device further comprising a first plurality of semiconductor dies (e.g., 1032) and a second plurality of semiconductor dies (e.g., 1022a), the method comprising:
(A) mounting the first plurality of semiconductor dies on the substrate;
(B) after mounting the first plurality of semiconductor dies on the substrate, mechanically coupling a fixture to the substrate; and
(C) after mechanically coupling the fixture to the substrate, mounting the second plurality of semiconductor dies on the substrate.

In some embodiments, the substrate comprises a first material (e.g., fiberglass) having a first thermal expansion coefficient (e.g., 16 parts-per-million per degree Celsius (ppm/° C.) and the fixture comprises a second material (e.g., nickel-iron alloy) having a second thermal expansion coefficient (e.g., 1.2 ppm/° C.) that is lower than the first thermal expansion coefficient. In some embodiments, the second thermal expansion coefficient is less than 5 ppm/° C., and/or less than 2 ppm/° C.

In some embodiments, the first plurality of semiconductor dies comprise a third material (e.g., semiconductor material) having a third thermal expansion coefficient (e.g., 3 ppm/° C.) that is lower than the first thermal expansion coefficient.

In some embodiments, the substrate comprises a first edge (e.g., 1007a) and a second edge (e.g., 1007b) opposite the first edge in the second direction; and mechanically coupling the fixture to the substrate comprises fastening the fixture to the substrate at a first point within a threshold distance of the first edge and at a second point within the threshold distance of the second edge. In some embodiments, fastening the fixture to the substrate at the first point comprises using a first fastener (e.g., 1006a) and fastening the fixture to the substrate at the second point comprises using a second fastener (e.g., 1006b).

In some embodiments, mounting the first plurality of semiconductor dies on the substrate comprises tiling a first row of semiconductor dies (e.g., 1032) of the first plurality of semiconductor dies on the substrate in the second direction; and mounting the second plurality of semiconductor dies on the substrate comprises tiling a first column (e.g., 1021) of semiconductor dies (e.g., 1022a) on the substrate in the first direction.

In some embodiments, the method further comprises, after mechanically coupling the fixture to the substrate, underfilling the first plurality of semiconductor dies.

In some embodiments, mounting the first plurality of semiconductor dies on the substrate comprises using a ball-grid-array (BGA); and mounting the second plurality of semiconductor dies on the substrate comprises wire-bonding the second plurality of semiconductor dies on the substrate.

In some embodiments, each of the first plurality of semiconductor dies comprises a first antenna array (e.g., 1489 in FIG. 14A) and first circuitry (e.g., 1480 in FIG. 14B) coupled to the first antenna array; and each of the second plurality of semiconductor dies comprises a second antenna array (e.g., 1132 in FIG. 11A) and second circuitry (e.g., 1160 in FIG. 11B) coupled to the second antenna array.

In some embodiments, the first antenna array comprises a first receive antenna array (e.g., 1489 in FIG. 14A); the first circuitry comprises first receive circuitry (e.g., 1480 in FIG. 14B); the second antenna array comprises a second transmit antenna array (e.g., 1132 in FIG. 11A); and the second circuitry comprises second transmit circuitry (e.g., 1160 in FIG. 11B).

In some embodiments, the method further comprises mounting signal generation circuitry (e.g., 1110 in FIG. 11A, 1410 in FIG. 14A) on the substrate and coupling the signal generation circuitry to the first plurality of semiconductor dies and to the second plurality of semiconductor dies.

In some embodiments, after using a fixture to limit thermal expansion and/or compression of a substrate during manufacture (e.g., mounting semiconductor dies to the substrate), the fixture may be mechanically decoupled from the substrate and a heat spreader may be mechanically coupled to the substrate at points where the fixture was mechanically coupled to the substrate during manufacture.

Some embodiments provide for a device (e.g., 1000), comprising:
(A) a substrate (e.g., 1004) defining a plane extending in a first direction (e.g., x-direction) and a second direction (e.g., y-direction) that are substantially orthogonal to one another, the substrate comprising a first point (e.g., 1001a) and a second point (e.g., 1001b) that are configured for mechanically coupling to a fixture (e.g., 1005) during manufacture of the device;
(B) a plurality of semiconductor dies (e.g., 1032) mounted on the substrate and each having integrated thereon: a first antenna array (e.g., 1439 in FIG. 14A) comprising a first plurality of antennas (e.g., 1486 in FIG. 14B); and first circuitry (e.g., 1480 in FIG. 14B) coupled to the first plurality of antennas; and
(C) a heat spreader (e.g., 1009) mechanically coupled to the substrate at the first point and at the second point.

In some embodiments, the first point is configured to receive a first fastener (e.g., 1006a in FIG. 10B) to mechanically couple the substrate to the fixture during manufacture; the second point is configured to receive a second fastener (e.g., 1006a in FIG. 10B) to mechanically couple the substrate to the fixture during manufacture; and the device comprises the first fastener mechanically coupling the heat spreader to the substrate at the first point and the second fastener mechanically coupling the heat spreader to the substrate at the second point (e.g., FIG. 10C).

In some embodiments, the plurality of semiconductor dies are disposed, in the second direction, between the first point and the second point.

In some embodiments, the substrate comprises a first edge (e.g., 1007a) and a second edge (e.g., 1007b) opposite the first edge in the second direction; the first point is within a threshold distance of the first edge; and the second point is within the threshold distance of the second edge.

In some embodiments, the plurality of semiconductor dies comprises a first row of semiconductor dies mounted on the substrate and tiled in the second direction, the first row of semiconductor dies having a first length (e.g., L1) in the first direction and a second length (e.g., L2) in the second direction that is at least ten times the first length.

FIG. 10A is a side view of a cross-section of an example device 1000 having a substrate 1004 with a receive semiconductor die 1032 mounted thereon and a fixture 1005 used for assembling device 1000, which may be included in system 10, in accordance with some embodiments of the technology described herein. FIG. 10B is a top view of device 1000 mechanically coupled to fixture 1005 further illustrating the transmitter 1020 of the device 1000, in accordance with some embodiments of the technology described herein.

In some embodiments, device 1000 may be configured as described herein for device 400 including in connection with FIGS. 4A-4B. For example, as shown in FIG. 10B, substrate 1004 may define a plane extending in a first direction (e.g., the y-direction in FIG. 10B) and a second direction (e.g., the x-direction in FIG. 10B) that are substantially orthogonal to one another.

In some embodiments, a first semiconductor die may be mounted on substrate 1004 having integrated thereon a first antenna array including a first plurality of antennas and first circuitry coupled to the first plurality of antennas. For example, in FIGS. 10A-10B, receive semiconductor die 1032 is shown mounted on substrate 1004. In some embodiments, receive semiconductor die 1032 may be configured as described herein for receive semiconductor die 1432 including in connection with FIGS. 14A-14B, such as including a receive antenna array (e.g., 1439) including a plurality of receive antennas (e.g., 1486) and receive circuitry (e.g., 1480) coupled to the plurality of antennas.

In some embodiments, device 1000 may include a first row of semiconductor dies mounted on the substrate tiled in the second direction and including semiconductor dies spaced from one another in the second direction. For example, as shown in FIG. 10B, device 1000 includes a first row of receive semiconductor dies 1032 including tiled in the x-direction, with ones of receive semiconductor dies 1032 spaced at a distance from one another the in the x-direction. In some embodiments, each receive semiconductor die 1032 of the first row may include a plurality of receive antennas (e.g., 1486) and receive circuitry (e.g., 1480) coupled to the second plurality of antennas. In some embodiments, each receive semiconductor die 1032 may include wafer-level chip-scale packaging (WLCSP), such as a thin dielectric (e.g., polyimide) layer supporting the die (e.g., around a bottom redistribution layer). For example, WLCSP may limit displacement and/or deformation of receive semiconductor dies 1032 due to thermal expansion and/or compression (e.g., of substrate 1004) within an operational temperature range (e.g., −40° C. to 85° C.) of device 1000.

In some embodiments, the first row of semiconductor dies may have a first length in the first direction and a second length in the second direction. For example, the row of receive semiconductor dies 1032 shown in FIG. 10B has a first length L1 in the y-direction and a second length L2 in the x-direction. In some embodiments, second length L2 may be at least five times, at least seven times, at least ten times, and/or at least twenty times first length L1. The inventors have recognized that long arrays such as having a second length of at least 10 times and/or at least 20 times the first length may be especially susceptible to thermal expansion of the substrate during assembly, though other array configurations may be used. In some embodiments, the first row of semiconductor dies may include at least 10 receive semiconductor dies 1032, with center-to-center spacing of the semiconductor dies being at least as long in the x-direction as each semiconductor die of the row is in the y-direction. In the illustrated embodiment, the first row of semiconductor dies has 26 receive semiconductor dies, though other numbers of receive semiconductor dies may be included. While a single row of receive semiconductor dies is shown in FIG. 10B, it should be appreciated that multiple rows may be included in other embodiments.

As shown in FIG. 10B, device 1000 further includes transmit semiconductor dies 1022a and 1022b, which may be configured as described herein for transmit semiconductor dies 422a and 422b, including in connection with FIGS. 4A-4B. In some embodiments, the first semiconductor die may be alternatively or additionally configured as a transmit semiconductor die, such as described herein for transmit semiconductor die 1122 including in connection with FIGS. 11A-11B. For example, first column 421 may have a first length in the x-direction and a second length in the y-direction that is at least ten times the first length (e.g., in the configuration shown in FIG. 10B for the row of receive semiconductor dies 1032).

While not labeled in FIG. 10B, in some embodiments, device 1000 may further include signal generation circuitry mounted on the substrate and coupled to each of the first row of semiconductor dies. Example signal generation circuitry that may be included in device 1000 has been described above including in connection with FIG. 4A and is described further herein including in connection with FIG. 14A below.

In some embodiments, during manufacture of device 1000, fixture 1005 may be mechanically coupled to substrate 1004 to limit thermal expansion of substrate 1004. For example, as shown in FIG. 10B, device 1000 includes a first fastener 1006a and a second fastener 1006b mechanically coupling fixture 1005 to substrate 1004. In the illustrated example, first fastener 1006a and second fastener 1006b are shown as screws, though other fasteners may be used instead or in addition to screws, e.g., nails, nuts and bolts, clamps, clips, pins, and/or ties.

In some embodiments, during manufacture of device 1000, first fastener 1006a and second fastener 1006b may be positioned within a threshold distance of respective edges of substrate 1004. For example, as shown in FIG. 10B, substrate 1004 includes a first edge 1007a and a second edge 1007b opposite first edge 1007a in the x-direction, with first fastener 1006a positioned proximate first edge 1007a and second fastener 1006b positioned proximate second edge 1007b. For instance, the threshold distance may be small enough that fixture 1007 can limit curvature of substrate 1004 due to thermal expansion. In the illustrated embodiment, no circuitry (e.g., semiconductor dies) are positioned between first fastener 1006a and first edge 1007a or between second fastener 1006b and second edge 1007b. As further shown in FIG. 10B, alternative or additional fasteners (not labeled) may mechanically couple fixture 1005 to substrate 1004, the fasteners being spaced from one another in the x-direction along an outer perimeter of substrate 1004, such as to further limit thermal expansion of substrate 1004.

In some embodiments, fixture 1005 may be mechanically coupled to substrate 1004 after at least some semiconductor dies (e.g., 1032) have been mounted to substrate 1004 and before substrate 1004 has been heated as part of a soldering process. For example, fixture 1005 may be mechanically coupled to substrate 1004 after mounting at least some of receive semiconductor dies 1032 and before mounting at least some of transmit semiconductor dies 1022a.

In some embodiments, substrate 1004 may include a first material having a first thermal expansion coefficient and fixture 1005 may have a second material having a second thermal expansion coefficient that is lower than the first thermal expansion coefficient. For example, substrate 1004 may include fiberglass, such as where substrate 1004 includes a printed circuit board, and/or fixture 1005 may include a nickel-iron alloy. For instance, the first thermal expansion coefficient of substrate 1004 be between 10 ppm/° C. and 20 ppm/° C., such as 16 ppm/° C., whereas the second thermal expansion coefficient of fixture 1005 may be less than 5 ppm/° C., less than 2 ppm/° C., between 1.2 ppm/° C. and 5 ppm/° C., and/or between 1.2 ppm/° C. and 2 ppm/° C.

In some embodiments, receive semiconductor die 1032 may include a third material having a third thermal expansion coefficient that is lower than the first thermal expansion coefficient of substrate 1004, such as semiconductor material having a thermal expansion coefficient between 1.2 ppm/° C. and 5 ppm/° C., such as 3 ppm/° C.

In some embodiments, device 1000 may be manufactured at least in part by mounting a first plurality of semiconductor dies on substrate 1004, after mounting the first plurality of semiconductor dies on substrate 1004, mechanically coupling fixture 1005 to substrate 1004, and, after mechanically coupling fixture 1005 to substrate 1004, mounting a second plurality of semiconductor dies on the substrate. For example, the first plurality of semiconductor dies may include receive semiconductor dies 1032 each including a receive antenna array and receive circuitry, such as described above. Alternatively or additionally, the second plurality of semiconductor dies may include transmit semiconductor dies 1022a, such as including a transmit antenna array (e.g., 1132 in FIG. 11A) and transmit circuitry (e.g., 1160 in FIG. 11B) coupled to the transmit antenna array.

In some embodiments, mounting the first plurality of semiconductor dies on substrate 1004 may include tiling a first row of semiconductor dies of the first plurality of semiconductor dies on substrate 1004 in the second direction. For example, receive semiconductor dies 1032 may be tiled on substrate 1004 in the x-direction in FIG. 10B. In some embodiments, mounting the second plurality of semiconductor dies on the substrate may include tiling a first column of semiconductor dies on substrate 1004 in the first direction. For example, transmit semiconductor dies 1022a may be tiled on substrate 1004 in first column 1021 in the y-direction in FIG. 10B.

In some embodiments, mechanically coupling fixture 1005 to substrate 1004 may include fastening fixture 1005 to substrate 1004 at a first point within a threshold distance of first edge 1007a and at a second point within the threshold distance of second edge 1007b, such as using first fastener 1006a and second fastener 1006b.

In some embodiments, manufacturing device 1000 may further include, after mechanically coupling fixture 1005 to substrate 1004, underfilling the first plurality of semiconductor dies. For example, mounting the first plurality of semiconductor dies on substrate 1004 may include using a ball-grid-array (BGA), such as to mount receive semiconductor dies 1032. In some embodiments, mounting the second plurality of semiconductor dies on substrate 1004 may include wire-bonding the second plurality of semiconductor dies on substrate 1004, such as for transmit semiconductor dies 1022a. It should be appreciated that receive semiconductor dies may be wire-bonded and/or transmit semiconductor dies may be alternatively or additionally BGA mounted in some embodiments.

In some embodiments, manufacturing of device 1000 may further include mounting signal generation circuitry (e.g., 1110 in FIG. 11A, 1410 in FIG. 14A) on substrate 1004 and coupling the signal generation circuitry to the first plurality of semiconductor dies and to the second plurality of semiconductor dies, such as to receive semiconductor dies 1032 and/or transmit semiconductor dies 1022a.

In some embodiments, at least some surface mount components may be mounted to substrate 1004 prior to mounting receive semiconductor dies 1032 to substrate 1004. In some embodiments, a lens 1008 may be mounted over receive semiconductor dies 1032 and/or over transmit semiconductor dies 1022a after attaching the receive semiconductor dies 1032 to substrate 1004 and/or after attaching transmit semiconductor dies 1022a to substrate 1004. In some embodiments, lens 1008 may be omitted.

It should be appreciated that transmit semiconductor dies 1022b may be configured as described herein for transmit semiconductor dies 1022a, such as shown in FIG. 10B tiled in a transmitter column 1021.

FIG. 10C is a top view of device 1000 with fixture 1005 removed and replaced by heat spreader 1009, in accordance with some embodiments of the technology described herein.

In some embodiments, substrate 1004 may include a first point and a second point that are configured for mechanically coupling to a fixture during manufacture of device 1000. For example, as described above in connection with FIG. 10B, first point 1001a and second point 1001b may be configured for mechanically coupling to fixture 1005 during manufacture (e.g., after mounting at least some receive semiconductor dies 1032 and before mounting at least some transmit semiconductor dies 1022a). For instance, as shown in FIG. 10B, first point 1001a may be configured to receive first fastener 1006a to mechanically couple substrate 1004 to fixture 1005 during manufacture and the second point 1001b may be configured to receive second fastener 1006a to mechanically couple substrate 1004 to fixture 1005 during manufacture.

In some embodiments, heat spreader 1009 of device 1000 may be mechanically coupled to substrate 1004 at first point 1004a and at second point 1004b. For example, as shown in FIG. 10C, first fastener 1006a may mechanically couple heat spreader 1009 to substrate 1004 at first point 1001a and second fastener 1006b mechanically couple heat spreader 1009 to substrate 1004 at second point 1001b. For instance, fixture 1005 may be mechanically decoupled from substrate 1004 (e.g., by removing fasteners 1006a and 1006b) and replaced with heat spreader 1009. In some embodiments, heat spreader 1009 may be fastened to substrate 1004 with the same type of fasteners 1006a and 1006b at the same points 1001a and 1001b, respectively, where fixture 1005 is shown fastened to substrate 1004 in FIG. 10B. For example, the screws shown as fasteners 1006a and 1006b in FIG. 10B may be the same size as the screws shown as fasteners 1006a and 1006b in FIG. 10C. For instance, the same exact fasteners used for mechanically coupling to fixture 1005 may be used for mechanically coupling to heat spreader 1009, and/or the fasteners may be replaced with fasteners of the same type (e.g., screws replaced with screws of the same size).

In some embodiments, heat spreader 1009 may be configured as described herein for heat spreader 307 including in connection with FIG. 3.

FIG. 10D is a bottom view of device 1000 further illustrating interface circuitry 1050, in accordance with some embodiments of the technology described herein. In some embodiments, interface circuitry 1050 may be configured as described herein for interface circuitry 450 including in connection with FIG. 4A. For example, as shown in FIG. 10D, interface circuitry 1050 includes AFE/ADC units 1052 mounted on substrate 1004. In the illustrated embodiment, interface circuitry 1050 may be communicatively coupled to receiver 1030 via traces within substrate 1004. While the illustrated embodiment shows interface circuitry 1050 on an opposite side of substrate 1004 from receiver 1030, it should be appreciated that interface circuitry 1050 and receiver 1030 may be on a same side of a substrate, and/or on separate substrates, as embodiments described herein are not so limited.

While processing circuitry is not shown in FIGS. 10A-10D, it should be appreciated that processing circuitry (e.g., 440) may be mounted on substrate 1004 or on another substrate as embodiments described herein are not so limited.

### Transmitter Architecture

As described above, the inventors have developed techniques for mitigating the impact of atmospheric attenuation to facilitate RADAR ranging at Terahertz frequencies to detect target objects at a large distance from a RADAR device. The inventors have recognized that atmospheric attenuation may be mitigated, at least in part, using techniques that increase the aperture size of the transmitter without necessarily adding more transmit elements to the transmitter.

In some embodiments, RF antennas may be arranged on a transmit semiconductor die in a two-dimensional array. While a two-dimensional array results in a loss of elevation resolution when compared to a one-dimensional array having the same number of elements, it confers a number of important benefits. Chip layout may be simplified because it is easier, in some embodiments, to distribute a reference RF signal to two mirrored rows of elements (e.g., from opposite edges of the die) than to a single row having the same total number of elements. For example, as a result of arranging 32 RF antennas in two columns and 16 rows on a single transmit semiconductor die, instead of splitting the reference RF signal into 32 parts from one edge of the chip, the reference RF signal can enter two opposite edges of the die and only needs to be split into 16 parts on each side of the die, which is easier than splitting one signal into 32 parts. In addition, a two-dimensional array may have a larger aperture size than a one-dimensional array having the same number of elements, resulting in larger transmitter gain. For instance, a 16×2 array may transmit the same amount of power as a 32×1 array, but the aperture size of the 16×2 array is larger, which increases overall transmitter gain and results in greater range from the transmitter for the same link budget.

In some embodiments, a device (e.g., 1100 in FIG. 11A) comprises a substrate (e.g., 1104) defining a plane extending in first and second directions substantially orthogonal to one another (e.g., y and x). In some embodiments, the device further comprises a transmitter (e.g., 1120) mounted on the substrate, the transmitter comprising a first transmit semiconductor die (e.g., 1122) having integrated thereon first transmit circuitry (e.g., 1160 in FIG. 11B) configured to generate first RF signals based on a reference RF signal and a first transmit antenna array (e.g., 1132) comprising a plurality of RF antennas (e.g., 1170) configured to transmit the first RF signals and having a first aperture with a first length extending in the first direction (e.g., y) and a first width extending in the second direction (e.g., x), the first length being larger than the first width. In some embodiments, the plurality of RF antennas is arranged in a two-dimensional grid and has mirror symmetry across a line (e.g., 1102) extending in the first direction (e.g., y).

In some embodiments, the device further comprises a receiver (e.g., 430 in FIG. 4A) mounted on the substrate, the receiver comprising a first receive semiconductor die (e.g., 1432 in FIG. 14A) having integrated thereon a first receive antenna array (e.g., 1439) comprising a plurality of RF antennas (e.g., 1486 in FIG. 14B) configured to receive second RF signals and having a second aperture with a second length extending in the first direction (e.g., y) and a second width extending in the second direction (e.g., x), the second length being smaller than the second width, and first receive circuitry (e.g., 1480 in FIG. 14B) configured to obtain the second RF signals via the plurality of RF antennas of the first receive antenna array.

FIG. 11A is a schematic view of a substrate 1104 of an example device 1100 having a transmitter 1120, which may be included in system 10, in accordance with some embodiments of the technology described herein.

In some embodiments, device 1100 may be configured as described herein for device 400 and/or 500 including in connection with FIGS. 4-5. For example, as shown in FIG. 11A, device 1100 includes substrate 1104 having mounted thereon signal generation circuitry 1110 and transmitter 1120.

In some embodiments, transmitter 1120 may have a transmit semiconductor die having integrated thereon transmit circuitry (1160, FIG. 11B) configured to generate RF signals based on a reference RF signal and a transmit antenna array having RF antennas configured to transmit the RF signals. For example, as shown in FIG. 11A, transmitter 1120 has a transmit semiconductor die 1122 with a plurality of transmit elements 1124 and transmit antenna array 1132. For instance, each transmit element 1124 may have a portion of the transmit circuitry configured to feed a respective transmit antenna of transmit antenna array 1132.

In some embodiments, an RF transmit antenna array may have a transmit aperture with a transmit aperture length extending in a first direction and a transmit aperture width extending in a second direction, the transmit aperture length being larger than the transmit aperture width. For example, as shown in FIG. 11A, antenna array 1132 has more antennas in the y direction than in the x direction, which pay provide a larger transmit aperture length in the y direction than transmit aperture width in the x direction.

In some embodiments, transmit semiconductor die 1122 may have an RF transmit antenna array arranged in a two-dimensional grid. For example, as shown in FIG. 11A, transmit antenna array 1132 is arranged in first and second columns 1106a and 1106 extending in the first direction (e.g., y-direction), with each column having multiple rows extending in the second direction (e.g., x-direction). In some embodiments, the RF transmit circuitry onboard transmit semiconductor die 1122 may be further arranged in the two-dimensional grid. For example, transmit circuitry of transmit elements 1124 may be arranged in a first transmit circuitry portion in first column 1106a and configured to feed the antennas in first column 1106a and a second transmit circuitry portion in second column 1106b configured to feed the antennas in second column 1106b. For instance, the first transmit circuitry portion may include the transmit circuitry of transmit elements 1124 shown in first column 1106a in FIG. 11A and the second transmit circuitry portion may include the transmit circuitry of transmit elements 1124 shown in second column 1106b in FIG. 11A. In FIG. 11A, first and second columns 1106a and 1106b have 8 rows, though it should be appreciated that any number of rows may be included, such as two or more rows (e.g., more rows than columns).

In some embodiments, transmit semiconductor die 1122 may have components with mirror symmetry across a line extending in the first direction. For example, in FIG. 11A, first and second columns 1106a and 1106b of transmit antenna array 1132 mirror one another across a symmetry line 1102 that separates first and second columns 1106a and 1106b. For instance, antennas of transmit antenna array 1132 in first column 1106a may have mirror symmetry with corresponding antennas of transmit antenna array 1132 in second column 1106b. In some embodiments, the first and second transmit circuitry portions may be further mirrored across symmetry line 1102 separating first and second columns 1106a and 1106b. For example, a first transmit circuitry portion, including transmit circuitry in first column 1106a configured to feed antennas of first column 1106a, may have mirror symmetry with a second transmit circuitry portion across symmetry line 1102, the second transmit circuitry portion including transmit circuitry in second column 1106b configured to feed antennas of second column 1106b.

In some embodiments, transmit semiconductor die 1122 may further include multiple interfaces configured to receive a reference RF signal from signal generation circuitry 1110 and provide the reference RF signal to transmit elements 1124. For example, in FIG. 11A, transmit semiconductor die 1122 has a first interface 1150a and a second interface 1150b, with first interface 1150a coupled between signal generation circuitry 1110 and transmit elements 1124 of first column 1106a and second interface 1150b coupled between signal generation circuitry 1110 and transmit elements 1124 of second column 1106b.

In some embodiments, first interface 1150a may be positioned within a threshold distance of a first outer edge of transmit semiconductor die 1122 and second interface 1150b may be positioned within the threshold distance of a second outer edge of transmit semiconductor die 1122 opposite the first outer edge. For example, as shown in FIG. 11A, transmit semiconductor die 1122 has a first outer edge 1126a and a second outer edge 1126b that is opposite first outer edge 1126a (e.g., along the x-axis), and first interface 1150a includes a first power divider 1154a disposed proximate first outer edge 1126a and second interface 1150b includes a second power divider 1154b disposed proximate second outer edge 1126b. In some embodiments, first power divider 1154a may be positioned within a threshold distance of first outer edge 1126a and second power divider 1154b may be positioned within the threshold distance of second outer edge 1126b. For instance, the threshold distance may be a distance from the outer edge of the die in which bond pads are disposed for connecting to substrate 1104 (e.g., via wire bond). It should be appreciated that first and second power dividers 1154a and 1154b may both be within the same threshold distance of respective outer edges 1126a and 1126b without necessarily being spaced identically from respective outer edges 1126a and 1126b (e.g., one power divider may be more closely spaced to the respective outer edge).

In some embodiments, power dividers of transmit semiconductor die 1122 may be configured to divide a reference RF signal from signal generation circuitry 1110 into a plurality of reference RF signals and provide the plurality of reference RF signals to transmit circuitry of transmit semiconductor die 1122 for feeding antenna array 1132. For example, power divider 1154a may be configured to receive a reference RF signal from signal generation circuitry 1110 (e.g., via bonds pads at first outer edge 1126a), divide the reference RF signal into a reference RF signal for each respective antenna of first column 1106a, and provide the reference RF signals to the respective antennas of first column 1106a. Similarly, power divider 1154b may be configured to receive the reference RF signal from signal generation circuitry 1110 (e.g., via bond pads at second outer edge 1126b), divide the reference RF signal into a reference RF signal for each respective antenna of second column 1106b, and provide the reference RF signals to the respective antennas of second column 1106b. For instance, as shown in FIG. 11A, first and second columns 1106a and 1106b have 8 rows of transmit elements 1124, and power dividers 1154a and 1154b are each configured as a 1-to-8 (1:8) power divider.

In some embodiments, transmit circuitry of transmit semiconductor die 1122 may be configured to propagate reference RF signals, from first and second interfaces 1150a and 1150b to respective first and second columns 1106a and 1106b of antenna array 1132, in opposite propagation directions. For example, in FIG. 11A, transmit circuitry of transmit elements 1124 in first column 1106a may be configured to propagate the reference RF signals from power divider 1154a in a first propagation direction (e.g., parallel to the x-direction) from first outer edge 1126a to antenna array 1132, and transmit circuitry of transmit elements 1124 in second column 1106b may be configured to propagate the reference RF signals from power divider 1154b in a second propagation direction (e.g., parallel to the x-direction) from second outer edge 1126b to antenna array 1132. For instance, in FIG. 11A, first and second outer edges 1126a and 1126b are opposite one another along the x-axis, and the first and second propagation directions are opposite one another along the x-axis.

While a single transmit semiconductor die 1122 is shown in FIG. 11A, a device may have multiple transmit semiconductor dies 1122 shown as configured in FIG. 11A, such as organized into one or more columns, such as shown in FIGS. 4-5. For example, transmit semiconductor die 1122 may be a first die (e.g., 422a) and device 1100 may further include a second transmit semiconductor die (e.g., 422b) configured as described herein for die 1122, with mirror symmetry across symmetry line 1102. Alternatively or additionally, device 1100 may further include a transmit semiconductor die (e.g., 422c) configured as described herein for die 1122, with mirror symmetry across another symmetry line (e.g., extending parallel to the y-axis).

While signal generation circuitry 1110 is shown on the same substrate 1104 as transmit semiconductor die 1124 in FIG. 11A, signal generation circuitry 1110 may be on a separate substrate in some embodiments.

In some embodiments, device 1100 may further have a receiver (e.g., 430 and/or 530) with a receive antenna array having a receive aperture with a receive aperture length extending in the first direction (e.g., y direction) and a receive aperture width extending in the second direction (e.g., x direction), the receive aperture length being smaller than the receive aperture width, such as described above and further herein.

FIG. 11B is a circuit diagram of transmit circuitry 1160 of transmitter 1120, in accordance with some embodiments of the technology described herein.

In some embodiments, interface 1150a may further include frequency multiplication circuitry configured to up-convert a reference RF signal from signal generation circuitry 1110 to a center frequency of or closer to the center frequency of transmission. For example, where signal generation circuitry 1110 and transmit semiconductor die 1122 are mounted on substrate 1104, the reference RF signal may be propagated from signal generation circuitry 1110 to transmit semiconductor die 1122 using traces on substrate 1104, which may not have suitable characteristics for propagating signals at THz frequencies. Rather, in some embodiments, the reference RF signal may be propagated from signal generation circuitry 1110 to transmit semiconductor die 1122 at a relatively low center frequency (e.g., 17.22 GHz), and interface 1150a may have a frequency multiplier 1152a configured to up-convert the reference RF signal to a center frequency (e.g., 155 GHz) closer to transmit center frequency (e.g., 310 GHz). In the illustrated embodiment, frequency multiplier 1164a is configured to provide the up-converted reference RF signal to power divider 1154a to be divided among transmit elements 1124. For example, frequency multiplication may be less noisy to perform a signal having a large power level (e.g., prior to power division.

In some embodiments, transmit semiconductor die 1122 may have transmit circuitry 1160 configured to generate RF signals based on the reference RF signal obtained from signal generation circuitry 1110 and feed the RF signals to transmit antenna array 1132. For example, as shown in FIG. 11B, transmit element 1124 includes an antenna 1170 of transmit antenna array 1132a coupled to a phase shifter 1162, amplifier 1164, frequency multiplier 1166, a balanced power amplifier 1168 of transmit circuitry 1160.

In some embodiments, phase shifter 1162 may be configured to introduce a beamforming phase shift to RF signals transmitted by antenna 1170, such as with phase shifters 1162 of some or all transmit elements 1124 providing a different phase shift so as to steer transmitted RF signals at a particular angle (e.g., in elevation and/or azimuth). In some embodiments, amplifier 1164 may be configured to add power to phase shifted signals prior to multiplication by frequency multiplier 1166, which may mitigate at least some noise from frequency multiplication.

In some embodiments, frequency multiplier 1166 may be configured to output an RF signal having a center frequency desired for transmission via antenna 1170. For example, in FIG. 11B, some frequency multiplication to reach the center frequency desired for transmission may be performed by frequency multiplier 1152a of interface 1150a and some frequency multiplication may be performed by frequency multiplier 1166. For instance, a 9× multiplication may be performed by frequency multiplier 1152a (e.g., from 17.22 GHz to 155 GHz), and a 2× multiplication (e.g., frequency doubling) may be performed by frequency multiplier 1166. For instance, frequency multiplication by a larger scalar may be performed with less noise impact on signals having higher power levels, such as 9× multiplication on a received reference RF signal at full power followed by 2× multiplication on several reference RF signals divided from the reference RF signal into smaller power levels.

In some embodiments, balanced power amplifier 1168 may be configured to amplify the RF signal to a power level suitable for transmission via antenna 1170. For instance, the power level may be set based on a desired transmission range (e.g., object detection range) and the known attenuation at the center frequency of the transmitted RF signal. In some embodiments, a balanced power amplifier may be used where antenna 1170 is fed using a balanced feed, (e.g., for a balanced fed dipole or patch), whereas an unbalanced power amplifier may be used antenna 1170 is fed using an unbalanced feed (e.g., for an unbalanced fed dipole, patch, or monopole).

While not shown in FIG. 11B, it should be appreciated that power divider 1154a may be coupled to the transmit elements 1124 of first column 1106a, and that power divider 1154b may be coupled to transmit elements 1124 of second column 1106b and configured as described herein for (e.g., mirrored with respect to) the portion of device 1100 shown in FIG. 11B.

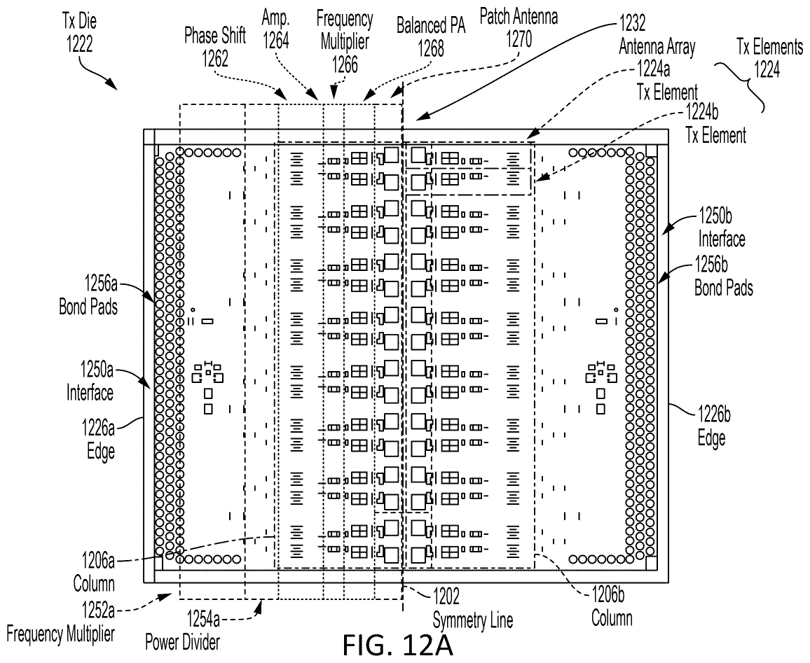

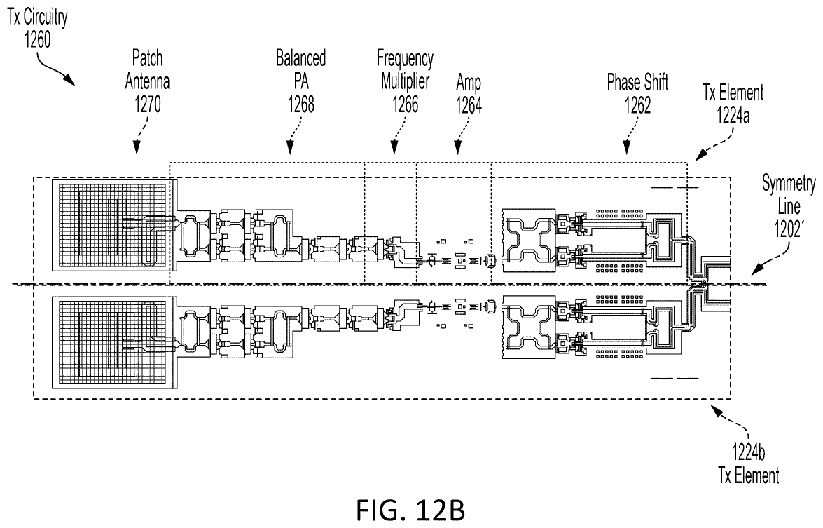

FIG. 12A is a top view of an example transmit semiconductor die 1222 that may be included in transmitter 1120, in accordance with some embodiments of the technology described herein. FIG. 12B is a magnified view of transmit circuitry 1260 of transmit elements 1224a and 1224b, in accordance with some embodiments of the technology described herein.

In some embodiments, transmit semiconductor die 1222 may be configured as described herein for transmit semiconductor die 1122. For example, as shown in FIG. 12A, transmit semiconductor die 1222 includes transmit elements 1224 and antenna array 1232 arranged in first and second columns 1206a and 1206b having mirror symmetry across symmetry line 1202. Also shown in FIG. 12A, transmit semiconductor die 1222 has a first interface 1250a at a first outer edge 1226a, including frequency multiplier 1252a and power divider 1254a and further including bond pads 1256a, and a second interface 1250b at a second outer edge 1226b, including frequency multiplier 1252b and power divider 1254b and further including bonds pads 1256b. For instance, in some embodiments, bond pads 1256a and 1256b may be wire bonded to a substrate (e.g., 1104) such that antenna array 1232 faces away from the substrate.

In some embodiments, transmit elements 1224 may be configured as described herein for transmit elements 1124. For example, as shown in FIGS. 12A-12B, each transmit element 1224 includes an antenna 1270 of antenna array 1232 and transmit circuitry 1260 including phase shifter 1262, amplifier 1264, frequency multiplier 1266, and balanced power amplifier (PA) 1268. In FIGS. 12A-12B, antennas 1270 are configured as patch antennas with balanced feeds, which may be advantageous for transmitting and receiving circularly polarized RF signals to mitigate the impact of raindrops on reception, though other antenna configurations (e.g., dipoles) may be used.

In some embodiments, transmit elements 1224 may be arranged in pairs of transmit elements that are further mirrored with respect to one another across lines that extend orthogonal to symmetry line 1202. For example, in FIGS. 12A-12B, a pair of transmit elements 1224 of second column 1206b are labeled 1224a and 1224b, and are shown in FIG. 12B mirrored across a symmetry line 1202′ that separates transmit elements 1224a and 1224b from one another. For instance, symmetry lines 1202′ may extend between rows of transmit elements 1224. In some embodiments, such pairs of transmit elements 1224a and 1224b may be configured to operate as transmit channel pairs. For example, having transmit channel pairs arranged in a mirror configuration may make further efficient use of space on the transmit semiconductor die.

### Receiver Architecture

As described above, the inventors have developed techniques for mitigating the impact of atmospheric attenuation to facilitate RADAR ranging at Terahertz frequencies to detect target objects at a large distance from a RADAR device. The inventors have recognized that atmospheric attenuation may be mitigated, at least in part, using techniques that increase the sensitivity of a RADAR receiver. In some embodiments, a receiver may be made more sensitive by increasing the gain of a mixer of the receiver using a reflector coupled between the mixer and an amplifier and configured to reflect at least some RF energy generated by the mixer back into the mixer. For example, by reflecting RF energy back into the mixer (e.g., at frequencies other than those of a mixed signal output by the mixer), RF energy that might otherwise be wasted may be converted into useful signal energy (e.g., within a mixed signal used for downstream processing), improving the efficiency and gain of the mixer and resulting in increased sensitivity.

In some embodiments, a RADAR device (e.g., 1400 in FIG. 14A) comprises a substrate (e.g., 1404) and a receiver (e.g., 1430) mounted on the substrate. For example, the device, substrate, and receiver may be configured as described herein including in connection with FIGS. 4-5.

In some embodiments, the receiver may comprise a first receive semiconductor die (e.g., 1432) having integrated thereon a first RF antenna (e.g., 1486 in FIG. 14B) configured to receive RF signals and first receive circuitry (e.g., 1480). In some embodiments, the first receive circuitry may comprise a first mixer (e.g., 1484) coupled to the first RF antenna and configured to mix an RF signal obtained using the first RF antenna with a reference RF signal (e.g., from signal generation circuitry 1410) to output a first mixed signal. For example, the RF signal may be obtained using the first RF antenna to receive an RF signal and further using a filter (e.g., 1504) coupled between the first RF antenna and the first mixer. Mixing the RF signal with the reference signal may cause the resulting first mixed signal to have frequency content indicating a distance between the receiver and a target object.

In some embodiments, the first receive circuitry may further include a first amplifier (e.g., 1488) coupled to the first mixer and configured to amplify the first mixed signal output by the first mixer. For example, the first mixed signal may be provided to downstream processing circuitry (e.g., 1440) to determine a distance between the receiver and a target object therefrom.

In some embodiments, the first receive circuitry may further include a first reflector coupled between the first mixer and the first amplifier. For example, the first reflector may be configured to reflect at least some RF energy generated by the first mixer back into the first mixer. For instance, the first reflector may be configured to reflect at least some RF energy at the center frequency of the RF signal back into the mixer to be recycled into energy within the first mixed signal, thereby increasing the efficiency and mixer gain of the mixer, resulting in higher sensitivity.

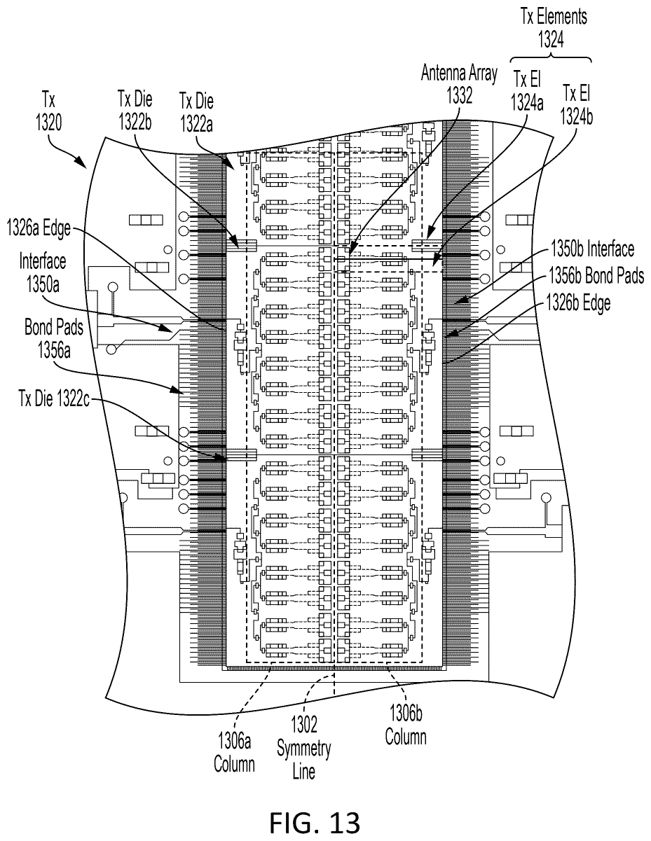

FIG. 13 is a top view of a plurality of an example transmitter 1320 that may be included in device 400, in accordance with some embodiments of the technology described herein.

In some embodiments, transmitter 1320 may be configured as described herein for transmitter 1120. For example, as shown in FIG. 13, transmitter 1320 includes transmit semiconductor dies 1322a, 1322b, and 1322c, each including transmit elements 1324 and antenna array 1332 arranged in first column 1306a and second column 1306b having mirror symmetry across symmetry line 1302. As shown in FIG. 13, transmit semiconductor die 1322b has a first interface 1350a at a first outer edge 1326a including bond pads 1356a, and a second interface 1350b at a second outer edge 1326b including bond pads 1356b. In some embodiments, transmit elements 1324 may be configured as described herein for transmit elements 1224, such as arranged in pairs of transmit elements that are further mirrored with respect to one another across lines that extend orthogonal to symmetry line 1302. For example, in FIG. 13, a pair of transmit elements 1324 of transmit semiconductor die 1322b in second column 1306b are labeled 1324a and 1324b, and may be mirrored across a symmetry line (e.g., 1202′) that separates transmit elements 1324a and 1324b from one another. In some embodiments, transmit circuitry of each transmit element 1324a and 1324b may be configured as described herein for transmit circuitry 1260 including in connection with FIG. 12B.

FIG. 14A is a schematic view of a substrate 1404 of an example device 1400 having a receiver 1430, interface circuitry 1450, and processing circuitry 1440, which may be included in system 10, in accordance with some embodiments of the technology described herein. FIG. 14B is a circuit diagram of a receive element 1438 of receiver 1430, in accordance with some embodiments of the technology described herein.

In some embodiments, device 1400 may be configured as described herein for device 400 and/or 500 including in connection with FIGS. 4-5. For example, as shown in FIG. 14A, device 1400 includes substrate 1404 having mounted thereon signal generation circuitry 1410, receiver 1430, interface circuitry 1450, and processing circuitry 1440.

In some embodiments, receiver 1430 may have a receive semiconductor die with a receive antenna array and receive circuitry. For example, in FIG. 14A, receiver 1430 includes receive semiconductor die 1432 including receive elements 1438 and receive antenna array 1439. For instance, each receive element 1438 may include an antenna of antenna array 1439 and receive circuitry 1480 configured to feed (e.g., obtain received RF signals via) the antenna.

In some embodiments, an RF receive antenna array may have a receive aperture with a receive aperture length extending in a first direction and a receive aperture width extending in a second direction, the receive aperture length being smaller than the receive aperture width. For example, as shown in FIG. 14A, antenna array 1439 has more antennas in the x direction than in the y direction, which pay provide a larger receive aperture length in the x direction than receive aperture width in the y direction.

In some embodiments, receiver 1430 may be configured to obtain a reference RF signal from signal generation circuitry 1410. For example, as shown in FIG. 14A, receive semiconductor die 1432 further includes an input interface 1460 configured to receive a reference RF signal from signal generation circuitry 1410. For instance, the reference RF signal may be propagated from signal generation circuitry 1410 to receive semiconductor die 1432 via traces on substrate 1404 and provided to bond pads of input interface 1460. And, as further shown in FIG. 14B, interface 1460 includes a frequency multiplier 1462 and power divider 1464, which may be configured as described herein for frequency multiplier 1252a and power divider 1254a of transmit semiconductor die 1222, respectively, in some embodiments. For instance, frequency multiplier 1454a may be configured to up-convert the reference RF signal to a higher center frequency (e.g., from 17.22 GHz to 155 GHz) for mixing with received RF signals, and power divider 1452b may be configured to divide the reference RF signal among multiple receive elements 1438 for providing to amplifiers 1482. In some embodiments, frequency multiplier 1454a may be configured to up-convert the reference RF signal to a center frequency lower than the center frequency of received RF signals, such as for mixing using a sub-harmonic mixer as described above. While not shown in FIG. 14B, it should be appreciated that power divider 1452a may be coupled to the receive elements 1438 of receive semiconductor die 1432 as described herein for the portion of device 1400 shown in FIG. 14B.

In some embodiments, receive circuitry 1480 may be configured to mix RF signals, received via antenna array 1439, with a reference RF signal. For example, as shown in FIG. 14B, receive element 1438 includes an antenna 1486 of antenna array 1439 and a portion of receive circuitry 1480 that includes a first amplifier 1482, a mixer 1484 coupled to antenna 1486, and a second amplifier 1488 coupled to mixer 1484. In some embodiments, first amplifier 1482 may be configured to obtain and provide a reference RF signal to mixer 1484, such as described further below. In some embodiments, mixer 1484 may be configured to mix an RF signal, received via antenna 1486, with the reference RF signal obtained via first amplifier 1482 to output a mixed signal. In some embodiments, second amplifier 1488 may be configured to amplify and provide the mixed signal to an output interface 1470 of receive semiconductor die 1432 (e.g., for offloading via interface circuitry 1450).

In some embodiments, mixer 1484 may be configured to output the mixed signal having a center frequency indicative of a distance between device 1400 and a target object from which the received RF signal was received by antenna 1486. For example, the received RF signal and the reference RF signal may be LFM signals that, when mixed, produce a mixed signal having a center frequency indicating a time delay between transmission of an RF signal (e.g., based on the reference RF signal) and reception of the received RF signal, such as described herein including in connection with FIGS. 6C-6D. In some embodiments, mixer 1484 may be configured as a sub-harmonic mixer.

For example, the reference RF signal obtained via amplifier 1482 may have a harmonic having the center frequency of the RF signal obtained via antenna 1486, and mixer 1484 may be configured to mix the RF signal obtained via antenna 1486 with that harmonic of the reference RF signal. For instance, mixer 1484 may be configured as a second sub-harmonic mixer configured to mix a second harmonic (e.g., center frequency of 310 GHz) of the reference RF signal (e.g., center frequency of 155 GHz) with the RF signal (e.g., center frequency of 310 GHz) obtained via antenna 1486, though other sub-harmonics, such as even-integer sub-harmonics may be used.

In some embodiments, receive circuitry 1480 may further include a reflector coupled between a mixer and an amplifier and configured to reflect at least some RF energy generated by the mixer back into the mixer. For example, as shown in FIG. 14B, receive element 1438 further includes reflector 1490 coupled between mixer 1484 and amplifier 1488. In some embodiments, a reflector 1490 may be included for each antenna 1486 of antenna array 1439, such as between a mixer 1484 and amplifier 1488 of each receive element 1438 of receive semiconductor die 1432.

In some embodiments, including reflector 1490 in a receive element 1438 may improve the gain and/or efficiency of receiver 1430. For example, mixer 1484 may be configured to obtain an RF signal having a first center frequency (e.g., 310 GHz) via antenna 1486 and output a mixed signal having a second center frequency (e.g., 3 GHz) to amplifier 1488, which may result in at least some RF energy at the first center frequency leaving mixer 1484 toward amplifier 1488. For instance, the RF energy may include a voltage and/or current wave having the first center frequency. In some embodiments, reflector 1490 may be configured to reflect RF energy, at least at the first center frequency (of the RF signal received via antenna 1486) back into mixer 1484. For example, reflecting RF energy at the first center frequency back into mixer 1484 may recycle at least some of the RF energy at the first center frequency into RF energy in the mixed signal output by mixer 1484, thereby increasing the gain and/or efficiency (e.g., output power vs. input power) of mixer 1484. In some embodiments, increases in gain and/or efficiency of mixers may thereby increase the sensitivity of the receiver to RF signals at low power levels (e.g., attenuated due to reception from farther away).

In some embodiments, interface circuitry 1450 may include AFE and/or ADC circuitry mounted on substrate 1404 and configured to receive mixed signals via receiver 1430 (e.g., amplifier 1488). For example, interface circuitry 1450 may include AFE and/or ADC circuitry integrated on receive semiconductor die 1432, such as with the AFE circuitry coupled to amplifier 1488 on-dic. Alternatively or additionally, AFE and/or ADC circuitry may be on one or more separate dies, such as a mixed-signal ASIC, and/or within an integrated circuit package with at least a portion of processing circuitry 1440.

While a single receive semiconductor die 1432 is shown in FIG. 14A, a device may have multiple receive semiconductor dies 1432 shown as configured in FIG. 14A, such as organized into one or more rows, such as shown in FIGS. 4-5. For example, receive semiconductor die 1432 may be a first die (e.g., 432a) and device 1400 may further include a second receive semiconductor die (e.g., 432b) configured as described herein for die 1432 and disposed in a row with the first die along the x-direction.

While signal generation circuitry 1410 is shown on the same substrate 1404 as receive semiconductor die 1432 in FIG. 14A, signal generation circuitry 1410 may be on a separate substrate in some embodiments.

In some embodiments, device 1400 may further have a transmitter (e.g., 420 and/or 520) mounted on substrate 1404 and configured to receive the reference RF signal from signal generation circuitry 1410, generate RF signals using the reference RF signal (e.g., by up-converting and dividing the reference RF signals), and feed the RF signals to a plurality of RF transmit antennas. In some embodiments, the transmitter may have a transmit antenna array having a transmit aperture with a transmit aperture length extending in the first direction (e.g., y direction) and a transmit aperture width extending in the second direction (e.g., x direction), the transmit aperture length being greater than the transmit aperture width, such as described above.

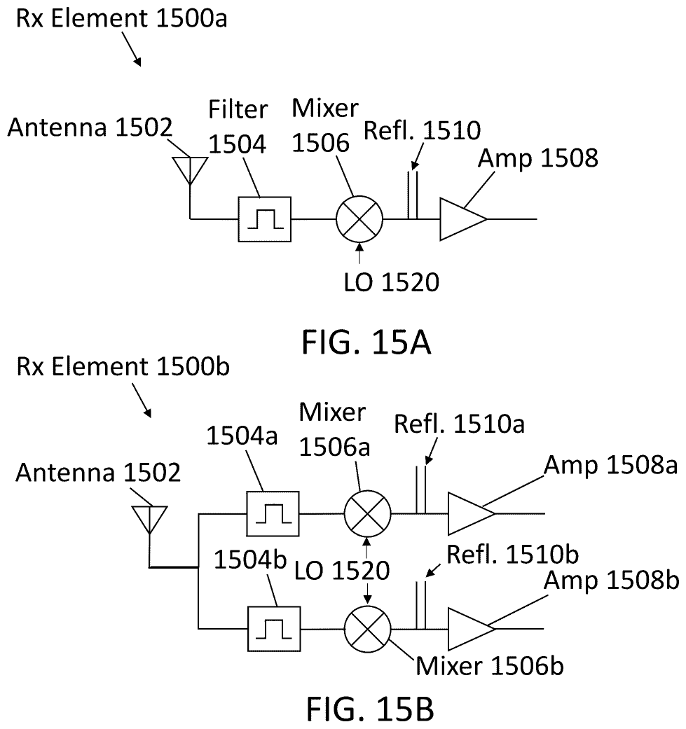

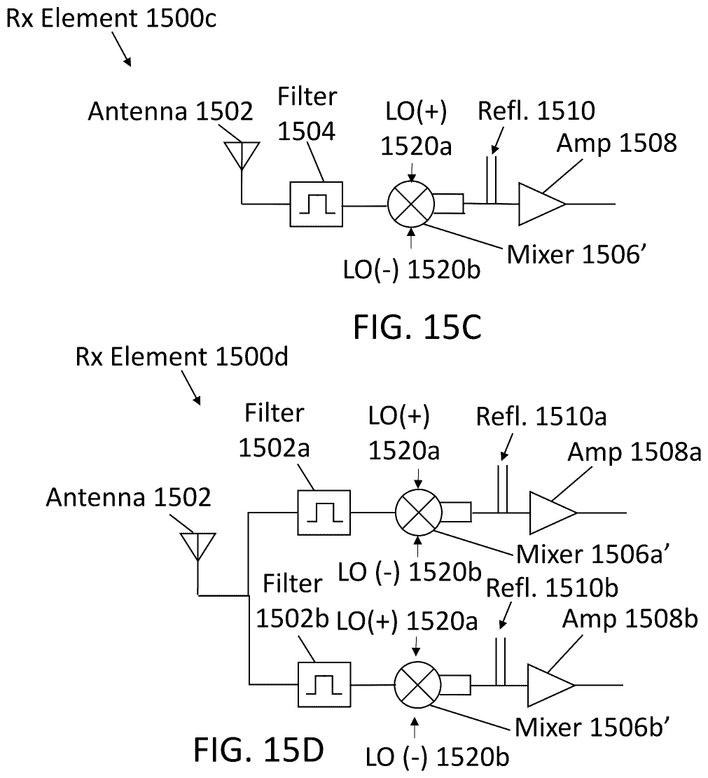

FIG. 15A is a circuit diagram of an example common mode receive element 1500a having a reflector 1510a, in accordance with some embodiments of the technology described herein.

In some embodiments, receive element 1500a may be configured as described herein for receive element 1438 including in connection with FIGS. 14A-14B. For example, as shown in FIG. 15A, receive element 1500a includes an antenna 1502 (e.g., of a receive antenna array) and receive circuitry including a mixer 1506, reflector 1510, and amplifier 1508. For instance, as shown in FIG. 15A, mixer 1506 may be configured to receive an LO signal 1520 for mixing with an RF signal obtained via antenna 1502, the LO signal 1520 being based on a reference RF signal.

In some embodiments, mixer 1506 may be configured to receive an RF signal via antenna 1502, the RF signal based on an RF signal received by antenna 1502. For example, as shown in FIG. 15A, receive circuitry of receive element 1500a further includes a filter 1504 coupled between antenna 1502 and mixer 1506. For instance, antenna 1502 may be configured to provide a received RF signal as an input to filter 1504 and mixer 1506 may be configured to obtain the RF signal via antenna 1502 as an output from filter 1504. In some embodiments, filter 1504 may be configured as a high-pass and/or band-pass filter having a passband that includes the center frequency (e.g., 310 GHz) and band (e.g., 307-313 GHz) of the received RF signal.

In some embodiments, receive element 1500a may be configured as a common mode receive element. For example, in FIG. 15A, antenna 1502 may be configured to provide a common mode signal to filter 1504 defined by a received RF signal with reference to ground. For instance, antenna 1502 may be fed by a signal feed terminal and a ground feed terminal, with the ground feed terminal coupled to a ground plane of the receive semiconductor die.

FIG. 15B is a circuit diagram of an example differential mode receive element 1500b having reflectors 1510a and 1510b, in accordance with some embodiments of the technology described herein.

In some embodiments, receive element 1500b may be configured as described herein for receive element 1500a. For example, as shown in FIG. 15B, receive element 1500b includes antenna 1502, and further includes filters 1504a and 1504b, mixers 1506a and 1506b, reflectors 1510a and 1510b, and amplifiers 1508a and 1508b. As shown in FIG. 15B, mixer 1506a is coupled between filter 1504a and amplifier 1508a, and mixer 1506b is coupled between filter 1504b and amplifier 1508b, with reflector 1510a coupled between mixer 1506a and amplifier 1508a and reflector 15010b coupled between mixer 1506b and amplifier 1508b. In some embodiments, reflector 1510a may be configured to reflect at least some RF energy generated by mixer 1506a back into mixer 1506a and reflector 1510b may be configured to reflect at least some RF energy generated by mixer 1506b back into mixer 1506b.

In some embodiments, receive element 1500b may be configured as a differential mode receive element. For example, in FIG. 15B, antenna 1502 may be configured to provide a differential mode signal to filters 1504a and 1504b defined by a first differential component provided to filter 1504a and a second differential component provided to filter 1504b. For instance, in FIG. 15B, antenna 1502 may be fed by a pair of differential signal feed terminals, with each differential signal feed terminals being separate from and defined with respect to a ground plane of the receive semiconductor die. In some embodiments, mixer 1506a may be configured to mix the first differential component from filter 1504a with LO signal 1520 to output a first mixed signal and mixer 1506b may be configured to mix the second differential component from filter 1504b with LO signal 1520 to output a second mixed signal. For example, the first and second mixed signals may define a differential mixed signal. In some embodiments, amplifier 1508a may be configured to amplify the first mixed signal output by mixer 2106a and amplifier 1508b may be configured to amplify the second mixed signal output by mixer 1506b.

FIG. 15C is a circuit diagram of an example common mode receive element 1500c having a differential mixer 1506′ and a reflector 1510, in accordance with some embodiments of the technology described herein.

In some embodiments, receive element 1500c may be configured as described herein for receive element 1500a. For example, as shown in FIG. 15C, receive element 1500c includes antenna 1502, filter 1504, mixer 1506′, amplifier 1508, and reflector 1510.

In some embodiments, mixer 1506′ may be configured as a differential mixer. For example, as shown in FIG. 15C, mixer 1506′ may be configured to receive an LO signal defined by differential components 1520a and 1520b. In some embodiments, mixer 1506′ may be configured to mix differential component 1520a with an RF signal received via antenna 1502 to generate a first mixed signal component, mix differential component 1520b with the RF signal to generate a second mixed signal component, and combine the first and second mixed signal components to generate a mixed signal for amplification via amplifier 1508.

FIG. 15D is a circuit diagram of an example differential mode receive element 1500d having differential mixers 1506a′ and 1506b′ and reflectors 1510a and 1510b, in accordance with some embodiments of the technology described herein.

In some embodiments, receive element 1500d may be configured as described herein for receive elements 1500b and 1500c. For example, as shown in FIG. 15D, receive element 1500d includes an antenna 1502, filters 1502a and 1502b, mixers 1506a′ and 1506b′, amplifiers 1508a and 1508b, and reflectors 1510a and 1510b. In some embodiments, receive element 1500d may be configured as a differential mode receive element, such as described herein for receive element 1500b.

In some embodiments, mixers 1506a′ and 1506b′ may be configured as differential mixers, such as described herein for mixer 1506′. For example, as shown in FIG. 15D, each of mixers 1506a′ and 1506b′ may be configured to receive an LO signal defined by first component 1520a and second differential component 1520b. For instance, mixer 1506a′ may be configured to mix a first differential component of an RF signal received via antenna 1502 with differential components 1520a and 1520b of the LO signal to generate first and second mixed signals, respectively, and combine the first and second mixed signals to generate a third mixed signal. Similarly, mixer 1506b′ may be configured to mix a second differential component of the RF signal with differential components 1520a and 1520b of the LO signal to generate fourth and fifth mixed signals, respectively, and combine the fourth and fifth mixed signals to generate a sixth mixed signal. For example, the third and sixth mixed signals may define a differential mixed signal.

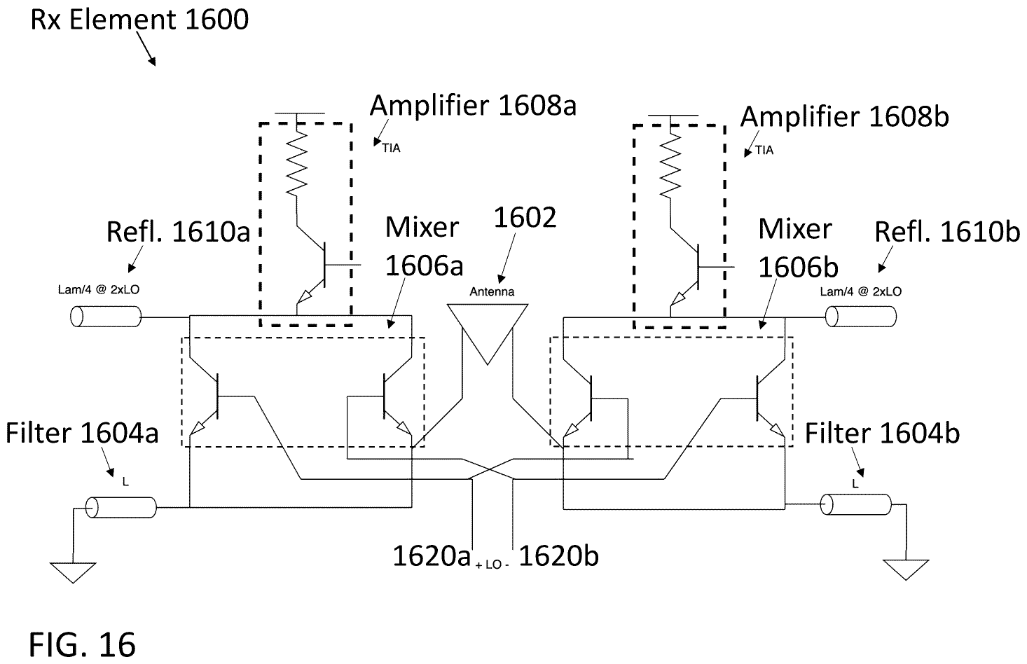

FIG. 16 is a circuit diagram of an example differential mode receive element 1600 having differential mixers 1606a and 1606b, current reflectors 1610a and 1610b, and transimpedance amplifiers (TIAs) 1608a and 1608b, in accordance with some embodiments of the technology described herein.

In some embodiments, receive element 1600 may be configured as described herein for receive element 1500d. For example, as shown in FIG. 16, receive element 1600 includes antenna 1602, filters 1604a and 1604b, mixers 1606a and 1606b, amplifiers 1608a and 1608b, and reflectors 1610a and 1610b. For instance, mixers 1606a and 1606b may be configured as differential mixers, each configured to receive an LO signal defined by a first differential component 1620a and a second differential component 1620b. In the illustrated embodiment, filters 1604a and 1604b include transmission line inductors having inductance L, which provide a high pass filter with cutoff frequency below the center frequency and band of received RF signals (e.g., below 307 GHz).

In some embodiments, receive element 1600 may be configured as a current mode receive element. For example, mixers 1606a and 1606b may be configured to output mixed signals as current signals, and amplifiers 1608a and 1608b may be configured as TIAs. For instance, in FIG. 16, amplifiers 1608a and 1608b each include a common gate amplifier and bias resistor, which may be configured to convert current signals output from mixers 1606a and 1606b into voltage signals for outputting to an output interface (e.g., 1470).

In some embodiments, reflectors 1610a and 1610b may be configured as current reflectors. For example, as shown in FIG. 16, mixers 1606a and 1606b may be configured to generate a current wave having the center frequency of the RF signals received via antenna 1602 (e.g., 310 GHz), and the current reflectors may be configured to reflect the current waves back into the respective mixers 1606a and 1606b. In some embodiments, reflectors 1610a and 1610b may include transmission line stubs. For example, as shown in FIG. 16, each reflector 1610a and 1610b includes a transmission line stub having a length of one quarter of a wavelength at the center frequency of RF signals received by RF antenna 1602. In some embodiments, transmission line stubs may be formed using open or short circuited microstrips (e.g., fabricated on the receive semiconductor die), though other types of transmission line stubs may be used.

It should be appreciated that, while receive element 1600 is shown in FIG. 16 as a differential current mode receive element having differential mixers, a current mode receive element may be alternatively or additionally implemented as a common mode receive element (e.g., 1500a and/or 1500c) and/or with a single-ended mixer or mixers (e.g., 1500a and/or 1500b).

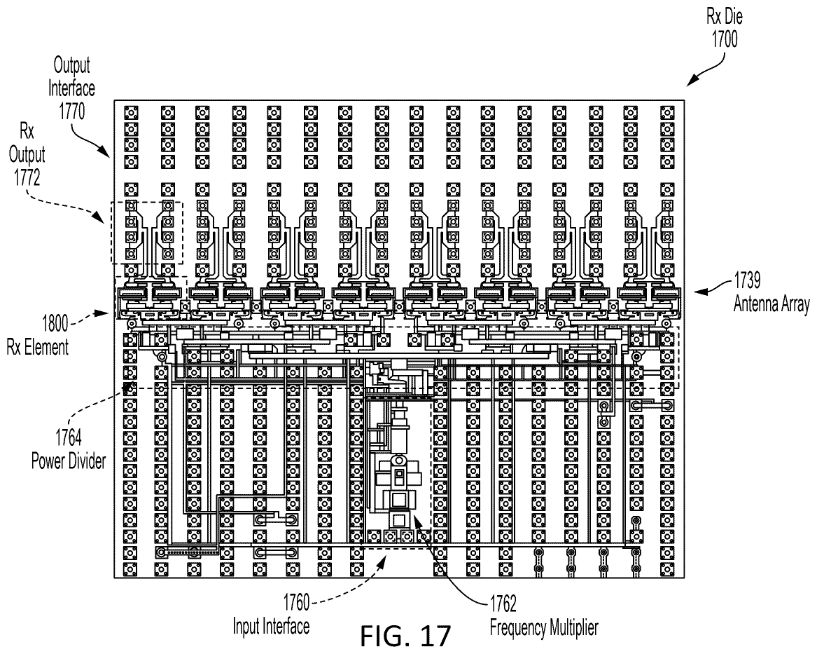

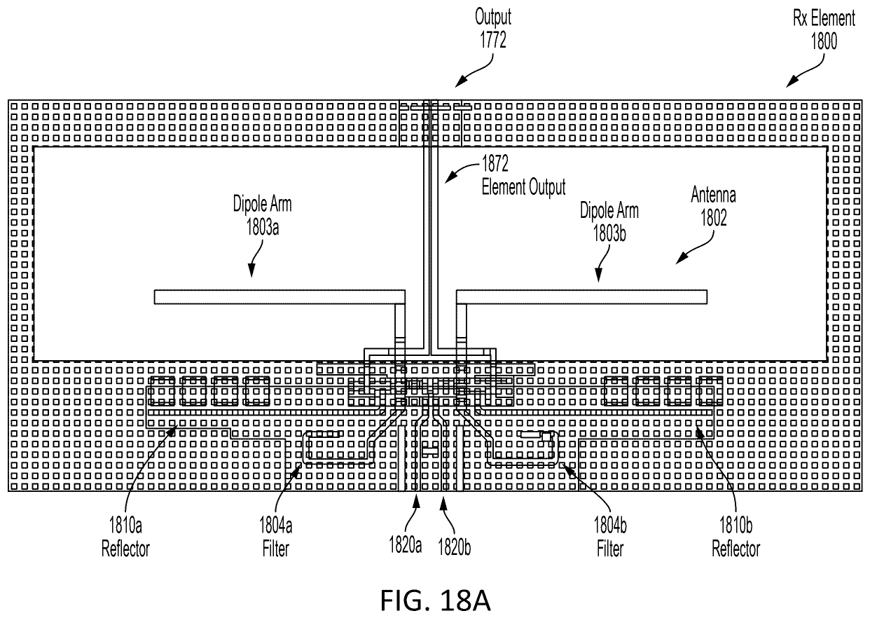

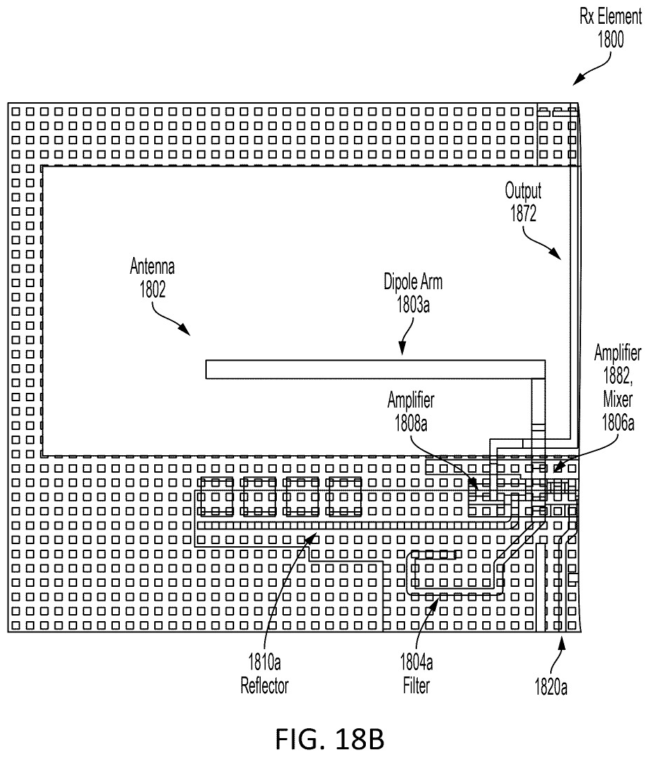

FIG. 17 is a top view of an example receive semiconductor die 1700 that may be included in receiver 1430, in accordance with some embodiments of the technology described herein. FIG. 18A is a top view of a receive element 1800 of receive semiconductor die 1700, in accordance with some embodiments of the technology described herein. FIG. 18B is a magnified top view of a portion of receive element 1800, in accordance with some embodiments of the technology described herein.

In some embodiments, receive semiconductor die 1700 may be configured as described herein for receive semiconductor die 1432. For example, as shown in FIG. 17, receive semiconductor die 1700 has an input interface 1760, including frequency multiplier 1762 and power divider 1764, an antenna array 1739, and receive elements 1800 including receive circuitry configured to feed respective antennas of antenna array 1739. For instance, as shown in FIG. 18A, each antenna 1802 of antenna array 1739 is configured as a dipole antenna having dipole arms 1803a and 1803b.

In some embodiments, each receive element 1800 may be configured as described herein for receive element 1600. For example, as shown in FIGS. 18A-18B, each receive element 1800 includes a respective antenna 1802 of antenna array 1739 and receive circuitry including an amplifier 1882, filters 1804a and 1804b, mixers (only 1806a is labeled), amplifiers (only 1808a is labeled), and reflectors 1810a and 1810b. As shown in FIG. 18A, each receive element 1800 may be configured to receive an LO signal defined by differential components 1820a and 1820b, and each amplifier (e.g., 1808a) is configured to output a mixed signal along a respective one of output lines 1872, which may be coupled to output lines 1772 of output interface 1770.

In some embodiments, output interface 1770 may be configured to offload the output mixed signals to interface circuitry (not shown), such as traces on receive semiconductor die 1700, when components of the interface circuitry are integrated on die 1700, and/or via bond pads when components of the interface circuitry are located off of die 1700.

While antennas 1802 are shown in FIGS. 18A-18B as dipole antennas, it should be appreciated that other types of antennas, such as patch antennas, may be used.

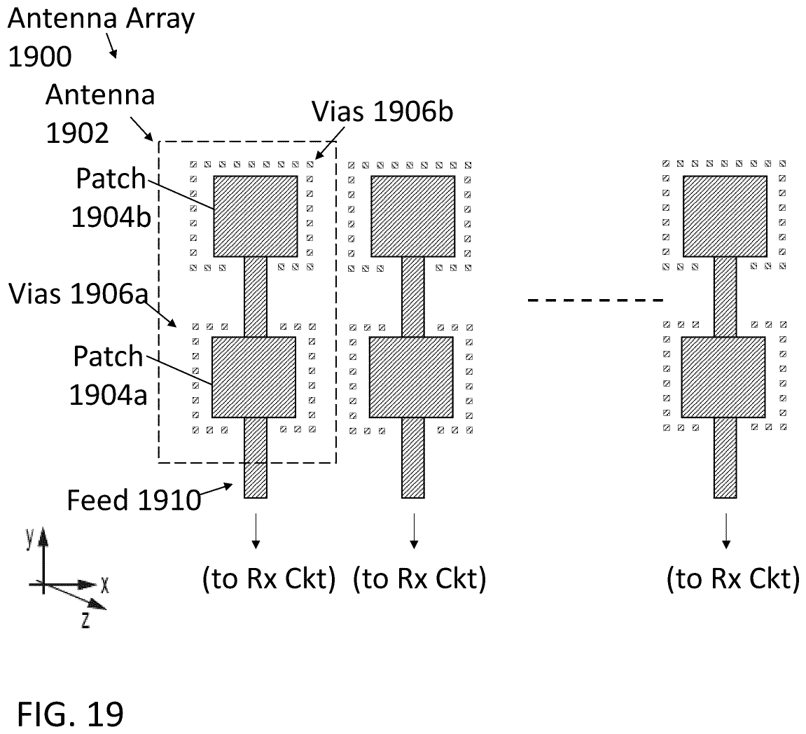

FIG. 19 is a top view of an alternative example antenna array 1900 that may be included in receive semiconductor die 1700, in accordance with some embodiments of the technology described herein. For example, in some embodiments, receive semiconductor die 1700 may include antennas including one or more patches, such as may be configured to receive circularly polarized RF signals.

In some embodiments, antenna array 1900 may have RF antennas that include two or more patches serially coupled to one another. For example, as shown in FIG. 19, antenna array 1900 includes antennas 1902, each including a first patch 1904a and a second patch 1904b coupled to first patch 1904a. In some embodiments, coupling between first and second patches 1904a and 1904b may provide a large antenna aperture for higher radiation efficiency than if only first or second patch 1904a or 1904b were included in antenna 1902. For example, first patch 1904a and second patch 1904b may each be sized to resonate at a center frequency of RF signals received by the RF antenna, and first and second patches 1904a and 1904b may be configured to couple conductively to one another to collectively contribute to the aperture of antenna 1902. In some embodiments, patches 1904a and 1904b may be configured as microstrip patches over a ground plane that are coupled to one another by a microstrip transmission line.

In some embodiments, for each particular one of the RF antennas in a receive antenna array, receive circuitry (e.g., 1480) may be coupled to one of the two or more patches of the particular RF antenna. For example, as shown in FIG. 19, first patch 1904a is coupled to a feed 1910, which may have a port coupled to receive circuitry integrated on the receive semiconductor die. In some embodiments, the receive circuitry may be coupled to only one of the patches of antenna 1902. For example, as shown in FIG. 19, patch 1904b is only coupled to feed 1910 via first patch 1904a. For instance, RF signals may only reach patch 1904b from the receive circuitry via patch 1904a. In some embodiments, having receive circuitry coupled to fewer than all patches of an antenna (e.g., only one of patches 1904a and 1904b in FIG. 19) may use less reception power than if receive circuitry were coupled to each patch, while still benefitting from the improved radiation efficiency of including multiple patches in the antenna coupled to one another. In some embodiments, feed 1910 may be configured as a microstrip transmission line.

In some embodiments, patches of antenna 1902 may be spaced from one another and from receive circuitry in a same direction. For example, as shown in FIG. 19, patch 1904a is spaced from feed 1910 in the y direction, and patch 1904b is spaced from patch 1904b in the y direction.

In some embodiments, antenna 1902 may further include vias disposed around patches of the antenna 1902. For example, as shown in FIG. 19, first vias 1906a are disposed around first patch 1904a and a second vias 1906b are disposed around second patch 1904b. In some embodiments, vias around patches of antenna 1902 may be configured to limit surface wave interaction with receive semiconductor die from received RF signals. For example, first and second vias 1906a and 1906b may be positioned with respect to one another to block undesired surface wave modes in the semiconductor die. In some embodiments, antennas including patches and vias disposed around patches may be implemented without a lens while mitigating the impact of surface waves in the semiconductor die, though it should be appreciated that a lens may be optional in any embodiments described herein.

While antennas 1902 are shown in FIG. 19 including two patches per antenna 1902, it should be appreciated that more than two patches may be included per antenna, such as 2, 3, or 4 patches per antenna (e.g., with fewer than all patches, such as only one patch, coupled to receive circuitry). In some embodiments including more than two patches, some or all patches of an antenna may be spaced from one another in the same direction.

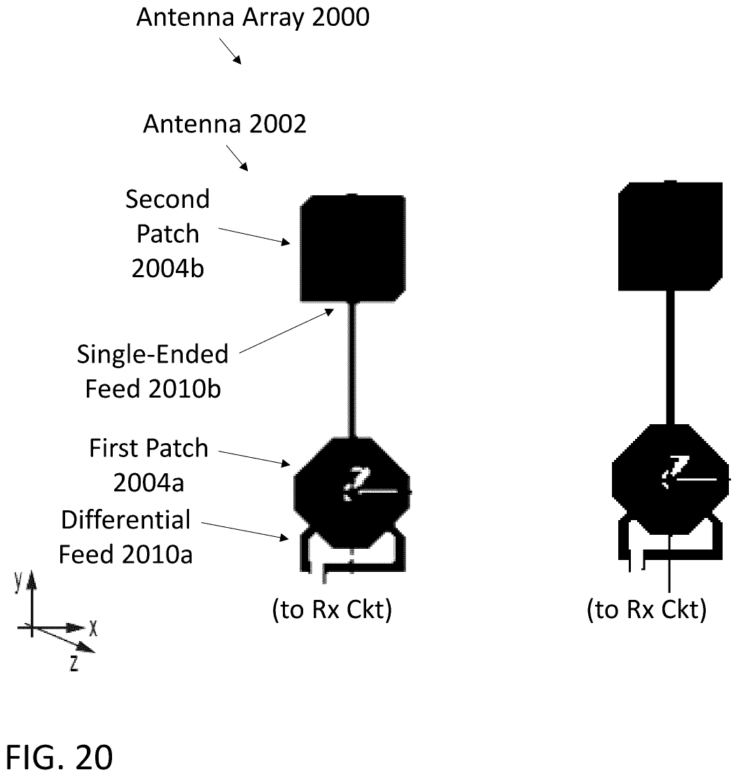

FIG. 20 is a top view of an example antenna array 2000 that may be included in receive semiconductor die 1700, in accordance with some embodiments of the technology described herein.

In some embodiments, antenna array 2000 may be configured as described herein for antenna array 1900. For example, as shown in FIG. 20, antenna array 2000 includes RF antennas 2002 that include two or more patches serially coupled to one another. In the illustrated embodiment, RF antennas 2002 include a first patch 2004a and a second patch 2004b serially coupled to first patch 2004a. As described herein for antenna array 1900, RF antennas 2002 may be coupled to receive circuitry (e.g., 1480) not shown. For example, as described herein including in connection with antenna array 1900, for each particular one of RF antennas 2002, the receive circuitry may be coupled to one of first patch 2004a and second patch 2004b of the particular one of RF antennas 2002.

In some embodiments, RF antennas 2002 may include serially-coupled patches having different geometries. For example, as shown in FIG. 20, second patch 2004b has a different geometry from first patch 2004a. In the illustrated embodiment, first patch 2004a has a differential feed 2010a and second patch 2004b has a single-ended feed 2010b. In some embodiments, differential feed 2010a of first patch 2004a may be configured to obtain an RF signal from receive circuitry (e.g., 1480) and single-ended feed 2010b of second patch 2004b may be configured to obtain the RF signal via first patch 2004a.

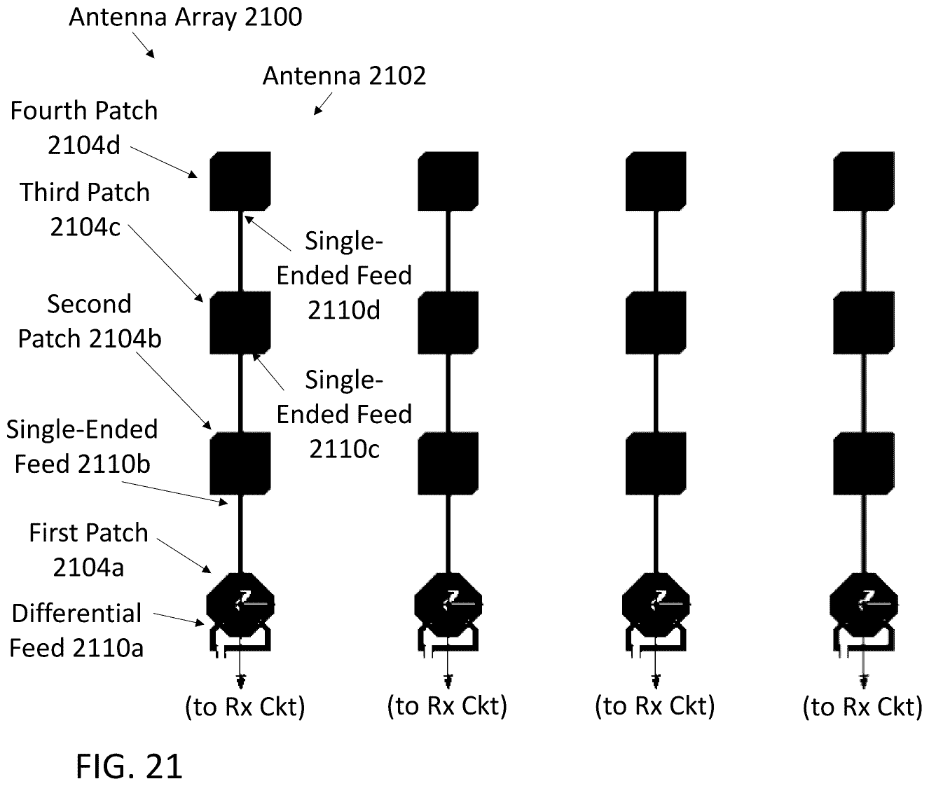

FIG. 21 is a top view of yet another alternative example antenna array 2100 that may be included in receive semiconductor die 1700, in accordance with some embodiments of the technology described herein.

In some embodiments, antenna array 2100 may be configured as described herein for antenna array 2000, such as including antennas 2102 each including a first patch 2104a and a second patch 2104b having a different geometry from first patch 2104a. For example, in FIG. 21, first patch 2104a has a differential feed 2110a and second patch 2104b has a single-ended feed 2110b.

As further shown in FIG. 21, each antenna 2102 further includes a third patch 2104c serially coupled to second patch 2104b. In the illustrated embodiment, third patch 2104c has a same geometry as second patch 2104b, such as having a single-ended feed 2110c. In the illustrated embodiment, each antenna 2102 further includes a fourth patch 2104d serially coupled to third patch 2104c and having a single-ended feed 2110d. It should be appreciated that antennas 2002 and/or 2102 may include any number of serially-coupled patches.

### Antenna Array Configurations & Manufacture

As described above, in some embodiments, multiple semiconductor dies having RF antenna arrays thereon may be spaced next to one another to preserve half-wavelength spacing between antennas located on different semiconductor dies. The inventors have recognized that half-wavelength spacing may be used to achieve Nyquist spatial sampling, which facilitates eliminating aliasing effects, such as grating lobes.

In some embodiments, a device (e.g., 2200 in FIG. 22) comprises a substrate (e.g., 1400 in FIGS. 14A-14B) and a receiver (e.g., 2204 in FIG. 22) mounted on the substrate. For example, the receiver may be mounted on an interposer (e.g., 2202), with the interposer mounted on the substrate.

In some embodiments, the receiver comprises a first semiconductor die (e.g., 2210 in FIG. 22) having integrated thereon a first plurality of RF antennas (e.g., 2211 in FIG. 22) configured to receive first RF signals having a first RF center frequency, the first plurality of RF antennas including a first RF antenna (e.g., 2212 in FIG. 22). In some embodiments, the receiver further comprises a second semiconductor die (e.g., 2220 in FIG. 22) having integrated thereon a second plurality of RF antennas (e.g., 2221 in FIG. 22) configured to receive second RF signals having the first RF center frequency, the second plurality of RF antennas including a second RF antenna (e.g., 2222). For example, the first and second pluralities of RF antennas may be configured as RF antenna arrays on the respective first and second semiconductor dies operating at the same frequencies.

In some embodiments, the first semiconductor die and the second semiconductor die are arranged in the receiver such that a center-to-center distance (e.g., D in FIG. 22) between the first RF antenna and the second RF antenna is less than or equal to (e.g., within 10% of) one half of a free-space wavelength at the first RF center frequency. For example, the first and second antennas may be proximate the outer edges (e.g., 2216, 2226) of the first and second semiconductor dies respectively, with the first and second antennas spaced from the respective outer edges, and the outer edges spaced from one another, in a way that facilitates one-half wavelength or less center-to-center spacing of the antennas. It should be appreciated that the center-to-center distance (e.g., D in FIG. 22) may be slightly above one-half wavelength, such as within 10% of one-half wavelength, within 7% of one-half wavelength, and/or within 5% of one-half wavelength.

FIG. 22 is a schematic view of an example receiver 2204 mounted on an interposer 2202 of a device 2200, which may be included in system 10, in accordance with some embodiments of the technology described herein.

In some embodiments, device 2200 may be configured as described herein for device 400 and/or 500. For example, device 2200 may include a substrate (e.g., 404 and/or 504) with receiver 2204 mounted in the substrate. For instance, as shown in FIG. 22, receiver 2204 is mounted on interposer 2202, which may be in turn mounted on the substrate.

In some embodiments, receiver 2204 may have multiple semiconductor dies with respective pluralities of RF antennas. For example, in FIG. 22, receiver 2204 includes a first semiconductor die 2210 having a first plurality of antennas 2211 integrated thereon, of which an antenna 2212 is labeled, and receiver 2204 further includes a second semiconductor die 2220 having a second plurality of antennas 2221 integrated thereon, of which an antenna 2222 is labeled. For instance, first antennas 2211 of first semiconductor die 2210 may be configured to form a first antenna array configured to receive RF signals and second antennas 2221 of second semiconductor die 2220 may be configured to form a second antenna array. In some embodiments, antennas 2221 and 2222 of the first and second semiconductor dies 2210 and 2220 may be configured to transmit and/or receive RF signals having a same RF center frequency.

In some embodiments, first and second semiconductor dies 2210 and 2220 may be arranged in receiver 2204 such that a center-to-center distance between antenna 2212 and antenna 2222 is less than or equal to (e.g., within 10% of) one half of a free-space wavelength at an RF center frequency of RF signals transmitted and/or received by antennas 2212 and 2222 and/or. For example, as shown in FIG. 22, antennas 2212 and 2222 are disposed at a center-to-center distance D. In some embodiments, center-to-center distance D may be equal to one half of a free-space wavelength at the RF center frequency of RF signals transmitted and/or received by antennas 2212 and 2222. For example, first antennas 2221 may be spaced from other first antennas 2221 by a center-to-center distance of one half of a free-space wavelength, and second antennas 2222 may be spaced from other second antennas 2222 by a center-to-center distance of one half of a free-space wavelength, such that the antenna array formed by dies 2210 and 2220 may be configured, at least in part, for Nyquist spatial sampling.

Alternatively or additionally, in some embodiments, center-to-center distance D between antennas 2212 and 2222 may be less than one half of a free-space wavelength at the RF center frequency of RF signals transmitted and/or received by antennas 2212 and 2222. For example, antennas of first and second semiconductor dies 2210 and 2220 may be spaced from other antennas of the dies 2210 and 2220 by a center-to-center distance less than one-half of a free-space wavelength, such that the antenna array formed by dies 2210 and 2220 may be configured, at least in part, for spatial oversampling. In some embodiments, a center of antenna 2212 and/or 2222 may be its respective phase center.

In some embodiments, each antenna of first antennas 2211 may be spaced center-to-center from adjacent ones of first antennas 2211 by center-to-center distance D, and/or each antenna of second antennas 2221 may be spaced center-to-center from adjacent ones of second antennas 2221 by center-to-center distance D. In other embodiments, at least some antennas of antennas 2211 and/or 2222 may have a different center-to-center distance.

In some embodiments, antennas of first and second antennas 2211 and 2221, having a center-to-center distance less than one half of a free-space wavelength, may be disposed proximate outer edges of the respective dies 2210 and 2220. For example, as shown in FIG. 22, antenna 2212 is proximate a first outer edge 2214 of first semiconductor die 2210 and antenna 2222 is proximate a second outer edge 2224 of second semiconductor die 2220. For instance, no antenna and/or other component may be disposed between antenna 2212 and first outer edge 2214, and no antenna and/or other component may be disposed between antenna 2222 and second outer edge 2224.

In some embodiments, semiconductor dies 2210 and 2220 may have seal rings positioned proximate one another. For example, a distance between seal rings of dies 2210 and 2220 may be between 50 and 70 microns in some embodiments. For example, outer edges 2214 and 2224 may be the seal rings of the respective dies 2210 and 2220. Alternatively or additionally, at least some semiconductor material (e.g., kerf buffer region) may be present between the seal rings and outer edges 2214 and 2224. In some embodiments, the seal rings may surround the antennas 2211, 2221 integrated on the respective die 2210, 2220.

In some embodiments, the outer edges of dies 2210 and 2220 may be disposed proximate one another in receiver 2204. For example, as shown in FIG. 22, first outer edge 2214 is spaced a distance B from second outer edge 2224. According to various embodiments, distance B may be between 25 and 100 microns, between 25 and 75 microns, between 25 and 50 microns, between 20 and 50 microns, and/or between 20 and 30 microns. In some embodiments, no component (e.g., mounted on interposer 2202) may be disposed between first outer edge 2214 and second outer edge 2224.

In some embodiments, antennas of first and second semiconductor dies 2210 and 2220 may have outer edges disposed proximate respective edges of the dies 2210 and 2220. For example, as shown in FIG. 22, antenna 2212 has an outer edge 2216 spaced from outer edge 2214 of die 2210 by a distance d and antenna 2222 has an outer edge 2226 spaced from outer edge 2224 of die 2220 by the same distance d. In other embodiments, outer edge 2226 may be spaced from outer edge 2224 by a different distance than d. According to various embodiments, the distance d (and/or different distance between one of antennas 2212 and 2222 and the respective outer edge 2214, 2224) may be less than 50 microns, less than 30 microns, between 10 and 50 microns, between 10 and 30 microns, between 10 and 20 microns, and/or between 10 and 15 microns.

While semiconductor dies 2210 and 2220 are described herein as part of receiver 2204, it should be appreciated that semiconductor dies 2210 and 2220 may be alternatively or additionally part of a transmitter, as techniques described herein are not so limited.

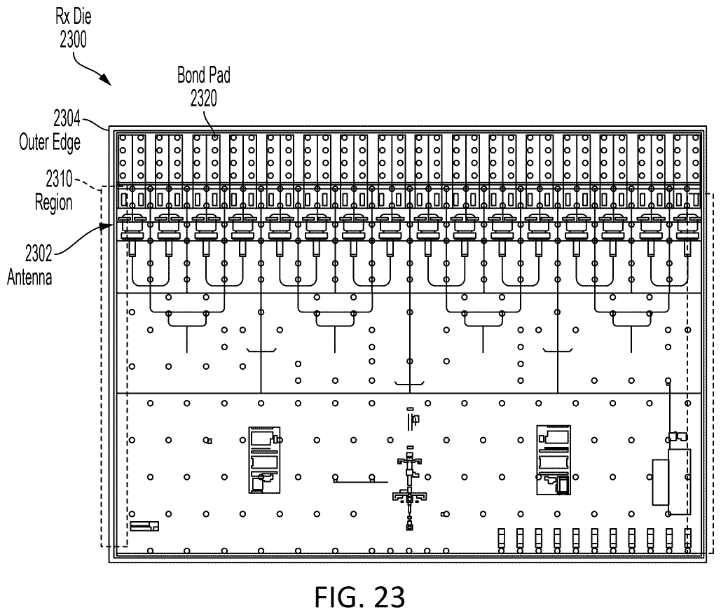

FIG. 23 is a top view of an example receive semiconductor die 2300 that may be included in receiver 2204, in accordance with some embodiments of the technology described herein.

In some embodiments, semiconductor die 2300 may be configured as described herein for semiconductor dies 2210 and 2220 including in connection with FIG. 22. For example, as shown in FIG. 23, semiconductor die 2300 has an antenna array including an antenna 2302 disposed proximate an outer edge 2304 of die 2300.

In some embodiments, semiconductor die 2300 may have regions disposed between antennas of the antenna array and outer edges of the die 2300 in which no components are disposed. For example, in FIG. 23, semiconductor die 2300 has bond pads, which may be configured as copper pillar bond pads, and a region 2310 of semiconductor die 2300 is disposed between antenna 2302 and outer edge 2304 in which no bond pads are disposed. Alternatively or additionally, in some embodiments, no antennas and/or electronics may be disposed in region 2310. In some embodiments, forming region 2310 without components (e.g., bond pads) may permit antenna 2302 to be disposed closer to outer edge 2304 than if bond pads were included in region 2310. In FIG. 23, another region is shown at an outer edge of die 2300 opposite outer edge 2304, though in some embodiments only one outer edge of a die may have a region 2310.

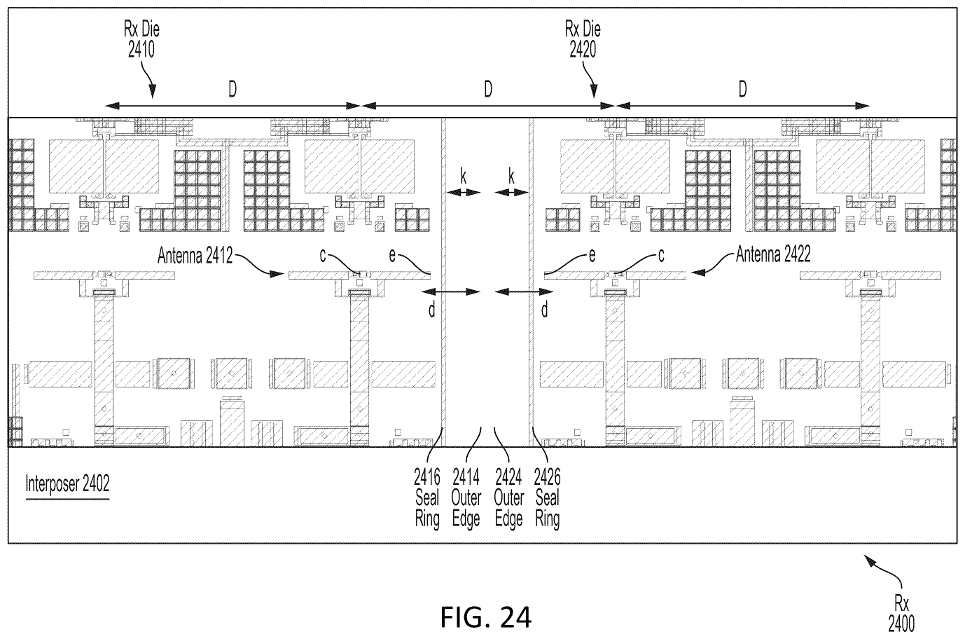

FIG. 24 is a top view of another example receiver 2400 mounted on an interposer 2402, which may be included in device 400, in accordance with some embodiments of the technology described herein.

In some embodiments, receiver 2400 may be configured as described herein for receiver 2204. For example, as shown in FIG. 24, receiver 2400 includes a first semiconductor die 2410 and a second semiconductor die 2420. For instance, in FIG. 24, first semiconductor die 2410 has an antenna 2412 with its outer edge e spaced from outer edge 2414 of semiconductor die 2410 by a distance d, and second semiconductor die 2420 has an antenna 2422 with its outer edge e spaced from outer edge 2424 of semiconductor die 2420 by the distance d. Also shown in FIG. 24, antenna 2412 has its center c spaced from the center c of antenna 2422 by a center-to-center distance D, as are antennas of each semiconductor die 2410, 2420 spaced from adjacent antennas of the respective semiconductor die 2410, 2420. FIG. 24 also shows a scal ring 2416 of first semiconductor die 2410 spaced from outer edge 2414 by a kerf buffer of width k and a seal ring 2426 of second semiconductor die 2420 spaced from outer edge 2424 by a kerf buffer having the width k. While kerf buffer k appears almost as large as distance d in FIG. 24 for case of illustration, kerf buffer k is typically much smaller than distance d. For example, the distance from an outer edge e of an antenna 2412, 2422 and the respective seal ring 2416, 2426 may be between 5 and 25 microns.

In some embodiments, antenna 2412 and/or 2422 may be integrated on respective semiconductor die 2410 and/or 2420 such that its center c is located at a distance from respective outer edge 2414 and/or 2424 is less than one quarter of a free-space wavelength at an RF center frequency at which antenna 2412 and/or 2422 is configured to transmit and/or receive. For example, as shown in FIG. 24, centers c of antennas 2412 and 2422 are spaced by center-to-center distance D, which may be less than or equal to (e.g., within 10% of) one-half of a free-space wavelength. With outer edges of dies 2410 and 2420 touching one another, the distance from each antenna 2412, 2422 to the respective outer edge is thus less than or within 5% of (e.g., equal to) one-quarter of a free-space wavelength, whereas with at least some space (e.g., distance B in FIG. 22) between the outer edges of dies 2410 and 2420, the distance from each antenna 2412, 2422 to the respective outer edge is less than one-quarter of a free-space wavelength.

For example, as shown in FIG. 24, antennas 2412 and 2422 are implemented as dipoles, such as quarter-wave dipoles. For instance, each antenna 2412 and 2422 may have a pair of dipole arms that are shorter than or equal to one-eighth of a free-space wavelength (e.g., leveraging a high dielectric constant of semiconductor material proximate the dipole arms for enhanced electrical length). Where each antenna 2412 and 2422 has a dipole arm shorter than or equal to one eighth of a free-space wavelength terminating at the outer edge e of the antenna 2412, 2422,

While antennas 2412 and 2422 are shown in FIG. 24 implemented as dipole antennas, though it should be appreciated that other types of antennas, such as patch antennas, may be used.

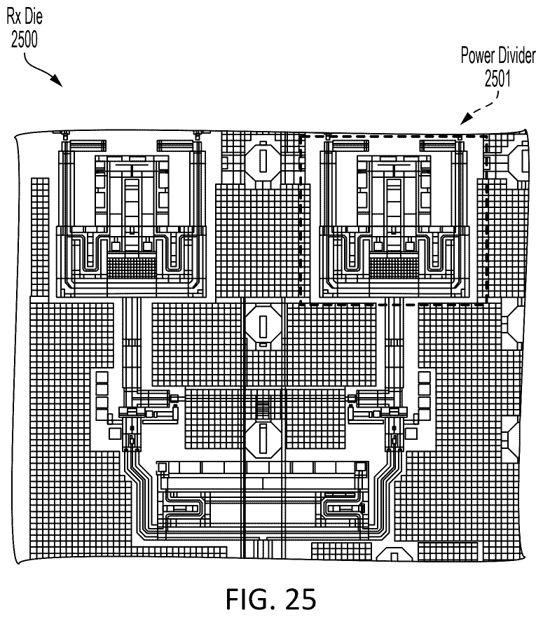

FIG. 25 is a top view of a portion of an example receive semiconductor die 2500 that includes a power divider 2501, which may be included in receiver 2204, in accordance with some embodiments of the technology described herein. In some embodiments, power divider 2501 may be configured as a Gysel power divider in a physical layout that makes efficient use of space on receive semiconductor die 2500.

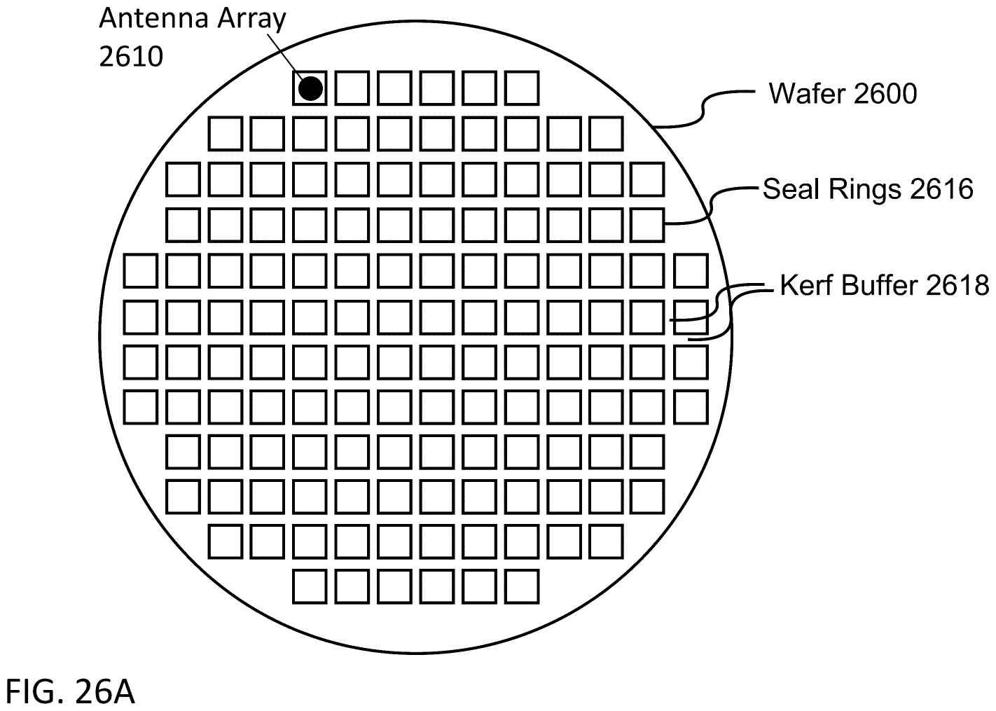

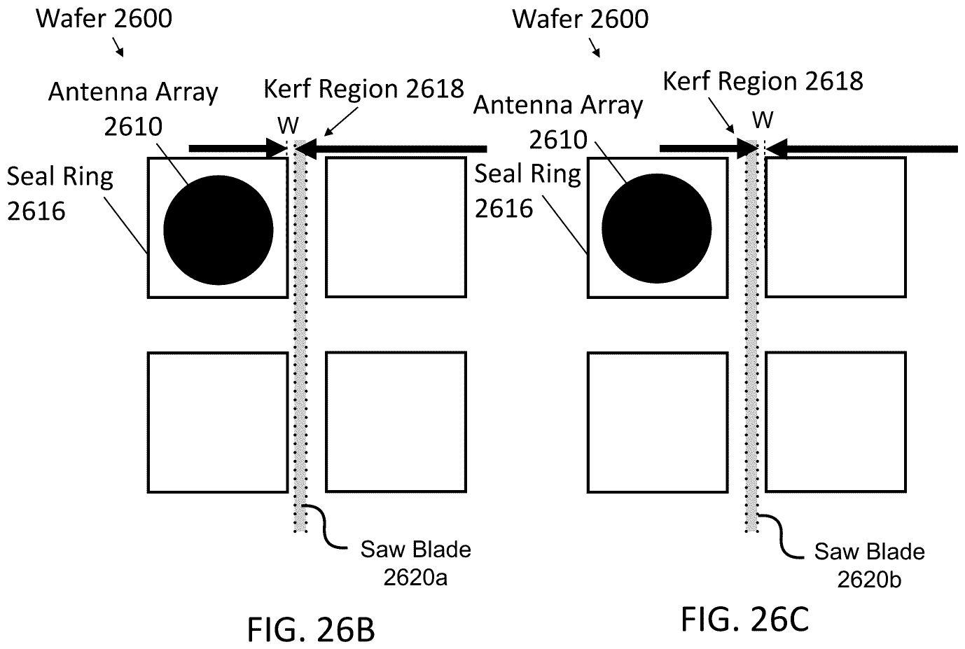

FIG. 26A is a schematic view of an example semiconductor wafer 2600 having a plurality of antenna arrays 2610 integrated thereon, surrounded by respective seal rings 2616, and separated from one another by kerf regions 2618, in accordance with some embodiments of the technology described herein.

In some embodiments, semiconductor dies (e.g., 2210) may be diced from semiconductor wafer 2600. For example, semiconductor wafer 2600 may be obtained and diced into a plurality of semiconductor dies. For instance, as shown in FIG. 26A, each of the plurality of semiconductor dies may have integrated thereon an antenna array of the antenna arrays 2610.

FIG. 26B is a magnified schematic view of a portion of semiconductor wafer 2600 illustrating a location of a saw blade cut 2620a to dice semiconductor dies from semiconductor wafer 2600, in accordance with some embodiments of the technology described herein. FIG. 26C is a magnified schematic view of the portion of semiconductor wafer 2600 shown in FIG. 26B, illustrating another location of another saw blade cut 2620b to dice semiconductor dies from semiconductor wafer 2600, in accordance with some embodiments of the technology described herein.

In some embodiments, dicing semiconductor dies from semiconductor wafer 2600 may include sawing through semiconductor material in kerf regions 2618 of wafer 2600. For example, as shown in FIG. 26B, a first sawing step may be applied with a saw blade 2620a within a width W of seal rings 2616 of a first column of semiconductor wafer 2600. And, as shown in FIG. 26C, a second sawing step may be applied with a saw blade 2620b within a width W of scal rings 2616 of a second column of semiconductor wafer 2600. According to various embodiments, the first and/or second sawing step may remove at least 40 microns, 50 microns, and/or 60 microns from the kerf region 2618 around the seal ring 2616 of some or all resulting semiconductor dies.

It should be appreciated that the second sawing step may be omitted in some embodiments, such as where the saw blade 2620a is wide enough to leave the width W of semiconductor material outside of seal rings 2616 of both first and second columns of semiconductor wafer 2600. It should also be appreciated that different widths of semiconductor material may be left outside of seal rings 2616 of respective columns of semiconductor wafer 2600.

In some embodiments, antennas of antenna arrays 2610 may be disposed proximate the seal rings 2616 such that the first and/or second sawing step saws within a close distance of at least one of the antennas. For example, according to various embodiments, the first and/or second sawing steps may include sawing within 75 microns, 50 microns, and/or 30 microns of at least one antenna of some or all antenna arrays 2610 (e.g., in a column and/or pair of adjacent columns of semiconductor wafer 2600).

In some embodiments, regions (e.g., 2310) without bond pads may be present at outer edges of the resulting semiconductor dies.

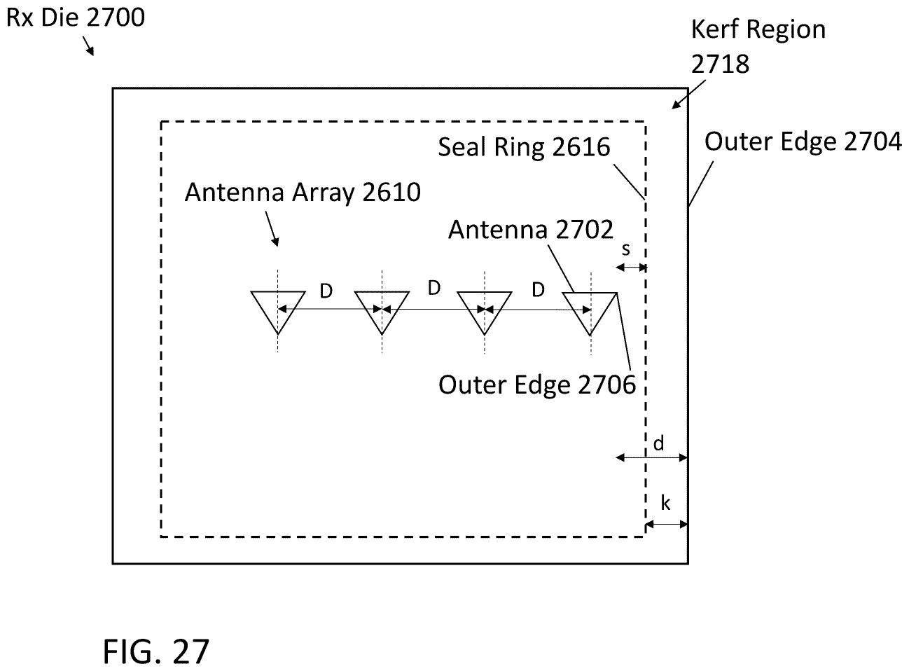

FIG. 27 is a schematic view of an example receive semiconductor die 2700 diced from semiconductor wafer 2600, in accordance with some embodiments of the technology described herein.

In some embodiments, receive semiconductor die 2700 may be diced from semiconductor wafer 2600 to have an antenna array of semiconductor wafer 2600 integrated thereon. For example, as shown in FIG. 27, receive semiconductor die 2700 has one of the antenna arrays 2610 surrounded by a seal ring 2616 spaced from an outer edge 2704 of semiconductor die 2700. For instance, during dicing of semiconductor die 2700 from semiconductor wafer 2600, a sawing step (e.g., FIG. 26B) may remove semiconductor material from kerf region 2618, resulting in a remaining kerf width k between seal ring 2616 and outer edge 2704.

In some embodiments, in one or more semiconductor dies diced from semiconductor wafer 2600, antennas of antenna arrays 2610 may be disposed proximate an outer edge of the die. For example, as shown in FIG. 27, an antenna 2702 of antenna array 2610 has an outer edge 2706 at a distance d from outer edge 2704 of semiconductor die 2700. For instance, distance d may include a distance s from outer edge 2706 of antenna 2702 to seal ring 2616 plus kerf width k. According to various embodiments, distance d may be between 10 and 50 microns, between 10 and 30 microns, between 10 and 20 microns, and/or between 10 and 15 microns.

The inventors have recognized that, in some applications, it may be challenging to implement a fully (e.g., Nyquist-rate or higher) spatially sampled antenna array using RF antenna arrays implemented on multiple semiconductor dies. For example, spacing between the semiconductor dies and between at least some of the RF antennas (e.g., proximate the die edges) and the edges of the semiconductor dies may be so large that at least some antenna elements in the array are spaced from one another by more than one half of a free-space wavelength. Alternatively or additionally, in some embodiments, it may be advantageous to implement a spatially undersampled antenna array due to cost and/or power savings of using and/or feeding fewer antenna elements. At the same time, however, using a spatially undersampled antenna array may lead to undesirable aliasing effects in range measurements obtained using the antenna array, which may affect the accuracy and/or usability of the resulting measurements.

As a solution to mitigate the aliasing effects of spatially undersampled antenna arrays, the inventors developed spatial anti-aliasing techniques. In some embodiments, spatial anti-aliasing techniques described herein may mitigate aliasing effects caused by spatially undersampling an antenna array in which at least some antennas of the array are spaced center-to-center from adjacent antennas of the array by one half of a free-space wavelength or less, while at least some other antenna elements spaced center-to-center from adjacent antenna elements by more than one half of a free-space wavelength. For example, such techniques may be useful in an antenna array in which a plurality of antennas are spaced center-to-center from adjacent antennas by one half of a free-space wavelength or less, while at least one antenna in the array is spaced center-to-center form at least one other antenna of the array by one free-space wavelength (e.g., due to spacing between semiconductor dies in which a half-wavelength spaced antenna is missing).

In some embodiments, spatial anti-aliasing techniques may include generating and associating, by processing circuitry (e.g., 440) mixed signal content with a spatial position between a pair of antennas that are spaced center-to-center by more than one-half of a free-space wavelength. For example, the mixed signal content may be generated as an average of mixed signal content received from the pair of antennas. For instance, using such techniques may facilitate processing RF signals from the spatially undersampled antenna array as though an antenna were present between the pair of antennas, thereby mitigating at least some aliasing caused by the spatial undersampling.

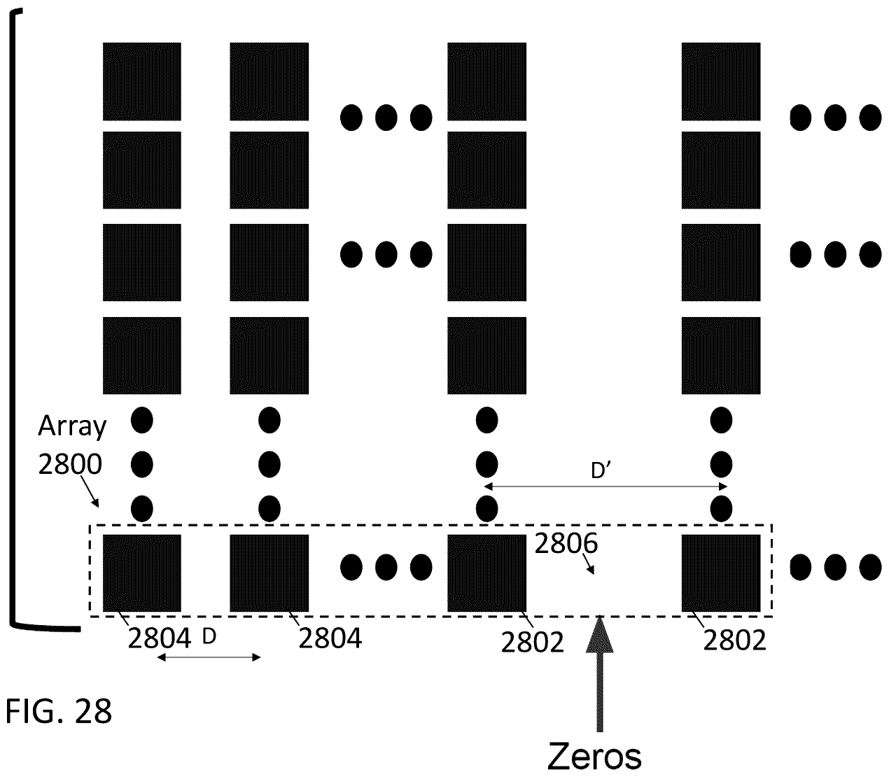

FIG. 28 is a diagram illustrating an example of a spatially undersampled antenna array 2800 that may be included in receiver 430, in accordance with some embodiments of the technology described herein. The vertical axis shown in FIG. 28 represents digital sampling in time of mixed signals output from receive circuitry (e.g., 1480) coupled to the respective antennas of the array 2800.

In some embodiments, antenna array 2800 may be spatially undersampled. For example, antenna array 2800 may have at least some antennas spaced center-to-center from one another by more than one-half of a free-space wavelength. For instance, as shown in FIG. 28, a pair of antennas 2802 are disposed adjacent one another (e.g., with no antenna disposed between the antennas 2802) and spaced center-to-center by a distance D′. According to various embodiments, distance D′ may be between one-half of a free-space wavelength and two free-space wavelengths, such as between one-half and three halves of a free-space wavelength, between one-half and one free-space wavelength, and/or between one half and one free-space wavelength. For instance, antennas 2802 may be disposed on separate semiconductor dies (e.g., proximate respective outer edges of the dies that are proximate one another), without any antennas disposed between the dies.

In some embodiments, antenna array 2800 may have at least some antennas spaced center-to-center from one another by one-half of a free-space wavelength or less. For example, as shown in FIG. 28, antenna array further has a pair of antennas 2804 spaced center-to-center by the distance D (e.g., described elsewhere herein). For instance, antennas 2804 may be disposed on the same semiconductor die and/or on the same semiconductor die as one of antennas 2802. It should be appreciated that each antenna 2802 and/or 2804 may be disposed on its own semiconductor die, and/or on the same semiconductor die, as techniques described herein are not so limited.

In some embodiments, processing circuitry (e.g., 440) spatial anti-aliasing techniques may include may be configured to generate and associate mixed signal content with a spatial position between antennas 2802. For example, as shown in FIG. 28, a spatial position 2806 is between antennas 2802, such as spaced equidistantly from centers of antennas 2802. In some embodiments, the processing circuitry may be configured to generate the mixed signal content as an average of mixed signal content received from antennas 2802. For instance, the processing circuitry may be configured to receive mixed signals (e.g., in digitized versions) from receive circuitry (e.g., 1480) coupled to the antennas 2802 and generate an average of the mixed signals, processing (e.g., phase-shifting) the generated mixed signal as though it were received from an antenna located at spatial position 2806.

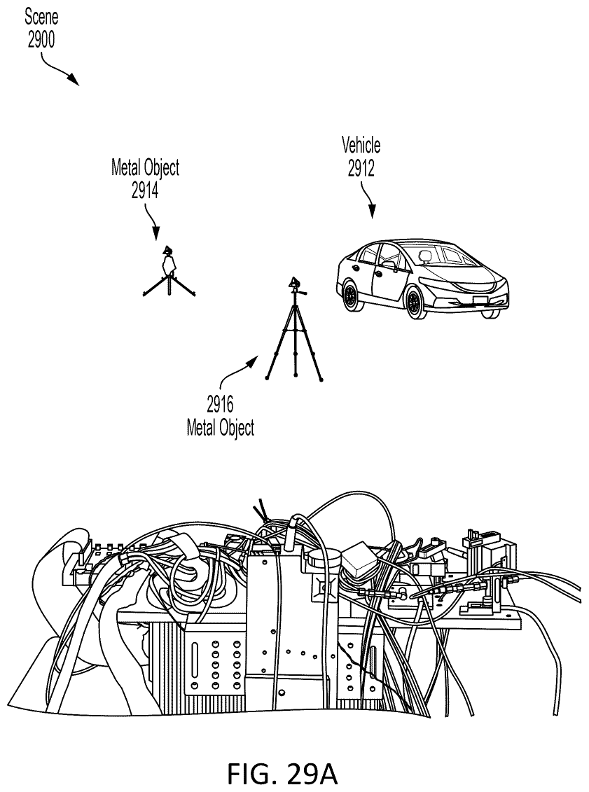

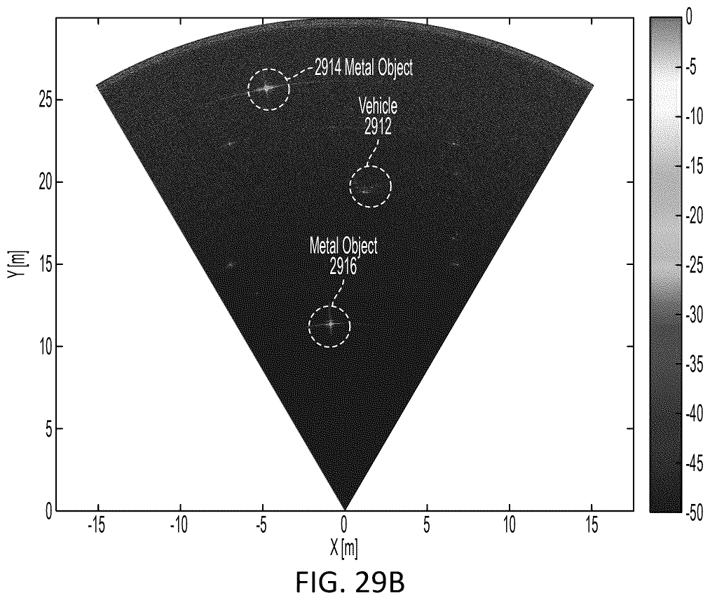

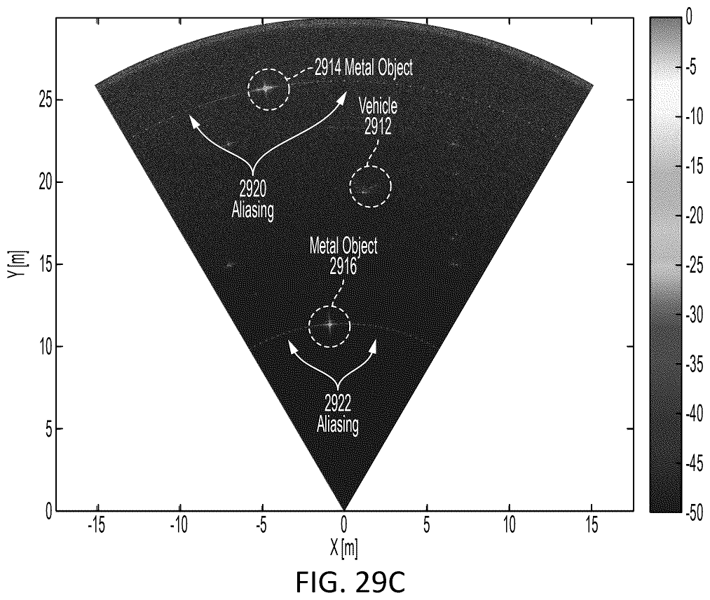

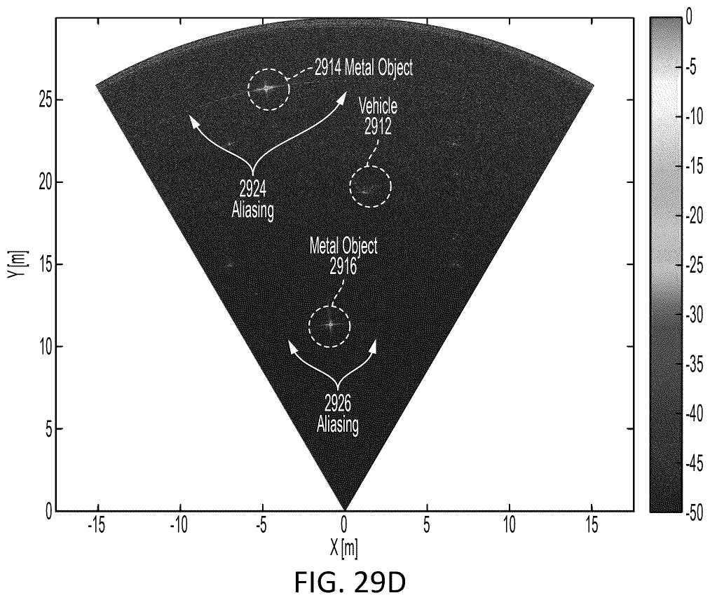

FIG. 29A is a an example scene 2900 in which to perform a range-cross range measurement using device 400, in accordance with some embodiments of the technology described herein. As shown in FIG. 29A, the scene includes a vehicle 2912 and metal objects 2914 and 2916. In the illustrated example, metal objects 2914 and 2916 are tetrahedral shaped.

FIG. 29B is an example range-cross range measurement of the scene of FIG. 29A performed using a spatially Nyquist-sampled antenna array, in accordance with some embodiments of the technology described herein.

For the measurement of FIG. 29B, an antenna array was used having Nyquist-sampling, with each antenna in the array spaced center-to-center from other antennas of the array by one-half of a free-space wavelength. As shown in FIG. 29B, the metal objects 2914 and 2916 appear brighter than the vehicle 2912, due to higher reflectivity of the metal than the paint on the vehicle.

FIG. 29C is an example range-cross range measurement of the scene of FIG. 29A performed using a spatially undersampled antenna array, in accordance with some embodiments of the technology described herein.

For the measurement of FIG. 29C, an antenna array was used having spatial undersampling, with each antenna in the array spaced center-to-center from other antennas of the array by one-half of a free-space wavelength, except one pair of antennas in the array were spaced center-to-center by a full free-space wavelength. As shown in FIG. 29C, aliasing effects 2920 and 2922 are visible proximate the metal objects 2914 and 2916, respectively. For example, aliasing due to the spatial undersampling in the array results in signal power reflected from the metal objects 2914 and 2916 being repeated angularly at the same distance from the objects. Little to no aliasing is visible proximate the vehicle 2912, as signal power repeated angularly around the vehicle may be too low to create impactful noise in the measurement.

FIG. 29D is an example range-cross range measurement of the scene of FIG. 29A performed using a spatially undersampled antenna array and spatial anti-aliasing processing techniques, in accordance with some embodiments of the technology described herein.

For the measurement of FIG. 29D, the same antenna array was used as for the measurement of FIG. 29C, except that anti-aliasing techniques were used to generate the measurement. For the pair of antennas spaced center-to-center by a full free-space wavelength, an additional mixed signal was generated having an average of mixed signals obtained from that pair of antennas, and the additional mixed signal was phase shifted and included (e.g., in a beamforming sum) in the measurement as though it were received from an antenna spaced between the pair of antennas, such as if Nyquist sampling were achieved in the array. As shown in FIG. 29D, aliasing effects 2924 are still visible proximate the metal object 2914, but the aliasing effects 2924 are lower in power than in FIG. 29C, and little to no aliasing effects 2926 are visible proximate the metal object 2916.

### Power Efficiency Techniques

The inventors recognized that a RADAR device having multiple active components may consume a significant amount of power. For example, in the RADAR devices described herein, there are multiple power-consuming components including the signal generation circuitry (e.g., to generate a reference RF signal), transmitter (e.g., the transmit circuitry integrated on transmit semiconductor dies part of the transmitter), the receiver (e.g., the receive circuitry integrated on receive semiconductor dies part of the receiver), ADC circuitry, the serial link coupling the ADC circuitry to processing circuitry (e.g., an FPGA, and the processing circuitry (e.g., that performs RADAR signal processing functions examples of which include, but are not limited to, fast Fourier transforms, formation of range cross-range images, interpretation of the RADAR data for various applications examples of which are described herein).

Among these components, the receive circuitry, transmit circuitry, and ADC circuitry may consume a substantial amount of the available power. The inventors recognized that it would be beneficial to conserve the amount of power drawn by such components to the extent possible in order to leave more power for the link budget (and, ideally, use it to extend the range of the device).

Accordingly, in some embodiments, one or more components of a RADAR device may be operated in a lower power state (e.g., a powered down state) in order to conserve power resources. For example, as shown in FIG. 30, during transmission of RF signals during the period t1-t2, various components may be operated in a first operating state (e.g., drawing an appropriate amount of power to perform their designed functions), but may be operated in a second operating state (e.g., in low-power or a powered down state) outside of the t1-t2 period. For example, as shown in FIG. 30, the signal generation circuitry (e.g., 410), transmit circuitry (e.g., 1160), receive circuitry (e.g., 1480) and the serial link (e.g., 3842) may be operated in the first operating state (drawing an appropriate amount of power to perform their functions) during the t1-t2 and t4-t5 time periods (during which RF signals are sent, received, digitized, and offloaded) and in the second operating state (e.g., a powered down state) between the t1-t2 and t4-t5 time periods. The ADC circuitry (e.g., unit(s) 452a-452c) may also be transitioned between the first and second operating states, though with suitable warm-up and cool-down periods, in some embodiments. The processing circuitry may be operated longer (e.g., in the t1-t3 and t4-t6 time intervals) to provide sufficient time for performing various RADAR signal processing (and subsequent) operations on the digitized data. However, as shown in FIG. 30, even the processing circuitry (e.g., 440) is operated in a lower power (e.g., powered down) state for an amount of time between pulse repetitions (during the t3-t4 period in the example of FIG. 30). A similar illustration is shown in FIG. 30.

Accordingly, some embodiments provide for a device, comprising:
(A) a substrate (e.g., 404);
(B) a transmitter (e.g., 420) mounted on the substrate, the transmitter comprising: a transmit semiconductor die (e.g., 422a) having integrated thereon: a transmit antenna array (e.g., 1132) comprising a first plurality of transmit RF antennas (e.g., 1170, 1270) configured to transmit first RF signals; and transmit circuitry (e.g., 1160) configured to feed the plurality of RF antennas in the transmit antenna array;
(C) a receiver (e.g., 430) mounted on the substrate, the receiver comprising: a receive semiconductor die (e.g., 432a) having integrated thereon: a receive antenna array (e.g., antennas 1486) comprising a second plurality of RF antennas configured to receive second RF signals; receive circuitry (e.g., 1480) configured to process the RF signals received by the plurality of RF antennas to obtain processed RF signals;
(D) analog-to-digital conversion (ADC) circuitry (e.g., 454) mounted on the substrate, the ADC circuitry coupled to the receive circuitry and configured to digitize the processed RF signals to obtain digitized RF signals; and
(E) processing circuitry (e.g., 440) configured to operate at least one of the transmit circuitry, receive circuitry, and the ADC circuitry in: (1) a first operating state in a plurality of time intervals (e.g., the t1-t2 and t4-t5 intervals shown in FIG. 30), each of the plurality of time intervals including time when the first plurality of RF antennas are being operated to transmit the first RF signals and/or time when the second plurality of RF antennas are being operated to receive the second RF signals; and (2) a second operating state outside of the plurality of time intervals (e.g., during the t2-t4 and/or the t3-t4 time periods shown in FIG. 30), wherein the at least one of the transmit circuitry, the receive circuitry, and the ADC circuitry is operated using less power in the second operating state than is used to operate it in the first operating state.

In some embodiments, the processing circuitry is configured to operate the transmit circuitry in the first operating state in the plurality of time intervals (e.g., t1-t2 and t4-t5) and in the second operating state outside of the plurality of time intervals (e.g., between t3-t4).

In some embodiments, the processing circuitry is configured to operate the receive circuitry in the first operating state in the plurality of time intervals (e.g., t1-t2 and t4-t5) and in the second operating state outside of the plurality of time intervals (e.g., between t2-t4).

In some embodiments, the processing circuitry is configured to operate the ADC circuitry in the first operating state in the plurality of time intervals (e.g., t1-t3) and in the second operating state outside of the plurality of time intervals (e.g., t3-t4).

In some embodiments, the processing circuitry operates at least one of the transmit circuitry, receive circuitry, and the ADC circuitry in the second operating state by powering off the at least one of the transmit circuitry, receive circuitry, and the ADC circuitry.

In some embodiments, the ADC circuitry is integrated on the receive semiconductor die (e.g., FIGS. 38E, 39A-39B). In some embodiments, the ADC circuitry is mounted on the substrate. In some embodiments, the ADC circuitry is configured to communicate the digitized RF signals to the processing circuitry using a standardized serial interface (e.g., JESD). In some embodiments, the processing circuitry is mounted on the substrate (e.g., 404).

In some embodiments, the processing circuitry is configured to operate the at least one of the transmit circuitry, the receive circuitry, and the ADC circuitry in the second operating state between a first time interval (e.g., t1-t2) of the plurality of time intervals and a second time interval (e.g., t4-t5) of the plurality of time intervals.

In some embodiments, the ADC circuitry comprises a plurality of ADC channels including a first number (e.g., 13) of ADC channels; the receiver comprises a plurality of receive channels including a second number of receive channels (e.g., 32) that is greater than the first number of ADC channels; and the interface circuitry further comprises a time-division multiplexer configured to interface between the second number of receive channels and the first number of ADC channels.

FIG. 30 is a timing diagram illustrating example states in which components of device 400 may be operated, in accordance with some embodiments of the technology described herein. For example, as shown in FIG. 30, the timing diagram illustrates operation of ADC circuitry (e.g., AFE/ADC unit(s) 452a-452c), transmit circuitry (e.g., 1160), receive circuitry (e.g., 1480), processing circuitry (e.g., 440), signal generation circuitry (e.g., 410), and a serial link.

In some embodiments, the serial link illustrated in FIG. 30 may be configured to communicate digitized signals from receiver 430 to processing circuitry 440. For example, the serial link may use a standardized serial interface such as JESD interface. In some embodiments, a serial link may be executed using communication circuitry coupled to the ADC circuitry and configured for sending serial messages over the link to processing circuitry 440. For example, in some embodiments in which ADC circuitry is integrated on a receive semiconductor die (e.g., die 432), a serial link may be executed using communication circuitry integrated on the receive semiconductor die. Alternatively or additionally, in some embodiments in which ADC circuitry is integrated on a separate semiconductor die (e.g., a mixed-signal ASIC), a serial link may be executed using communication circuitry integrated on the separate semiconductor. It should be appreciated, as well, that a serial link may be omitted in some embodiments, such as where ADC circuitry is integrated on a same semiconductor die (and/or within a same package) as processing circuitry 440.

In some embodiments, processing circuitry 440 of device 400 may be configured to operate at least some components of device 400 in multiple operating states. For example, as shown in FIG. 30, processing circuitry 440 may be configured to operate each of transmitter 420, receiver 430, signal generation circuitry 410, and the serial link in a first operating state in time interval t1 to t2 and time interval 14 to t5, and in a second operating state outside of those time intervals. For instance, in FIG. 30, transmitter 420, receiver 430, signal generation circuitry 410, and the serial link are shown operating in the second operating state between time interval t1 to t2 and time interval t4 to t5. Also shown in FIG. 30, processing circuitry 440 may be configured to operate AFE/ADC units 452-452c in a first operating state in time interval t1′ to t2′ and time interval t4′ to t5′, and in a second operating state outside of those intervals. For instance, in FIG. 30, AFE/ADC units 452a-452c are shown operating in the second operating state between time interval t1′ to t2′ and time interval t4′ to t5′. In some embodiments, AFE/ADC units 452a-452e may be operated in the first operating state between times t1′ and t1 and/or between times t4′ and t4 as part of a warmup prior to arrival of signals from receiver 430 for digitizing. In some embodiments AFE/ADC units 452a-452c may be operated in the first operating state between times t2 and t2′ and/or between times t5 and t5′ as part of a cooldown following digitizing of signals from receiver 430.

While FIG. 30 shows each of transmitter 420, receiver 430, AFE/ADC units 452a-452c, signal generation circuitry 410, and the serial link operating in first and second operating states in the illustrated time intervals, it should be appreciated that only some circuitry may be so configured depending on the embodiment. According to various embodiments, fewer than all of transmitter 420, receiver 430, AFE/ADC units 452a-452e, signal generation circuitry 410, and the serial link may be operated in the first and second operating states. For example, at least one, at least two, and/or all three of transmitter 420, receiver 430, and AFE/ADC units 452a-452e may be operated in the first and second operating states, in some embodiments. For instance, while transmitter 420 and receiver 430 are shown operated in the first and second operating states in the same time intervals in FIG. 30, in some embodiments, they may be operated in the first and second operating states during different time intervals.

In some embodiments, time intervals in which transmitter 420, receiver 430, and/or AFE/ADC units 452a-452e are operated in a first operating state may include time in which RF antennas of transmitter 420 are being operated to transmit RF signals and/or time when RF antennas of receiver 430 are being operated to receive RF signals. For example, in FIG. 30, the time intervals t1 to t2, t4 to t5, t1′ to t2′, and/or t4′ to t5′ may each include time when transmitter 420 is transmitting RF signals and/or receiver 430 is receiving RF signals in response to reflection of the transmitted RF signals off of a target object.

In some embodiments, transmit circuitry of transmitter 420 (e.g., frequency multipliers and/or amplifiers), receive circuitry of receiver 430 (e.g., frequency multipliers, mixers, and/or amplifiers), and/or ADC circuitry of AFE/ADC units 452a-452e may be operated differently (e.g., using different amounts of power) depending on the operating state. For example, in some embodiments, the transmit circuitry, receive circuitry, and/or ADC circuitry may be operated using less power in the second operating state than is used to operate it in the first operating state. For instance, the transmit circuitry, receive circuitry, and/or ADC circuitry may powered off in the second operating state.

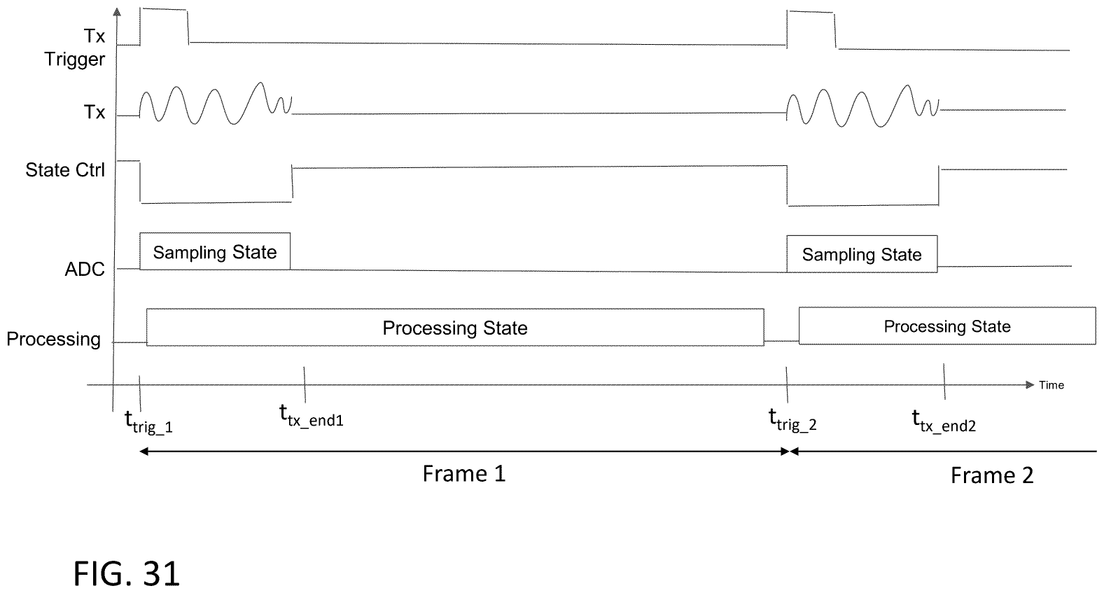

FIG. 31 is a timing diagram illustrating alternative example states in which components of device 400 may be operated over multiple frames, in accordance with some embodiments of the technology described herein.

In some embodiments, the example states shown in FIG. 31 may operate as described herein including in connection with FIG. 30. For example, as shown in FIG. 30, the timing diagram illustrates operation of ADC circuitry, transmit circuitry, and processing circuitry. As further shown in FIG. 30, the timing diagram illustrates a transmission trigger signal (e.g., sent from the processing circuitry to the transmitter) and a state control signal (e.g., sent from the processing circuitry to the receiver and/or ADC circuitry).

In some embodiments, device 400 may be operated in different operating states over multiple frames. For example, FIG. 31 shows Frame 1 starting at time t_{trig_1} and ending at time t_{trig_2}, at which point Frame 2 begins. For example, each frame may begin with a pulse of the transmission trigger signal, such as may cause the transmit circuitry to transmit RF signals. In the illustrated embodiment, each frame may include transmission up to a transmission end time t_{tx_end1}. For instance, within Frame 1, transmit circuitry may be operated in the first operating state from time t_{trig_1} to transmission end time t_{tx_end1} and in the second operating state outside of that interval. Similarly, within Frame 2, transmit circuitry may be operated in the first operating state from time t_{trig_2} to transmission end time t_{tx_end2} (e.g., to transmit one or more RF signals) and in the second operating state outside of that interval (e.g., to conserve power).

In some embodiments, the ADC circuitry (e.g., and receiver) may be in the first operating state starting from transmission of RF signals and ending shortly after the transmission end time (e.g., allowing time for reflected signals from a maximum range to arrive). For example, the processing circuitry may be configured to provide the state control signal to the ADC circuitry (e.g., and receiver) to operate in the first operating state based on the state control signal. In some embodiments, the processing circuitry may enter the first operating state shortly after the receiver and/or ADC circuitry enter the first operating state, such as to receive digital samples of received RF signals once generated by the ADC circuitry.

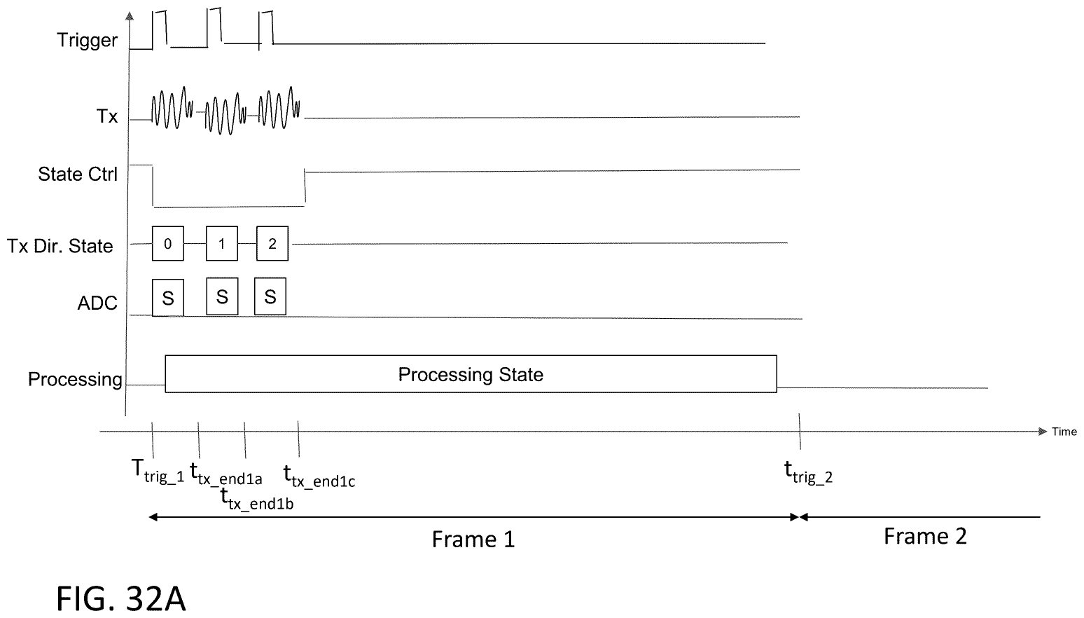

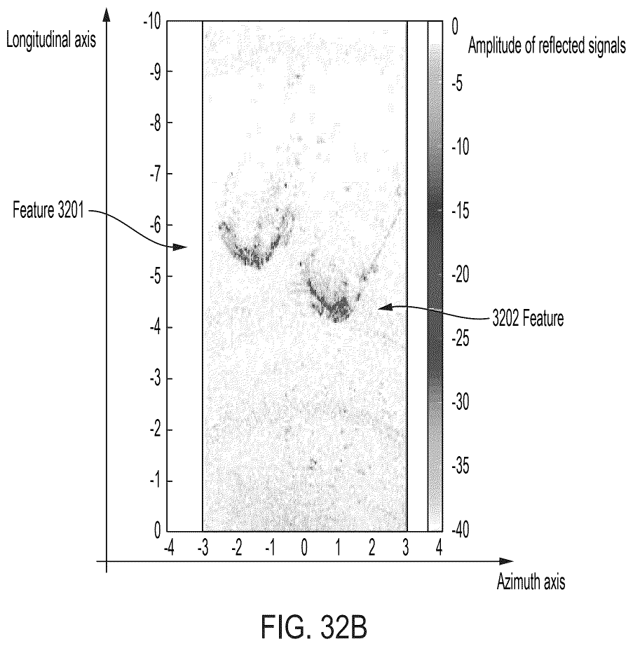

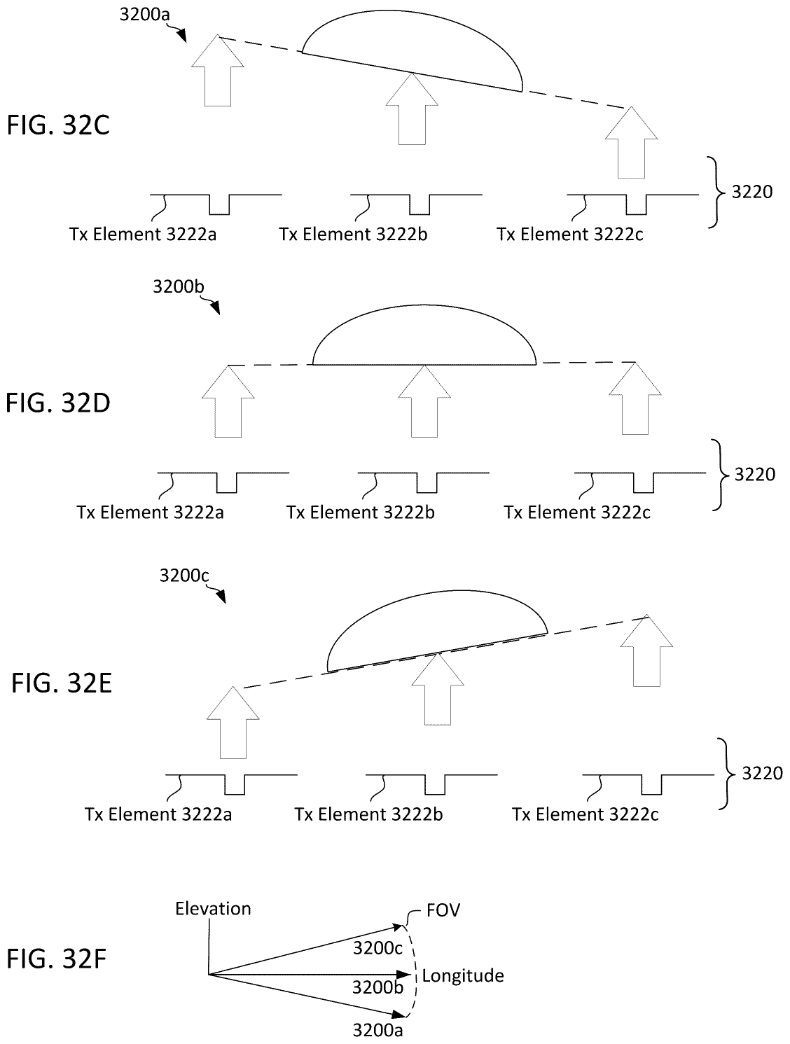

FIG. 32A is a timing diagram illustrating example states in which components of the device of FIG. 4A may be operated within Frame 1 of FIG. 31, in accordance with some embodiments of the technology described herein.

In some embodiments, a RADAR device (e.g., 400) may be configured to transmit RF signals over multiple directions (e.g., in elevation) and/or receive RF signals over multiple direction (e.g., in azimuth) within a frame. For example, the timing diagram of FIG. 32A further shows a transmit directional state signal having different states within Frame 1, each of which may control the transmitter to focus transmission of an RF signal in a respective direction (e.g., along the elevation axis). For instance, as shown in FIG. 32A, the transmit directional state signal has a first state from time t_{trig_1} to a first transmission end time t_{tx_end1a}, a second state from first transmission end time t_{tx_end1a} to second transmission end time t_{tx_end1b}, and a third state from second transmission end time t_{tx_end1b} to third transmission end time t_{tx_end1c}. In some embodiments, during each illustrated state of the transmit directional state signal, the transmitter may be configured to focus transmission of RF signals (e.g., in response to a pulse of the transmit trigger signal) in a different direction (e.g., in elevation), such as by applying a different phase shift pattern to the transmit antenna array(s). In some embodiments, ADC circuitry may be in the first operating state at least shortly after each transmission trigger signal pulse.

While not shown in FIG. 32A, it should be appreciated that multiple RF signals may be transmitted in each transmit directional state, such as by operating the receiver in different receive directional states (e.g., in azimuth) for each RF signal transmission. For instance, by scanning one axis (e.g., elevation) with transmitted RF signals and scanning another axis (e.g., azimuth) with reception of RF signals, each received RF signal may be determined (e.g., by the processing circuitry) as having been reflected (e.g., from a target object) in a particular direction in two-dimensional space (e.g., with a third dimensional constraint on the location of the target object being obtained by determined distance from the device to the object.

The inventors have further developed systems and methods (which may be used in connection with any of the hardware implementations described herein) for imaging target objects in multiple dimensions. Some embodiments, for example, relate to systems and methods for imaging target objects in two dimensions (e.g., along the longitudinal axis and the elevation axis or along the longitudinal axis and the azimuth axis) or in three dimensions (along the longitudinal axis, the elevation axis and the azimuth axis). Multi-dimensional images provide a more complete picture of the surrounding area relative to one-dimensional images.

Images of the types described herein include data sets relating a characteristic of reflected waves (e.g., the amplitude, power or phase of reflected waves) to space. A one-dimensional image, for example, may include a data set relating the power of reflected waves to the longitudinal axis. To each location along the longitudinal axis corresponds a value representing a characteristic of the reflected waves. As another example, a two-dimensional image may include a data set relating the power of reflected waves to the longitudinal axis and the azimuth axis (a range-cross range image), or a data set relating the power of reflected waves to the longitudinal axis and the elevation axis. An example of a range-cross range image is depicted in FIG. 32B. Here, the y-axis represents the longitudinal direction, and the x-axis represents the azimuth direction. Both axes are discretized, thereby forming a two-dimensional grid. To each element of the grid corresponds a value representing the power of a reflected signal. The image of FIG. 32B includes two features, 3201 and 3202. Each feature indicates the presence of a target object at a particular location in space relative to the transmitter/receiver. As another example, a three-dimensional image may include a data set relating the power of a reflected signal to the longitudinal axis, the azimuth axis and the elevation axis. In some embodiments, imaging an object involves generating a data set relating a characteristic of reflected waves (e.g., the amplitude, power or phase of reflected waves) to space in one, two or three dimensions.

Information with respect to the elevation axis may be obtained using a sequence of pulses transmitted over time in different directions along the elevation axis. For example, within an imaging frame, several scans may be performed, each corresponding to a different slice with respect to the elevation axis. Transmission of a pulse in a desired elevation direction may be obtained using beamforming (e.g., using a phased transmit array). Each transmitted pulse may result in a return signal (e.g., received at each receive element) indicating a distance traveled by the transmitted pulse. The return signal may be associated with an elevation direction with respect to the elevation axis based on the elevation direction in which the pulse was transmitted. The return signal may be further associated with a longitudinal distance based on a center frequency of the return signal (e.g., using linear frequency modulated transmit pulses). A two-dimensional range-cross range image (e.g., along the longitudinal axis and the elevation axis) or a three-dimensional range-cross range image (e.g., along the longitudinal axis, the elevation axis, and the azimuth axis) may be obtained. In some embodiments, a three-dimensional image may be obtained by performing a two-dimensional Fast Fourier Transform (FFT) on return signals received at multiple receive elements into a spatial-frequency domain, with a first dimension of the transform including the center frequency of the return signal (e.g., indicating longitudinal distance) and a second dimension of the transform including the receive element that received the return signal.

FIGS. 32C-32F illustrate example operation of a transmitter 3220 configured to transmit pulses in different elevation directions along the elevation axis using respective beamforming patterns.

FIG. 32C is a diagram illustrating example operation of transmitter 3220 according to a first transmit beamforming pattern 3200a, in accordance with some embodiments of the technology described herein.

As shown in FIG. 32C, each transmit antenna element 3222a, 3222b, and 3222c of transmitter 3220 transmits an RF transmit signal to produce a transmit beam. In the illustrated embodiment, each transmit antenna element 3222a, 3222b, and 3222c transmits with a different phase-shifted version of the RF transmit signal, resulting in a phase front oriented in a nonzero elevation angular direction. For instance, phase shifters of transmitter 3220 may be configured to apply different phase shifts in response to a phase shift control signal (e.g., from processing circuitry). In the illustrated embodiment, with a phase front oriented in an angular direction of elevation, transmission may be focused in that direction.

FIG. 32D is a diagram illustrating example operation of transmitter 3220 according to a second transmit beamforming pattern 3200b, in accordance with some embodiments of the technology described herein.

As shown in FIG. 32D, each transmit antenna element 3222a, 3222b, and 3222c transmits an RF transmit signal to produce a transmit beam with the same phase version of the RF transmit signal, resulting in a phase front oriented at 0 degrees in elevation. For instance, phase shifters of transmitter 3220 may be configured to apply the same (and/or zero) phase shift in response to the phase shift control signal.

FIG. 32E is a diagram illustrating example operation of transmitter 3220 according to a third transmit beamforming pattern 3200c, in accordance with some embodiments of the technology described herein.

As shown in FIG. 32E, each transmit antenna element 3222a, 3222b, and 3222c transmits an RF transmit signal to produce a transmit beam with a different phase shifted version of the RF transmit signal, resulting in a phase front oriented in a nonzero elevation angular direction that is different from the angular direction shown in FIG. 32C. For instance, phase shifters of transmitter 3220 may be configured to apply different phase shifts from one another and with respect to phase shift pattern 3200a in response to the phase shift control signal.

In some embodiments, transmitter 3320 may be configured to transmit, at a first time (e.g., between t_{trig_1} and t_{txend_1a} in FIG. 32A), a first RF transmit signal according to a first beamforming pattern (e.g., 3200a) and transmit, at a second time after the first time (e.g., between t_{txend_1a} and t_{txend_1b} in FIG. 32A), a second RF transmit signal according to a second beamforming pattern (e.g., 3200b). For example, the first RF transmit signal and the second RF transmit signal may be transmitted during a frame (e.g., Frame 1 in FIG. 32A).

In some embodiments, processing circuitry of the device may be configured to generate a range-cross range image using RF receive signal(s) generated at least in part by reflection of the first RF transmit signal and/or of the second RF transmit signal from the target object (e.g., where the first RF transmit signal and the second RF transmit signal are transmitted during a frame). For example, a first two-dimensional range-cross range image (e.g., along the longitudinal axis and the azimuth axis) may be obtained using return signals generated at least in part by reflection of the first RF transmit signal, and a second two-dimensional range-cross range image may be obtained using return signals generated at least in part by reflection of the second RF transmit signal, and a three-dimensional range-cross range image (e.g., along the longitudinal axis, azimuth axis, and elevation axis) may be obtained by combining (e.g., superimposing) the first and second two-dimensional range-cross range images into three-dimensional image at their respective locations along the elevation axis.

In some embodiments, a two-dimensional range-cross range image may be obtained using return signals, generated at least in part by reflection of a (e.g., beamformed) transmit RF signal, by inputting the return signals to a two-dimensional FFT. For example, processing circuitry (e.g., 440) may be configured obtain digital representations of the return signals (e.g., via interface circuitry 450) from a receiver (e.g., 430) and input the digital representations to a two-dimensional FFT. In some embodiments, a first dimension of the two-dimensional FFT may include a center-frequency of the return signal. For example, the return signals may be mixed to an intermediate frequency (IF) band (e.g., having 5 MHz bandwidth) with a center-frequency indicating longitudinal distance traveled by the return signals. In some embodiments, a second dimension of the two-dimensional FFT may include azimuth positions of receive elements that received the receive signals. For example, differences in longitudinal distance traveled by azimuth position of the receive elements may indicate an azimuth direction from which the return signal was received.

In some embodiments, RADAR thresholding techniques may be applied to the FFT output to identify peaks indicating azimuth directions from which and longitudinal distances over which return signals were received. For example, a signal-to-noise ratio (SNR) threshold (e.g., 13.4 dB) may be used, and optionally may be adjusted to account for atmospheric attenuation based on the range of longitudinal distances indicating the highest return signal power (e.g., the threshold may be lowered where return signal power is concentrated at long range and/or raised where return signal power is concentrated at short range). In the same or another example, first order rejection techniques may be applied (e.g., to reject ground reflections where the transmitted pulse was not focused toward the ground). In some embodiments, synthetic receive data may be generated and input to the FFT, along with the data of the received return signals, to simulate the presence of additional receive elements for populating the FFT. In some embodiments, calibration data (e.g., indicating a measured phase shift per receive element) may be used to adjust return signal data (e.g., to account for the measured phase shifts) prior to inputting the return signal data to an FFT.

FIG. 32F is a diagram illustrating angular directions of transmission focus in elevation for transmit beamforming patterns 3200a, 3200b, and 3200c, respectively, in accordance with some embodiments of the technology described herein.

In some embodiments, beamforming patterns such as shown in FIGS. 32C-32E may be used to perform an angular transmit sweep over an angular field of view. For example, according to beamforming pattern 3200a, transmitter 3220 may be configured to focus transmission of a first RF transmit signal in a first angular direction and, according to beamforming pattern 3200b, transmitter 3220 may be configured to focus transmission of a second RF transmit signal in a second angular direction. For instance, as shown in FIG. 32F, the angular directions of beamforming patterns 3200a, 3200b, and 3200c are different in the elevation-longitude plane, with beamforming patterns 3200a and 3200c above and below 0 degrees in elevation and beamforming pattern 3200b at 0 degrees in elevation, along the longitudinal axis.

In some embodiments, TX beamforming patterns may be selectable by processing circuitry to perform a scan during a frame (e.g., Frame 1), such as described above in connection with FIG. 32A. It should be appreciated that, while phase shifting is described herein as providing beamforming patterns, other beamforming methods may be used, such as using mechanical steering and/or transmit element selection (e.g., in which different subsets of transmit elements are selected to transmit pulses focused in different respective directions).

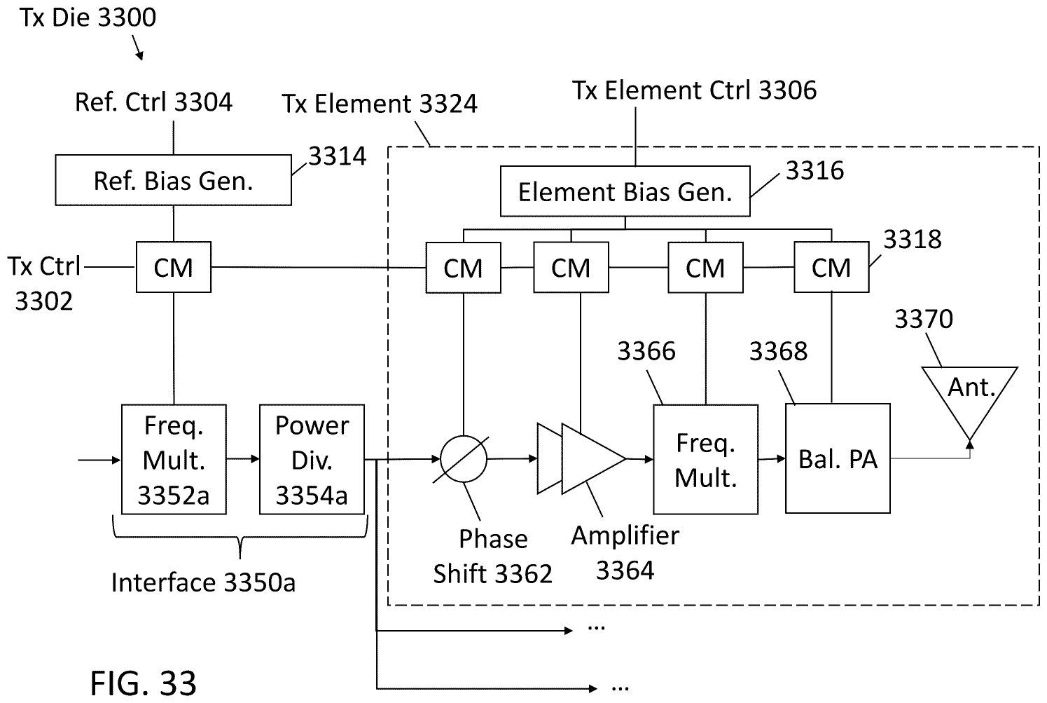

FIG. 33 is a block diagram of an example transmit element 3324 of a transmit semiconductor die 3300 that may be included in device 400, in accordance with some embodiments of the technology described herein.

In some embodiments, transmit semiconductor die 3300 may be configured as described herein for transmit semiconductor die 922 including in connection with FIG. 11A. For example, as shown in FIG. 33, transmit semiconductor die 3300 includes an interface 3350a including frequency multiplier 3352a and power divider 3354a. Also shown in FIG. 33, transmit semiconductor die 3300 includes transmit elements 3324, which may be configured as described herein for transmit element 1124 including in connection with FIG. 11A. For instance, in FIG. 33, a transmit element 3324 includes a phase shifter 3362, amplifier 3364, frequency multiplier 3366, balanced power amplifier 3368, and an antenna 3370 (e.g., of a transmit antenna array).

In some embodiments, processing circuitry (e.g., 440) of device 400 may be configured to operate transmit circuitry on transmit semiconductor die 3300 in a first operating state and a second operating state by providing one or more control signals to transmit semiconductor die 3300. For example, as shown in FIG. 33, transmit semiconductor die 3300 receives a transmit control (Tx Ctrl) signal 3302, a reference control (Ref. Ctrl) signal 3304, and a transmit element control (Tx El. Ctrl) signal 3306, which may be received from processing circuitry 440. It should be appreciated that a transmit semiconductor die 3300 may be configured to receive fewer than all control signals 3302, 3304, and 3306, such as any one or any two of control signals 3302, 3304, and 3306.

In some embodiments, processing circuitry of device 400 may be configured to operate transmit semiconductor die 3300 in a first operating state and a second operating state using transmit control signal 3302. For example, as shown in FIG. 33, transmit semiconductor die 3300 includes a plurality of current mirrors (CM) 3318 coupled to respective active components of die 3300, with each current mirror 3318 configured to receive transmit control signal 3302. For instance, in FIG. 33, current mirrors 3318 are coupled to frequency multiplier 3352a, phase shifter 3362, amplifier 3364, frequency multiplier 3366, and balanced power amplifier 3368, respectively.

In some embodiments, transmit control signal 3302 may be configured to adjust the biasing of current mirrors 3318 such that, when transmit control signal 3302 has a first voltage level, active components of transmit semiconductor die 3300 may be operated in the first operating state, whereas when transmit control signal 3302 has a second voltage level, the active components of transmit semiconductor die 3300 may be operated in the second operating state. In some embodiments, transmit element control signal 3302 may be configured to adjust the biasing of current mirrors 3318 between a high current level and a low current level (e.g., powered off). For example, where current mirrors 3318 are implemented using PMOS transistors, a low voltage level may bias the current mirrors 3318 to operate the active components of transmit semiconductor die 3300 in the first operating state, and a high voltage level may bias the current mirrors 3318 to operate the active components in the second operating state, though it should be appreciated that different current levels may be used (e.g., for NMOS transistors). While, in some embodiments, transmit control signal 3302 may be configured to switch current mirrors 3318 between full and no power, in other embodiments, transmit control signal 3302 may be configured to switch current mirrors 3318 between multiple power levels (e.g., full power and reduced power).

In some embodiments, processing circuitry of device 400 may be configured to operate some or all transmit elements 3324 in a first operating state and a second operating state using transmit element control signal 3306. For example, as shown in FIG. 33, some of current mirrors 3318 are coupled to respective active components of a transmit element 3324. For instance, current mirrors 3318 may be provided for some or all transmit elements 3324, and/or transmit element control signals 3306 may be received from the processing circuitry for some or all transmit elements 3324.

In some embodiments, transmit element control signal 3306 may be configured to disable biasing of current mirrors 3318. For example, as shown in FIG. 33, current mirrors 3318 of transmit element 3324 are coupled to a transmit element bias generator 3316, which is configured to receive transmit element control signal 3306. For instance, when transmit element control signal 3306 enables transmit element bias generator 3316, active components of transmit element 3324 may be operated in the first operating state, whereas when transmit element control signal 3306 disables transmit element bias generator 3316, the active components of transmit semiconductor die 3300 may be operated in the second operating state. While in some embodiments transmit element control signal 3306 may be configured to fully enable and disable transmit element bias generator 3316, in other embodiments, transmit element control signal 3306 may be configured to switch transmit element bias generator 3316 between multiple power levels (e.g., full power and reduced power).

In some embodiments, processing circuitry of device 400 may be configured to operate active components of interface 3350a in a first operating state and a second operating state using reference control signal 3304. For example, as shown in FIG. 33, a current mirror 3318 is coupled to frequency multiplier 3352a and further coupled to a reference bias generator 3314 that is configured to receive reference control signal 3304. For instance, when reference control signal 3304 enables reference bias generator 3314, frequency multiplier 3352a may be operated in the first operating state, whereas when reference control signal 3304 disables reference bias generator 3314, frequency multiplier 3352a may be operated in the second operating state.

In some embodiments, transmit element bias generator 3316 and/or reference bias generator 3314 may include bandgap voltage reference generators.

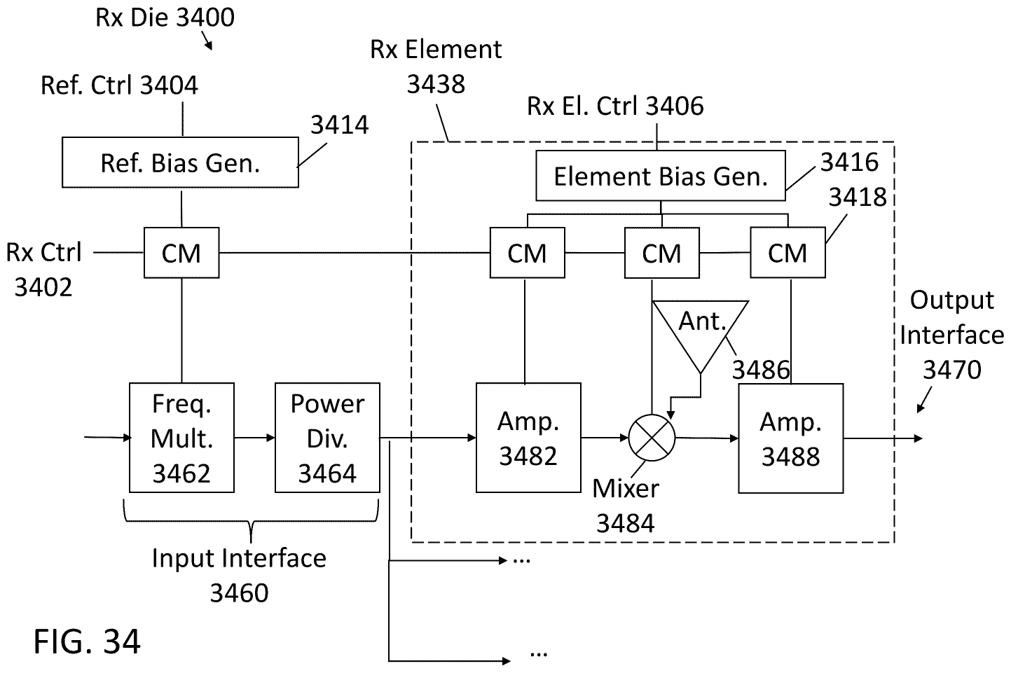

FIG. 34 is a block diagram of an example receive element 3438 of a receive semiconductor die 3400 that may be included in device 400, in accordance with some embodiments of the technology described herein.

In some embodiments, receive semiconductor die 3400 may be configured as described herein for receive semiconductor die 1432 including in connection with FIG. 14A. For example, as shown in FIG. 34, receive semiconductor die 3400 includes an input interface 3460 including frequency multiplier 3462 and power divider 3464. Also shown in FIG. 34, receive semiconductor die 3400 includes receive elements 3438, which may be configured as described herein for receive element 1438 including in connection with FIG. 14A. For instance, in FIG. 34, a receive element 3438 includes an amplifier 3482, mixer 3484, antenna 3486 (e.g., of a receive antenna array), and amplifier 3488 coupled to an output interface 3470.

In some embodiments, processing circuitry (e.g., 440) of device 400 may be configured to operate receive circuitry on receive semiconductor die 3400 in a first operating state and a second operating state by providing one or more control signals to receive semiconductor die 3400. For example, as shown in FIG. 34, receive semiconductor die 3400 receives a receive control (Rx Ctrl) signal 3402, a reference control (Ref. Ctrl) signal 3404 (e.g., the same or separate from signal 3304), and a receive element control (Rx El. Ctrl) signal 3406, which may be received from processing circuitry 340. It should be appreciated that a receive semiconductor die 3400 may be configured to receive fewer than all control signals 3402, 3404, and 3406, such as any one or any two of control signals 3402, 3404, and 3406.

In some embodiments, processing circuitry of device 400 may be configured to operate receive semiconductor die 3400 in a first operating state and a second operating state using receive control signal 3402. For example, as shown in FIG. 34, receive semiconductor die 3300 includes a plurality of current mirrors 3418 coupled to respective active components of die 3400, with each current mirror 3418 configured to receive the receive control signal 3402. For instance, in FIG. 34, current mirrors 3418 are coupled to frequency multiplier 3462, amplifier 3482, mixer 3484, and amplifier 3488, respectively.

In some embodiments, receive control signal 3402 may be configured to adjust the biasing of current mirrors 3418 such that, when receive control signal 3402 has a first voltage level, active components of receive semiconductor die 3400 may be operated in the first operating state, whereas when receive control signal 3402 has a second voltage level, the active components of receive semiconductor die 3400 may be operated in the second operating state. In some embodiments, receive element control signal 3402 may be configured to adjust the biasing of current mirrors 3418 between a high current level and a low current level (e.g., powered off). While, in some embodiments, receive control signal 3402 may be configured to switch current mirrors 3418 between full and no power, in other embodiments, receive control signal 3402 may be configured to switch current mirrors 3418 between multiple power levels (e.g., full power and reduced power).

In some embodiments, processing circuitry of device 400 may be configured to operate some or all receive elements 3438 in a first operating state and a second operating state using receive element control signal 3406. For example, as shown in FIG. 34, some of current mirrors 3418 are coupled to respective active components of a receive element 3438. For instance, current mirrors 3418 may be provided for some or all receive elements 3438, and/or receive element control signals 3406 may be received from the processing circuitry for some or all receive elements 3438.

In some embodiments, receive element control signal 3406 may be configured to disable biasing of current mirrors 3418. For example, as shown in FIG. 34, current mirrors 3418 of receive element 3438 are coupled to a receive element bias generator 3416, which is configured to receive a receive element control signal 3406. For instance, when receive element control signal 3406 enables receive element bias generator 3416, active components of receive element 3438 may be operated in the first operating state, whereas when receive element control signal 3406 disables receive element bias generator 3416, the active components of receive semiconductor die 3400 may be operated in the second operating state. While in some embodiments receive element control signal 3406 may be configured to fully enable and disable receive element bias generator 3416, in other embodiments, receive element control signal 3406 may be configured to switch receive element bias generator 3416 between multiple power levels (e.g., full power and reduced power).

In some embodiments, processing circuitry of device 400 may be configured to operate active components of input interface 3460 in a first operating state and a second operating state using reference control signal 3404. For example, as shown in FIG. 34, a current mirror 3418 is coupled to frequency multiplier 3462 and further coupled to a reference bias generator 3414 that is configured to receive reference control signal 3404. For instance, when reference control signal 3404 enables reference bias generator 3414, frequency multiplier 3462 may be operated in the first operating state, whereas when reference control signal 3404 disables reference bias generator 3414, frequency multiplier 3462 may be operated in the second operating state.

In some embodiments, receive element bias generator 3416 and/or reference bias generator 3414 may include bandgap voltage reference generators.

### Receiver Offloading Configurations

As described above, the inventors have recognized that it would be beneficial to consolidate channels of a RADAR device, as doing so provides multiple benefits. One such benefit is conserving the amount of power drawn by components of the RADAR device, as consolidating channels reduces the number of components that are powered to process data from each channel. One benefit of saving power drawn by components is that more power is available for transmitting signals (e.g., as transmission distance is limited by atmospheric attenuation). Another benefit of consolidating channels of a RADAR device is it may simplify the layout of the RADAR device, which reduces the complexity of manufacturing the RADAR device.

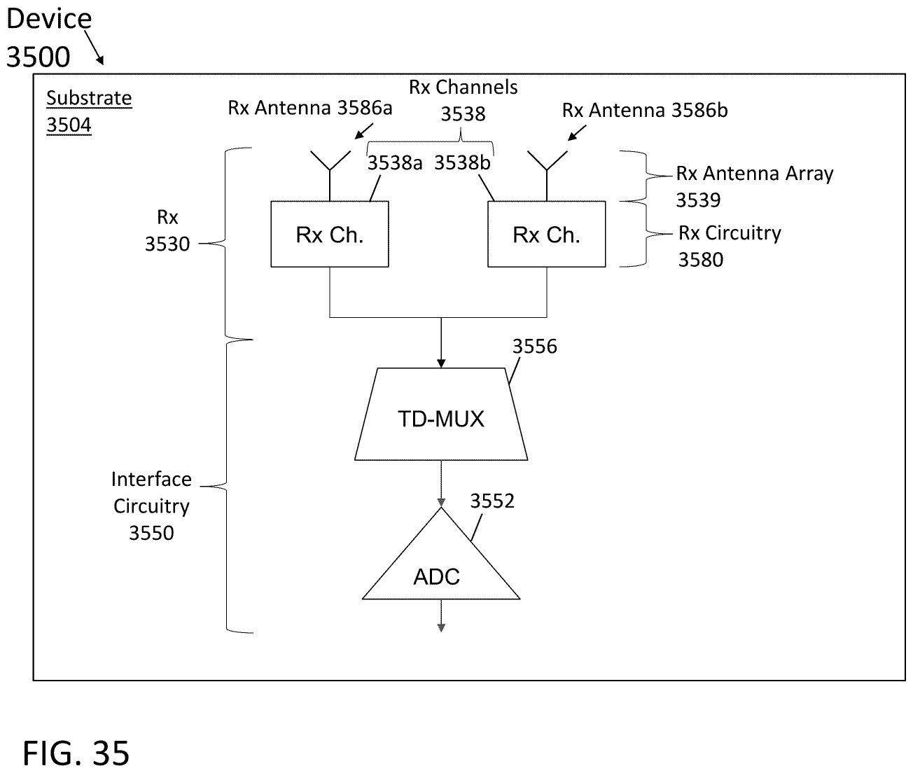

Accordingly, in some embodiments, time-division multiplexing may be implemented in interface circuitry coupled to a receiver of a RADAR device to reduce the number of ADC channels used to digitize signals from receive channels of the receiver. The introduction of such time-division multiplexing reduces the amount of power drawn by the components of the RADAR device and therefore confers the above-described benefits. For example, as shown in FIG. 35, interface circuitry (e.g., 3550) of a RADAR device (e.g., 3500) may include time-division multiplexing circuitry (e.g., 3556) configured to combine processed RF signals, obtained from a first receive channel (e.g., 3538a) and a second receive channel (e.g., 3538b) of a receiver (e.g., 3530) of the RADAR device, into a time-division multiplexed signal to be digitized by ADC circuitry (e.g., 3552). In some embodiments, by combining the processed RF signals from first and second receive channels into a single time-division multiplexed signal, the ADC circuitry (e.g., 3552) may devote only a single ADC channel to digitizing the processed RF signal combined from the first and second receive channels, thereby conserving power that might otherwise be consumed in digitizing the same processed RF signals using multiple ADC channels.

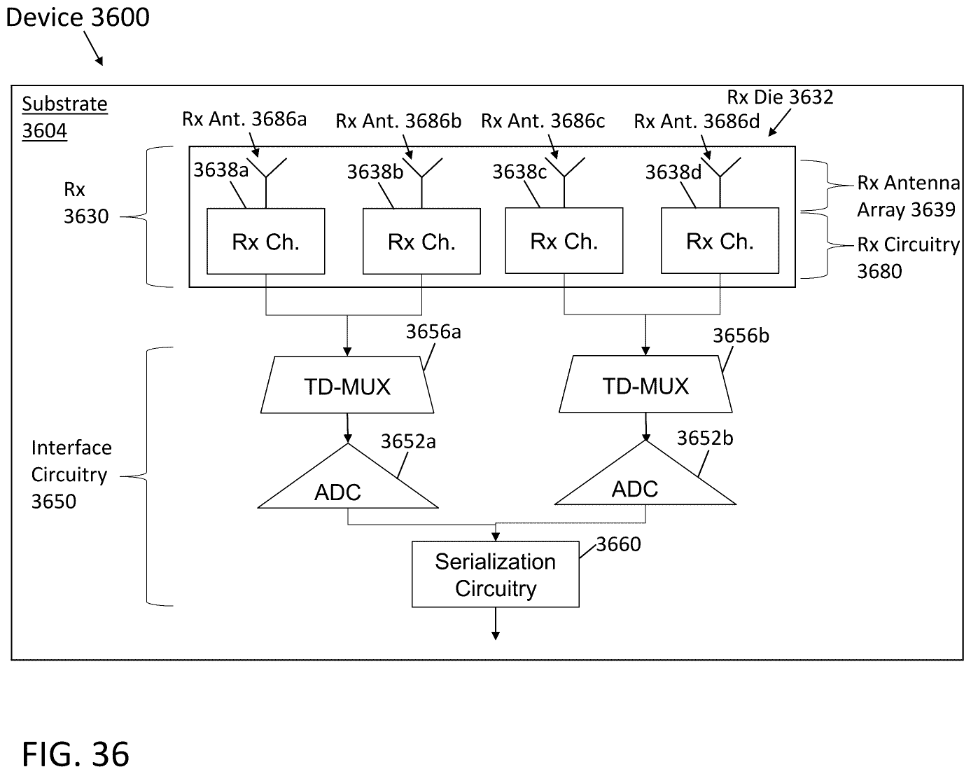

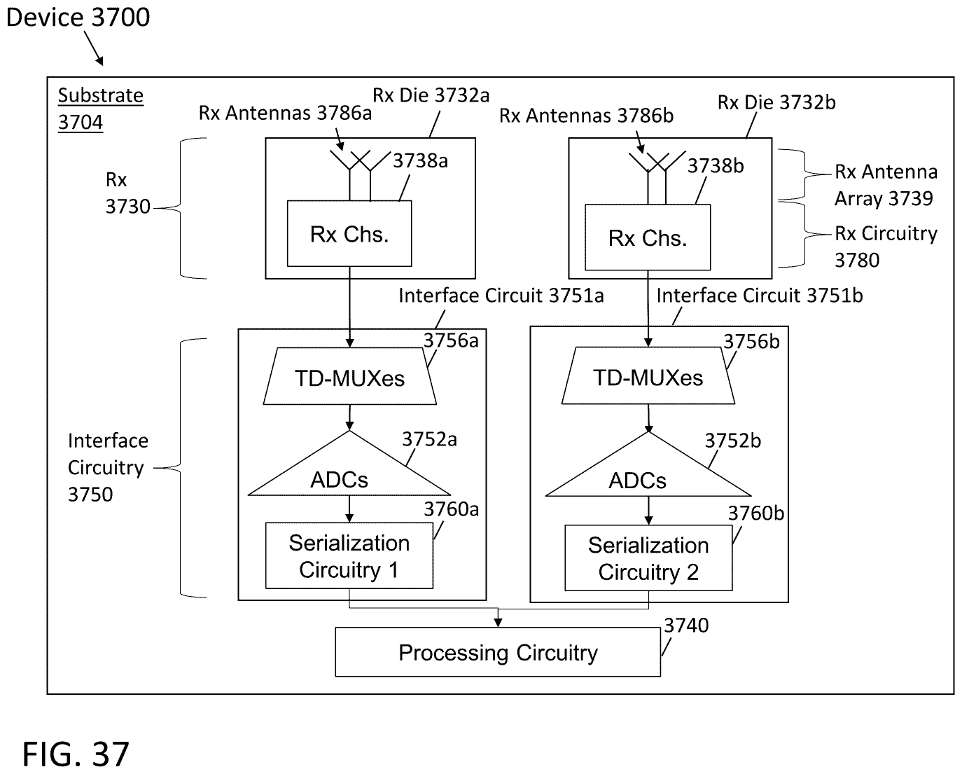

In some embodiments, a device (e.g., 3500 in FIG. 35, 3600 in FIG. 36, 3700 in FIG. 37) comprises:
(A) a substrate (e.g., 3504, 3604, 3704);
(B) a receiver (e.g., 3530, 3630, 3730) mounted on the substrate, the receiver comprising: a receive antenna array (e.g., 3539, 3639, 3739) comprising a first plurality of receive RF antennas (e.g., 3586a-3586b, 3686a-3686b, 3786a), the first plurality of receive RF antennas comprising: a first receive RF antenna (e.g., 3586a, 3686a) configured to receive a first receive RF signal; and a second receive RF antenna (e.g., 3586b, 3686b) configured to receive a second receive RF signal; and receive circuitry (e.g., 3580, 3680, 3780) comprising a first plurality of receive channels (e.g., 3538a-3538b, 3638a-3638b, 3738a), the first plurality of receive channels comprising: a first receive channel (e.g., 3538a, 3638a) coupled to the first receive RF antenna and configured to process the first receive RF signal to obtain a first processed RF signal; and a second receive channel (e.g., 3538b, 3638b) coupled to the second receive RF antenna and configured to process the second receive RF signal to obtain a second processed RF signal; and
(C) interface circuitry (e.g., 3550, 3650, 3750) mounted on the substrate, the interface circuitry comprising: time-division multiplexing circuitry (e.g., 3556, 3656a-3656b, 3756a-3756b) coupled to the receive circuitry, the time-division multiplexing circuitry comprising a first time-division multiplexer (e.g., 3556, 3656a, 3756a) coupled to the first receive channel and to the second receive channel and configured to combine the first processed RF signal and the second processed RF signal into a first single time-division multiplexed signal; and analog-to-digital conversion (ADC) circuitry (e.g., 3552, 3652a-3652b, 3752a-3752b) comprising a first ADC circuit (e.g., 3552, 3652a, 3752a) coupled to the first time-division multiplexer and configured to digitize the first single time-division multiplexed signal into a first single digitized time-division multiplexed signal.

In some embodiments, the receive antenna array (e.g., 3639 in FIG. 36, 3739 in FIG. 37) further comprises a second plurality of receive RF antennas (e.g., 3686c-3686d, 3738b), the second plurality of receive RF antennas comprising: a third receive RF antenna (e.g., 3686c) configured to receive a third receive RF signal; and a fourth receive RF antenna (e.g., 3686d) configured to receive a fourth receive RF signal. In some embodiments, the receive circuitry (e.g., 3680 in FIG. 36, 3780 in FIG. 37) further comprises a second plurality of receive channels (e.g., 3638c-3638d, 3738b), the second plurality of receive channels comprising: a third receive channel (e.g., 3638c) coupled to the third receive RF antenna and configured to process the third receive RF signal to obtain a third processed RF signal; and a fourth receive channel (e.g., 3638d) coupled to the fourth receive RF antenna and configured to process the fourth receive RF signal to obtain a fourth processed RF signal. In some embodiments, the time-division multiplexing circuitry (e.g., 3656a-3656b in FIG. 36, 3756a-3756b in FIG. 37) further comprises a second time-division multiplexer (e.g., 3656b, 3756b) coupled to the third receive channel and to the fourth receive channel and configured to combine the third processed RF signal and the fourth processed RF signal into a second single time-division multiplexed signal. In some embodiments, the ADC circuitry (e.g., 3652a-3652b, 3752a-3752b) further comprises a second ADC circuit (e.g., 3652b, 3752b) coupled to the second time-division multiplexer and configured to digitize the second single time-division multiplexed signal into a second single digitized time-division multiplexed signal.

In some embodiments, the receiver (e.g., 3630 in FIG. 36) comprises a first receive semiconductor die (e.g., 3632) having integrated thereon: the first plurality of receive RF antennas (e.g., 3686a-3686b); the second plurality of receive RF antennas (e.g., 3686c-3686d); the first plurality of receive channels (e.g., 3638a-3638b); and the second plurality of receive channels (e.g., 3638c-3638d).

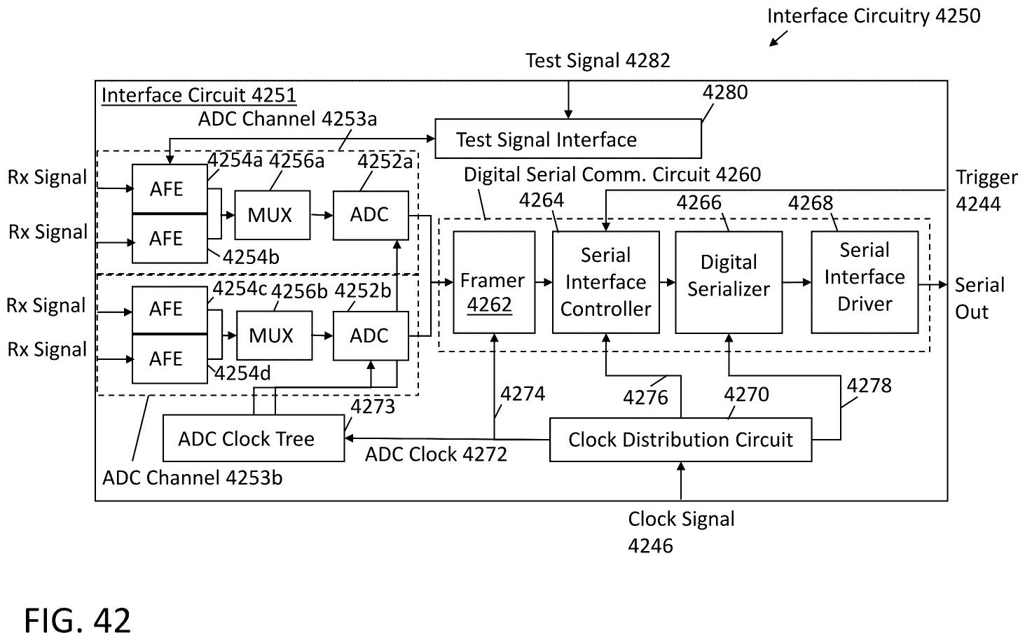

In some embodiments, the interface circuitry (e.g., 4250 in FIG. 42) further comprises: a digital serializer (e.g., 4266) configured to combine the first single digitized time-division multiplexed signal and the second single digitized time-division multiplexed signal into a single digital serial signal; and a serial interface driver (e.g., 4268) configured to transmit the single digital serial signal from the interface circuitry via the substrate.

In some embodiments, the receiver (e.g., 3730 in FIG. 37) comprises: a first receive semiconductor die (e.g., 3732a) having integrated thereon: the first plurality of receive RF antennas (e.g., 3786a); and the first plurality of receive channels (e.g., 3738a); and a second receive semiconductor die (e.g., 3732b) having integrated thereon: the second plurality of receive RF antennas (e.g., 3732b); and the second plurality of receive channels (e.g., 3738b).

In some embodiments, the interface circuitry (e.g., 3730 in FIG. 37) comprises: a first interface integrated circuit (e.g., 3751) having integrated therein: the first time-division multiplexer (e.g., 3756a); and the first ADC circuit (e.g., 3752a); and a second interface integrated circuit (e.g., 3751b) having integrated therein: the second time-division multiplexer (e.g., 3756b); and the second ADC circuit (e.g., 3752b).

In some embodiments, the device (e.g., 3700) further comprises processing circuitry (e.g., 3740) mounted on the substrate, communicatively coupled to the interface circuitry (e.g., 3750), and configured to determine a distance between the device and a target object that generated the first receive RF signal and the second receive RF signal based on the first single digitized time-division multiplexed signal.

In some embodiments, the first receive channel comprises a first mixer (e.g., 1484 in FIG. 14B) configured to mix the first receive RF signal with a reference signal to obtain the first processed RF signal, the first processed RF signal having a first center frequency; the second receive channel comprises a second mixer (e.g., 1484) configured to mix the second receive RF signal with the reference signal to obtain the second processed RF signal, the second processed RF signal having a second center frequency; and the first center frequency and the second center frequency are indicative of the distance between the device and the target object.

In some embodiments, the device (e.g., 400 in FIG. 4A) further comprises a transmitter (e.g., 420) mounted on the substrate, the transmitter comprising: a transmit antenna array (e.g., 1132 in FIG. 11A) comprising a plurality of transmit RF antennas (e.g., 1170 in FIG. 11B) configured to transmit first RF signals; and transmit circuitry (e.g., 1160 in FIG. 11B) configured to drive the plurality of transmit RF antennas to transmit the first RF signals, and the first receive RF signal and the second receive RF signal are generated, at least in part, by reflection of the first RF signals by the target object.

In some embodiments, the interface circuitry (e.g., 4250 in FIG. 42) further comprises amplification circuitry (e.g., 4254a-4254d) comprising: a first amplifier (e.g., 4254a) coupled between the first receive channel and the first time-division multiplexer (e.g., 4256a); and a second amplifier (e.g., 4254b) coupled between the second receive channel and the first time-division multiplexer (e.g., 4256a).

In some embodiments, the first receive RF signal and the second receive RF signal have an RF center frequency between 150 GHz and 1.5 THz. In some embodiments, the first receive RF signal and the second receive RF signal have an RF center frequency between 300 GHz and 320 GHz. In some embodiments, the first receive RF signal and the second receive RF signal have a bandwidth of at least 3 GHz or at least 6 GHz.

In some embodiments, a device (e.g., 3700 in FIG. 37), comprises
(A) a substrate (e.g., 3704)
(B) a receiver (e.g., 3730) mounted on the substrate, the receiver comprising: a first receive semiconductor die (e.g., 3732a) having integrated thereon: a first receive antenna array (e.g., 3739) comprising a first plurality of receive RF antennas (e.g., 3786a) configured to receive first receive RF signals; and first receive circuitry (e.g., 3780) comprising a first plurality of receive channels (e.g., 3738a) coupled to the first plurality of receive RF antennas and configured to process the first receive RF signals to obtain first processed RF signals; and
(C) interface circuitry (e.g., 3750) mounted on the substrate, the interface circuitry comprising: first time-division multiplexing circuitry (e.g., 3756a) coupled to the first receive circuitry, the first time-division multiplexing circuitry comprising a first plurality of time-division multiplexers configured to combine the first processed RF signals into first time-division multiplexed signals; and first analog-to-digital conversion (ADC) circuitry (e.g., 3752a) coupled to the first time-division multiplexing circuitry and comprising a first plurality of ADC circuits configured to digitize the first time-division multiplexed signals into first digitized time-division multiplexed signals.

In some embodiments, the device (e.g., 3700) further comprises processing circuitry (e.g., 3740) mounted on the substrate. In some embodiments, the receiver (e.g., 3730) further comprises a second receive semiconductor die (e.g., 3732b) having integrated thereon: a second receive antenna array (e.g., within 3739) comprising a second plurality of receive RF antennas (e.g., 3786b) configured to receive second receive RF signals; and second receive circuitry (e.g., within 3780) comprising a second plurality of receive channels (e.g., 3738b) coupled to the second plurality of receive RF antennas and configured to process the second receive RF signals to obtain second processed RF signals. In some embodiments, the interface circuitry (e.g., 3750) further comprises: second time-division multiplexing circuitry (e.g., 3756b) coupled to the second receive circuitry, the second time-division multiplexing circuitry comprising a second plurality of time-division multiplexers configured to combine the second processed RF signals into second time-division multiplexed signals; and second analog-to-digital conversion (ADC) circuitry (e.g., 3752b) coupled to the second time-division multiplexing circuitry and comprising a second plurality of ADC circuits configured to digitize the second time-division multiplexed signals into second digitized time-division multiplexed signals. In some embodiments, the processing circuitry (e.g., 3740) is configured to combine the first digitized time-division multiplexed signals with the second digitized time-division multiplexed signals.

In some embodiments, the first plurality of receive RF antennas comprises 36 receive RF antennas; the first plurality of receive channels comprises 36 receive channels coupled to the 36 receive RF antennas; the first plurality of time-division multiplexers comprises 16 time-division multiplexers coupled to the 36 receive channels; and the first plurality of ADC circuits comprises 16 ADC circuits coupled to the 16 time-division multiplexers.

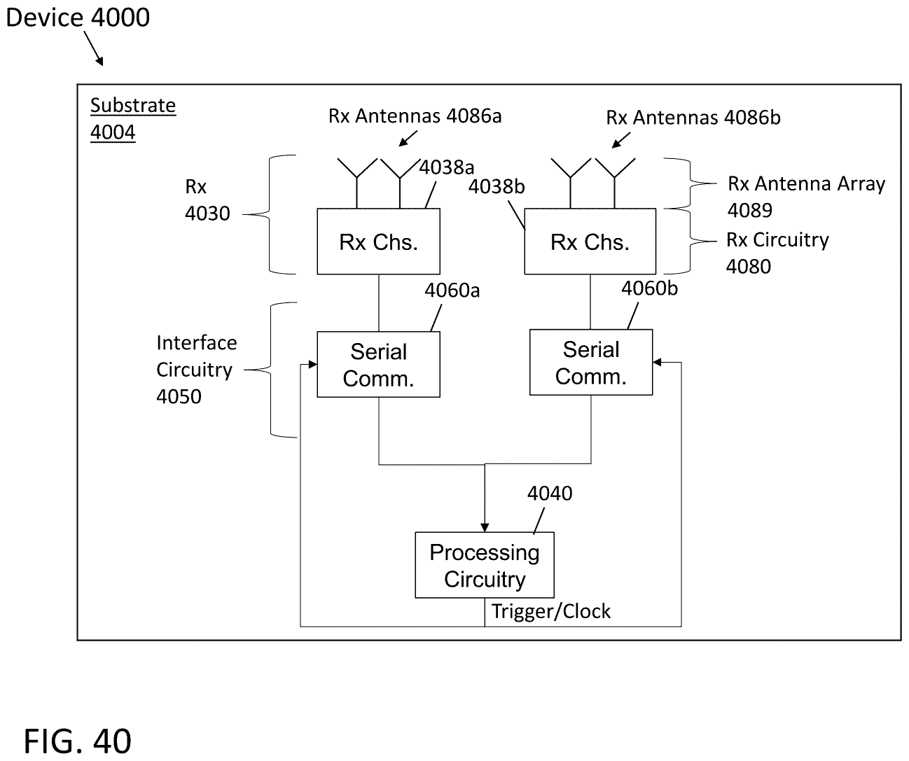

Alternatively or additionally, in some embodiments, synchronized serial communication circuitry may be implemented in interface circuitry coupled to a receiver of a RADAR device to reduce the number of routing channels and associated driving electronics used to offload signals from receive channels of the receiver, thereby conserving power and simplifying the layout of the RADAR device, and without compromising downstream processing of the serialized signals. For example, as shown in FIG. 40, interface circuitry (e.g., 4050) of a RADAR device (e.g., 4000) may include first serial communication circuitry (e.g., 4060a) configured to serialize first processed RF signals, obtained from a first plurality of receive channels (e.g., 4038a) of a receiver (e.g., 4030) of the RADAR device, and second serial communication circuitry (e.g., 4060b) configured to serialize second processed RF signals, obtained from a second plurality of receive channels (e.g., 4038b) of the receiver, and processing circuitry (e.g., 4040) of the RADAR device may be configured to synchronize serialization by the first serial communication circuitry and the second serial communication circuitry. In some embodiments, by serializing the first processed RF signals and the second processed RF signals in synchronization, the resulting first serialized processed RF signals and second serialized processed RF signals may be offloaded using fewer routing channels (e.g., substrate traces) than receive channels without compromising ways in which received signals may be processed (e.g., beamformed) or utilized downstream (e.g., by the processing circuitry). In some embodiments, using fewer routing channels than receive channels simplifies the layout of the RADAR device (e.g., on the substrate) and conserve power that might otherwise be consumed (e.g., in driving the processed RF signals in the substrate traces) by offloading the processed RF signals from each receive channel individually (e.g., in respective substrate traces).

In some embodiments, a device (e.g., 4000 in FIG. 40) comprises:
(A) a substrate (e.g., 4004);
(B) a receiver (e.g., 4030) mounted on the substrate, the receiver comprising: a receive antenna array (e.g., 4089) comprising: a first plurality of receive RF antennas (e.g., 4086a), the first plurality of receive RF antennas configured to receive first receive RF signals; and a second plurality of receive RF antennas (e.g., 4086b), the second plurality of receive RF antennas configured to receive second receive RF signals; and receive circuitry (e.g., 4080) comprising: a first plurality of receive channels (e.g., 4038a) coupled to the first plurality of receive RF antennas and configured to process the first receive RF signals to obtain first processed RF signals; and a second plurality of receive channels (e.g., 4038b) coupled to the second plurality of receive RF antennas and configured to process the second receive RF signals to obtain second processed RF signals;
(C) interface circuitry (e.g., 4050) mounted on the substrate, the interface circuitry comprising: first serial communication circuitry (e.g., 4060a) configured to serialize the first processed RF signals to obtain and transmit a first serialized processed RF signal; and second serial communication circuitry (e.g., 4060b) configured to serialize the second processed RF signals to obtain and transmit a second serialized processed RF signal; and
(D) processing circuitry (e.g., 4040) mounted on the substrate, communicatively coupled to the interface circuitry, and configured to synchronize serialization of the first processed RF signals by the first serial communication circuitry with serialization of the second processed RF signals by the second serial communication circuitry.

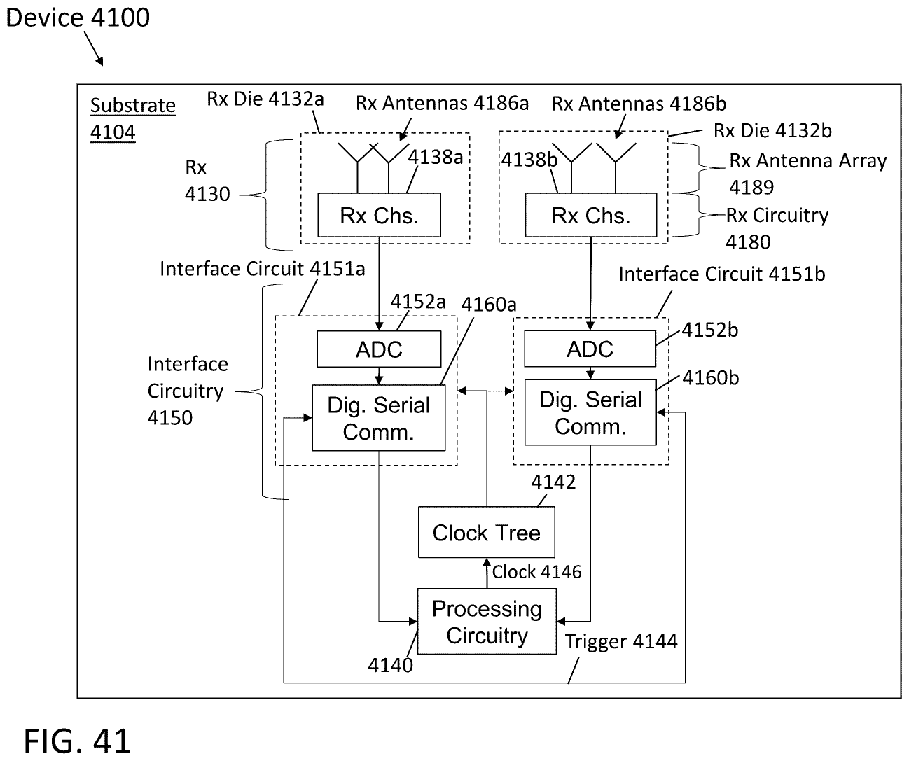

In some embodiments, the processing circuitry is configured to synchronize serialization of the first processed RF signals with serialization of the second processed RF signals at least in part by providing a trigger signal (e.g., 4144 in FIG. 41) to the first serial communication circuitry and to the second serial communication circuitry.

In some embodiments, the first serial communication circuitry (e.g., 4260 in FIG. 42) comprises: a first serial interface controller (e.g., 4264); and a first framer (e.g., 4262) configured to provide a first frame of the first processed RF signals to the first serial interface controller in response to the trigger signal. In some embodiments, the second serial communication circuitry (e.g., 4260 in FIG. 42) comprises: a second serial interface controller (e.g., 4264); and a second framer (e.g., 4262) configured to provide a second frame of the second processed RF signals to the second serial communication circuitry in response to the trigger signal. In some embodiments, the first serialized processed RF signal comprises the first frame of the first processed RF signals; the second serialized processed RF signal comprises the second frame of the second processed RF signals; and the processing circuitry is configured to combine the first frame of the first serialized processed RF signal with the second frame of the second serialized processed RF signal.

In some embodiments, the processing circuitry is configured to synchronize serialization of the first processed RF signals with serialization of the second processed RF signals at least in part by providing a clock signal (e.g., 4146 in FIG. 41) to the first serial communication circuitry and to the second serial communication circuitry.

In some embodiments, the device (e.g., 4100 in FIG. 41) further comprises: a first clock tree (e.g., 4142) coupled between the processing circuitry (e.g., 4140), the first serial communication circuitry (e.g., 4160a), and the second serial communication circuitry (e.g., 4160b), and the processing circuitry is configured to provide the clock signal to the first serial communication circuitry and to the second serial communication circuitry via the first clock tree.

In some embodiments, the interface circuitry (e.g., 4150 in FIG. 41) further comprises: first analog-to-digital conversion (ADC) circuitry (e.g., 4152a) coupled to the first plurality of receive channels (e.g., 4138a) and configured to digitize the first processed RF signals to obtain first digitized processed RF signals; and second ADC circuitry (e.g., 4152b) coupled to the second plurality of receive channels (e.g., 4138b) and configured to digitize the second processed RF signals to obtain second digitized processed RF signals. In some embodiments, the first serial communication circuitry comprises first digital serial communication circuitry (e.g., 4160a) configured to serialize the first processed RF signals at least in part by serializing the first digitized processed RF signals; and the second serial communication circuitry comprises second digital serial communication circuitry (e.g., 4160b) configured to serialize the second processed RF signals at least in part by serializing the second digitized processed RF signals.

In some embodiments, the interface circuitry (e.g., 4150) comprises: a first interface integrated circuit (e.g., 4151a) having integrated therein the first digital serial communication circuitry (e.g., 4160a) and the first ADC circuitry (e.g., 4152a); and a second interface integrated circuit (e.g., 4151b) having integrated therein the second digital serial communication circuitry (e.g., 4160b) and the second ADC circuitry (e.g., 4152b). In some embodiments, the processing circuitry (e.g., 4140 in FIG. 41) is further configured to synchronize digitization by the first ADC circuitry and the second ADC circuitry.

In some embodiments, the interface circuitry (e.g., 4250 in FIG. 42) further comprises: first amplification circuitry (e.g., 4254a) coupled between the first plurality of receive channels and the first serial communication circuitry (e.g., 4260); and second amplification circuitry (e.g., 4254a) coupled between the second plurality of receive channels and the second serial communication circuitry (e.g., 4260).

In some embodiments, the interface circuitry (e.g., 4250 in FIG. 42) further comprises a first test signal interface (e.g., 4280) configured to receive a test signal (e.g., 4282) and input the test signal to the first amplification circuitry (e.g., 4254a); the interface circuitry further comprises a second test signal interface (e.g., 4282) configured to receive the test signal and input the test signal to the second amplification circuitry (e.g., 4254a); and the processing circuitry is configured to provide the test signal to the first test signal interface and to the second test signal interface.

In some embodiments, the first amplification circuitry (e.g., 4254a in FIG. 42) ais configured to provide a first amplification output signal in response to receiving the test signal; and the first test signal interface is further configured to receive a first amplification output control signal from the processing circuitry and, in response to the first amplification output control signal, provide the first amplification output signal from the first amplification circuitry to the processing circuitry.

In some embodiments, the receiver (e.g., 4130 in FIG. 41) comprises: a first receive semiconductor die (e.g., 4132a) having integrated thereon the first plurality of receive RF antennas (e.g., 4186a) and the first plurality of receive channels (e.g., 4138a); and a second receive semiconductor die (e.g., 4132b) having integrated thereon the second plurality of receive RF antennas (e.g., 4186b) and the second plurality of receive channels (e.g., 4138b).

In some embodiments, the processing circuitry (e.g., 4040 in FIG. 40) is configured to receive the first serialized processed RF signal from the first serial communication circuitry and to receive the second serialized processed RF signal from the second serial communication circuitry.

In some embodiments, the first serial communication circuitry is configured to transmit the first serialized processed RF signal to the processing circuitry using a standardized serial interface protocol (e.g., JESD); and the second serial communication circuitry is configured to transmit the second serialized processed RF signal to the processing circuitry using the standardized serial interface protocol.

In some embodiments, the processing circuitry is configured to determine a distance between the device and a target object that generated the first receive RF signals and the second receive RF signals based on the first serialized processed RF signal and the second serialized processed RF signal.

In some embodiments, the device (e.g., 400 in FIG. 4A) further comprises a transmitter (e.g., 420) mounted on the substrate, the transmitter comprising: a transmit antenna array (e.g., 1132 in FIG. 11A) comprising a plurality of transmit RF antennas (e.g., 1170 in FIG. 11B) configured to transmit first RF signals; and transmit circuitry (e.g., 1160 in FIG. 11B) configured to drive the plurality of transmit RF antennas to transmit the first RF signals, and the first receive RF signals and the second receive RF signals are generated, at least in part, by reflection of the first RF signals by the target object.

In some embodiments, a device (e.g., 4000 in FIG. 40), comprises:
(A) a substrate (e.g., 4004);
(B) a receiver (e.g., 4030) mounted on the substrate, the receiver comprising: a receive antenna array (e.g., 4089) comprising: a first plurality of receive RF antennas (e.g., 4086a), the first plurality of receive RF antennas configured to receive first receive RF signals; and a second plurality of receive RF antennas (e.g., 4086b), the second plurality of receive RF antennas configured to receive second receive RF signals; and receive circuitry (e.g., 4080) comprising: a first plurality of receive channels (e.g., 4038a) coupled to the first plurality of receive RF antennas and configured to process the first receive RF signals to obtain first processed RF signals; and a second plurality of receive channels (e.g., 4038b) coupled to the second plurality of receive RF antennas and configured to process the second receive RF signals to obtain second processed RF signals;
(C) interface circuitry (e.g., 4050) mounted on the substrate, the interface circuitry comprising: first serial communication circuitry (e.g., 4060a) configured to serialize the first processed RF signals to obtain and transmit a first serialized processed RF signal; and second serial communication circuitry (e.g., 4060b) configured to serialize the second processed RF signals to obtain and transmit a second serialized processed RF signal; and
(D) processing circuitry (e.g., 4040) mounted on the substrate, communicatively coupled to the interface circuitry, and configured to transmit a trigger signal (e.g., 4144 in FIG. 41) and a clock signal (e.g., 4146 in FIG. 41) to the first serial communication circuitry and the second serial communication circuitry.

FIG. 35 is a schematic diagram of an example substrate 3504 having a receiver 3530 and interface circuitry 3550 mounted thereon that may be included in a RADAR device, for example device 3500, in system 10, in accordance with some embodiments of the technology described herein.

In some embodiments, device 3500 may be configured as described herein for device 1400 including in connection with FIGS. 14A-14B.

In some embodiments, receiver 3530 may include a receive antenna array including a first plurality of receive RF antennas. For example, as shown in FIG. 35, receiver 3530 includes receive antenna array 3539 including first receive RF antenna 3586a and second receive RF antenna 3586b, which may be configured as described herein for receive RF antenna 1486, including in connection with FIG. 14B. For instance, first receive RF antenna 3586a may be configured to receive a first receive RF signal and second receive RF antenna 3586b may be configured to receive a second receive RF signal.

In some embodiments, receiver 3530 may include receive circuitry including a first plurality of receive channels. For example, as shown in FIG. 35, receiver 3530 includes receive circuitry 3580 including a first receive channel 3538a and a second receive channel 3538b, which may be configured as described herein for receive circuitry 1480 including in connection with FIG. 14B. For instance, first receive channel 3538a may be coupled to first receive RF antenna 3586a and configured to process the first receive RF signal to obtain a first processed RF signal and second receive channel 3538b may be coupled to second receive RF antenna 3586b and configured to process the second receive RF signal to obtain a second processed RF signal.

In some embodiments, interface circuitry 3550 may include time-division multiplexing circuitry. For example, as shown in FIG. 35, interface circuitry 3550 includes time-division multiplexing circuitry 3556 coupled to receive circuitry 3580. For instance, time-division multiplexing circuitry 3556 may include a first time-division multiplexer coupled to first receive channel 3538a and to second receive channel 3538b and configured to combine the first processed RF signal and the second processed RF signal into a first single time-division multiplexed signal. In some embodiments, time-division multiplexing circuitry 3556 may be configured to operate based on a clock signal, such as having a clock rate that is at least twice as high (e.g., at least four times as high, at least eight times as high) as a data rate at which the first processed RF signal and the second processed RF signal are obtained, such that the output of time-division multiplexing circuitry 3556 includes the first processed RF signal and the second processed RF signals combined (e.g., interleaved) in the first single time-division multiplexed signal. In some embodiments, time-division multiplexing circuitry 3556 may include analog multiplexing circuitry.

In some embodiments, interface circuitry 3550 may further include analog-to-digital conversion (ADC) circuitry. For example, as shown in FIG. 35, interface circuitry 3550 includes ADC circuitry 3552. For instance, ADC circuitry 3552 may include a first ADC circuit (coupled to the first time-division multiplexer and configured to digitize the first single time-division multiplexed signal into a first single digitized time-division multiplexed signal. In some embodiments ADC circuitry 3552 may be configured as described for ADC circuitry of AFE/ADC units 452a-452e including in connection with FIG. 4A.

FIG. 36 is a schematic diagram of another example substrate 1604 having a receiver 3630 and interface circuitry 3650 mounted thereon that may be included in a device 3600 in system 10, in accordance with some embodiments of the technology described herein.

In some embodiments, device 3600 may be configured as described herein for device 3500 including in connection with FIG. 35. For example, as shown in FIG. 36, receiver 3630 includes a receive antenna array 3639 including a first receive RF antenna 3686a and a second receive RF antenna 3686b, as well as receive circuitry 3680 including a first receive channel 3638a and a second receive channel 3638b. Also shown in FIG. 36, interface circuitry 3650 includes a first time-division multiplexer 3656a and a first ADC circuit 3652a.

In some embodiments, receive antenna array 3639 may further include a second plurality of receive RF antennas. For example, as shown in FIG. 36, receive antenna array 3639 further includes a third receive RF antenna 3686c and a fourth receive RF antenna 3686d. For example, third receive RF antenna 3686c may be configured to receive a third receive RF signal and fourth receive RF antenna 3686d may be configured to receive a fourth receive RF signal.

In some embodiments, receive circuitry 3680 may further include a second plurality of receive channels. For example, as shown in FIG. 36, receive circuitry 3680 further includes a third receive channel 3638c and a fourth receive channel 3638d. For example, third receive channel 3638c may be coupled to third receive RF antenna 3686c and configured to process the third receive RF signal to obtain a third processed RF signal and fourth receive channel 3638d may be coupled to fourth receive RF antenna 3686d and configured to process the fourth receive RF signal to obtain a fourth processed RF signal.

In some embodiments, time-division multiplexing circuitry of interface circuitry 3650 may further include a second time-division multiplexer. For example, as shown in FIG. 36, interface circuitry 3650 further includes a second time-division multiplexer 3656b. For instance, time-division multiplexer 3656b may be coupled to third receive channel 3638c and to fourth receive channel 3638d and configured to combine the third processed RF signal and the fourth processed RF signal into a second single time-division multiplexed signal.

In some embodiments, ADC circuitry of interface circuitry 3650 may further include a second ADC circuit. For example, as shown in FIG. 36, interface circuitry 3650 further includes a second ADC circuit 3652b. For instance, second ADC circuit 3652b may be coupled to second time-division multiplexer 3656b and configured to digitize the second single time-division multiplexed signal into a second single digitized time-division multiplexed signal.

In some embodiments, the first and second pluralities of receive RF antennas and first and second pluralities of receive channels may be integrated on a single receive semiconductor die. For example, as shown in FIG. 36, receiver 3630 includes a first receive semiconductor die 3632 having integrated thereon receive RF antennas 3686a-3686d and receive channels 3638a-3638d.

In some embodiments, interface circuitry 3650 may further include serialization circuitry 3660 configured to serialize the first single digitized time-division multiplexed signal and the second single digitized time-division multiplexed signal into a serialized digitized time-division multiplexed signal, as described further below including in connection with FIGS. 40-45.

FIG. 37 is a schematic diagram of an example substrate 3704 having a receiver 3730, interface circuitry 3750 including multiplexing circuitry 3756a, 3756b, and processing circuitry 3740 mounted thereon that may be included in a device 3700 in system 10, in accordance with some embodiments of the technology described herein.

In some embodiments, device 3700 may be configured as described herein for device 3600 including in connection with FIG. 36. For example, as shown in FIG. 37, receiver 3730 includes a receive antenna array 3739 including a first plurality of receive RF antennas 3786a and a second plurality of receive RF antennas 3786b, as well as receive circuitry 3780 including a first plurality of receive channels 3738a and a second plurality of receive channels 3738b. Also shown in FIG. 37, interface circuitry 3750 includes first time-division multiplexers 3756a, second time-division multiplexers 3756b, first ADC circuits 3752a, second ADC circuits 3752b, first serialization circuitry 3760a, and second serialization circuitry 3760b.

In some embodiments, the first and second pluralities of receive RF antennas and first and second pluralities of receive channels may be distributed over multiple receive semiconductor dies. For example, as shown in FIG. 37, receiver 3730 includes a first receive semiconductor die 3732a having integrated thereon first receive RF antennas 3786a and first receive channels 3738a), and receiver 3730 further includes a second receive semiconductor die 3732b having integrated thereon second receive RF antennas 3732b and second receive channels 3738b.

In some embodiments, the first and second time-division multiplexers and the first and second ADC circuits may be distributed over multiple integrated circuits. For example, as shown in FIG. 37, interface circuitry 3750 includes a first interface integrated circuit 3751 having integrated therein first time-division multiplexer 3756a and first ADC circuit 3752a, and interface circuitry 3750 further includes a second interface integrated circuit 3751b having integrated therein second time-division multiplexer 3756b and second ADC circuit 3752b. For instance, an interface integrated circuit may be included for each receive semiconductor die in device 3700, though it should be appreciated that fewer interface integrated circuits than receive semiconductor dies may be included in some embodiments.

In some embodiments, processing circuitry 3740 may be communicatively coupled to interface circuitry 3750 and configured to determine a distance between device 3700 and a target object that generated the first receive RF signal received by the first receive RF antenna (e.g., of first receive RF antennas 3786a) and the second receive RF signal received by the second receive RF antenna (e.g., of second receive RF antennas 3786b) based on the first single digitized time-division multiplexed signal. For example, while not shown in FIG. 37, in some embodiments, device 3700 may further include a transmitter mounted on substrate 3704, such as described herein for transmitter 420 including in connection with FIGS. 4A-4B. For instance, the transmitter may include a transmit antenna array (e.g., 1132 in FIG. 11A) including a plurality of transmit RF antennas (e.g., 1170 in FIG. 11B) configured to transmit first RF signals and transmit circuitry (e.g., 1160 in FIG. 11B) configured to drive the plurality of transmit RF antennas to transmit the first RF signals. For instance, and the first receive RF signal and the second receive RF signal, received by first receive RF antenna and second receive RF antenna, respectively, may be generated at least in part by reflection of the first RF signals by the target object.

In some embodiments, the first receive channel (e.g., of first receive channels 3738a) may include a first mixer configured to mix the first receive RF signal with a reference signal to obtain the first processed RF signal, and the second receive channel (e.g., of second receive channels 3738b) may include a second mixer configured to mix the second receive RF signal with the reference signal to obtain the second processed RF signal, such as described herein for mixer 1484 including in connection with FIG. 14B. For example, the first processed RF signal may have a first center frequency, the second processed RF signal may have a second center frequency, and the first center frequency and the second center frequency may be indicative of the distance between the device and the target object.

In some embodiments, first receive RF antennas 3786a may include 36 receive RF antennas, first receive channels 3738a may include 36 receive channels coupled to the 36 receive RF antennas, first time-division multiplexers 3756a may include 16 time-division multiplexers coupled to the 36 receive channels, and first ADC circuits 3752a may include 16 ADC circuits coupled to the 16 time-division multiplexers, though other numbers of antennas, channels, multiplexers, and/or ADC circuits may be used. For example, more than two multiplexers may be included per receive channel where more processing bandwidth is available and/or where processing resolution may be compromised to trade off for increased consolidation.

FIG. 38A is a block diagram of example interface circuitry 3850a including multiplexers 3856a, which may be included on substrate 404, in accordance with some embodiments of the technology described herein.

In some embodiments, interface circuitry of device 400 may include ADC and AFE circuitry on separate semiconductor dies. For example, in FIG. 38A, interface circuitry 3850a includes AFE 3854 on a first semiconductor die coupled to receive semiconductor dies 3832 of a receiver 3830a and ADCs 3853 on a same semiconductor die as at least a portion of processing circuitry 3840. For instance, processing circuitry 3840 may include an FPGA and/or ASIC having built-in ADC circuitry.

In some embodiments, device 400 may include receive circuitry and ADC circuitry having a different number of channels. For example, in FIG. 38A, ADC circuitry 3852 may have a first number of ADC channels and receiver 3830a may have a second number of receive channels that is greater than the first number of ADC channels. For instance, where a receive semiconductor die 3832 has 16 receive elements (e.g., 538 in FIG. 5), four receive semiconductor dies 3832 shown in FIG. 38A coupled to a pair of ADC circuits 3852, may have 64 receive channels, whereas each ADC circuit 3852 may have a single ADC channel.

In some embodiments, interface circuitry of device 400 may include multiplexing circuitry configured to interface between the receive circuitry and the ADC circuitry. The inventors have recognized that using multiplexing circuitry to interface between receive and ADC channels may permit interfacing of different numbers of receive and ADC channels, facilitating use of ADC circuitry having any number of available ADC circuits (e.g., as may be found in low cost off-the-shelf processing circuitry components). For example, as shown in FIG. 38A, interface circuitry 3850a further includes multiplexers (MUX) coupled between AFE 3854 and each ADC circuit 3852. For instance, multiplexers 3856a may be integrated on the same semiconductor die as AFE 3854. In some embodiments, multiplexers 3856a may be configured to interface between the number of receive channels of receiver 3830a and the number of ADC channels of the ADC circuitry. For example, multiplexers 3856a may be configured as time-division multiplexers configured to selectively transmit data from the receive channels through a smaller number of ADC channels. For instance, where four receive semiconductor dies 3832 shown in FIG. 38A have 64 receive channels coupled to a pair of ADC circuits 3852, each multiplexer 3856a may be configured as a 32 receive channel to 1 ADC channel (32:1) multiplexer.

FIG. 38B is a block diagram of example interface circuitry 3850b including multiplexers 3856b integrated on receive semiconductor dies 3832 and further multiplexers 3858 coupled between receive semiconductor dies 3832 and processing circuitry 3840, which may be included on substrate 404, in accordance with some embodiments of the technology described herein.

In some embodiments, interface circuitry of device 400 may include AFE circuitry integrated on receive semiconductor dies of a receiver. For example, in FIG. 38B, receive semiconductor dies 3832′ may be configured as described herein for semiconductor dies 3832, with AFE 3854 and multiplexers 3856b of interface circuitry 3850b integrated thereon. For instance, multiplexers 3856b may be configured as described herein for multiplexers 3856a.

In some embodiments, interface circuitry of device 400 may include multiplexing circuitry on multiple semiconductor dies. For example, as shown in FIG. 38B, interface circuitry 3850b further includes multiplexers 3858 coupled between receive semiconductor dies 3832′ of receiver 3830b and ADC circuits 3852 of processing circuitry 3840. In some embodiments, multiplexers 3856b and 3858 may be configured to operate together as described herein for multiplexers 3856a. For instance, where each receive semiconductor die 3832′ has 16 receive elements, each multiplexer 3856b may be configured as a 16 receive channel to 1 output channel (16:1) multiplexer, and multiplexer 3858 may be configured as a 2 output channel to 1 ADC channel (2:1) multiplexer, thus providing 32 receive channels to 1 ADC channel over the combined multiplexing circuitry.

FIG. 38C is a block diagram of example interface circuitry 3850c including multiplexers 3856c integrated on a receive semiconductor die 3832a of a pair of interconnected receive semiconductor dies 3832a and 3832b, which may be included on substrate 404, in accordance with some embodiments of the technology described herein.

In some embodiments, receiver 3830c may include pairs of receive semiconductor dies sharing AFE and multiplexing circuitry. For example, as shown in FIG. 38C, receiver 3830c has pairs of semiconductor dies including first receive semiconductor die 3832a and second receive semiconductor die 3832b. In some embodiments, first receive semiconductor die 3832a may be configured as described herein for receive semiconductor die 3832′, such as having AFE 3854 and multiplexers 3856c of interface circuitry 3850c integrated thereon.

In some embodiments, AFE 3854 and multiplexers 3856c of interface circuitry 3850c may be configured to interface between first and second semiconductor dies 3832a and 3832b and an ADC circuit 3852 as described herein for interface circuitry 3850a. For instance, where each receive semiconductor die 3832a and 3832b has 16 receive channels, multiplexer 3856c may be configured to interface between the 32 receive channels of dies 3832a and 3832b (via AFE 3854) and 1 ADC channel (32:1).

FIG. 38D is a block diagram of example interface circuitry 3850d including ADC circuitry 3852 directly coupled to receive semiconductor dies 3832, which may be included on substrate 404, in accordance with some embodiments of the technology described herein.

In some embodiments, interface circuitry of device 400 may include ADC circuitry integrated on a semiconductor die separate from the receive semiconductor die(s) and mounted on substrate 404. For example, as shown in FIG. 38D, interface circuitry 3850d includes ADC circuitry 3852 coupled between receive semiconductor dies 3832 of receiver 3830a and processing circuitry 3840′. For instance, AFE circuitry (not shown) may be included on receive semiconductor dies 3832 and/or the semiconductor dies having ADC circuitry 3852 (e.g., in a mixed-signal ASIC). In some embodiments, ADC circuitry 3852 may be configured to communicate digitized RF signals to processing circuitry 3840′ using a standardized serial interface (Serial I/O) such as a JESD interface. For instance, the semiconductor dies having ADC circuitry 3843 integrated thereon may further have communication circuitry integrated thereon configured to execute the standardized serial interface.

FIG. 38E is a block diagram of example interface circuitry 3850e including ADC circuitry 3852 integrated on a receive semiconductor die 3832″, which may be included on substrate 404, in accordance with some embodiments of the technology described herein.

In some embodiments, interface circuitry 3850e may include ADC circuitry integrated on receive semiconductor dies of receiver 430. For example, as shown in FIG. 38E, receiver 3830′ includes receive semiconductor dies 3832″ with ADC circuitry 3852 integrated thereon. For example, receive semiconductor dies 3832″ may include AFE circuitry coupled between receive circuitry and ADC circuitry 3852. In some embodiments, receive semiconductor dies 3832″ may be configured to communicate digitized RF signals to processing circuitry 3840′ using a standardized serial interface. For instance, receive semiconductor dies 3832″ may further have integrated thereon communication circuitry configured to execute the standardized serial interface.

FIG. 39A is a block diagram of example interface circuitry 3950a including multiple ADC units 3952a integrated on a receive semiconductor die 3932a, which may be included on substrate 404, in accordance with some embodiments of the technology described herein.

In some embodiments, receive semiconductor die 3930a may be configured as described herein for receive semiconductor die 3832″, such as including ADC units 3952a integrated thereon. For example, an ADC unit 3952a may be included for each receive channel of receive semiconductor die 3930a. Also shown in FIG. 39A, receive semiconductor die 3930a has AFE circuitry 3954a coupled to ADC units 3952a, and ADC units 3952a are coupled to communication circuitry 3956 configured to execute a standardized serial interface for sending digitized RF signals to communication circuitry 3942 of processing circuitry 3940.

FIG. 39B is a block diagram of example interface circuitry 3950b including a single ADC unit 3952b integrated on a receive semiconductor die 3932b, which may be included on substrate 404, in accordance with some embodiments of the technology described herein.

In some embodiments, receive semiconductor die 3930b may be configured as described herein for receive semiconductor die 3930a, such as including ADC unit 3952b integrated thereon. Also shown in FIG. 39B, receive semiconductor die 3930b further has AFE circuitry and multiplexing circuitry 3954b coupled to ADC unit 3952b. For example, the multiplexing circuitry may be configured to interface between several (e.g., 16) receive channels and one ADC unit 3952b (e.g., 16:1), such as described herein for multiplexer 3856b.

FIG. 40 is a schematic diagram of an example substrate 4004 having a receiver 4030, interface circuitry 4050 including serial communication circuitry 4060a, 4060b, and processing circuitry 4040 mounted thereon that may be included in a device 4000 in system 10, in accordance with some embodiments of the technology described herein.

In some embodiments, device 4000 may be configured as described herein for device 3700 including in connection with FIG. 37. For example, receiver 4030 includes receive antenna array 4089 including first receive RF antennas 4086a and second receive RF antennas 4086b. For instance, first receive RF antennas 4086a may be configured to receive first receive RF signals and second receive RF antennas 4086b may be configured to receive second receive RF signals.

As further shown in FIG. 40, receiver 4030 includes receive circuitry 4080 including first receive channels 4038a and second receive channels 4038b. For example, first receive channels 4038a may be coupled to first receive RF antennas 4086a and configured to process the first receive RF signals to obtain first processed RF signals, and second plurality of receive channels 4038b may be coupled to second receive RF antennas 4086b and configured to process the second receive RF signals to obtain second processed RF signals.

In some embodiments, interface circuitry 4050 may include serial communication circuitry. For example, as shown in FIG. 40, interface circuitry 4050 includes first serial communication circuitry 4060a and second serial communication circuitry 4060b. In some embodiments, first serial communication circuitry 4060a may be configured to serialize the first processed RF signals to obtain and transmit a first serialized processed RF signal and second serial communication circuitry 4060b may be configured to serialize the second processed RF signals to obtain and transmit a second serialized processed RF signal. For example, first serial communication circuitry 4060a may be configured to operate based on a clock signal, such as having a clock rate that is at least twice as high (e.g., at least four times as high, and/or at least eight times as high) as a data rate at which the first processed RF signals are obtained (e.g., multiplied by the number of first receive channels 4038a), such that the output of first serial communication circuitry 4060a includes the first processed RF signals combined (e.g., interleaved) in the first serialized processed RF signal (e.g., second serial communication circuitry 4060b may be configured in like manner). In some embodiments, first serial communication circuitry 4060a and second serial communication circuitry 4060b may include digital multiplexing circuitry.

In some embodiments, processing circuitry 4040 may be communicatively coupled to interface circuitry 4050 and configured to synchronize serialization of the first processed RF signals by first serial communication circuitry 4060a with serialization of the second processed RF signals by second serial communication circuitry 4060b. For example, processing circuitry 4040 may be configured to transmit a trigger signal and/or a clock signal to first serial communication circuitry 4060a and second serial communication circuitry 4060b, such as described further below including in connection with FIG. 41.

In some embodiments, processing circuitry 4040 may be configured to receive the first serialized processed RF signal from first serial communication circuitry 4060a and to receive the second serialized processed RF signal from second serial communication circuitry 4060b. For example, processing circuitry 4040 may be configured to determine a distance between device 4000 and a target object that generated the first receive RF signals and the second receive RF signals based on the first serialized processed RF signal and the second serialized processed RF signal. For instance, while not shown in FIG. 40, device 4000 may further include a transmitter (e.g., 420 in FIGS. 4A-4B) mounted on the substrate, such as including a transmit antenna array (e.g., 1132 in FIG. 11A) including a plurality of transmit RF antennas (e.g., 1170 in FIG. 11B) configured to transmit first RF signals and transmit circuitry (e.g., 1160 in FIG. 11B) configured to drive the plurality of transmit RF antennas to transmit the first RF signals, and the first receive RF signals and the second receive RF signals may be generated, at least in part, by reflection of the first RF signals by the target object. In some embodiments, first serial communication circuitry 4060a may be configured to transmit the first serialized processed RF signal to processing circuitry 4040 using a standardized serial interface protocol (e.g., JESD) and second serial communication circuitry 4040 may be configured to transmit the second serialized processed RF signal to processing circuitry 4040 using the standardized serial interface protocol.

It should be appreciated that, while processing circuitry 4040 in FIG. 40 may be configured to synchronize serialization and to receive the serialized processed RF signals (e.g., and determine a distance based thereon) in some embodiments, it should be appreciated that separate processing circuitry may be included to synchronize serialization and to receive the serialized processed RF signals in some embodiments.

FIG. 41 is a schematic diagram of an example substrate 4104 having a receiver 4130, interface circuitry 4150 including digital serial communication circuitry 4160a, 4160b, and processing circuitry 4140 mounted thereon that may be included in a device 4100 in system 10, in accordance with some embodiments of the technology described herein.

In some embodiments, device 4100 may be configured as described herein for device 4000 including in connection with FIG. 40. For example, as shown in FIG. 41, receiver 4130 includes receive antenna array 4189 including first receive antennas 4186a and second receive antennas 4186b and receive circuitry 4180 including first receive channels 4138a and second receive channels 4138b.

In some embodiments, first receive antennas 4186a, second receive antennas 4186b, first receive channels 4138a, and second receive channels 4138b may be distributed over multiple semiconductor dies. For example, as shown in FIG. 41, receiver 4130 includes a first receive semiconductor die 4132a having integrated thereon first receive RF antennas 4186a and first receive channels 4138a, and receiver 4130 further includes a second receive semiconductor die 4132b having integrated thereon second receive antennas 4186b and second receive channels 4138b.

In some embodiments, digital serial communication circuitry 4160a and 4160b may be configured to serialize digitized processed RF signals obtained via ADC circuitry. For example, as shown in FIG. 41, interface circuitry 4150 further includes first ADC circuitry 4152a and second ADC circuitry 4152b. For instance, first ADC circuitry 4152a may be coupled to first receive channels 4138a and configured to digitize the first processed RF signals to obtain first digitized processed RF signals and second ADC circuitry 4152b may be coupled to second receive channels 4138b and configured to digitize the second processed RF signals to obtain second digitized processed RF signals. In some embodiments, first digital serial communication circuitry 4160a may be configured to serialize the first processed RF signals at least in part by serializing the first digitized processed RF signals and second digital serial communication circuitry 4160b may be configured to serialize the second processed RF signals at least in part by serializing the second digitized processed RF signals. For example, the processed RF signals as obtained and serialized using first digital serial communication circuitry 4160a and second digital serial communication circuitry 4160b may have been digitized using first ADC circuitry 4152a and second ADC circuitry 4152b, respectively.

In some embodiments, interface circuitry 4150 may be distributed over multiple integrated circuits. For example, as shown in FIG. 41, interface circuitry 4150 includes a first interface integrated circuit 4151a having integrated therein first digital serial communication circuitry 4160a and first ADC circuitry 4152a, and interface circuitry 4150 further includes a second interface integrated circuit 4151b having integrated therein second digital serial communication circuitry 4160b and second ADC circuitry 4152b. For instance, an interface integrated circuit may be included in device 3700 for each receive semiconductor die such as described above including in connection with FIG. 37.

In some embodiments, processing circuitry 4140 may be configured to synchronize serialization of the first processed RF signals with serialization of the second processed RF signals at least in part by providing a trigger signal and/or a clock signal to the first serial communication circuitry and to the second serial communication circuitry. For example, as shown in FIG. 41, processing circuitry 4140 may be configured to provide a trigger signal 4144 to first digital serial communication circuitry 4160a and second digital serial communication circuitry 4160b. For instance, first digital serial communication circuitry 4160a and second digital serial communication circuitry 4160b may be configured to operate based on trigger signal 4144, such as basing a beginning and/or end of a frame (e.g., Frame 1 in FIG. 31) on timing of (e.g., a pulse of) trigger signal 4144. In some embodiments, processing circuitry 4140 may be configured to provide trigger signal 4144 to each interface integrated circuit of device 4100, such as to synchronize serialization of each interface integrated circuit.

As an alternative or additional example, as shown in FIG. 41, processing circuitry 4140 may be configured to provide a clock signal 4146 to first digital serial communication circuitry 4160a and second digital serial communication circuitry 4160b. For instance, first digital serial communication circuitry 4160a and second digital serial communication circuitry 4160b may be configured to operate based on clock signal 4146, such as to separate processed RF signals in a sequence within a frame and/or to serialize multiple processed RF signals obtained from respective receive channels. In some embodiments, within a frame, processed RF signals may be received in sequence, such as following respective transmissions of RF signals (e.g., in different elevation directions), which may be separated in time with respect to a clock rate based on clock signal 4146. Alternatively or additionally, in some embodiments, serialization of processed RF signals obtained from respective receive channels (e.g., within first receive channels 4138a) may include combining (e.g., interleaving) the processed RF signals in a serialized processed RF signal in time with respect to a clock rate based on clock signal 4146.

Moreover, as described further below including in connection with FIG. 42, serialization may alternatively or additionally include combining (e.g., serially encoding) parallel bits digitally representing a processed RF signal into a serial stream of bits. For example, parallel bits received over a given clock cycle may represent a portion of one processed RF signal (e.g., that has been interleaved with other processed RF signals in time), which may be serialized into a stream of fewer parallel bits provided over multiple (e.g., higher speed) clock cycles. In some embodiments, processing circuitry 4140 may be configured to provide clock signal 4146 to each interface integrated circuit of device 4100, such as to synchronize serialization of each interface integrated circuit.

In some embodiments, device 4100 may further include a first clock tree configured to provide clock signal 4146 to first digital serial communication circuitry 4160a and second digital serial communication circuitry 4160b. For example, as shown in FIG. 41, device 4100 further includes clock tree 4142 coupled between processing circuitry 4140, first digital serial communication circuitry 4160a, and second digital serial communication circuitry 4160b. For instance, processing circuitry 4140 may be configured to provide clock signal 4146 to first digital serial communication circuitry 4160a and to second digital serial communication circuitry 4160b via clock tree 4142. In some embodiments, clock tree 4142 may include equal length (e.g., equidistant) conductive paths (e.g., traces on substrate 4104) from processing circuitry 4140 to first digital serial communication circuitry 4160a and second digital serial communication circuitry 4160b. For example, the conductive paths may be configured to equalize propagation delays introduced into clock signal 4146 in transit to first digital serial communication circuitry 4160a and second digital serial communication circuitry 4160b, such that operation based on clock signal 4146 may be synchronized. In some embodiments, clock tree 4142 may include equal length (e.g., equidistant) conductive paths from processing circuitry 4140 to each serial communication circuitry to which processing circuitry 4140 is configured to provide clock signal 4146.

While FIG. 41 shows an example of a trigger signal and clock signal being provided to digital serial communication circuitry, it should be appreciated that a trigger signal and/or clock signal may be alternatively or additionally provided to analog serial communication circuitry, as embodiments described herein are not so limited.

FIG. 42 is a schematic diagram of example interface circuitry 4250 that may be included in device 400, in accordance with some embodiments of the technology described herein.

In some embodiments, interface circuitry 4250 may be configured as described herein for interface circuitry 3750 including in connection with FIG. 37. For example, as shown in FIG. 42, interface circuitry 4250 includes an interface integrated circuit 4251, which may be configured as described herein for interface integrated circuit 3751 including in connection with FIG. 37. For instance, as shown in FIG. 42, interface integrated circuit 4251 includes time-division multiplexing circuitry including first time-division multiplexer 4256a and second time-division multiplexer 4256b, as well as ADC circuitry including first ADC circuit 4252a and second ADC circuit 4252b. For instance, first time-division multiplexer 4256a may be coupled to first and second receive channels and configured to combine first and second processed RF signals, obtained from the first and second receive channels, into a first single time-division multiplexed signal, and second time-division multiplexer 4256b may be coupled to third and fourth receive channels and configured to combine third and fourth processed RF signals, obtained from the third and fourth receive channels, into a second single time-division multiplexed signal. In some embodiments, a time-division multiplexer may be included in the time-division multiplexing circuitry for each pair of receive channels that interface integrated circuit 4251 is coupled to (e.g., for each pair of receive channels of a receive semiconductor die to which interface integrated circuit 4251 is coupled to).

While FIG. 42 shows a time-division multiplexer for each pair of receive channels, it should be appreciated that more than two receive channels may be coupled to a time-division multiplexer in some embodiments. For instance, the sampling rate of downstream ADC circuitry and/or the serialization rate of downstream serialization circuitry may be increased (e.g., at the expense of some power budget in a tradeoff) and/or the frame rate (and/or scans per frame, in the example of FIG. 32A) may be decreased (e.g., at the expense of some resolution in a tradeoff).

In some embodiments, operation of ADC circuitry of interface integrated circuit 4251 may be synchronized using a clock signal. For example, as shown in FIG. 42, interface integrated circuit 4251 includes a clock distribution circuit 4270 configured to receive clock signal 4246 (e.g., from the processing circuitry of the device) and provide an ADC clock signal 4272 to the ADC circuitry via an ADC clock tree 4273. For instance, ADC clock tree 4273 may be configured to equalize propagation delays in ADC clock signal 4272 in conductive paths to respective ADC circuits (e.g., 4252a and 4252b) so as to synchronize sampling by the ADC circuitry.

In some embodiments, interface circuitry 4250 may further include amplification circuitry coupled between receive channels and the time-division multiplexing circuitry. For example, as shown in FIG. 42, interface circuitry 4250 further includes first analog front-end (AFE) circuitry 4254a, second AFE circuitry 4254b, third AFE circuitry 4254c, and fourth AFE circuitry 4254d, which may include amplification circuitry. For instance, first AFE circuitry 4254a may include a first amplifier coupled between a first receive channel and first time-division multiplexer 4256a and second AFE circuitry 4254b may include a second amplifier coupled between a second receive channel and first time-division multiplexer 4256a. Similarly, third AFE circuitry 4254c may include a third amplifier coupled between a third receive channel and second time-division multiplexer 4256b and fourth AFE circuitry 4254d may include a fourth amplifier coupled between a fourth receive channel and fourth time-division multiplexer 4256d. In some embodiments, each of AFE circuitry 4254a-4254d may include a high-pass filter, a preamplifier, a programmable-gain amplifier (PGA), an anti-aliasing filter, and a unity-gain buffer, though it should be appreciated that other configurations are possible.

In some embodiments, each of AFE circuitry 4254a-4254d may be configured to receive an intermediate frequency (IF) processed RF signal from a respective receive channel, such as having a bandwidth of less than 10 MHZ (e.g., 5 MHZ) and may be configured to provide the processed RF signal. In some embodiments, ADC circuits 4252a-4252b may be configured to perform digital sampling at a rate of 20 million samples per second (MSPs), though other ADC configurations are possible. In the illustrated example, first AFE circuitry 4254a, second AFE circuitry 4254b, first time-division multiplexer 4256a, and first ADC circuitry 4252a provide a first ADC channel 4253a, and third AFE circuitry 4254c, fourth AFE circuitry 4254d, second time-division multiplexer 4256b, and second ADC circuitry 4252b provide a second ADC channel 4253b.

In some embodiments, interface circuitry 4250 may further include a test signal interface configured for testing amplification circuitry. For example, as shown in FIG. 42, interface integrated circuit 4251 further includes a first test signal interface 4280, which may be configured to receive a test signal 4282. For instance, first test signal interface 4280 may be configured to input test signal 4282 to first amplification circuitry (e.g., within AFE circuitry 4254a-4254d). In some embodiments, AFE circuitry 4254a-4254d may be configured to provide test signal 4282 to time-division multiplexers 4256a-4256b and on to first ADC circuitry 4252a and second ADC circuitry 4252b for offloading like processed RF signals received from receive channels.

In some embodiments, interface integrated circuit 4251 may be alternatively or additionally configured as described herein for interface integrated circuit 4151 including in connection with FIG. 41. For example, as shown in FIG. 42, interface integrated circuit 4251 further includes digital serial communication circuitry 4260, which may be configured as described herein for first digital serial communication circuitry 4160a and second digital serial communication circuitry 4160b including in connection with FIG. 41.

In some embodiments, digital serial communication circuitry 4260 may include a serial interface controller and a framer configured to provide frames of processed RF signals in response to a trigger signal. For example, as shown in FIG. 42, digital serial communication circuitry 4260 includes serial interface controller 4264 and framer 4262. In some embodiments, framer 4262 may be configured to provide a first frame (e.g., Frame 1 in FIG. 31) of first processed RF signals to serial interface controller 4264 in response to trigger signal 4244. For example, the first processed RF signals may be obtained from a first plurality of receive channels digitized via first ADC circuitry 4252a.

In some embodiments, digital serial communication circuitry 4260 may include a digital serializer configured to combine digitized time-division multiplexed signals into a single digital serial signal and a serial interface driver configured to transmit the single digital serial signal. For example, as shown in FIG. 42, digital serial communication circuitry 4260 further includes a digital serializer 4266, which may be configured to combine a first single digitized time-division multiplexed signal (e.g., obtained from first ADC circuitry 4252a) a second single digitized time-division multiplexed signal (e.g., obtained from second ADC circuitry 4252b) into a single digital serial signal. For instance, digital serializer 4266 may be configured to obtain the digitized time-division multiplexed signals represented by respective groups of parallel digital bits and serialize the groups of parallel digital bits into a single digital bit stream. Also shown in FIG. 42, digital serial communication circuitry further includes a serial interface driver 4268, which may be configured to transmit the single digital serial signal from interface circuitry 4250 (e.g., via the substrate of the device). For example, serial interface driver 4268 may be configured to transmit the signal using a low-voltage differential signaling (LVDS) protocol.

In some embodiments, operation of digital serial communication circuitry 4260 may be synchronized using a clock signal. For example, as shown in FIG. 42, clock distribution circuit 4270 may be configured to provide clock signals 4274, 4276, and 4278 to framer 4262, serial interface controller 4264, and digital serializer 4266, respectively. For instance, clock signals 4274, 4276, and 4278 may have different clock rates, such as due to the higher clock rates that may be used for serialization as compared to framing digitized RF signals from the ADC circuitry.

While only a single interface integrated circuit 4251 is shown in FIG. 42, it should be appreciated that multiple interface integrated circuits 4251 may be included in a device. For example, as shown in FIG. 42, interface integrated circuit 4251 may be configured to receive trigger signal 4244 and clock signal 4246, such as provided (e.g., by processing circuitry of the device) to multiple or all interface integrated circuits of the device, such as described herein for device 4100 including in connection with FIG. 41.

In some embodiments, each interface integrated circuit may include first amplification circuitry (e.g., within AFE circuitry 4254a) coupled between (e.g., one of) a first plurality of receive channels and first digital serial communication circuitry (e.g., 4260) and second amplification circuitry (e.g., within AFE circuitry 4254a) coupled between (e.g., one of) a second plurality of receive channels and digital serial communication circuitry (e.g., 4260). Alternatively or additionally, in some embodiments, the processing circuitry may be configured to synchronize digitization by first ADC circuitry (e.g., 4252a) of a first interface integrated circuit and second ADC circuitry (e.g., 4252a) of a second interface integrated circuit, such as by providing clock signal 4246 for distribution via ADC clock trees 4273.

In some embodiments, each interface integrated circuit may include a test signal interface (e.g., 4282) configured to receive a test signal (e.g., 4282) and input the test signal to amplification circuitry (e.g., within AFE circuitry 4254a-4254d), and the processing circuitry may configured to provide the test signal to each test signal interface. For example, the processing circuitry may be configured to test each interface integrated circuit, such as using the same test signal, though different test signals may be used in some embodiments.

In some embodiments, digital serial communication circuitry (e.g., 4260) of each interface integrated circuit may include a serial interface controller (e.g., 4264) and a framer (e.g., 4262) configured to provide a respective frame (e.g., each corresponding to a same frame, such as a part of Frame 1 in FIG. 31) of a set of processed RF signals to the digital serial communication circuitry in response to the same trigger signal. For example, serialized processed RF signals offloaded from the respective interface integrated circuits may include the respective frames of the processed RF signal. For instance, the processing circuitry is configured to combine the frames of the serialized processed RF signals into a consolidated frame (e.g., part of Frame 1 in FIG. 31), such as to beamform processed RF signals serialized from respective receive channels of the receiver.

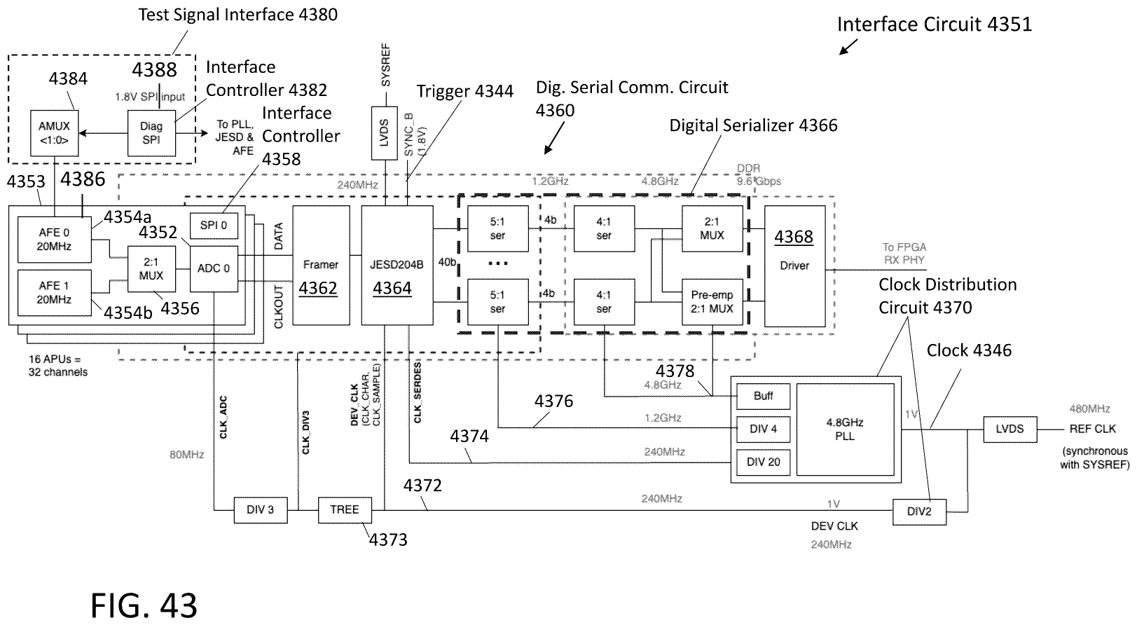

FIG. 43 is a schematic diagram of an example interface integrated circuit 4351 that may be included in device 400, in accordance with some embodiments of the technology described herein.

In some embodiments, interface integrated circuit 4351 may be configured as described herein for interface integrated circuit 4251 including in connection with FIG. 42. For example, as shown in FIG. 43, interface integrated circuit 4351 includes a plurality of ADC channels 4353, each including first AFE circuitry 4354a and second AFE circuitry 4354b coupled to a 2:1 time-division multiplexer 4356 and an ADC circuit 4352. In the illustrated example, interface integrated circuit 4351 further includes an interface controller 4358, which may be configured as a serial peripheral interface (SPI) configured to receive instructions (e.g., from processing circuitry).

As further shown in FIG. 43, interface integrated circuit 4351 includes digital serial communication circuitry 4360 including framer 4362, serial interface controller 4364, digital serializer 4366, and serial interface driver 4368. In the illustrated example, serial interface controller 4364 includes a JESD serial interface controller, which is configured to receive a trigger signal 4344.

In some embodiments, digital serializer 4366 may be configured to serialize a 40-bit digital representation of time-division multiplexed processed RF signals into a 1-bit serial data stream. For example, as shown in FIG. 43, digital serializer 4366 includes multiple (e.g., 4) 5:1 bit parallel serializers configured to output two 4-bit parallel data streams, followed by two 4:1 bit parallel serializers configured to output two 1-bit serial data streams, with two 2:1 multiplexers (e.g., one for pre-emphasis) coupled to serial interface driver 4368. It should be appreciated that other numbers of bits and/or serialization schemes may be implemented.

Also shown in FIG. 43, interface integrated circuit 4351 includes clock distribution circuit 4370, which may be configured to receive clock signal 4346 and provide ADC clock signal 4372 to the ADC circuitry via ADC clock tree 4373, clock signal 4374 to serial interface controller 4364, and clock signals 4376 and 4378 to digital serializer 4366. For example, clock distribution circuit 4370 is shown in FIG. 43 including a phase locked loop (PLL), which may be configured to upconvert clock signal 4346 (e.g., by 10) to generate clock signals 4376 and 4378, including clock divider DIV 4 configured to divide clock signal 4378 (e.g., by 4) to generate clock signal 4376. FIG. 43 further shows clock distribution circuit 4370 including a clock divider DIV 20 configured to divide the up-converted clock signal (e.g., by 20) to generate clock signal 4374, and further including a clock divider DIV2 configured to divide clock signal 4346 (e.g., by 2) to generate clock signal 4372. It should be appreciated that other ratios of clock signals may be used, such as depending on the serialization scheme.

As also shown in FIG. 43, interface integrated circuit 4351 further includes a test signal interface 4380 which may be configured to receive a test signal (e.g., 4282). For example, as shown in FIG. 43, test signal interface 4380 includes an interface controller 4382, which may be configured to receive the test signal, and a test analog multiplexer (AMUX) 4384, which may be configured to selectively provide the test signal to the AFE circuitry.

In some embodiments, amplification circuitry (e.g., within the AFE circuitry) may be configured to provide amplification output signal 4386 in response to receiving the test signal. For example, amplification output signal 4386 may be an analog signal output by the AFE circuitry. In some embodiments, test signal interface 4380 may be further configured to receive amplification output control signal 4388 (e.g., from the processing circuitry) and, in response to amplification output control signal 4388, offload the amplification output signal 4386 from AFE circuitry (e.g., to the processing circuitry). In some embodiments, the test signal may be input to and output from AFE circuitry that is also configured to obtain a processed RF signal from a receive channel, and/or in some embodiments, dedicated diagnostic AFE circuitry may be used.

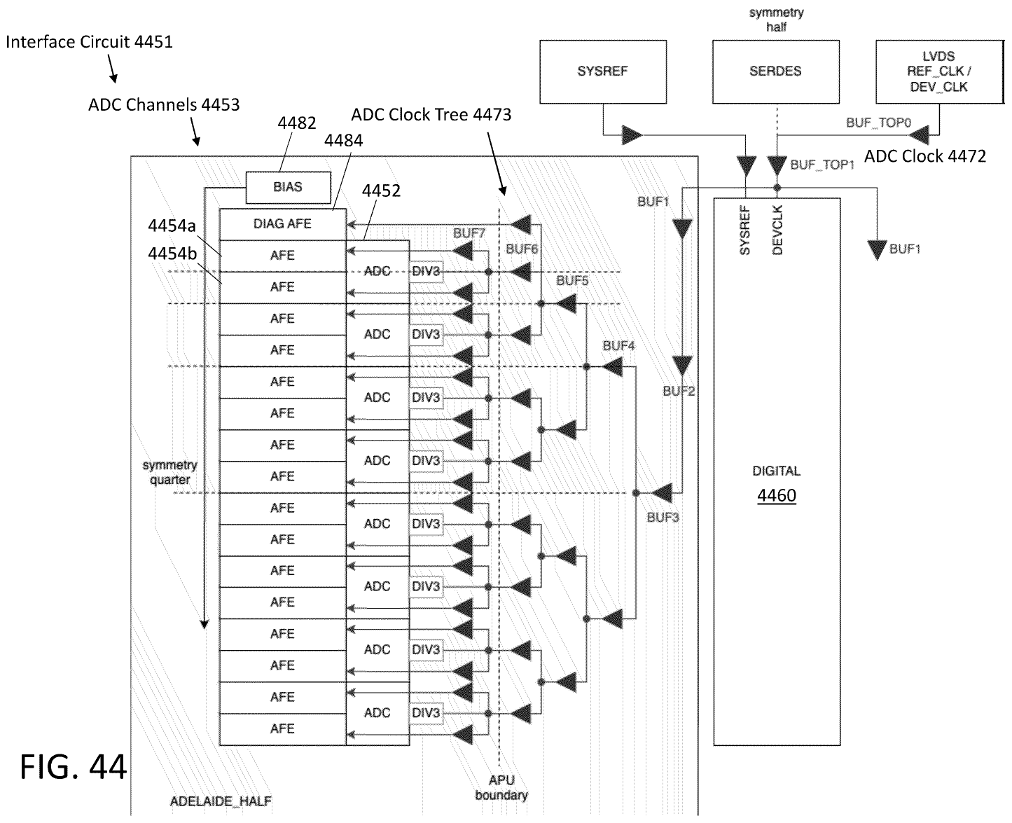

FIG. 44 is a schematic diagram of a portion of an example interface integrated circuit 4451 that may be included, for example, in device 400, in accordance with some embodiments of the technology described herein.

In some embodiments, interface integrated circuit 4451 may be configured as described herein for interface integrated circuit 4351 including in connection with FIG. 43. For example, as shown in FIG. 44, interface integrated circuit 4351 includes ADC channels 4453, each including AFE circuitry 4454a and 4454b, an ADC circuit 4452, and interface integrated circuit 4351 further includes digital serial communication circuitry 4460. In the illustrated embodiment, dedicated diagnostic AFE circuitry 4484 is included alongside AFE circuitry 44254a, which may be configured to receive a test signal, and the illustrated AFE circuitry and dedicated diagnostic AFE circuitry are configured to receive a bias signal via a bias circuit 4482.

Also shown in FIG. 44, interface integrated circuit 4451 includes an ADC clock tree 4473, which includes a network of buffers (BUF1-BUF7) configured to deliver an ADC clock signal 4472 to each ADC circuit 4452. In the illustrated example, the interface integrated circuit 4451 includes 16 ADC channels, of which 8 ADC channels are shown in a symmetrical configuration, though other configurations may be used.

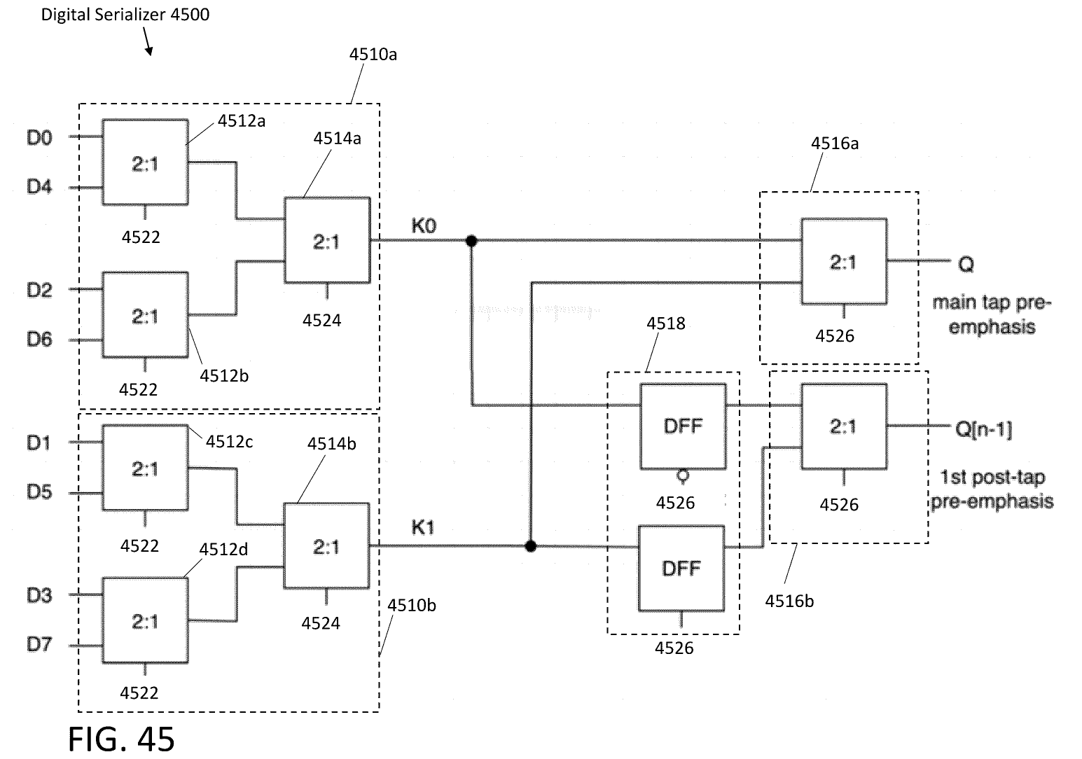

FIG. 45 is a schematic diagram of an example digital serializer 4500 that may be included in device 400, in accordance with some embodiments of the technology described herein.

In some embodiments, digital serializer 4500 may be configured as described herein for digital serializer 4366 including in connection with FIG. 43. For example, as shown in FIG. 45, the illustrated portion of digital serializer 4500 includes 4:1 parallel serializers 4510a and 4510b coupled to 2:1 multiplexers 4516a and 4516b. In some embodiments, the illustrated portion of digital serializer 4500 may be configured to receive two 4-bit inputs (D0-D7) from two 5-bit serializers such as described herein including in connection with FIG. 43.

In the illustrated example, serializer 4510a is shown in FIG. 45 including three 2:1 multiplexers, in which outputs of a first multiplexer 4512a and a second multiplexer 4512b are coupled to inputs of a third multiplexer 4514a. Similarly, serializer 4510b is shown in FIG. 45 including three 2:1 multiplexers, in which outputs of a first multiplexer 4512c and a second multiplexer 4512d are coupled to inputs of a third multiplexer 4514b. In the illustrated example, first multiplexers 4512a, 4512c and second multiplexers 4512b, 4512d are configured to receive a first clock signal 4522, which may have twice the clock rate of the input signals (D0-D7) so as to interleave the inputs in serialized fashion into the outputs. Similarly, as shown in FIG. 45, third multiplexers 4514a, 4514b are configured to receive a second clock signal 4524, which may have twice the clock rate of first clock signal 4522, so as to interleave the inputs in serialized fashion into the outputs. For instance, interleaving may be achieved by switching, within a clock cycle of the first clock signal 4522, at the rate of the second clock signal 4524, between outputting one of the two inputs to outputting the other of the two inputs. Also shown in the illustrated example, first pre-emphasis multiplexer 4516a and second pre-emphasis multiplexer 4516b are configured to receive a third clock signal 4526, which may have twice the clock rate of second clock signal 4524 so as to interleave the inputs in serialized fashion into the outputs.

Digital serializer 4500 is further shown in FIG. 45 including D-Flip Flops (DFF) 4518 coupled between serializer 4510a and second pre-emphasis multiplexer 4516b and between serializer 4510b and second pre-emphasis multiplexer 4516b, which is shown configured to receive third clock signal 4526. In some embodiments, DFFs 4518 may be configured to introduce a 1-bit delay between outputs of digital serializer 4500 for pre-emphasis, which may mitigate at least some inter-symbol interference in the outputs when transmitted (e.g., over the substrate).

### Material Detection and Identification

The inventors have recognized that materials and material properties can be characterized by their effect on electromagnetic waves during reflection. For example, a reflection may be influenced by the specific structure of the material, making a particular material detectable using its reflection, and further by the possible presence of a layer on the material surface, which may be further detectable using the reflection. For example, exposed metal may reflecting strongly (e.g., showing as white in an image). If metal is painted, or if a road has ice or snow or water on it, the reflected wave will not only carry spectral content indicating the metal but also spectral content indicating the layer, such as due to an excited waveguide mode (e.g., cavity resonance) within the layer. Based on the spectral content resulting from reflection off of the surface, the layer may be detected and/or identified.

In some embodiments, a device (e.g., 400) comprises a substrate (e.g., 404) and a transmitter (e.g., 420) mounted on the substrate. In some embodiments, the transmitter comprises transmit circuitry (e.g., 1160) configured to generate first RF signals having an RF center frequency between 300 GHz and 3 THz and a transmit antenna array (e.g., 1132) comprising a plurality of RF antennas (e.g., 1170) configured to transmit the first RF signals. In some embodiments, the device further comprises a receiver mounted on the substrate, the receiver comprising a receive antenna array (e.g., 1439) configured to receive second RF signals having the RF center frequency, the second RF signals being generated at least in part by first RF signals being reflected by a target object, and receive circuitry (e.g., 1480) configured to process the received second RF signals to obtain processed RF signals. In some embodiments, the device further comprises ADC circuitry (e.g., 452a-452c) coupled to the receive circuitry and configured to digitize the processed RF signals to obtain digitized RF signals.

In some embodiments, the device further comprises processing circuitry (e.g., 440) configured to identify a material of the target object using one or more of the digitized RF signals, wherein the material is any material having a dielectric constant greater than 1. For example, according to various embodiments, the material may be selected from a first group consisting of water, ice, snow, metal, paint, road material, wood, rubber, nylon, plastic, and fabric. In some embodiments, the material may be road material, the road material comprising concrete. In some embodiments, the concrete is asphalt concrete or cement concrete.

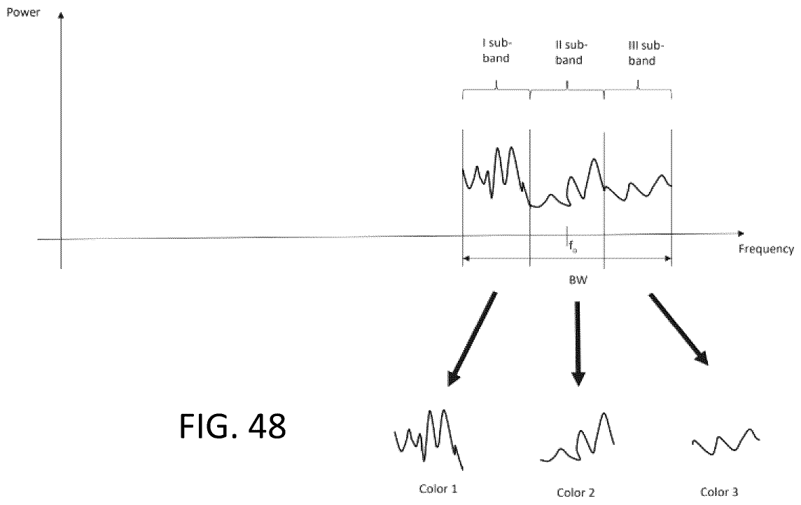

In some embodiments, each of the one or more digitized RF signals has frequency content in a frequency band having a plurality of sub-bands (e.g., sub-bands I, II, and III in FIG. 48), and the processing circuitry is configured to identify the material of the target object based on spectral content of the digitized RF signal in individual ones of one or more of the plurality of sub-bands. For example, the frequency band may have a bandwidth of at least 6 GHz. In some embodiments, the spectral content for a particular digitized RF signal of the one or more digitized RF signals comprises, for each particular sub-band of one or more of the plurality of sub-bands, a respective magnitude and/or power of the spectrum of the digitized RF signal in the particular sub-band.

In some embodiments, the processing circuitry is configured to identify the material by comparing spectral content of the digitized RF signal in each of one or more of the plurality of sub-bands with spectral content associated with a plurality of materials including the material. For example, the processing circuitry may be configured to identify the material by processing one or more features derived from the spectral content by using a trained machine learning model (e.g., executed using computer system 5100) trained to identify the material based on the one or more features derived from spectral content of digitized RF signals in each of one or more of the plurality of sub-bands. According to various embodiments, the trained machine learning model may be a neural network model, a logistic regression model, a random forest model, a decision tree model, or a gradient boosted decision tree model.

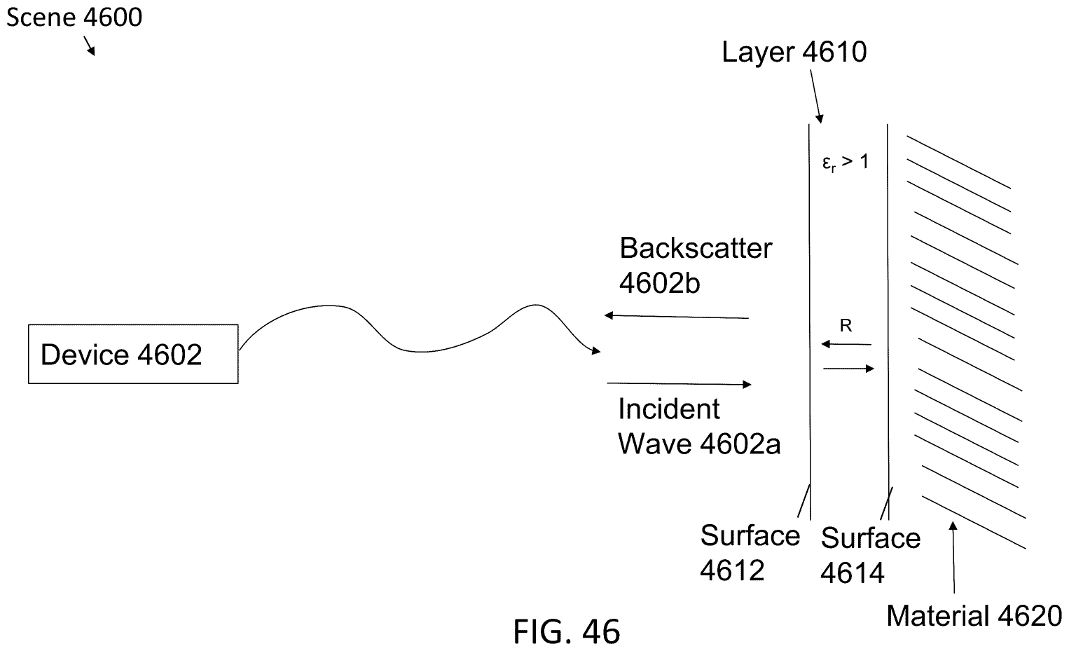

Alternatively or additionally, in some embodiments, the processing circuitry (e.g., 440) is configured to detect a material (e.g., layer 4610 in FIG. 46) disposed on the target object (e.g., material disposed on target object 4620) using one or more of the digitized RF signals. In some embodiments, the processing circuitry is further configured to identify the material disposed on the target object using the one or more of the digitized RF signals.

In some embodiments, the processing circuitry is configured to detect the material disposed on the target object based on spectral content of the one or more digitized RF signals at a first frequency indicating an excited waveguide mode (e.g., R in FIG. 46) in a region between a surface (e.g., 4612) of the material and a surface (e.g., 4614) of the target object. In some embodiments, the excited waveguide mode indicates the material, a material of the target object, and a distance from the surface of the material to the surface of the target object.

In some embodiments, the processing circuitry is configured to detect the material disposed on the target object based on spectral content of the one or more digitized RF signals at the first frequency. In some embodiments, spectral content of the one or more digitized RF signals at the first frequency comprises an amplitude, a magnitude, or a power of each of the one or more digitized RF signals at the first frequency.

In some embodiments, the processing circuitry is configured to detect the material disposed on the target object by comparing spectral content of the digitized RF signal at the first frequency with spectral content, at the first frequency, associated with a plurality of materials including the material. For example, the processing circuitry is configured to detect the material disposed on the target object by using a trained machine learning model (e.g., executed using computer system 5100) to process one or more features derived from the spectral content at the first frequency to obtain an output indicating the material disposed on the target object, wherein the trained machine learning model was trained to detect the material based on the one or more features derived from spectral content of the one or more digitized RF signals at the first frequency. In some embodiments, the processing circuitry is configured to detect the material disposed on the target object by using the trained machine learning model to process the one or more features derived from the spectral content at the first frequency and information indicating one or more materials part of the target object (e.g., a known material of a road) to obtain the output indicating the material disposed on the target object (e.g., snow, rain, or ice). According to various embodiments, the trained machine learning model may be a neural network model, a logistic regression model, a random forest model, a decision tree model, or a gradient boosted decision tree model.

FIG. 46 is another example scene 4600 in which to detect and/or identify a target object, scene 4600 including a target object 4620 and a layer 4610 disposed on target object 4620, in accordance with some embodiments of the technology described herein. In the example scene 4600 in FIG. 46, when incident electromagnetic waves (e.g., 4602a) hits a material surface (e.g., 4612) of a layer (e.g., 4610) on an object (e.g., 4620), resonance effects R will result in peaks/maximums in sub-bands. The resonance R (e.g., cavity resonance) depends how the thickness of the surface relates to the wavelength (e.g., quarter wavelength) (e.g., at the center frequency).

For instance, a layer of a paint typically presents as a dielectric material of about 200 microns thickness. This may be a quarter wavelength at some Terahertz frequencies. When an incident wave enters the layer (e.g., 4610), it will result in a standing resonance wave (e.g., cavity resonance) inside of the layer (e.g., between surfaces 4612 and 4614). Backscatter (e.g., 4602b) out of the resonance R can be detected as frequency content (e.g., a peak or peaks defining a particular material) in a sub frequency band.

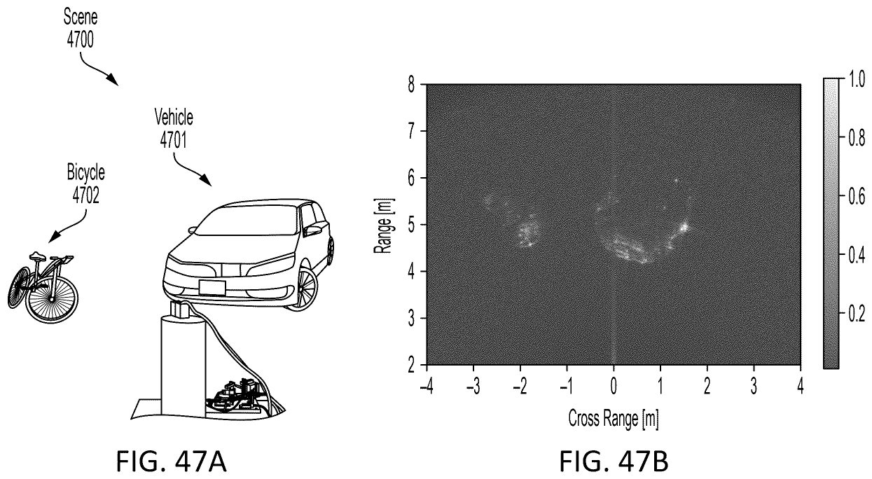

FIG. 47A is yet another example scene 4700 in which to detect and/or identify a target object, scene 4700 including a vehicle 4701 and a bicycle 4702, in accordance with some embodiments of the technology described herein. FIG. 47B is a range-cross-range measurement of scene 4700, in accordance with some embodiments of the technology described herein.

As shown in FIG. 47A, both the vehicle 4701 and the bicycle 4702 have regions of exposed metal and regions that are painted. In FIG. 47B, the painted regions and exposed metal regions exhibit a different amplitude response, as metal regions may reflect RF energy across a broad spectrum whereas painted regions may exhibit a more narrowband frequency response, such as due to the cavity resonance of the paint.

Because of the shorter wavelengths, Terahertz waves are more likely to produce resonance R in surface layers than gigahertz waves or lower. This is an advantage of Terahertz ranging.

Material properties and surface qualities can be detected by a multispectral imaging of the returning signal, such as described below.

A conventional 77 GHz RADAR is limited in the spectrum it can use. Above 290 GHz, Terahertz ranging can use a much wider spectrum due to increased bandwidth. As a result, a Terahertz ranging device can be used to detect a much wider range of signatures (e.g., identifying frequency content) in the returning signal (e.g., 4602b). This is another advantage of Terahertz ranging.

For other examples, the signature of a road may be chaotic since the surface is not homogeneous. A wet surface has a layer of water molecules on top of the road surface. As a result, the reflectivity will increase and it will look much more homogeneous to a Terahertz RADAR device (e.g., the road surface signature changes and looks more like metal or similar).

Due to the shorter wavelengths, Terahertz ranging sees more and other signatures than sensors at lower frequencies. Ice may be distinguished from water because of its crystalline structure resulting in a different signature. Rubber may look different from metal or wood or stone.

Detection or identification of a material may be based on a unique waveform using multiple sub-bands by comparing frequency content in the sub-bands. A database may store material signatures that may be correlated with (e.g., by looking up) the sub-band content of a reflected wave for material determination. This correlation could be performed by processing circuitry (e.g., 440) on substrate (e.g., 404) or on another substrate or a separate device. Material identifications and/or detections may be used within the device and/or may be reported out from the device (e.g., communicated to vehicle computer to alert a user).

The inventors have further recognized that Terahertz ranging may be used to predict movement of an object into or out of a projected path of the RADAR device. Camera image computing techniques exist for movement prediction, but camera images do not contain velocity information or relative velocity information of multiple parts of an object (e.g., movement of different parts of a person that may indicate weight distribution, such as using joint-to-joint person model). Terahertz ranging can provide, in some cases, distance, velocity, and relative velocity from a single ranging frame (e.g., single transmit pulse and reception). Terahertz ranging may further indicate a material of the object (e.g., metal or paint indicating a vehicle, or fabric or skin indicating a person). Movement prediction algorithms using Terahertz ranging may thus more precisely predict movement of an object (e.g., pedestrian or car) using the additional information provided using Terahertz ranging.

In some embodiments, processing circuitry (e.g., 440) of a device (e.g., 400) may be configured to determine a first velocity of at least a part of the target object (e.g., person, vehicle) using one or more of the digitized RF signals and predict movement of the target object using the first velocity. For example, the processing circuitry may be configured to predict, using the first velocity, whether the movement of the target object is into a projected path of the device (e.g., onboard a vehicle), and/or whether the movement of the target object is out of a projected path of the device. In some embodiments, the processing circuitry is configured to predict, using the first velocity, whether the movement of the target object is parallel to a projected path of the target device.

In some embodiments, the processing circuitry is configured to determine, using the one or more of the digitized RF signals, a plurality of velocities of the target object, the plurality of velocities including the first velocity of a first portion (e.g., arm) of the target object (e.g., person) and a second velocity of a second portion (e.g., torso) of the target object, and predict the movement of the target object using on the first and second velocities. In some embodiments, the processing circuitry is further configured to predict the movement of the target object into the projected path of the device based on a difference between the first and second velocities (e.g., using recognition of movement based on relative velocity). In some embodiments, the target object is a person, the plurality of velocities includes velocities of different parts of the person's body, and the processing circuitry is configured to determine a gesture being made by the person using the plurality of velocities, and predict movement of the person using the gesture.

In some embodiments, the processing circuitry is further configured to determine a distance between the target object and the device using one or more of the digitized RF signals and predict the movement of the target object using the distance. In some embodiments, the processing circuitry is further configured to determine a material of the target object using the one or more digitized RF signals. In some embodiments, the processing circuitry is further configured to determine, based on the material of the target object, whether the target object is a person or a vehicle. In some embodiments, the processing circuitry is further configured to determine a weight distribution of the target object using the one or more digitized RF signals and predict the movement of the target object into the projected path of the device based on the weight distribution of the target object.

FIG. 48 is a diagram illustrating example segmentation of a THz band into multiple sub-bands I, II, and III, in accordance with some embodiments of the technology described herein.

In this example, the bandwidth BW of a signal is segmented in three sub-bands (though it may be segmented in any suitable number of sub-bands, such as 2, 4, 6, 7, 8, 9, 10, etc.). In some embodiments, a first image is produced based on the first sub-band, a second image is produced based on the second sub-band and a third image is produced based on the third sub-band. Upon reflection from a target object, each sub-band of the signal may capture slightly different information about the target object relative to the other sub-bands. As a result, each image may have slightly different content. In some embodiments, the images obtained from the different sub-bands are combined to produce a multi-channel image. In some embodiments, a multi-channel image may be provided as input to train a machine learning model. In some embodiments, a multi-channel image may be provided as input to a previously trained machine learning model to identify the presence and/or characteristics (e.g., nature, composition) of an object.

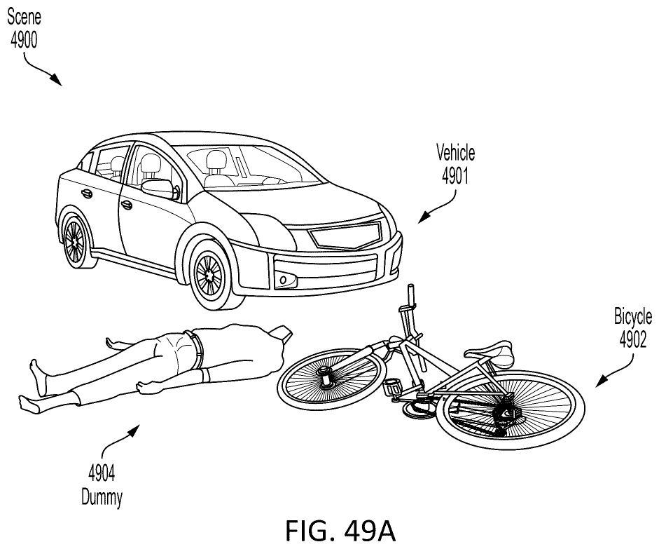

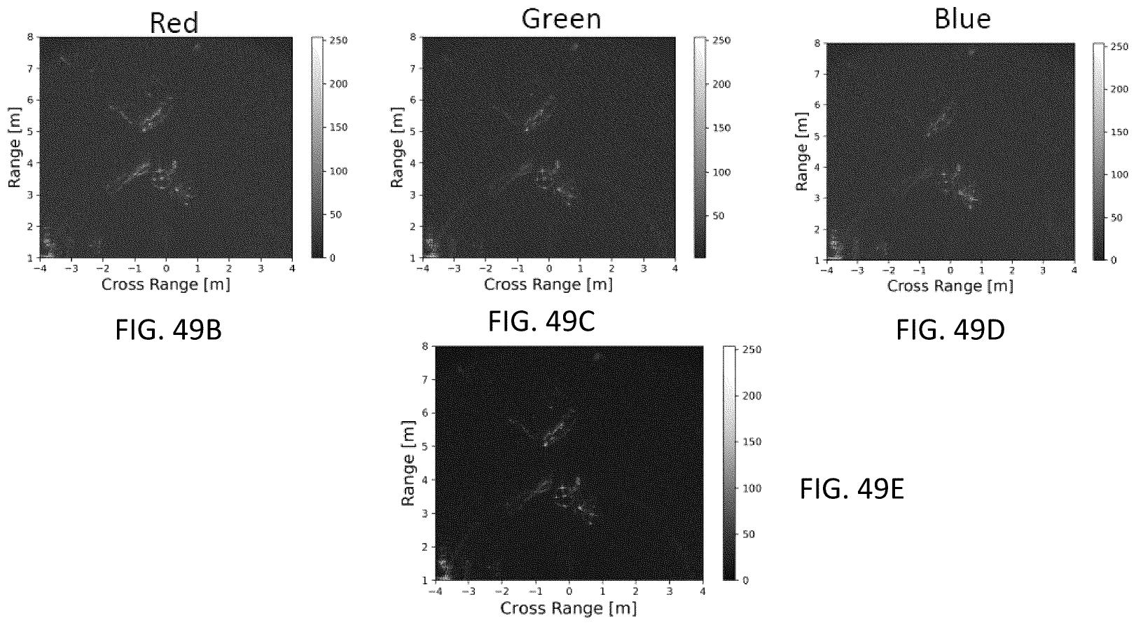

In some embodiments, each image may be colorized using a certain color. For example, each image may be assigned a certain color and may be displayed in accordance with the assigned color. For example, the image corresponding to a first sub-band I of FIG. 48 may be displayed in red, the image corresponding to a second sub-band II of FIG. 48 may be displayed in green, and the image corresponding to a third sub-band III of FIG. 48 may be displayed in blue. In some embodiments, the images so obtained are combined to produce a multi-color image (a multi-channel image where each channel corresponds to a different color). An example of a composite image generated in this way is shown in FIG. 49E, which is below.

Some embodiments relate to a method of imaging a target object using a device, the method comprising transmitting a first RF signal having a frequency band having a frequency content in a frequency band of 300 GHz-3 THz, the frequency band having at least first and second sub-bands; receiving a second RF signal produced by reflection of the first RF signal from the target object; and generating a multi-channel image having a first channel and a second channel, wherein data in the first channel is determined using frequency content of the first RF signal in the first sub-band, wherein data in the second channel is determined using frequency content of the second RF waveform in the second sub-band. In some embodiments, the frequency band has a bandwidth of 3 GHz-10 GHz. In some embodiments, the first frequency sub-band has a bandwidth of 1 GHz-6 GHz (e.g., 1 GHz-3 GHz). In some embodiments, the method further comprises determining a state (e.g., the position) of the target object using the multi-channel image. In some embodiments, the method further comprises assigning a first color to the data in the first channel; and assigning a second color to the data in the second channel. Generating the multi-channel image may comprise combining the data in the first channel having the first color assigned thereto with the data in the second channel having the second color assigned thereto.

FIG. 49A is an example scene 4900 in which to detect and/or identify a target object, scene 4900 including a vehicle 4901, a bicycle 4902, and a dummy 4904, in accordance with some embodiments of the technology described herein. FIG. 49B is a plot illustrating a range-cross range measurement of scene 4900 performed in first sub-band I, in accordance with some embodiments of the technology described herein. FIG. 49C is a plot illustrating a range-cross range measurement of scene of 4900 performed in second sub-band II, in accordance with some embodiments of the technology described herein. FIG. 49D is a plot illustrating a range-cross range measurement of scene 4900 performed in third sub-band III, in accordance with some embodiments of the technology described herein. FIG. 49E is a plot illustrating a range-cross range measurement of scene 4900 obtained by combining the measurements of FIGS. 49B-49D, in accordance with some embodiments of the technology described herein.

In some circumstances, different target objects may present different response in the frequency sub-bands, especially for target objects made of different materials. The inventors have recognized that complex target objects of the types that may be encountered on the road may be detected and/or distinguished using their different frequency responses. FIG. 49A is an example setup for performing range-cross range measurements. This setup includes a THz ranging device 100 (not shown in FIG. 49A), a vehicle 4901, a bicycle 4902 and a dummy 4904. Each of these objects is complex in that it includes various materials arranged in different shapes. The inventors have recognized that these types of target objects can benefit from the use of multi-channel imaging techniques of the types described herein. Consider for example that the vehicle's rims are made of aluminum, the chassis is covered with paint, the tires are made of rubber, the headlights are made of plastic, the windshield is made of glass, etc. While metal presents a largely white response, the other materials may reflect THz signals in accordance with different frequency responses.

FIGS. 49B-49D are plots illustrating example range-cross range measurements performed at different frequency ranges in connection with the setup of FIG. 49A and in accordance with the multi-channel imaging techniques described in connection with FIG. 48. As can be appreciated from these figures, each sub-band highlights different features of the target objects. FIG. 49E is a plot illustrating a range-cross range measurement obtained by assigning colors to the measurements of FIGS. 49B-49D (red, green and blue, respectively) and by adding the measurements together. As can be appreciated from FIG. 49E, the combined image is much richer than the images corresponding to the individual sub-bands.

### Sensor Fusion

The inventors have recognized that Terahertz ranging data may be fused with data from other sensors, such as a camera, conventional RADAR, LiDAR, and/or ultrasound. Data may be fused as raw data (e.g., processed ranges and/or velocities), and/or data may be packaged prior to fusion (e.g., range data may be translated into a data structure and/or incoming image data from a camera may have a common image file format).

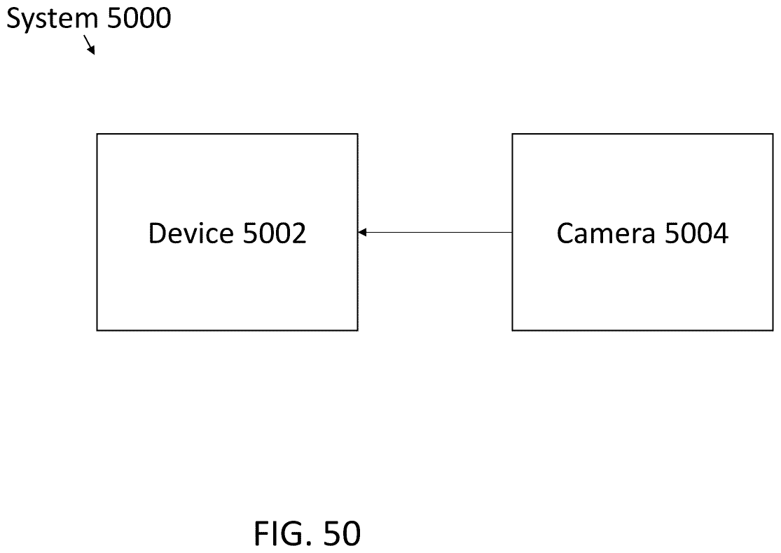

In some embodiments, a device (e.g., 5002 in FIG. 50) may comprise a substrate (e.g., 404), a transmitter (e.g., 420) mounted on the substrate, the transmitter comprising transmit circuitry (e.g., 1160) configured to generate first RF signals having an RF center frequency between 300 GHz and 3 THz and a transmit antenna array (e.g., 1132) comprising a plurality of RF antennas configured to transmit the first RF signals. In some embodiments, the device may further comprise a receiver (e.g., 430) mounted on the substrate, the receiver comprising a receive antenna array (e.g., 1439) configured to receive second RF signals generated as a result of the first RF signals being reflected by one or more target objects in a scene and receive circuitry (e.g., 1480) configured to process the received second RF signals to obtain processed RF signals. In some embodiments, the device may further comprise ADC circuitry (e.g., 450) coupled to the receive circuitry and configured to digitize the processed RF signals to obtain digitized RF signals.

In some embodiments, the device may further comprise processing circuitry (e.g., 440) configured to perform obtaining sensor data about the scene from a sensor (e.g., camera 5004 in FIG. 50) separate from the device and associating the sensor data obtained from the sensor with data derived from one or more of the digitized RF signals. For example, the sensor data may include pixels of a camera image, which may be associated with a target object detected in range data derived from the digitized RF signal(s), thereby enhancing the sensor data with additional information beyond that which the sensor could provide on its own.

In some embodiments, aggregated data (e.g., a number of ranging frames) and/or detected objects and/or layers (e.g., road boundaries, pedestrians, snow, ice, water) may be fused with other sensor data, such as camera images.

Sensor fusion can be applied based on two sensor modalities or based on multiple sensor modalities. Fusing Terahertz ranging with a camera image provides some unique advantages due to the way Terahertz ranging may complement optical imaging. Camera data provides a high resolution (horizontal, vertical resolution), contrast, and color. Terahertz ranges add depth and velocity to some or all pixels of a camera image. Terahertz ranging may further distinguish materials based on their signatures, and/or detect and/or identify a layer material such as snow, ice, and water. Fusion of camera images and Terahertz ranging may create an enhanced image that can be used for multiple applications, such as spotting road or lane boundaries around the vehicle and/or spotting objects around the vehicle (e.g., while driving or parking). An enhanced image may combine the qualities of a camera image with the depth, the velocity and material/surface property information (e.g., sub-band signatures), provided by Terahertz ranging.

In some cases, an enhanced image can be used as the primary source of information for vehicle detection and tracking algorithms executed onboard a vehicle (e.g., as used in autonomous driving, such as to spot lane and/or road boundaries). Alternatively, an enhanced image may be used as a secondary information source, such as to confirm a decision of a primary sensor (e.g., conventional RADAR, camera, LiDAR, ultrasound) or to add a new modality to an existing sensor architecture to enhance the safety level of a detection or ultimately, the safety level of a driving policy.

For fusion, information retained from Terahertz ranging may include the 3D set of points cloud providing focus on depth and vector of each pixel or voxel and/or material/surface information (e.g., sub-band frequency content and/or materials and/or surfaces detected and/or identified therefrom). Terahertz ranging information retained may also include velocity from doppler information. Camera information received from a camera may be used to superimpose higher resolution azimuth information and/or color in the visual spectrum.

In some cases, using Terahertz RADAR may render depth information from a camera less important, with a conflict resolved by Terahertz RADAR. Terahertz ranging in the azimuth resolution may be less useful than a camera image, and so the camera image may resolve a conflict therebetween. Ultrasound, LiDAR, and cameras may be subject to light and weather interference that, if detected, may cause Terahertz ranging data to be used to resolve conflicting data. Where Terahertz ranging is fused with conventional RADAR data having longer range than the Terahertz ranging, Terahertz ranging may be performed to provide high resolution close-range sensing (e.g., in a low power transmit mode) in combination with longer range sensing from the conventional RADAR.

FIG. 50 is a block diagram of an example system 5000 including a device 5002 configured for active THz sensing and a camera 5004 coupled to device 5002, in accordance with some embodiments of the technology described herein.

As described above for system 10, in some embodiments, other sensing devices may be included. For example, system 10 may be configured to fuse data from other sensing devices with data from device 100. For instance, in FIG. 50, system 5000 may be configured as described herein for system 10, including a device 5002 that may be configured as described herein for device 100 and a camera 5004.

In some embodiments, fusion may be performed by processing circuitry (e.g., 440) on a substrate (e.g., 404) of device 5002, though it may be at least partially performed on another substrate or a separate device of system 10. Sensed data, such as one or more images, from the other sensors (e.g., camera 5004) may be obtained at the processing circuitry for fusion. For example, the information may be received over a communication link within a vehicle having the sensor and device equipped.

In some embodiments, processing circuitry of device 5002 may be configured to associate sensor data obtained from a sensor with Terahertz RADAR data from a receiver of the device to enhance the sensor data with distance information. For example, for a set of one or more pixels in an image obtained by camera 5004, the processing circuitry may be configured to use data derived from digitized RF signal(s) (e.g., from the receiver) to determine a distance between the device and an item or a part of an item captured by the set of one or more pixels and associate the distance with each pixel in the set of one or more pixels. For instance, pixels corresponding to an item may have depth added thereto using the distance information obtained using the receiver.

Alternatively or additionally, in some embodiments, the processing circuitry may be configured to, for each pixel in the image obtained by camera 5004, use the data derived from the digitized RF signal(s) to determine a respective distance between the device and an item or a part of an item captured by the pixel and associate the respective distance with the pixel. For instance, depth information may be added to each individual pixel using the distance information obtained using the receiver.

In some embodiments, processing circuitry of device 5002 may be configured to update a distance initially determined using Terahertz RADAR ranging to a target object using results of associating sensor data with Terahertz RADAR data. For example, the processing circuitry may be configured to update one or more distances, initially determined by using digitized RF signal(s) (e.g., from the receiver), between the device and one or more items or portions thereof captured by one or more pixels in the camera image by using results of association with the pixels to obtain one or more updated distance(s).

In some embodiments, processing circuitry of device 5002 may be configured to associate sensor data with points in a range-cross range image formed using Terahertz RADAR ranging. For example, the processing circuitry may be configured to form a range cross-range image using the digitized RF signal(s) and associate each of one or more points in the range cross-range image with a respective set of one or more pixels in the image obtained by camera 5004.

In some embodiments, processing circuitry of device 5002 may be further configured to detect, in the sensor data from the sensor, at least a portion of a road, a person, and/or a vehicle. For example, the processing circuitry may be configured to detect, in an image obtained by camera 5004, a road boundary or a lane boundary using the data derived from the digitized RF signal(s) and results of the association with the image. In some embodiments, target objects in the scene may include one or more people and/or one or more vehicles.

While a camera 5004 is shown in FIG. 50 in system 5000, it should be appreciated that other embodiments of the system may alternatively include an ultrasound sensor and/or a LIDAR sensor.

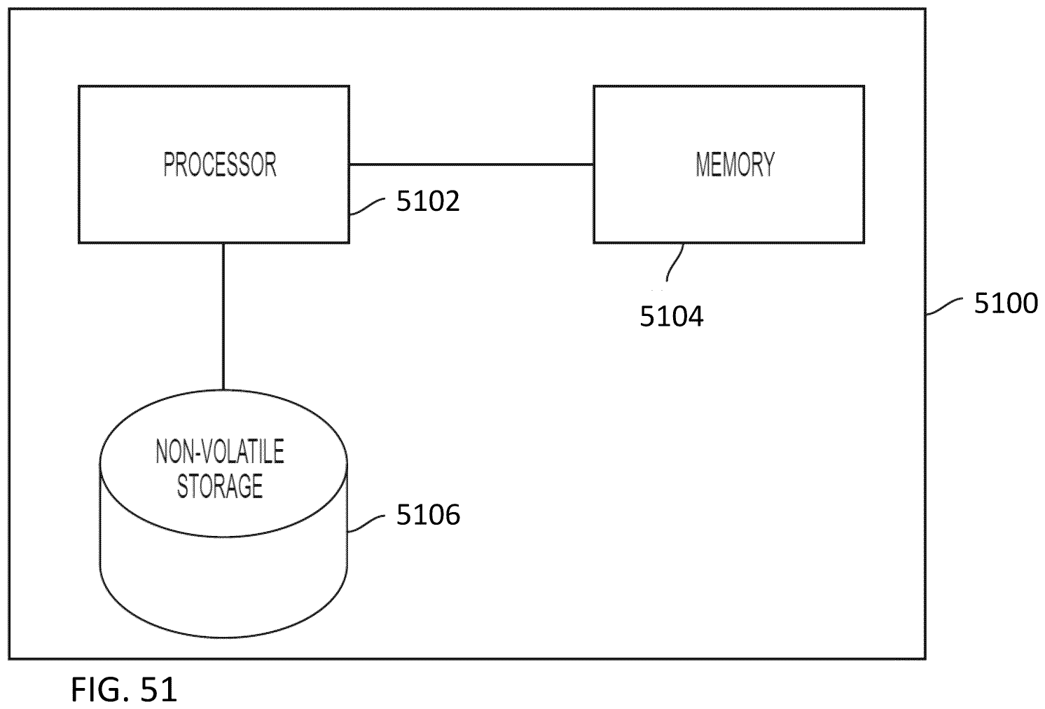

FIG. 51 is a block diagram of an example computer system 5100 that may be configured to perform at least some processing operations described herein for device 100 of system 10 and system 5000, in accordance with some embodiments of the technology described herein.

An illustrative implementation of a computer system 5100 that may be used in connection with any of the embodiments of the disclosure provided herein is shown in FIG. 51. For example, in some embodiments, operations described herein including in connection with FIGS. 6C-6D, 28-29D, 30-32F, 40-44, and 46-50 may be performed using the computer system 5100 (e.g., implemented using processing circuitry mounted on and/or coupled to a substrate of a device). The computer system 5100 may include one or more processors 5102 and one or more articles of manufacture that comprise non-transitory computer-readable storage media (e.g., memory 5104 and one or more non-volatile storage media 5106). The processor 5102 may control writing data to and reading data from the memory 5104 and the non-volatile storage device 5106 in any suitable manner, as the aspects of the disclosure provided herein are not limited in this respect. To perform any of the functionality described herein, the processor 5102 may execute one or more processor-executable instructions stored in one or more non-transitory computer-readable storage media (e.g., the memory 5104), which may serve as non-transitory computer-readable storage media storing processor-executable instructions for execution by the processor 5102.

Below is a list of non-limiting example embodiments of the technology described herein:

Example 1. A device, comprising: a substrate defining a plane extending in first and second directions substantially orthogonal to one another; signal generation circuitry mounted on the substrate and configured to generate a reference RF signal; a transmitter mounted on the substrate, the transmitter comprising: a first transmit semiconductor die coupled to the signal generation circuitry and having integrated thereon: first transmit circuitry configured to generate, based on the reference RF signal, first RF signals having an RF center frequency between 300-320 GHz, and a first transmit antenna array comprising a first plurality of RF antennas configured to transmit the first RF signals; a receiver mounted on the substrate, the receiver comprising: a first receive semiconductor die coupled to the signal generation circuitry and having integrated thereon: a first receive antenna array comprising a second plurality of RF antennas configured to receive second RF signals having the RF center frequency; and first receive circuitry configured to: generate third RF signals based on the reference RF signal; and mix the second RF signals with the third RF signals to obtain fourth RF signals and provide the fourth RF signals to the interface circuitry; and interface circuitry mounted on the substrate and coupled to the first receive circuitry, the interface circuitry comprising analog-to-digital conversion (ADC) circuitry configured to digitize the fourth RF signals.

Example 2. The device of Example 1, wherein the substrate comprises a printed circuit board (PCB).

Example 3. The device of Example 1 or 2, wherein the signal generation circuitry is configured to generate the reference RF signal as a linear frequency modulated (LFM) chirp signal.

Example 4. The device of Example 3, wherein the LFM chirp signal has a center frequency between 16 and 20 GHz.

Example 5. The device of any one of Examples 1-4, wherein the transmitter comprises a first column of transmit semiconductor dies tiled in the first direction, the column of transmit semiconductor dies including the first transmit semiconductor die and a second transmit semiconductor die spaced at a distance from the first transmit semiconductor die in the first direction, and wherein the second transmit semiconductor die is coupled to the signal generation circuitry and has integrated thereon: a second transmit antenna array; and second transmit circuitry configured to generate RF signals based on the reference RF signal and feed the generated RF signals to RF antennas in the second transmit antenna array.

Example 6. The device of Example 5, wherein: the first transmit semiconductor die has a first transmit RF antenna integrated thereon, the second transmit semiconductor die has a second transmit RF antenna integrated thereon, and the first transmit semiconductor die and the second transmit semiconductor die are arranged in the transmitter such that a center-to-center distance between the first transmit RF antenna and the second transmit RF antenna is less than or within 10% of one half of a free-space wavelength at the first RF center frequency.

Example 7. The device of Example 6, wherein the center-to-center distance between the first transmit RF antenna and the second transmit RF antenna is equal to one half of the free-space wavelength at the first RF center frequency.

Example 8. The device of any one of Examples 5-7, wherein the transmitter comprises a second column of transmit semiconductor dies tiled in the first direction, wherein the second column of transmit semiconductor dies is spaced at a distance from the first column of transmit semiconductor dies in the second direction, wherein the second column of transmit semiconductor dies includes third and fourth transmit semiconductor dies each having integrated thereon respective transmit circuitry and transmit antenna array and each being coupled to the signal generation circuitry.

Example 9. The device of any one of Examples 1-8, wherein each of the first plurality of RF antennas comprises a patch.

Example 10. The device of any one of Examples 1-8, wherein each of the first plurality of RF antennas comprises a dipole.

Example 11. The device of any one of Examples 1-10, wherein the first plurality of RF antennas integrated on first transmit semiconductor die are arranged in a two-dimensional grid having two columns and multiple rows, and wherein the first plurality of RF antennas has mirror symmetry across a line extending in the first direction.

Example 12. The device of Example 11, wherein the first plurality of RF antennas consists of 32 RF antennas arranged into a grid having 2 columns and 16 rows.

Example 13. The device of any one of Examples 1-12, wherein the receiver comprises a row of receive semiconductor dies tiled in the second direction, the row of receive semiconductor dies including the first receive semiconductor die and a plurality of other receive semiconductor dies, each of which is coupled to the signal generation circuitry and has integrated thereon a respective receive antenna array and respective receive circuitry configured to process, using the reference RF signal, RF signals received by the respective receive antenna array.

Example 14. The device of Example 13, further comprising a fixture mechanically coupled to the substrate and configured to limit thermal expansion of the substrate.

Example 15. The device of Example 13 or 14, wherein: the plurality of other receive semiconductor dies includes a second receive semiconductor die, the first receive semiconductor die has a first receive RF antenna integrated thereon, the second receive semiconductor die has a second receive RF antenna integrated thereon, and the first receive semiconductor die and the second receive semiconductor die are arranged in the receiver such that a center-to-center distance between the first receive RF antenna and the second receive RF antenna is less than or within 10% of one half of a free-space wavelength at the first RF center frequency.

Example 16. The device of Example 15, wherein the center-to-center distance between the first receive RF antenna and the second receive RF antenna is equal to one half of the free-space wavelength at the first RF center frequency.

Example 17. The device of any one of Examples 13-16, wherein the row of receive semiconductor dies comprises 26 receive semiconductor dies, each of which has integrated thereon 16 receive antennas.

Example 18. The device of any one of Examples 1-17, wherein each of the second plurality of RF antennas comprises a patch.

Example 19. The device of any one of Examples 1-18, wherein each of the second plurality of RF antennas comprises a dipole.

Example 20. The device of any one of Examples 1-18, wherein the first receive semiconductor die is mounted on an interposer and the interposer is mounted on the substrate.

Example 21. The device of Example 13, wherein each receive semiconductor die in the row of receive semiconductor dies is mounted on an interposer and the interposer is mounted on the substrate.

Example 22. The device of Example 21, further comprising a focusing element mounted on the interposer and at least partially covering receive semiconductor dies in the row of receive semiconductor dies.

Example 23. The device of Example 22, wherein the focusing element comprises a cylindrical lens having a primary axis extending across the second direction.

Example 24. The device of Example 23, where the receiver has an aperture having a length extending along the first direction and a width extending parallel to the second direction, wherein the width is larger than the length.

Example 25. The device of Example 22, wherein the focusing element is formed of silicon.

Example 26. The device of Example 22, wherein the focusing element comprises a spherical or elliptical lens.

Example 27. The device of any one of Examples 1-26, wherein the third RF signals have a second harmonic at the RF center frequency, and the first receive circuitry is configured to mix the second RF signals with the second harmonic of the third RF signals to obtain the fourth RF signals.

Example 28. The device of any one of Examples 1 to 27, wherein the fourth RF signals are indicative of a distance between the device and a target object that reflected RF energy to generate, at least in part, the second RF signals received by the first receive antenna array.

Example 29. The device of any one of Examples 1-28, wherein the first RF signals have a bandwidth of at least 3 GHz or at least 6 GHz.

Example 30. The device of any one of Examples 1-29, wherein the first transmit circuitry comprises frequency multiplication circuitry configured to multiply a center frequency of the reference RF signal to the RF center frequency.

Example 31. The device of any one of Examples 1-30, wherein the first transmit circuitry comprises power divider circuitry configured to divide the reference RF signal into reference RF signals, and the first RF signals are based on the reference RF signals, respectively.

Example 32. The device of Example 31, wherein the transmit circuitry comprises a plurality of frequency multipliers configured to multiply the reference RF signals, respectively, to generate the first RF signals.

Example 33. The device of any one of Examples 1-32, wherein the first receive circuitry comprises frequency multiplication circuitry configured to multiply a center frequency of the reference RF signal to generate the third RF signals.

Example 34. The device of any one of Examples 1-33, wherein the first receive circuitry comprises power divider circuitry configured to divide the reference RF signal into reference RF signals and the third RF signals are based on the reference RF signal portions, respectively.

Example 35. The device of Example 34, wherein the frequency multiplication circuitry of the first receive circuitry comprises a plurality of frequency multipliers configured to multiply the reference RF signals, respectively, to generate the third RF signals.

Example 36. The device of any one of Examples 1-35, wherein the ADC circuitry comprises a plurality of ADCs mounted on the substrate.

Example 37. The device of any one of Examples 1 to 36, wherein: the first receive circuitry comprises a first plurality of receive channels coupled to the second plurality of RF antennas and configured to mix the second RF signals with the third RF signals to obtain the fourth RF signals; the interface circuitry comprises time-division multiplexing circuitry comprising a plurality of time-division multiplexers configured to combine the fourth RF signals into time-division multiplexed signals; and the ADC circuitry is configured to digitize the fourth RF signals at least in part by digitizing the time-division multiplexed signals into digitized time-division multiplexed signals.

Example 38. The device of any one of Examples 1 to 37, wherein: the interface circuitry comprises first serial communication circuitry configured to serialize a first subset of the fourth RF signals to obtain and transmit a first serialized processed RF signal; the interface circuitry further comprises second serial communication circuitry configured to serialize a second subset of the fourth RF signals to obtain and transmit a second serialized processed RF signal; and the device comprises processing circuitry configured to synchronize serialization of the first subset of the fourth RF signals by the first serial communication circuitry with serialization of the second subset of the fourth RF signals by the second serial communication circuitry.

Example 39. The device of any one of Examples 36 to 38, wherein the receiver comprises a row of receive semiconductor dies tiled in the second direction, the row of receive semiconductor dies including the first receive semiconductor die and a plurality of other receive semiconductor dies, and wherein each of the plurality of ADCs is coupled to a respective set of one or more receive semiconductor dies in the row of receive semiconductor dies and is configured to digitize signals output by the respective set of one or more receive semiconductor dies.

Example 40. The device of Example 39, where each of the plurality of ADCs is coupled to a respective pair of receive semiconductor dies in the row of receive semiconductor dies and is configured to digitize signals output by the pair of receive semiconductor dies.

Example 41. The device of any one of Examples 1-40, further comprising: processing circuitry configured to process digitized signals output by the interface circuitry.

Example 42. The device of Example 41, wherein the processing circuitry is coupled to the interface circuitry using a JESD interface protocol.

Example 43. The device of any one of Examples 41-42, wherein the processing circuitry comprises one or more FPGAs and/or one or more processors.

Example 44. The device of any one of Examples 41-43, wherein the processing circuitry is mounted on the substrate.

Example 45. A device, comprising: a substrate defining a plane extending in first and second directions substantially orthogonal to one another; signal generation circuitry mounted on the substrate and configured to generate a reference RF signal; a transmitter mounted on the substrate, the transmitter comprising: a first transmit semiconductor die coupled to the signal generation circuitry and having integrated thereon: first transmit circuitry configured to generate, based on the reference RF signal, first RF signals having an RF center frequency in a particular frequency range within a range of 150 GHz to 1.5 THz, and a first transmit antenna array comprising a first plurality of RF antennas configured to transmit the first RF signals; a receiver mounted on the substrate, the receiver comprising: a first receive semiconductor die coupled to the signal generation circuitry and having integrated thereon: a first receive antenna array comprising a second plurality of RF antennas configured to receive second RF signals having the RF center frequency; and first receive circuitry configured to: generate third RF signals based on the reference RF signal; and mix the second RF signals with the third RF signals to obtain fourth RF signals and provide the fourth RF signals to the interface circuitry; and interface circuitry mounted on the substrate and coupled to the first receive circuitry, the interface circuitry comprising analog-to-digital conversion (ADC) circuitry configured to digitize the fourth RF signals.

Example 46. The device of Example 44, wherein the particular frequency range is 190 to 300 GHz, 300 to 320 GHz, 390 to 450 GHz, 440 to 480 GHz, 455 to 495 GHz, or 820 to 880 GHz.

Example 47. A device, comprising: a substrate; and a receiver mounted on the substrate, the receiver comprising: a first receive semiconductor die having integrated thereon: a first receive antenna array configured to receive RF signals, the first receive antenna array comprising a first RF antenna; and first receive circuitry comprising: a plurality of mixers coupled to respective RF antennas in the first receive antenna array, the plurality of mixers comprising a first mixer coupled to the first RF antenna and configured to mix an RF signal obtained using the first RF antenna with a reference RF signal to output a first mixed signal; a first amplifier coupled to the first mixer and configured to amplify the first mixed signal output by the first mixer; and a first reflector coupled between the first mixer and the first amplifier and configured to reflect at least some RF energy generated by the first mixer back into the first mixer.

Example 48. The device of Example 47, wherein: the first RF antenna is configured to receive a first RF signal, the RF signal is based on the first RF signal, and the first mixed signal has a center frequency indicative of a distance between the device and a target object from which the first RF signal was received by the first RF antenna.

Example 49. The device of Example 48, wherein: the first receive circuitry further comprises a filter coupled between the first RF antenna and the first mixer, the first RF antenna is configured to provide the first RF signal as an input to the filter, and the first mixer is configured to obtain the RF signal as an output from the filter.

Example 50. The device of any one of Examples 47-49, wherein: the RF signal has a center frequency, and the at least some RF energy comprises a voltage and/or current wave having the center frequency of the RF signal.

Example 51. The device of Example 50, wherein: the first mixer is configured to output the first mixed signal as a current signal, the first amplifier comprises a transimpedance amplifier (TIA) configured to convert the current signal into a voltage signal, the at least some RF energy comprises a current wave having the center frequency of the RF signal, and the first reflector comprises a current reflector configured to reflect the current wave back into the first mixer.

Example 52. The device of any one of Examples 50 and 51, wherein the center frequency of the RF signal is between 300 GHz and 320 GHz.

Example 53. The device of any one of Examples 50-52, wherein the first reflector comprises a current reflector.

Example 54. The device of any one of Examples 50-53, wherein the first reflector comprises a transmission line stub.

Example 55. The device of Example 54, wherein the transmission line stub has a length of one quarter of a wavelength at the center frequency of the RF signal.

Example 56. The device of any one of Examples 50-56, wherein: the reference RF signal comprises a second harmonic having the center frequency of the RF signal, and the first mixer is configured to mix the RF signal with the second harmonic of the reference RF signal.

Example 57. The device of any one of Examples 47-56, wherein: the RF signal is defined by a first differential component and a second differential component, the first mixer is configured to mix the first differential component of the RF signal with the reference RF signal to output the first mixed signal, the plurality of mixers further comprises a second mixer coupled to the first RF antenna and configured to mix the second differential component of the RF signal with the reference RF signal to output a second mixed signal, the first receive circuitry further comprises: a second amplifier coupled to the second mixer and configured to amplify the second mixed signal output by the second mixer, and a second reflector coupled between the second mixer and the second amplifier and configured to reflect at least some RF energy generated by the second mixer back into the second mixer.

Example 58. The device of any one of Examples 47-56, wherein: the first receive antenna array further comprises a second RF antenna, the plurality of mixers further comprises a second mixer coupled to the second RF antenna and configured to mix a second RF signal obtained using the second RF antenna with the reference RF signal to output a second mixed signal, the first receive circuitry further comprises: a second amplifier coupled to the second mixer and configured to amplify the second mixed signal output by the second mixer, and a second reflector coupled between the second mixer and the second amplifier and configured to reflect at least some RF energy generated by the second mixer back into the second mixer.

Example 59. The device of any one of Examples 47-58, wherein: the first mixer comprises a first differential mixer configured to: mix the RF signal with a first differential component of the reference RF signal to generate a first mixed signal component; mix the RF signal with a second differential component of the reference RF signal to generate a second mixed signal component; and combine the first and second mixed signal components to generate the first mixed signal.

Example 60. The device of any one of Examples 47-59, further comprising: an analog-to-digital converter (ADC) mounted on the substrate and configured to receive the first mixed signal via the first amplifier.

Example 61. The device of Example 60, wherein the ADC is integrated on the first receive semiconductor die.

Example 62. The device of any one of Examples 47-61, further comprising: signal generation circuitry mounted on the substrate and configured to generate a reference RF signal; and a transmitter mounted on the substrate, the transmitter comprising: a first transmit semiconductor die having integrated thereon: a plurality of RF antennas, and transmit circuitry configured to generate, using the reference RF signal, first RF signals and feed the first RF signals to the plurality of RF antennas, wherein the signal generation circuitry is coupled to the first receive circuitry and is configured to provide the reference RF signal to the first receive circuitry.

Example 63. The device of any one of Examples 47-62, wherein the RF antennas in the first receive antenna array are dipole antennas.

Example 64. The device of any one of Examples 47-63, wherein each of the RF antennas in the first receive antenna array comprises a patch.

Example 65. A device, comprising: a substrate; and a receiver mounted on the substrate, the receiver comprising: a first receive semiconductor die having integrated thereon: a first RF antenna configured to receive RF signals; and first receive circuitry comprising: a first mixer coupled to the first RF antenna and configured to mix an RF signal obtained using the first RF antenna with a reference RF signal to output a first mixed signal; a first amplifier coupled to the first mixer and configured to amplify the first mixed signal output by the first mixer; and a first reflector coupled between the first mixer and the first amplifier.

Example 66. A device, comprising: a substrate; and a receiver mounted on the substrate, the receiver comprising: a first receive semiconductor die having integrated thereon: a first receive antenna array comprising a plurality of RF antennas, each of the plurality of RF antennas comprising two or more patches serially coupled to one another; and first receive circuitry coupled to the plurality of RF antennas, wherein, for each particular one of the plurality of RF antennas, the first receive circuitry is coupled to one of the two or more patches of the particular RF antenna.

Example 67. The device of Example 66, wherein the plurality of RF antennas comprises a first RF antenna, wherein the first RF antenna comprises a first patch and a second patch coupled to the first patch, and wherein the first receive circuitry is coupled to a port of the first patch.

Example 68. The device of Example 67, wherein the first patch is spaced from the first receive circuitry in a first direction and the second patch is spaced from the first patch in the first direction.

Example 69. The device of Example 67 or 68, wherein the first RF antenna further comprises a first plurality of vias disposed around the first patch and a second plurality of vias disposed around the second patch.

Example 70. The device of any one of Examples 66-69, wherein, for each particular one of the plurality of RF antennas, the first receive circuitry is coupled to only one of the two or more patches of the particular RF antenna.

Example 71. The device of any one of Examples 66 to 70, wherein the plurality of RF antennas are configured to receive RF signals having a center frequency between 300 GHz and 320 GHz.

Example 72. The device of any one of Examples 66 to 70, wherein the plurality of RF antennas are configured to receive RF signals having a center frequency between 650 GHz and 690 GHz.

Example 73. The device of any one of Examples 66 to 70, wherein the plurality of RF antennas are configured to receive RF signals having a center frequency in a range of 190 to 300 GHz, 300 to 320 GHz, 390 to 450 GHz, 440 to 480 GHz, 455 to 495 GHz, or 820 to 880 GHz.

Example 74. A device, comprising: a substrate defining a plane extending in first and second directions substantially orthogonal to one another; a transmitter mounted on the substrate, the transmitter comprising: a first transmit semiconductor die having integrated thereon: first transmit circuitry configured to generate first RF signals based on a reference RF signal; and a first transmit antenna array comprising a plurality of RF antennas configured to transmit the first RF signals and having a first aperture with a first length extending in the first direction and a first width extending in the second direction, the first length being larger than the first width, wherein the plurality of RF antennas is arranged in a two-dimensional grid and has mirror symmetry across a line extending in the first direction; and a receiver mounted on the substrate, the receiver comprising a first receive semiconductor die having integrated thereon: a first receive antenna array comprising a plurality of RF antennas configured to receive second RF signals and having a second aperture with a second length extending in the first direction and a second width extending in the second direction, the second length being smaller than the second width; and first receive circuitry configured to obtain the second RF signals via the plurality of RF antennas of the first receive antenna array.

Example 75. The device of Example 74, wherein: the plurality of RF antennas is arranged in two columns and two or more rows in the two-dimensional grid, the two columns including a first column and a second column that are separated by the line extending in the first direction, and the first transmit circuitry comprises: a first transmit circuitry portion configured to feed RF antennas in the first column, and a second transmit circuitry portion configured to feed RF antennas in the second column.

Example 76. The device of Example 75, wherein the plurality of RF antennas consists of 32 antennas arranged in two columns and 16 rows.

Example 77. The device of Example 75 or 76, wherein the first transmit circuitry portion is arranged in the first column and the second transmit circuitry portion is arranged in the second column.

Example 78. The device of any one of Examples 75-77, further comprising: signal generation circuitry mounted on the substrate and configured to generate the reference RF signal, wherein the first transmit semiconductor die further comprises: a first interface, positioned within a threshold distance of a first outer edge of the first transmit semiconductor die, configured to receive the reference RF signal from the signal generation circuitry and provide the reference RF signal to the first transmit circuitry portion, and a second interface, positioned with the threshold distance of a second outer edge of the first transmit semiconductor die, configured to receive the reference RF signal from the signal generation circuitry and provide the reference RF signal to the second transmit circuitry portion, wherein the first outer edge is opposite the second outer edge.

Example 79. The device of Example 78, wherein: the first interface further comprises power divider circuitry configured to divide the reference RF signal into first reference RF signals and provide the first reference RF signals to the first transmit circuitry portion for feeding the RF antennas in the first column, respectively, and the second interface further comprises power divider circuitry configured to divide the reference RF signal into second reference RF signals and provide the second reference RF signals to the second transmit circuitry portion for feeding the RF antennas in the second column, respectively.

Example 80. The device of any one of Examples 74 to 79, wherein: the first transmit circuitry portion is configured to propagate the reference RF signal to the RF antennas in the first column in a first propagation direction substantially parallel to the second direction, and the second transmit circuitry portion is configured to propagate the reference RF signal to the RF antennas in the second column in a direction opposite to the first propagation direction.

Example 81. The device of any one of Examples 74 to 80, wherein the first RF signals have a center frequency between 300 GHz and 320 GHz.

Example 82. The device of any one of Examples 74 to 81, wherein the transmitter further comprises: a second transmit semiconductor die spaced from the first transmit semiconductor die in the first direction and having integrated thereon: second transmit circuitry, and a second transmit antenna array comprising a second plurality of RF antennas configured to transmit RF signals provided by the second transmit circuitry and having a third aperture with a third length extending in the first direction and a third width extending in the second direction, the third length being larger than the third width, wherein the second plurality of RF antennas is arranged in a two-dimensional grid and has mirror symmetry across the first line extending in the first direction.

Example 83. The device of any one of Examples 74 to 82, wherein the transmitter further comprises: a third transmit semiconductor die spaced from the first transmit semiconductor die in the second direction and having integrated thereon: third transmit circuitry; and a third transmit antenna array comprising a third plurality of RF antennas configured to transmit RF signals provided by the third transmit circuitry and having a fourth aperture with a fourth length extending in the first direction and a fourth width extending in the second direction, the fourth length being larger than the fourth width, wherein the plurality of RF antennas is arranged in a two-dimensional grid and has mirror symmetry across a second line extending in the first direction.

Example 84. The device of any one of Examples 74-83, wherein each of the plurality of RF antennas comprises a respective patch.

Example 85. The device of any one of Examples 74-83, wherein each of the plurality of RF antennas comprises a dipole.

Example 86. The device of any one of Examples 74-85, wherein the first transmit semiconductor die is wire bonded to the substrate such that the plurality of RF antennas face away from the substrate.

Example 87. A device, comprising: a substrate defining a plane extending in first and second directions substantially orthogonal to one another; and a transmitter mounted on the substrate, the transmitter comprising: a first transmit semiconductor die having integrated thereon: a first transmit antenna array comprising a plurality of RF antennas arranged in a two-dimensional grid having: first and second columns of RF antennas each extending in the first direction; and a plurality of rows of RF antennas each extending in the second direction, wherein the plurality of RF antennas is arranged to have mirror symmetry across a line that extends in the first direction and separates the first and second columns; and first transmit circuitry comprising a first transmit circuitry portion configured to feed RF antennas in the first column and a second transmit circuitry portion configured to feed RF antennas in the second column, wherein the first transmit circuitry portion and the second transmit circuitry portion are arranged to have mirror symmetry across the line.

Example 88. The device of Example 87, wherein the first transmit circuitry portion is arranged in the first column and the second transmit circuitry portion is arranged in the second column.

Example 89. The device of Example 87 or 88, further comprising: signal generation circuitry mounted on the substrate and configured to generate a reference RF signal, wherein the first transmit circuitry is configured to generate first RF signals based on the reference RF signal and feed the first RF signals to the first transmit antenna array.

Example 90. The device of Example 89, wherein the first transmit semiconductor die further comprises: a first interface, positioned within a threshold distance of a first outer edge of the first transmit semiconductor die, configured to receive the reference RF signal from the signal generation circuitry and provide the reference RF signal to the first transmit circuitry portion, and a second interface, positioned within the threshold distance of a second outer edge of the first transmit semiconductor die, configured to receive the reference RF signal from the signal generation circuitry and provide the reference RF signal to the second transmit circuitry portion, wherein the first outer edge is opposite the second outer edge.

Example 91. The device of Example 90, wherein: the first interface further comprises power divider circuitry configured to divide the reference RF signal into first reference RF signals and provide the first reference RF signals to the first transmit circuitry portion for feeding RF antennas in the first column, respectively; and the second interface further comprises power divider circuitry configured to divide the reference RF signal into second reference RF signals and provide the second reference RF signals to the second transmit circuitry portions for feeding RF antennas in the second column, respectively.

Example 92. The device of any one of Examples 88-91, wherein: the first transmit circuitry portion is configured to propagate the reference RF signal to the RF antennas in the first column in a first propagation direction; and the second column of the plurality of transmit circuitry portions is configured to propagate the reference RF signal to the RF antennas in the second column in a direction opposite to the first propagation direction.

Example 93. The device of Example 92, wherein the first propagation direction is substantially parallel to the second direction.

Example 94. The device of any one of Examples 88-93, further comprising a receiver mounted on the substrate, the receiver comprising a first receive semiconductor die having integrated thereon: a first receive antenna array comprising a plurality of RF antennas configured to receive second RF signals; and first receive circuitry configured to obtain the second RF signals via the plurality of RF antennas of the first receive antenna array.

Example 95. The device of any one of Examples 88-94, wherein the first RF signals have a center frequency between 300 GHz and 320 GHz.

Example 96. The device of any one Examples 88 to 95, wherein the first RF signals have a bandwidth of at least 6 GHz.

Example 97. The device of any one of Examples 87 to 96, wherein the transmitter further comprises: a second transmit semiconductor die spaced from the first transmit semiconductor die in the first direction and having integrated thereon: a second transmit antenna array comprising a second plurality of RF antennas arranged in a two-dimensional array having: third and fourth columns each extending in the first direction; and a second plurality of rows each extending in the second direction, wherein the second plurality of RF antennas is arranged to have mirror symmetry across the first line that extends in the first direction and separates the third and fourth columns; and second transmit circuitry comprising a third transmit circuitry portion configured to feed RF antennas in the third column and a fourth transmit circuitry portion configured to feed RF antennas in the fourth column, wherein the third transmit circuitry portion and the fourth transmit circuitry portion are arranged to have mirror symmetry across the first line.

Example 98. The device of any one of Examples 87 to 97, wherein the transmitter further comprises: a third transmit semiconductor die spaced from the first transmit semiconductor die in the second direction and having integrated thereon: a third transmit antenna array comprising a third plurality of RF antennas arranged in a two-dimensional array having: fifth and sixth columns each extending in the first direction; and a third plurality of rows each extending in the second direction, wherein the third plurality of RF antennas is arranged to have mirror symmetry across a second line that extends in the first direction and separates the fifth and sixth columns; and third transmit circuitry comprising a fifth transmit circuitry portion configured to feed RF antennas in the fifth column and a sixth transmit circuitry portion configured to feed RF antennas in the sixth column, wherein the fifth transmit circuitry portion and the sixth transmit circuitry portion are arranged to have mirror symmetry across the second line.

Example 99. The device of any one of Examples 87-98, wherein each of the plurality of RF antennas comprises a respective patch.

Example 100. The device of any one of Examples 87-98, wherein each of the plurality of RF antennas comprises a dipole.

Example 101. The device of any one of Examples 87-100, wherein the first transmit semiconductor die is wire bonded to the substrate such that the plurality of RF antennas face away from the substrate.

Example 102. A device, comprising: a substrate; and a receiver mounted on the substrate, the receiver comprising: a first semiconductor die having integrated thereon a first plurality of RF antennas configured to receive first RF signals having a first RF center frequency, the first plurality of RF antennas including a first RF antenna; and a second semiconductor die having integrated thereon a second plurality of RF antennas configured to receive second RF signals having the first RF center frequency, the second plurality of RF antennas including a second RF antenna, wherein the first semiconductor die and the second semiconductor die are arranged in the receiver such that a center-to-center distance between the first RF antenna and the second RF antenna is less than or within 10% of one half of a free-space wavelength at the first RF center frequency.

Example 103. The device of Example 102, wherein the center-to-center distance between the first RF antenna and the second RF antenna is equal to the one half of the free-space wavelength at the first RF center frequency.

Example 104. The device of Example 102 or 103, wherein the first RF center frequency is in a range from 300 GHz to 1.5 THz.

Example 105. The device of Example 102 or 103, wherein the first RF center frequency is in a range of 650 to 690 GHz.

Example 106. The device of Example 102 or 103, wherein the first RF center frequency is in a range of 300 GHz to 320 GHz.

Example 107. The device of Example 102 or 103, wherein the first RF center frequency is in a range of 190 to 300 GHz, 300 to 320 GHz, 390 to 450 GHz, 440 to 480 GHz, 455 to 495 GHz, or 820 to 880 GHz.

Example 108. The device of any one of Examples 102-107, wherein the first antenna is disposed proximate a first outer edge of the first semiconductor die, the second antenna is disposed proximate a second outer edge of the second semiconductor die, and the first outer edge of the first semiconductor die is disposed proximate the second outer edge of the second semiconductor die.

Example 109. The device of Example 108, wherein an outer edge of the first antenna is spaced less than 50 microns from the first outer edge of the first semiconductor die and an outer edge of the second antenna is spaced a distance between 20 and 50 microns from the second outer edge of the second semiconductor die.

Example 110. The device of Example 108, wherein an outer edge of the first antenna is spaced less than 30 microns from the first outer edge of the first semiconductor die and an outer edge of the second antenna is spaced a distance between 20 and 30 microns from the second outer edge of the second semiconductor die.

Example 111. The device of any one of Examples 108-110, wherein the first outer edge of the first semiconductor die is spaced a distance between 25 and 100 microns from the second outer edge of the second semiconductor die.

Example 112. The device of any one of Examples 108-110, wherein the first outer edge of the first semiconductor die is spaced a distance between 25 and 75 microns from the second outer edge of the second semiconductor die

Example 113. The device of any one of Examples 108-110, wherein the first outer edge of the first semiconductor die is spaced a distance between 25 and 50 microns from the second outer edge of the second semiconductor die.

Example 114. The device of any one of Examples 102-113, further comprising an interposer mounted on the substrate, wherein the first and second semiconductor dies are mounted on the interposer.

Example 115. The device of any one of Examples 102-115, wherein: each of the first plurality of RF antennas is spaced center-to-center from adjacent ones of the first plurality of RF antennas by the center-to-center distance; and each of the second plurality of RF antennas is spaced center-to-center from adjacent ones of the second plurality of RF antennas by the center-to-center distance.

Example 116. The device of any one of Examples 102-116, wherein each of the first plurality of RF antennas comprises a patch.

Example 117. The device of any one of Examples 102-116, wherein each of the first plurality of RF antennas comprises a dipole.

Example 118. The device of any one of Examples 102-117, wherein the first semiconductor die comprises a first seal ring surrounding the first plurality of antennas, wherein the second semiconductor die comprises a second seal ring surrounding the second plurality of antennas, and wherein a distance between edges of the first seal ring and the second seal ring is between 50 and 75 microns.

Example 119. A semiconductor die having integrated thereon: a first plurality of RF antennas configured to receive RF signals having a first RF center frequency, the first plurality of RF antennas including a first RF antenna, wherein the first RF antenna is integrated on the semiconductor die such that a center of the first RF antenna is located at a distance from an outer edge of the semiconductor die that is less than one quarter of a free-space wavelength at the first RF center frequency.

Example 120. The semiconductor die of Example 119, wherein the distance from an outer edge of the first RF antenna and an outer edge of the semiconductor die is between 10 and 50 microns.

Example 121. The semiconductor die of Example 119, wherein the distance from an outer edge of the first RF antenna and an outer edge of the semiconductor die is between 10 and 30 microns, between 10 and 20 microns, or between 10 and 15 microns.

Example 122. The semiconductor die of Example 119, wherein the semiconductor die comprises a seal ring surrounding the first plurality of antennas, and wherein the distance from an outer edge of the first RF antenna and the seal ring is between 5 and 25 microns.

Example 123. The semiconductor die of any one of Examples 119-122, wherein the first RF center frequency is in a range of 300 GHz to 1.5 THz.

Example 124. The semiconductor die of any one of Examples 119-122, wherein the first RF center frequency is in a range of 650 to 690 GHz.

Example 125. The semiconductor die of any one of Examples 119-122, wherein the first RF center frequency is in a range of 300 GHz to 320 GHz.

Example 126. The semiconductor die of any one of Examples 119-122, wherein the first RF center frequency is in a range of 190 to 300 GHz, 300 to 320 GHz, 390 to 450 GHz, 440 to 480 GHz, 455 to 495 GHz, or 820 to 880 GHz.

Example 125. The semiconductor die of any one of Examples 119-126, wherein the first plurality of RF antennas are spaced center-to-center from one another by a second distance that is less than one half of a free-space wavelength at the first RF center frequency.

Example 128. A method of manufacturing a plurality of semiconductor dies having RF antenna arrays integrated thereon for use in a transmitter and/or receiver, the method comprising: obtaining a semiconductor wafer comprising a plurality of RF antenna arrays; and dicing the semiconductor wafer into a plurality of semiconductor dies each having integrated thereon a respective one of the plurality of RF antenna arrays such that, on each of the plurality of semiconductor dies, a distance between an outer edge of the semiconductor die and an outer edge of at least one RF antenna of the RF antenna array integrated on the semiconductor die is between 10 and 50 microns.

Example 129. The method of Example 128, wherein the distance is between 10 and 30 microns.

Example 130. The method of Example 128, wherein the distance is between than 10 and 20 microns.

Example 131. The method of Example 128, wherein the distance is between than 10 and 15 microns.

Example 132. The method of any one of Examples 128 to 131, wherein dicing the semiconductor wafer comprises removing at least 40 microns of semiconductor material from the outer edge of each of the plurality of semiconductor dies.

Example 133. The method of Example 132, wherein dicing the semiconductor wafer comprises removing at least 50 microns of semiconductor material from the outer edge of each of the plurality of semiconductor dies.

Example 134. The method of Example 133, wherein dicing the semiconductor wafer comprises removing at least 60 microns of semiconductor material from the outer edge of each of the plurality of semiconductor dies.

Example 135. The method of any one of Examples 128 to 134, wherein dicing the semiconductor wafer comprises sawing within 75 microns of the at least one antenna of each of the plurality of RF antenna arrays.

Example 136. The method of Example 135, wherein dicing the semiconductor wafer comprises sawing within 50 microns of the at least one antenna of each of the plurality of RF antenna arrays.

Example 137. The method of Example 136, wherein dicing the semiconductor wafer comprises sawing within 30 microns of the at least one antenna of each of the plurality of RF antenna arrays.

Example 138. The method of any one of Examples 128 to 137, wherein no copper pillar bond pads are present in a region between the outer edge of the at least one antenna and the outer edge of the semiconductor die.

Example 139. A device, comprising: a substrate; a transmitter mounted on the substrate, the transmitter comprising: a transmit semiconductor die having integrated thereon: a transmit antenna array comprising a first plurality of transmit RF antennas configured to transmit first RF signals; and transmit circuitry configured to feed the plurality of RF antennas in the transmit antenna array; a receiver mounted on the substrate, the receiver comprising: a receive semiconductor die having integrated thereon: a receive antenna array comprising a second plurality of RF antennas configured to receive second RF signals; and receive circuitry configured to process the RF signals received by the plurality of RF antennas to obtain processed RF signals; analog-to-digital conversion (ADC) circuitry mounted on the substrate, the ADC circuitry coupled to the receive circuitry and configured to digitize the processed RF signals to obtain digitized RF signals; and processing circuitry configured to operate at least one of the transmit circuitry, receive circuitry, and the ADC circuitry in: a first operating state in a plurality of time intervals, each of the plurality of time intervals including time when the first plurality of RF antennas are being operated to transmit the first RF signals and/or time when the second plurality of RF antennas are being operated to receive the second RF signals; and a second operating state outside of the plurality of time intervals, wherein the at least one of the transmit circuitry, the receive circuitry, and the ADC circuitry is operated using less power in the second operating state than is used to operate it in the first operating state.

Example 140. The device of Example 139, wherein the processing circuitry is configured to operate the transmit circuitry in the first operating state in the plurality of time intervals and in the second operating state outside of the plurality of time intervals.

Example 141. The device of Example 139 or 140, wherein the processing circuitry is configured to operate the receive circuitry in the first operating state in the plurality of time intervals and in the second operating state outside of the plurality of time intervals.

Example 142. The device of any one of Examples 139-141, wherein the processing circuitry is configured to operate the ADC circuitry in the first operating state in the plurality of time intervals and in the second operating state outside of the plurality of time intervals.

Example 143. The device of any one of Examples 139-142, wherein the processing circuitry operates at least one of the transmit circuitry, receive circuitry, and the ADC circuitry in the second operating state by powering off the at least one of the transmit circuitry, receive circuitry, and the ADC circuitry.

Example 144. The device of any one of Examples 139-142, wherein the ADC circuitry is integrated on the receive semiconductor die.

Example 145. The device of any one of Examples 139-142, wherein the ADC circuitry is mounted on the substrate.

Example 146. The device of any one of Examples 139-145, wherein the ADC circuitry is configured to communicate the digitized RF signals to the processing circuitry using a standardized serial interface.

Example 147. The device of any one of Examples 139-146, wherein the processing circuitry is mounted on the substrate.

Example 148. The device of any one of Examples 139-147, wherein the processing circuitry is configured to operate the at least one of the transmit circuitry, the receive circuitry, and the ADC circuitry in the second operating state between a first time interval of the plurality of time intervals and a second time interval of the plurality of time intervals.

Example 149. The device of any one of Examples 139-148, wherein: the ADC circuitry comprises a plurality of ADC channels including a first number of ADC channels; the receiver comprises a plurality of receive channels including a second number of receive channels that is greater than the first number of ADC channels; and the interface circuitry further comprises a time-division multiplexer configured to interface between the second number of receive channels and the first number of ADC channels.

Example 150. A device, comprising: a substrate; a transmitter mounted on the substrate, the transmitter comprising: a transmit semiconductor die having integrated thereon: transmit circuitry configured to generate, based on a reference RF signal, first RF signals having an RF center frequency between 300 GHz and 3 THz; and a transmit antenna array comprising a first plurality of RF antennas configured to transmit the first RF signals; a receiver mounted on the substrate, the receiver comprising: a receive semiconductor die having integrated thereon: a receive antenna array comprising a second plurality of RF antennas configured to receive second RF signals having the RF center frequency, the second RF signals being generated at least in part by first RF signals being reflected by a target object; and receive circuitry configured to: generate third RF signals based on the reference RF signal; and mix the second RF signals with the third RF signals to obtain fourth RF signals; interface circuitry mounted on the substrate and comprising analog-to-digital conversion (ADC) circuitry, the ADC circuitry coupled to the receive circuitry and configured to digitize the fourth RF signals to obtain digitized RF signals; and processing circuitry configured to identify a material of the target object using one or more of the digitized RF signals, wherein the material is any material having a dielectric constant greater than 1.

Example 151. The device of Example 150, wherein the material is selected from a first group consisting of water, ice, snow, metal, paint, road material, wood, rubber, nylon, plastic, and fabric.

Example 152. The device of Example 150 or 151, wherein the material is road material and wherein the road material comprises concrete.

Example 153. The device of Example 152, wherein the concrete is asphalt concrete or cement concrete.

Example 154. The device of any one of Examples 150 to 153, wherein each of the one or more digitized RF signals has frequency content in a frequency band having a plurality of sub-bands, and the processing circuitry is configured to identify the material of the target object based on spectral content of the digitized RF signal in individual ones of one or more of the plurality of sub-bands.

Example 155. The device of Example 154, wherein the frequency band has a bandwidth of at least 6 GHz.

Example 156. The device of Example 154 or 155, wherein the spectral content for a particular digitized RF signal of the one or more digitized RF signals comprises, for each particular sub-band of one or more of the plurality of sub-bands, a respective magnitude and/or power of the spectrum of the digitized RF signal in the particular sub-band.

Example 157. The device of any one of Examples 154-156, wherein the processing circuitry is configured to identify the material by comparing spectral content of the digitized RF signal in each of one or more of the plurality of sub-bands with spectral content associated with a plurality of materials including the material.

Example 158. The device of any one of Examples 154-156, wherein the processing circuitry is configured to identify the material by processing one or more features derived from the spectral content by using a trained machine learning model trained to identify the material based on the one or more features derived from spectral content of digitized RF signals in each of one or more of the plurality of sub-bands.

Example 159. The device of Example 158, wherein the trained machine learning model is a neural network model, a logistic regression model, a random forest model, a decision tree model, or a gradient boosted decision tree model.

Example 160. The device of any one of Examples 150 to 159, wherein the RF center frequency in a range of 190 to 300 GHz, 300 to 320 GHz, 390 to 450 GHz, 440 to 480 GHz, 455 to 495 GHz, or 820 to 880 GHz.

Example 161. A device, comprising: a substrate; a transmitter mounted on the substrate, the transmitter comprising: transmit circuitry configured to generate first RF signals having an RF center frequency between 300 GHz and 3 THz; and a transmit antenna array comprising a plurality of RF antennas configured to transmit the first RF signals; a receiver mounted on the substrate, the receiver comprising: a receive antenna array configured to receive second RF signals having the RF center frequency, the second RF signals being generated at least in part by first RF signals being reflected by a target object; and receive circuitry configured to process the received second RF signals to obtain processed RF signals; ADC circuitry coupled to the receive circuitry and configured to digitize the processed RF signals to obtain digitized RF signals; and processing circuitry configured to identify a material of the target object using one or more of the digitized RF signals, wherein the material is any material having a dielectric constant greater than 1.

Example 162. A method for use with a device comprising a substrate having a transmitter, a receiver, and analog-to-digital conversion (ADC) circuitry mounted thereon, the transmitter comprising a transmit antenna array, the receiver comprising a receive antenna array and receive circuitry, the method comprising: transmitting, using the transmit antenna array, first RF signals having an RF center frequency between 300 GHz and 3 THz; receiving, using the receive antenna array, second RF signals having the RF center frequency, the second RF signals being generated at least in part by first RF signals being reflected by a target object; processing, using the receive circuitry, the second RF signals to obtain processed RF signals; digitizing, using the ADC circuitry, the processed RF signals output by the receive circuitry to obtain digitized RF signals; and identifying, using processing circuitry, a material of the target object using one or more of the digitized RF signals, wherein the material is any material having a dielectric constant greater than 1.

Example 163. A device, comprising: a substrate; a transmitter mounted on the substrate, the transmitter comprising: a transmit semiconductor die having integrated thereon: transmit circuitry configured to generate, based on a reference RF signal, first RF signals having an RF center frequency between 300 GHz and 3 THz; and a transmit antenna array comprising a first plurality of RF antennas configured to transmit the first RF signals; a receiver mounted on the substrate, the receiver comprising: a receive semiconductor die having integrated thereon: a receive antenna array comprising a second plurality of RF antennas configured to receive second RF signals having the RF center frequency, the second RF signals being generated at least in part by first RF signals being reflected by a target object; and receive circuitry configured to: generate third RF signals based on the reference RF signal; and mix the second RF signals with the third RF signals to obtain fourth RF signals; interface circuitry mounted on the substrate and comprising analog-to-digital conversion (ADC) circuitry, the ADC circuitry coupled to the receive circuitry and configured to digitize the fourth RF signals to obtain digitized RF signals; and processing circuitry configured to detect a material disposed on the target object using one or more of the digitized RF signals.

Example 164. The device of Example 163, wherein the processing circuitry is further configured to identify the material disposed on the target object using the one or more of the digitized RF signals.

Example 165. The device of Example 163 or 164, wherein the target object comprises road material and the material is water, snow, or ice.

Example 166. The device of Example 165, wherein the road material comprises concrete.

Example 167. The device of Example 166, wherein the concrete is asphalt concrete or cement concrete.

Example 168. The device of any one of Examples 163-167, wherein the processing circuitry is configured to detect the material disposed on the target object based on spectral content of the one or more digitized RF signals at a first frequency indicating an excited waveguide mode in a region between a surface of the material and a surface of the target object.

Example 169. The device of Example 168, wherein the excited waveguide mode indicates the material, a material of the target object, and a distance from the surface of the material to the surface of the target object.

Example 170. The device of any one of Examples 163 to 167, wherein the processing circuitry is configured to detect the material disposed on the target object based on spectral content of the one or more digitized RF signals at the first frequency.

Example 171. The device of any one of Examples 168 to 170, wherein spectral content of the one or more digitized RF signals at the first frequency comprises an amplitude, a magnitude, or a power of each of the one or more digitized RF signals at the first frequency.

Example 172. The device of any one of Examples 168-171, wherein the processing circuitry is configured to detect the material disposed on the target object by comparing spectral content of the digitized RF signal at the first frequency with spectral content, at the first frequency, associated with a plurality of materials including the material.

Example 173. The device of any one of Examples 168-171, wherein the processing circuitry is configured to detect the material disposed on the target object by using a trained machine learning model to process one or more features derived from the spectral content at the first frequency to obtain an output indicating the material disposed on the target object, wherein the trained machine learning model was trained to detect the material based on the one or more features derived from spectral content of the one or more digitized RF signals at the first frequency.

Example 174. The device of Example 173, wherein the processing circuitry is configured to detect the material disposed on the target object by using the trained machine learning model to process the one or more features derived from the spectral content at the first frequency and information indicating one or more materials part of the target object to obtain the output indicating the material disposed on the target object

Example 175. The device of Example 173 or 174, wherein the trained machine learning model is a neural network model, a logistic regression model, a random forest model, a decision tree model, or a gradient boosted decision tree model.

Example 176. The device of any one of Examples 163 to 175, wherein the RF center frequency is in a range of 190 to 300 GHz, 300 to 320 GHz, 390 to 450 GHz, 440 to 480 GHz, 455 to 495 GHz, or 820 to 880 GHz.

Example 177. A device, comprising: a substrate; a transmitter mounted on the substrate, the transmitter comprising: transmit circuitry configured to generate first RF signals having an RF center frequency between 300 GHz and 3 THz; and a transmit antenna array comprising a first plurality of RF antennas configured to transmit the first RF signals; a receiver mounted on the substrate, the receiver comprising: a receive antenna array comprising a second plurality of RF antennas configured to receive second RF signals having the RF center frequency, the second RF signals being generated at least in part by first RF signals being reflected by a target object; and receive circuitry configured to process the received second RF signals to obtain processed RF signals; ADC circuitry coupled to the receive circuitry and configured to digitize the processed RF signals to obtain digitized RF signals; and processing circuitry configured to detect a material disposed on the target object using one or more of the digitized RF signals.

Example 178. A method for use with a device comprising a substrate having a transmitter, a receiver, and analog-to-digital conversion (ADC) circuitry mounted thereon, the transmitter comprising a transmit antenna array, the receiver comprising a receive antenna array and receive circuitry, the method comprising: transmitting, using the transmit antenna array, first RF signals having an RF center frequency between 300 GHz and 3 THz; receiving, using the receive antenna array, second RF signals having the RF center frequency, the second RF signals being generated at least in part by first RF signals being reflected by a target object; processing, using the receive circuitry, the second RF signals to obtain processed RF signals; digitizing, using the ADC circuitry, the processed RF signals output by the receive circuitry to obtain digitized RF signals; and detecting, using processing circuitry, a material disposed on the target object using one or more of the digitized RF signals.

Example 179. A device, comprising: a substrate; a transmitter mounted on the substrate, the transmitter comprising: a transmit semiconductor die having integrated thereon: transmit circuitry configured to generate, based on a reference RF signal, first RF signals having an RF center frequency between 300 GHz and 3 THz; and a transmit antenna array comprising a first plurality of RF antennas configured to transmit the first RF signals; a receiver mounted on the substrate, the receiver comprising: a receive semiconductor die having integrated thereon: a receive antenna array comprising a second plurality of RF antennas configured to receive second RF signals generated as a result of the first RF signals being reflected by a target object; and receive circuitry configured to: generate third RF signals based on the reference RF signal; and mix the second RF signals with the third RF signals to obtain fourth RF signals; interface circuitry mounted on the substrate and comprising analog-to-digital conversion (ADC) circuitry, the ADC circuitry coupled to the receive circuitry and configured to digitize the fourth RF signals to obtain digitized RF signals; and processing circuitry configured to: determine a first velocity of at least a part of the target object using one or more of the digitized RF signals; and predict movement of the target object using the first velocity.

Example 180. The device of Example 179, wherein the processing circuitry is configured to: predict, using the first velocity, whether the movement of the target object is into a projected path of the device.

Example 181. The device of Example 179, wherein the processing circuitry is configured to: predict, using the first velocity, whether the movement of the target object is out of a projected path of the device.

Example 182. The device of Example 179, wherein the processing circuitry is configured to: predict, using the first velocity, whether the movement of the target object is parallel to a projected path of the device.

Example 183. The device of Example 179, wherein the processing circuitry is configured to: determine, using the one or more of the digitized RF signals, a plurality of velocities of the target object, the plurality of velocities including the first velocity of a first portion of the target object and a second velocity of a second portion of the target object; and predict the movement of the target object using on the first and second velocities.

Example 184. The device of Example 183, wherein the processing circuitry is further configured to predict the movement of the target object into the projected path of the device based on a difference between the first and second velocities.

Example 185. The device of Example 183, wherein: the target object is a person, the plurality of velocities include velocities of different parts of the person's body, and the processing circuitry is configured to: determine a gesture being made by the person using the plurality of velocities, and predict movement of the person using the gesture.

Example 186. The device of any one of Examples 179 to 185, wherein the processing circuitry is further configured to: determine a distance between the target object and the device using one or more of the digitized RF signals; and predict the movement of the target object using the distance.

Example 187. The device of any one of Examples 179 to 186, wherein the processing circuitry is further configured to determine a material of the target object using the one or more digitized RF signals.

Example 188. The device of Example 187, wherein the processing circuitry is further configured to determine, based on the material of the target object, whether the target object is a person or a vehicle.

Example 189. The device of any one of Examples 179 to 188, wherein the processing circuitry is further configured to: determine a weight distribution of the target object using the one or more digitized RF signals; and predict the movement of the target object into the projected path of the device based on the weight distribution of the target object.

Example 190. The device of any one of Examples 179 to 189, wherein the target object is a person.

Example 191. The device of any one of Examples 179 to 189, wherein the target object is a vehicle.

Example 192. The device of any one of Examples 179 to 191, wherein the RF center frequency is in a range of 190 to 300 GHz, 300 to 320 GHz, 390 to 450 GHz, 440 to 480 GHz, 455 to 495 GHz, or 820 to 880 GHz.

Example 193. A device, comprising: a substrate; a transmitter mounted on the substrate, the transmitter comprising: transmit circuitry configured to generate first RF signals having an RF center frequency between 300 GHz and 3 THz; and a transmit antenna array comprising a first plurality of RF antennas configured to transmit the first RF signals; a receiver mounted on the substrate, the receiver comprising: a receive antenna array comprising a second plurality of RF antennas configured to receive second RF signals generated as a result of the first RF signals being reflected by a target object; and receive circuitry configured to process the received second RF signals to obtain processed RF signals; ADC circuitry coupled to the receive circuitry and configured to digitize the processed RF signals to obtain digitized RF signals; and processing circuitry configured to: determine a first velocity of at least a part of the target object using one or more of the digitized RF signals; and predict movement of the target object using the first velocity.

Example 194. A method for use with a device comprising a substrate having a transmitter, a receiver, and analog-to-digital conversion (ADC) circuitry mounted thereon, the transmitter comprising a transmit antenna array, the receiver comprising a receive antenna array and receive circuitry, the method comprising: transmitting, using the transmit antenna array, first RF signals having an RF center frequency between 300 GHz and 3 THz; receiving, using the receive antenna array, second RF signals having the RF center frequency, the second RF signals being generated at least in part by first RF signals being reflected by a target object; processing, using the receive circuitry, the second RF signals to obtain processed RF signals; digitizing, using the ADC circuitry, the processed RF signals output by the receive circuitry to obtain digitized RF signals; and determining, using the processing circuitry, a first velocity of at least a part of the target object using one or more of the digitized RF signals; predicting, using the processing circuitry, movement of the target object using the first velocity.

Example 195. A device, comprising: a substrate; a transmitter mounted on the substrate, the transmitter comprising: a transmit semiconductor die having integrated thereon: transmit circuitry configured to generate, based on a reference RF signal, first RF signals having an RF center frequency between 300 GHz and 3 THz; and a transmit antenna array comprising a plurality of RF antennas configured to transmit the first RF signals; a receiver mounted on the substrate, the receiver comprising: receive semiconductor die having integrated thereon: a receive antenna array configured to receive second RF signals generated as a result of the first RF signals being reflected by one or more target objects in a scene; and receive circuitry configured to: generate third RF signals based on the reference RF signal; and mix the second RF signals with the third RF signals to obtain fourth RF signals; interface circuitry mounted on the substrate and comprising analog-to-digital conversion (ADC) circuitry, the ADC circuitry coupled to the receive circuitry and configured to digitize the fourth RF signals to obtain digitized RF signals; and processing circuitry configured to perform: obtaining sensor data about the scene from a sensor separate from the device; and associating the sensor data obtained from the sensor with data derived from one or more of the digitized RF signals.

Example 196. The device of Example 195, wherein the sensor is a camera and the sensor data is an image of the scene obtained by the camera.

Example 197. The device of Example 196, wherein the associating comprises: for a set of one or more pixels in the image obtained by the camera, using the data derived from the one or more digitized RF signals to determine a distance between the device and an item or a part of an item captured by the set of one or more pixels; and associating the distance with each pixel in the set of one or more pixels.

Example 198. The device of Example 196, wherein the associating comprises: for each pixel in the image obtained by the camera, using the data derived from the one or more digitized RF signals to determine a respective distance between the device and an item or a part of an item captured by the pixel; and associating the respective distance with the pixel.

Example 199. The device of Example 197 or 198, wherein the processing circuitry is further configured to perform: updating one or more distances, initially determined by using the one or more digitized RF signals, between the device and one or more items or portions thereof captured by one or more pixels in the camera image by using results of the associating to obtain one or more updated distances.

Example 200. The device of Example 196, wherein the associating comprises: forming a range cross-range image using the one or more of the digitized RF signals; and associating each of one or more points in the range cross-range image with a respective set of one or more pixels in the image obtained by the camera.

Example 201. The device of any one of Examples 195-200, wherein the processing circuitry is further configured to perform: detecting, in the image obtained by the camera, a road boundary or a lane boundary using the data derived from one or more of the digitized RF signals and results of the associating.

Example 202. The device of any one of Examples 195 to 201, wherein the one or more target objects in the scene include one or more people and/or one or more vehicles.

Example 203. The device of any one of Examples 195 to 202, wherein the RF center frequency is in a range of 190 to 300 GHz, 300 to 320 GHz, 390 to 450 GHz, 440 to 480 GHz, 455 to 495 GHz, or 820 to 880 GHz.

Example 204. The device of Example 195, wherein the sensor comprises an ultrasound sensor.

Example 205. The device of Example 195, wherein the sensor comprises a LIDAR sensor.

Example 206. A device, comprising: a substrate; a transmitter mounted on the substrate, the transmitter comprising: transmit circuitry configured to generate first RF signals having an RF center frequency between 300 GHz and 3 THz; and a transmit antenna array comprising a plurality of RF antennas configured to transmit the first RF signals; a receiver mounted on the substrate, the receiver comprising: a receive antenna array configured to receive second RF signals generated as a result of the first RF signals being reflected by one or more target objects in a scene; and receive circuitry configured to process the received second RF signals to obtain processed RF signals; ADC circuitry coupled to the receive circuitry and configured to digitize the processed RF signals to obtain digitized RF signals; and processing circuitry configured to perform: obtaining sensor data about the scene from a sensor separate from the device; and associating the sensor data obtained from the sensor with data derived from one or more of the digitized RF signals.

Example 207. A method for use with a device comprising a substrate having a transmitter, a receiver, and analog-to-digital conversion (ADC) circuitry mounted thereon, the transmitter comprising a transmit antenna array, the receiver comprising a receive antenna array and receive circuitry, the method comprising: transmitting, using the transmit antenna array, first RF signals having an RF center frequency between 300 GHz and 3 THz; receiving, using the receive antenna array, second RF signals having the RF center frequency, the second RF signals being generated at least in part by first RF signals being reflected by a target object; processing, using the receive circuitry, the second RF signals to obtain processed RF signals; digitizing, using the ADC circuitry, the processed RF signals output by the receive circuitry; obtaining, using the processing circuitry, sensor data about the scene from a sensor separate from the device; and associating, using the processing circuitry, the sensor data obtained from the sensor with data derived from one or more of the digitized RF signals.

Example 208. A device, comprising: a substrate; signal generation circuitry mounted on the substrate and configured to generate a reference RF signal, the reference RF signal being a linear frequency modulated (LFM) chirp signal; a transmitter mounted on the substrate, the transmitter comprising: a first transmit semiconductor die coupled to the signal generation circuitry and having integrated thereon: first transmit circuitry configured to generate, based on the reference RF signal, first RF signals having an RF center frequency between 300-320 GHz, and a first transmit antenna array comprising a first plurality of RF antennas configured to transmit the first RF signals; and a receiver mounted on the substrate, the receiver comprising: a first receive semiconductor die coupled to the signal generation circuitry and having integrated thereon: a first receive antenna array comprising a second plurality of RF antennas configured to receive second RF signals having the RF center frequency, the second RF signals being generated at least in part by first RF signals being reflected by a target object; and first receive circuitry configured to process the second RF signals, using the reference RF signal, to output processed RF signals; analog-to-digital conversion (ADC) circuitry configured to digitize the processed RF signals to obtain digitized RF signals; and processing circuitry coupled to the ADC circuitry and configured to generate a range cross-range image of the target object using the digitized RF signals.

Example 209. The device of Example 208, wherein a duration of the reference RF signal is between 500 ms and 1.5 seconds.

Example 210. The device of Example 208 or 209, wherein the duration of the reference RF signal is between 750 ms and 1.25 seconds.

Example 211. The device of any one of Examples 208-210, wherein the duration of the reference RF signal is 1 ms.

Example 212. The device of any one of Examples 208-211, wherein the processing circuitry is configured to generate the range cross-range image only from the digitized RF signals.

Example 213. A method of imaging a target object using a device comprising a substrate having a transmitter, a receiver, and analog-to-digital conversion (ADC) circuitry, mounted thereon, the transmitter comprising a transmit antenna array, the receiver comprising a receive antenna array and receive circuitry, the method comprising: A) transmitting, using the transmit antenna array, first RF signals having an RF center frequency between 300 GHz and 320 GHz, wherein each of the first RF signals is a linear frequency modulated (LFM) chirp signal; B) receiving, using the receive antenna array, second RF signals having the RF center frequency, the second RF signals being generated at least in part by first RF signals being reflected by the target object; C) processing, using the receive circuitry, the second RF signals to obtain processed RF signals; D) digitizing, using the ADC circuitry, the processed RF signals output by the receive circuitry to obtain digitized RF signals; and E) generating, using processing circuitry coupled to the ADC circuitry and digitized RF signals, a range cross-range image of the target object.

Example 214. The method of Example 213, the method further comprising: prior to the transmitting, generating a reference RF signal using signal generation circuitry mounted on the substrate, wherein the reference RF signal is an LFM chirp signal; and generating the first RF signals from the reference signal using transmit circuitry part of the transmitter.

Example 215. The method of Example 214, wherein processing, using the receive circuitry, the second RF signals to obtain processed RF signals comprises: generating, using receive circuitry part of the receiver and the reference RF signal, third RF signals; and mixing the third RF signals with the second RF signals using a mixer part of the receive circuitry to obtain the processed RF signals.

Example 216. The method of Example 214 or 215, wherein a duration of the reference RF signal is between 500 ms and 1.5 seconds.

Example 217. The method of any one of Examples 214-216, wherein the duration of the reference RF signal is between 750 ms and 1.25 seconds.

Example 218. The method of any one of Examples 214-217, wherein the duration of the reference RF signal is 1 ms.

Example 219. The method of any one of Examples 213-218, wherein generating the range cross-range image of the target object is performed only from the digitized RF signals.

Example 220. The method of any one of Examples 213-219, further comprising performing repeatedly the set of acts (A), (B), (C), (D), (E) at a frame rate to obtain a series of range cross-range images generated at the frame rate.

Example 221. The method of Example 220, wherein the frame rate is between 10 and 50 Hz.

Example 222. The method of Example 221, wherein the frame rate is between 15 and 25 Hz.

Example 223. The method of Example 222, wherein the frame rate is 20 Hz.

Example 224. A device, comprising: a substrate; and a receiver mounted on the substrate, the receiver comprising: a first receive semiconductor die having integrated thereon: a first receive antenna array comprising a plurality of RF antennas, each of the plurality of RF antennas comprising: a first patch; and a second patch serially coupled to the first patch and having a different geometry from the first patch; and first receive circuitry coupled to the plurality of RF antennas.

Example 225. The device of Example 224, wherein, for each particular one of the plurality of RF antennas, the first receive circuitry is coupled to one of the first patch and the second patch of the particular one of the plurality of RF antennas.

Example 226. The device of Example 224 or Example 225, wherein the first patch comprises a differential feed and the second patch comprises a single-ended feed.

Example 227. The device of Example 226, wherein the differential feed of the first patch is configured to obtain an RF signal from the first receive circuitry and the single-ended feed of the second patch is configured to obtain the RF signal via the first patch.

Example 228. The device of any one of Examples 224 to 227, wherein each of the plurality of RF antennas further comprises a third patch serially coupled to the second patch.

Example 229. The device of Example 228, wherein the third patch has a same geometry as the second patch.

Example 230. The device of any one of Examples 224 to 229, wherein the plurality of RF antennas are configured to receive RF signals having a center frequency between 300 GHz and 320 GHz.

Example 231. The device of any one of Examples 224 to 230, wherein the plurality of RF antennas are configured to receive RF signals having a center frequency in a range of 190 to 300 GHz, 300 to 320 GHz, 390 to 450 GHz, 440 to 480 GHz, 455 to 495 GHz, or 820 to 880 GHz.

Example 232. A device, comprising: a substrate; and a receiver mounted on the substrate, the receiver comprising: a first receive semiconductor die having integrated thereon: a first receive antenna array comprising a plurality of RF antennas, each of the plurality of RF antennas comprising two or more patches serially coupled to one another; and first receive circuitry coupled to the plurality of RF antennas, wherein, for each particular one of the plurality of RF antennas, the first receive circuitry is coupled to one of the two or more patches of the particular RF antenna.

Example 233. The device of Example 232, wherein the plurality of RF antennas comprises a first RF antenna, wherein the first RF antenna comprises a first patch and a second patch coupled to the first patch, and wherein the first receive circuitry is coupled to a port of the first patch.

Example 234. The device of Example 233, wherein the first patch is spaced from the first receive circuitry in a first direction and the second patch is spaced from the first patch in the first direction.

Example 235. The device of Example 233 or 234, wherein the first RF antenna further comprises a first plurality of vias disposed around the first patch and a second plurality of vias disposed around the second patch.

Example 236. The device of any one of Examples 232-235, wherein, for each particular one of the plurality of RF antennas, the first receive circuitry is coupled to only one of the two or more patches of the particular RF antenna.

Example 237. The device of any one of Examples 232 to 236, wherein the plurality of RF antennas are configured to receive RF signals having a center frequency between 300 GHz and 320 GHz.

Example 238. The device of any one of Examples 232 to 236, wherein the plurality of RF antennas are configured to receive RF signals having a center frequency between 650 GHz and 690 GHz.

Example 239. The device of any one of Examples 232 to 236, wherein the plurality of RF antennas are configured to receive RF signals having a center frequency in a range of 190 to 300 GHz, 300 to 320 GHz, 390 to 450 GHz, 440 to 480 GHz, 455 to 495 GHz, or 820 to 880 GHz.

Example 240. A device, comprising: a substrate defining a plane extending in first and second directions substantially orthogonal to one another; signal generation circuitry mounted on the substrate and configured to generate a reference RF signal; a transmitter mounted on the substrate, the transmitter comprising: a first transmit semiconductor die coupled to the signal generation circuitry and having integrated thereon: first transmit circuitry configured to generate, based on the reference RF signal, first RF signals having an RF center frequency in a particular frequency range within a range of 150 GHz to 1.5 THz; and a first transmit antenna array comprising a first plurality of RF antennas configured to transmit the first RF signals; a receiver mounted on the substrate, the receiver comprising: a first receive semiconductor die coupled to the signal generation circuitry and having integrated thereon: a first receive antenna array comprising a second plurality of RF antennas configured to receive second RF signals having the RF center frequency, each of the second plurality of RF antennas comprising: a first patch; and a second patch serially coupled to the first patch and having a different geometry from the first patch; and first receive circuitry configured to: generate third RF signals based on the reference RF signal; and mix the second RF signals with the third RF signals to obtain fourth RF signals; and interface circuitry mounted on the substrate and coupled to the first receive circuitry, the interface circuitry comprising analog-to-digital conversion (ADC) circuitry configured to digitize the fourth RF signals.

Example 241. The device of Example 240, wherein the particular frequency range is 190 to 300 GHz, 300 to 320 GHz, 390 to 450 GHz, 440 to 480 GHz, 455 to 495 GHz, or 820 to 880 GHz.

Example 242. The device of Example 240 or 241, wherein the particular frequency range is 300 to 320 GHz.

Example 243. The device of any one of Examples 240 to 242, further comprising: processing circuitry mounted on the substrate and configured to determine a distance between the device and a target object that reflected the first RF signals to generate, at least in part, the second RF signals based on the fourth RF signals.

Example 244. A device, comprising: a substrate; a receiver mounted on the substrate, the receiver comprising: a receive antenna array comprising a first plurality of receive RF antennas, the first plurality of receive RF antennas comprising: a first receive RF antenna configured to receive a first receive RF signal; and a second receive RF antenna configured to receive a second receive RF signal; and receive circuitry comprising a first plurality of receive channels, the first plurality of receive channels comprising: a first receive channel coupled to the first receive RF antenna and configured to process the first receive RF signal to obtain a first processed RF signal; and a second receive channel coupled to the second receive RF antenna and configured to process the second receive RF signal to obtain a second processed RF signal; and interface circuitry mounted on the substrate, the interface circuitry comprising: time-division multiplexing circuitry coupled to the receive circuitry, the time-division multiplexing circuitry comprising a first time-division multiplexer coupled to the first receive channel and to the second receive channel and configured to combine the first processed RF signal and the second processed RF signal into a first single time-division multiplexed signal; and analog-to-digital conversion (ADC) circuitry comprising a first ADC circuit coupled to the first time-division multiplexer and configured to digitize the first single time-division multiplexed signal into a first single digitized time-division multiplexed signal.

Example 245. The device of Example 244, wherein: the receive antenna array further comprises a second plurality of receive RF antennas, the second plurality of receive RF antennas comprising: a third receive RF antenna configured to receive a third receive RF signal; and a fourth receive RF antenna configured to receive a fourth receive RF signal; the receive circuitry further comprises a second plurality of receive channels, the second plurality of receive channels comprising: a third receive channel coupled to the third receive RF antenna and configured to process the third receive RF signal to obtain a third processed RF signal; and a fourth receive channel coupled to the fourth receive RF antenna and configured to process the fourth receive RF signal to obtain a fourth processed RF signal; the time-division multiplexing circuitry further comprises a second time-division multiplexer coupled to the third receive channel and to the fourth receive channel and configured to combine the third processed RF signal and the fourth processed RF signal into a second single time-division multiplexed signal; and the ADC circuitry further comprises a second ADC circuit coupled to the second time-division multiplexer and configured to digitize the second single time-division multiplexed signal into a second single digitized time-division multiplexed signal.

Example 246. The device of Example 245, wherein the receiver comprises a first receive semiconductor die having integrated thereon: the first plurality of receive RF antennas; the second plurality of receive RF antennas; the first plurality of receive channels; and the second plurality of receive channels.

Example 247. The device of Example 245 or 246, wherein the interface circuitry further comprises: a digital serializer configured to combine the first single digitized time-division multiplexed signal and the second single digitized time-division multiplexed signal into a single digital serial signal; and a serial interface driver configured to transmit the single digital serial signal from the interface circuitry via the substrate.

Example 248. The device of Example 245, wherein the receiver comprises: a first receive semiconductor die having integrated thereon: the first plurality of receive RF antennas; and the first plurality of receive channels; and a second receive semiconductor die having integrated thereon: the second plurality of receive RF antennas; and the second plurality of receive channels.

Example 249. The device of Example 248, wherein the interface circuitry comprises: a first interface integrated circuit having integrated therein: the first time-division multiplexer; and the first ADC circuit; and a second interface integrated circuit having integrated therein: the second time-division multiplexer; and the second ADC circuit.

Example 250. The device of any one of Examples 244 to 249, further comprising processing circuitry mounted on the substrate, communicatively coupled to the interface circuitry, and configured to determine a distance between the device and a target object that generated the first receive RF signal and the second receive RF signal based on the first single digitized time-division multiplexed signal.

Example 251. The device of Example 250, wherein: the first receive channel comprises a first mixer configured to mix the first receive RF signal with a reference signal to obtain the first processed RF signal, the first processed RF signal having a first center frequency; the second receive channel comprises a second mixer configured to mix the second receive RF signal with the reference signal to obtain the second processed RF signal, the second processed RF signal having a second center frequency; and the first center frequency and the second center frequency are indicative of the distance between the device and the target object.

Example 252. The device of Example 250 or 251, further comprising a transmitter mounted on the substrate, the transmitter comprising: a transmit antenna array comprising a plurality of transmit RF antennas configured to transmit first RF signals; and transmit circuitry configured to drive the plurality of transmit RF antennas to transmit the first RF signals, wherein the first receive RF signal and the second receive RF signal are generated, at least in part, by reflection of the first RF signals by the target object.

Example 253. The device of any one of Examples 244 to 252, wherein the interface circuitry further comprises amplification circuitry comprising: a first amplifier coupled between the first receive channel and the first time-division multiplexer; and a second amplifier coupled between the second receive channel and the first time-division multiplexer.

Example 254. The device of any one of Examples 244 to 253, wherein the first receive RF signal and the second receive RF signal have an RF center frequency between 150 GHz and 1.5 THz.

Example 255. The device of any one of Examples 244 to 254, wherein the first receive RF signal and the second receive RF signal have an RF center frequency between 300 GHz and 320 GHz.

Example 256. The device of any one of Examples 244 to 255, wherein the first receive RF signal and the second receive RF signal have a bandwidth of at least 3 GHz or at least 6 GHz.

Example 257. A method for use with a device comprising a substrate having a receiver and interface circuitry mounted thereon, the receiver comprising a receive antenna array comprising a first plurality of receive antennas comprising a first receive RF antenna and a second receive RF antenna, the receiver further comprising receive circuitry comprising a first plurality of receive channels comprising a first receive channel coupled to the first receive RF antenna and a second receive channel coupled to the second receive RF antenna, the interface circuitry comprising time-division multiplexing circuitry coupled to the receive circuitry and comprising a first time-division multiplexer coupled to the first receive channel and the second receive channel, and the interface circuitry further comprising analog-to-digital conversion (ADC) circuitry comprising a first ADC circuit coupled to the first time-division multiplexer, the method comprising: receiving, using the first receive RF antenna, a first receive RF signal; receiving, using the second receive RF antenna, a second receive RF signal; processing, using the first receive channel, the first receive RF signal to obtain a first processed RF signal; processing, using the second receive channel, the second receive RF signal to obtain a second processed RF signal; combining, using the first time-division multiplexer, the first processed RF signal and the second processed RF signal into a first single time-division multiplexed signal; and digitizing, using the first ADC circuit, the first single time-division multiplexed signal into a first single digitized time-division multiplexed signal.

Example 258. The method of Example 257, wherein: the receive antenna array further comprises a second plurality of receive RF antennas comprising a third receive RF antenna and a fourth receive RF antenna; the receive circuitry further comprises a second plurality of receive channels comprising a third receive channel coupled to the third receive RF antenna and a fourth receive channel coupled to the fourth receive RF antenna; the time-division multiplexing circuitry further comprises a second time-division multiplexer coupled to the third receive channel and to the fourth receive channel; the ADC circuitry further comprises a second ADC circuit coupled to the second time-division multiplexer; and the method further comprises: receiving, using the third receive RF antenna, a third receive RF signal; receiving, using the fourth receive RF antenna, a fourth receive RF signal; processing, using the third receive channel, the third receive RF signal to obtain a third processed RF signal; processing, using the fourth receive channel, the fourth receive RF signal to obtain a fourth processed RF signal; combining, using the second time-division multiplexer, the third processed RF signal and the fourth processed RF signal into a second single time-division multiplexed signal; and digitizing, using the second ADC circuit, the second single time-division multiplexed signal into a second single digitized time-division multiplexed signal.

Example 259. The method of Example 258, wherein: the interface circuitry further comprises a digital serializer and a serial interface driver; and the method further comprises: combining, using the digital serializer, the first single digitized time-division multiplexed signal and the second single digitized time-division multiplexed signal into a single digital serial signal; and transmitting, using the serial interface driver, the single digital serial signal from the interface circuitry via the substrate.

Example 260. The method of any one of Examples 257 to 259, wherein: the device further comprises processing circuitry mounted on the substrate; and the method further comprises determining, using the processing circuitry, a distance between the device and a target object that generated the first receive RF signal and the second receive RF signal based on the first single digitized time-division multiplexed signal.

Example 261. A device, comprising: a substrate; a receiver mounted on the substrate, the receiver comprising: a first receive semiconductor die having integrated thereon: a first receive antenna array comprising a first plurality of receive RF antennas configured to receive first receive RF signals; and first receive circuitry comprising a first plurality of receive channels coupled to the first plurality of receive RF antennas and configured to process the first receive RF signals to obtain first processed RF signals; and interface circuitry mounted on the substrate, the interface circuitry comprising: first time-division multiplexing circuitry coupled to the first receive circuitry, the first time-division multiplexing circuitry comprising a first plurality of time-division multiplexers configured to combine the first processed RF signals into first time-division multiplexed signals; and first analog-to-digital conversion (ADC) circuitry coupled to the first time-division multiplexing circuitry and comprising a first plurality of ADC circuits configured to digitize the first time-division multiplexed signals into first digitized time-division multiplexed signals.

Example 262. The device of Example 261, further comprising: processing circuitry mounted on the substrate, wherein: the receiver further comprises a second receive semiconductor die having integrated thereon: a second receive antenna array comprising a second plurality of receive RF antennas configured to receive second receive RF signals; and second receive circuitry comprising a second plurality of receive channels coupled to the second plurality of receive RF antennas and configured to process the second receive RF signals to obtain second processed RF signals; the interface circuitry further comprises: second time-division multiplexing circuitry coupled to the second receive circuitry, the second time-division multiplexing circuitry comprising a second plurality of time-division multiplexers configured to combine the second processed RF signals into second time-division multiplexed signals; and second analog-to-digital conversion (ADC) circuitry coupled to the second time-division multiplexing circuitry and comprising a second plurality of ADC circuits configured to digitize the second time-division multiplexed signals into second digitized time-division multiplexed signals; and the processing circuitry is configured to combine the first digitized time-division multiplexed signals with the second digitized time-division multiplexed signals.

Example 263. The device of Example 261 or 262, wherein: the first plurality of receive RF antennas comprises 36 receive RF antennas; the first plurality of receive channels comprises 36 receive channels coupled to the 36 receive RF antennas; the first plurality of time-division multiplexers comprises 16 time-division multiplexers coupled to the 36 receive channels; and the first plurality of ADC circuits comprises 16 ADC circuits coupled to the 16 time-division multiplexers.

Example 264. A device, comprising: a substrate; a receiver mounted on the substrate, the receiver comprising: a receive antenna array comprising: a first plurality of receive RF antennas, the first plurality of receive RF antennas configured to receive first receive RF signals; and a second plurality of receive RF antennas, the second plurality of receive RF antennas configured to receive second receive RF signals; and receive circuitry comprising: a first plurality of receive channels coupled to the first plurality of receive RF antennas and configured to process the first receive RF signals to obtain first processed RF signals; and a second plurality of receive channels coupled to the second plurality of receive RF antennas and configured to process the second receive RF signals to obtain second processed RF signals; interface circuitry mounted on the substrate, the interface circuitry comprising: first serial communication circuitry configured to serialize the first processed RF signals to obtain and transmit a first serialized processed RF signal; and second serial communication circuitry configured to serialize the second processed RF signals to obtain and transmit a second serialized processed RF signal; and processing circuitry mounted on the substrate, communicatively coupled to the interface circuitry, and configured to synchronize serialization of the first processed RF signals by the first serial communication circuitry with serialization of the second processed RF signals by the second serial communication circuitry.

Example 265. The device of Example 264, wherein the processing circuitry is configured to synchronize serialization of the first processed RF signals with serialization of the second processed RF signals at least in part by providing a trigger signal to the first serial communication circuitry and to the second serial communication circuitry.

Example 266. The device of Example 265, wherein: the first serial communication circuitry comprises: a first serial interface controller; and a first framer configured to provide a first frame of the first processed RF signals to the first serial interface controller in response to the trigger signal; the second serial communication circuitry comprises: a second serial interface controller; and a second framer configured to provide a second frame of the second processed RF signals to the second serial communication circuitry in response to the trigger signal; the first serialized processed RF signal comprises the first frame of the first processed RF signals; the second serialized processed RF signal comprises the second frame of the second processed RF signals; and the processing circuitry is configured to combine the first frame of the first serialized processed RF signal with the second frame of the second serialized processed RF signal.

Example 267. The device of any one of Examples 264 to 266, wherein the processing circuitry is configured to synchronize serialization of the first processed RF signals with serialization of the second processed RF signals at least in part by providing a clock signal to the first serial communication circuitry and to the second serial communication circuitry.

Example 268. The device of Example 267, further comprising: a first clock tree coupled between the processing circuitry, the first serial communication circuitry, and the second serial communication circuitry, wherein the processing circuitry is configured to provide the clock signal to the first serial communication circuitry and to the second serial communication circuitry via the first clock tree.

Example 269. The device of any one of Examples 264 to 268, wherein: the interface circuitry further comprises: first analog-to-digital conversion (ADC) circuitry coupled to the first plurality of receive channels and configured to digitize the first processed RF signals to obtain first digitized processed RF signals; and second ADC circuitry coupled to the second plurality of receive channels and configured to digitize the second processed RF signals to obtain second digitized processed RF signals; the first serial communication circuitry comprises first digital serial communication circuitry configured to serialize the first processed RF signals at least in part by serializing the first digitized processed RF signals; and the second serial communication circuitry comprises second digital serial communication circuitry configured to serialize the second processed RF signals at least in part by serializing the second digitized processed RF signals.

Example 270. The device of Example 269, wherein the interface circuitry comprises: a first interface integrated circuit having integrated therein the first digital serial communication circuitry and the first ADC circuitry; and a second interface integrated circuit having integrated therein the second digital serial communication circuitry and the second ADC circuitry.

Example 271. The device of Example 270, wherein the processing circuitry is further configured to synchronize digitization by the first ADC circuitry and the second ADC circuitry.

Example 272. The device of any one of Examples 264 to 271, wherein the interface circuitry further comprises: first amplification circuitry coupled between the first plurality of receive channels and the first serial communication circuitry; and second amplification circuitry coupled between the second plurality of receive channels and the second serial communication circuitry.

Example 273. The device of Example 272, wherein: the interface circuitry further comprises a first test signal interface configured to receive a test signal and input the test signal to the first amplification circuitry; the interface circuitry further comprises a second test signal interface configured to receive the test signal and input the test signal to the second amplification circuitry; and the processing circuitry is configured to provide the test signal to the first test signal interface and to the second test signal interface.

Example 274. The device of Example 273, wherein: the first amplification circuitry is configured to provide a first amplification output signal in response to receiving the test signal; and the first test signal interface is further configured to receive a first amplification output control signal from the processing circuitry and, in response to the first amplification output control signal, provide the first amplification output signal from the first amplification circuitry to the processing circuitry.

Example 275. The device of any one of Examples 264 to 274, wherein the receiver comprises: a first receive semiconductor die having integrated thereon the first plurality of receive RF antennas and the first plurality of receive channels; and a second receive semiconductor die having integrated thereon the second plurality of receive RF antennas and the second plurality of receive channels.

Example 276. The device of any one of Examples 264 to 275, wherein the processing circuitry is configured to receive the first serialized processed RF signal from the first serial communication circuitry and to receive the second serialized processed RF signal from the second serial communication circuitry.

Example 277. The device of any one of Example 276, wherein: the first serial communication circuitry is configured to transmit the first serialized processed RF signal to the processing circuitry using a standardized serial interface protocol; and the second serial communication circuitry is configured to transmit the second serialized processed RF signal to the processing circuitry using the standardized serial interface protocol.

Example 278. The device of any one of Examples 264 to 277, wherein the processing circuitry is configured to determine a distance between the device and a target object that generated the first receive RF signals and the second receive RF signals based on the first serialized processed RF signal and the second serialized processed RF signal.

Example 279. The device of Example 278, further comprising a transmitter mounted on the substrate, the transmitter comprising: a transmit antenna array comprising a plurality of transmit RF antennas configured to transmit first RF signals; and transmit circuitry configured to drive the plurality of transmit RF antennas to transmit the first RF signals, wherein the first receive RF signals and the second receive RF signals are generated, at least in part, by reflection of the first RF signals by the target object.

Example 280. A method for use with a device comprising a substrate having a receiver, interface circuitry, and processing circuitry mounted thereon, the receiver comprising a receive antenna array comprising a first plurality of receive RF antennas and a second plurality of receive RF antennas, the receiver further comprising receive circuitry comprising a first plurality of receive channels coupled to the first plurality of receive RF antennas and a second plurality of receive channels coupled to the second plurality of receive RF antennas, the interface circuitry comprising first serial communication circuitry and second serial communication circuitry, and the processing circuitry being communicatively coupled to the interface circuitry, the method comprising: receiving, using the first plurality of receive RF antennas, first receive RF signals; receiving, using the second plurality of receive RF antennas, second receive RF signals; processing, using the first plurality of receive channels, the first receive RF signals to obtain first processed RF signals; processing, using the second plurality of receive channels, the second receive RF signals to obtain second processed RF signals; serializing, using the first serial communication circuitry, the first processed RF signals to obtain and transmit a first serialized processed RF signal; serializing, using the second serial communication circuitry, the second processed RF signals to obtain and transmit a second serialized processed RF signal; and synchronizing, using the processing circuitry, serialization of the first processed RF signals by the first serial communication circuitry with serialization of the second processed RF signals by the second serial communication circuitry.

Example 281. The method of Example 280, wherein synchronizing serialization of the first processed RF signals with serialization of the second processed RF signals comprises providing, using the processing circuitry, a trigger signal to the first serial communication circuitry and to the second serial communication circuitry.

Example 282. The method of Example 281, wherein: the first serial communication circuitry comprises a first serial interface controller and a first framer; the second serial communication circuitry comprises a second serial interface controller and a second framer; and the method further comprises: providing, using the first framer, a first frame of the first processed RF signals to the first serial interface controller in response to the trigger signal, the first serialized processed RF signal comprising the first frame of the first processed RF signals; providing, using the second framer, a second frame of the second processed RF signals to the second serial interface controller in response to the trigger signal, the second serialized processed RF signal comprising the second frame of the second processed RF signals; and combining, using the processing circuitry, the first frame of the first serialized processed RF signal with the second frame of the second serialized processed RF signal.

Example 283. The method of any one of Examples 280 to 282, wherein: the interface circuitry further comprises: first analog-to-digital conversion (ADC) circuitry coupled to the first plurality of receive channels; and second ADC circuitry coupled to the second plurality of receive channels; the first serial communication circuitry comprises first digital serial communication circuitry; the second serial communication circuitry comprises second digital serial communication circuitry; the method further comprises: digitizing, using the first ADC circuitry, the first processed RF signals to obtain first digitized processed RF signals; and digitizing, using the second ADC circuitry, the second processed RF signals to obtain second digitized processed RF signals; serializing the first processed RF signals comprises serializing, using the first digital serial communication circuitry, the first digitized processed RF signals; and serializing the second processed RF signals comprises serializing, using the second digital serial communication circuitry, the second digitized processed RF signals.

Example 284. The method of any one of Examples 280 to 283, wherein synchronizing serialization of the first processed RF signals with serialization of the second processed RF signals comprises providing, using the processing circuitry, a clock signal to the first serial communication circuitry and to the second serial communication circuitry.

Example 285. A device, comprising: a substrate; a receiver mounted on the substrate, the receiver comprising: a receive antenna array comprising: a first plurality of receive RF antennas, the first plurality of receive RF antennas configured to receive first receive RF signals; and a second plurality of receive RF antennas, the second plurality of receive RF antennas configured to receive second receive RF signals; and receive circuitry comprising: a first plurality of receive channels coupled to the first plurality of receive RF antennas and configured to process the first receive RF signals to obtain first processed RF signals; and a second plurality of receive channels coupled to the second plurality of receive RF antennas and configured to process the second receive RF signals to obtain second processed RF signals; interface circuitry mounted on the substrate, the interface circuitry comprising: first serial communication circuitry configured to serialize the first processed RF signals to obtain and transmit a first serialized processed RF signal; and second serial communication circuitry configured to serialize the second processed RF signals to obtain and transmit a second serialized processed RF signal; and processing circuitry mounted on the substrate, communicatively coupled to the interface circuitry, and configured to transmit a trigger signal and a clock signal to the first serial communication circuitry and the second serial communication circuitry.

Example 286. A method of manufacturing a device comprising a substrate defining a plane extending in a first direction and a second direction that are substantially orthogonal to one another, the device further comprising a first plurality of semiconductor dies and a second plurality of semiconductor dies, the method comprising: mounting the first plurality of semiconductor dies on the substrate; after mounting the first plurality of semiconductor dies on the substrate, mechanically coupling a fixture to the substrate; and after mechanically coupling the fixture to the substrate, mounting the second plurality of semiconductor dies on the substrate.

Example 287. The method of Example 286, wherein the substrate comprises a first material having a first thermal expansion coefficient and the fixture comprises a second material having a second thermal expansion coefficient that is lower than the first thermal expansion coefficient.

Example 288. The method of Example 287, wherein the first plurality of semiconductor dies comprise a third material having a third thermal expansion coefficient that is lower than the first thermal expansion coefficient.

Example 289. The method of Example 287 or 288, wherein the second thermal expansion coefficient is less than 5 parts per million per degree Celsius (ppm/° C.).

Example 290. The method of any one of Examples 287 to 289, wherein the second thermal expansion coefficient is less than 2 parts per million per degree Celsius (ppm/° C.).

Example 291. The method of any one of Examples 286 to 290, wherein the fixture comprises a nickel-iron alloy.

Example 292. The method of any one of Examples 286 to 291, wherein: the substrate comprises a first edge and a second edge opposite the first edge in the second direction; and mechanically coupling the fixture to the substrate comprises fastening the fixture to the substrate at a first point within a threshold distance of the first edge and at a second point within the threshold distance of the second edge.

Example 293. The method of Example 292, wherein fastening the fixture to the substrate at the first point comprises using a first fastener and fastening the fixture to the substrate at the second point comprises using a second fastener.

Example 294. The method of any one of Examples 286 to 293, wherein: mounting the first plurality of semiconductor dies on the substrate comprises tiling a first row of semiconductor dies of the first plurality of semiconductor dies on the substrate in the second direction; and mounting the second plurality of semiconductor dies on the substrate comprises tiling a first column of semiconductor dies of the second plurality of semiconductor dies on the substrate in the first direction.

Example 295. The method of any one of Examples 286 to 294, further comprising, after mechanically coupling the fixture to the substrate, underfilling the first plurality of semiconductor dies.

Example 296. The method of any one of Examples 286 to 295, wherein: mounting the first plurality of semiconductor dies on the substrate comprises using a ball-grid-array (BGA); and mounting the second plurality of semiconductor dies on the substrate comprises wire-bonding the second plurality of semiconductor dies on the substrate.

Example 297. The method of any one of Examples 286 to 296, wherein: each of the first plurality of semiconductor dies comprises a first antenna array and first circuitry coupled to the first antenna array; and each of the second plurality of semiconductor dies comprises a second antenna array and second circuitry coupled to the second antenna array.

Example 298. The method of Example 297, wherein: the first antenna array comprises a first receive antenna array; the first circuitry comprises first receive circuitry; the second antenna array comprises a second transmit antenna array; and the second circuitry comprises second transmit circuitry.

Example 299. The method of any one of Examples 286 to 298, further comprising mounting signal generation circuitry on the substrate and coupling the signal generation circuitry to the first plurality of semiconductor dies and to the second plurality of semiconductor dies.

Example 300. A method of manufacturing a device comprising a substrate defining a plane extending in a first direction and a second direction that are substantially orthogonal to one another, a transmitter comprising a plurality of transmit semiconductor dies each comprising transmit circuitry and a transmit antenna array coupled to the transmit circuitry, a receiver comprising a plurality of receive semiconductor dies each comprising a receive circuitry and a receive antenna array coupled to the receive circuitry, and a fixture, the method comprising: mounting the plurality of receive semiconductor dies on the substrate at least in part by tiling a first row of receive semiconductor dies of the plurality of receive semiconductor dies on the substrate in the second direction; after mounting the plurality of receive semiconductor dies on the substrate, mechanically coupling the fixture to the substrate at least in part by: fastening a first edge of the substrate to the fixture at a first point within a threshold distance of the first edge; and fastening a second edge of the substrate to the fixture at a second point within the threshold distance of the second edge, wherein the second edge is opposite the first edge in the second direction; and after mechanically coupling the fixture to the substrate, mounting the plurality of transmit semiconductor dies on the substrate at least in part by tiling a first column of transmit semiconductor dies of the plurality of transmit semiconductor dies on the substrate in the first direction.

Example 301. A device, comprising: a substrate defining a plane extending in a first direction and a second direction that are substantially orthogonal to one another, the substrate comprising a first point and a second point that are configured for mechanically coupling to a fixture during manufacture of the device; a plurality of semiconductor dies mounted on the substrate and each having integrated thereon: a first antenna array comprising a first plurality of antennas; and first circuitry coupled to the first plurality of antennas; and a heat spreader mechanically coupled to the substrate at the first point and at the second point.

Example 302. The device of Example 301, wherein: the first point is configured to receive a first fastener to mechanically couple the substrate to the fixture during manufacture; the second point is configured to receive a second fastener to mechanically couple the substrate to the fixture during manufacture; and the device comprises the first fastener mechanically coupling the heat spreader to the substrate at the first point and the second fastener mechanically coupling the heat spreader to the substrate at the second point.

Example 303. The device of Example 301 or 302, wherein the plurality of semiconductor dies are disposed, in the second direction, between the first point and the second point.

Example 304. The device of any one of Examples 301 to 303, wherein: the substrate comprises a first edge and a second edge opposite the first edge in the second direction; the first point is within a threshold distance of the first edge; and the second point is within the threshold distance of the second edge.

Example 305. The device of any one of Examples 301 to 304, wherein the plurality of semiconductor dies comprises a first row of semiconductor dies mounted on the substrate and tiled in the second direction, the first row of semiconductor dies having a first length in the first direction and a second length in the second direction that is at least ten times the first length.

Having thus described several aspects and embodiments of the technology set forth in the disclosure, it is to be appreciated that various alterations, modifications, and improvements will readily occur to those skilled in the art. Such alterations, modifications, and improvements are intended to be within the spirit and scope of the technology described herein. For example, those of ordinary skill in the art will readily envision a variety of other means and/or structures for performing the function and/or obtaining the results and/or one or more of the advantages described herein, and each of such variations and/or modifications is deemed to be within the scope of the embodiments described herein. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The above-described embodiments can be implemented in any of numerous ways. One or more aspects and embodiments of the present disclosure involving the performance of processes or methods may utilize program instructions executable by a device (e.g., a computer, a processor, or other device) to perform, or control performance of, the processes or methods. In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above. The computer readable medium or media can be transportable, such that the program or programs stored thereon can be loaded onto one or more different computers or other processors to implement various ones of the aspects described above. In some embodiments, computer readable media may be non-transitory media.

The terms “program” or “software” are used herein in a generic sense to refer to any type of computer code or set of computer-executable instructions that can be employed to program a computer or other processor to implement various aspects as described above. Additionally, it should be appreciated that according to one aspect, one or more computer programs that when executed perform methods of the present disclosure need not reside on a single computer or processor, but may be distributed in a modular fashion among a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a Personal Digital Assistant (PDA), a smartphone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than onc, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The terms “approximately” and “about” may be used to mean within +20% of a target value in some embodiments, within +10% of a target value in some embodiments, within +5% of a target value in some embodiments, within +2% of a target value in some embodiments. The terms “approximately” and “about” may include the target value.

What is claimed is:

1. A device, comprising:
a substrate; and
a receiver mounted on the substrate, the receiver comprising:
a first receive semiconductor die having integrated thereon:
a first receive antenna array configured to receive RF signals, the first receive antenna array comprising a first RF antenna; and
first receive circuitry comprising:
a plurality of mixers coupled to respective RF antennas in the first receive antenna array, the plurality of mixers comprising a first mixer coupled to the first RF antenna and configured to mix an RF signal obtained using the first RF antenna with a reference RF signal to output a first mixed signal;
a first amplifier coupled to the first mixer and configured to amplify the first mixed signal output by the first mixer; and
a first reflector coupled between the first mixer and the first amplifier and configured to reflect at least some RF energy generated by the first mixer back into the first mixer.

2. The device of claim 1, wherein:
the first RF antenna is configured to receive a first RF signal,
the RF signal is based on the first RF signal, and
the first mixed signal has a center frequency indicative of a distance between the device and a target object from which the first RF signal was received by the first RF antenna.

3. The device of claim 1, wherein:
the RF signal has a center frequency, and
the at least some RF energy comprises a voltage and/or current wave having the center frequency of the RF signal.

4. The device of claim 3, wherein:
the first mixer is configured to output the first mixed signal as a current signal,
the first amplifier comprises a transimpedance amplifier (TIA) configured to convert the current signal into a voltage signal,
the at least some RF energy comprises a current wave having the center frequency of the RF signal, and
the first reflector comprises a current reflector configured to reflect the current wave back into the first mixer.

5. The device of claim 3, wherein the center frequency of the RF signal is between 300 GHz and 320 GHz.

6. The device of claim 3, wherein:
the first reflector comprises a current reflector; and
the first reflector comprises a transmission line stub having a length of one quarter of a wavelength at the center frequency of the RF signal.

7. The device of claim 3, wherein:
the reference RF signal comprises a second harmonic having the center frequency of the RF signal, and
the first mixer is configured to mix the RF signal with the second harmonic of the reference RF signal.

8. The device of claim 1, wherein:
the RF signal is defined by a first differential component and a second differential component;
the first mixer is configured to mix the first differential component of the RF signal with the reference RF signal to output the first mixed signal;
the plurality of mixers further comprises a second mixer coupled to the first RF antenna and configured to mix the second differential component of the RF signal with the reference RF signal to output a second mixed signal; and
the first receive circuitry further comprises:
a second amplifier coupled to the second mixer and configured to amplify the second mixed signal output by the second mixer, and
a second reflector coupled between the second mixer and the second amplifier and configured to reflect at least some RF energy generated by the second mixer back into the second mixer.

9. The device of claim 1, wherein:
the first receive antenna array further comprises a second RF antenna;
the plurality of mixers further comprises a second mixer coupled to the second RF antenna and configured to mix a second RF signal obtained using the second RF antenna with the reference RF signal to output a second mixed signal; and
the first receive circuitry further comprises:
a second amplifier coupled to the second mixer and configured to amplify the second mixed signal output by the second mixer, and
a second reflector coupled between the second mixer and the second amplifier and configured to reflect at least some RF energy generated by the second mixer back into the second mixer.

10. The device of claim 1, wherein:
the first mixer comprises a first differential mixer configured to:
mix the RF signal with a first differential component of the reference RF signal to generate a first mixed signal component;
mix the RF signal with a second differential component of the reference RF signal to generate a second mixed signal component; and
combine the first and second mixed signal components to generate the first mixed signal.

11. The device of claim 1, further comprising:
signal generation circuitry mounted on the substrate and configured to generate a reference RF signal; and
a transmitter mounted on the substrate, the transmitter comprising:
a first transmit semiconductor die having integrated thereon:
a plurality of RF antennas, and
transmit circuitry configured to generate, using the reference RF signal, first RF signals and feed the first RF signals to the plurality of RF antennas,
wherein the signal generation circuitry is coupled to the first receive circuitry and is configured to provide the reference RF signal to the first receive circuitry.

12. A method for use with a device, the device comprising a substrate and a receiver mounted on the substrate, the receiver comprising a first receive semiconductor die having integrated thereon a first receive antenna array and first receive circuitry, the first receive antenna array comprising a first RF antenna, the first receive circuitry comprising a plurality of mixers coupled to respective RF antennas in the first receive antenna array, the plurality of mixers comprising a first mixer coupled to the first RF antenna, and the first receive circuitry further comprising a first amplifier coupled to the first mixer and a first reflector coupled between the first mixer and the first amplifier, the method comprising:
receiving, using the first receive antenna array, RF signals;
mixing, using the first mixer, an RF signal obtained using the first RF antenna with a reference RF signal to output a first mixed signal;
amplifying, using the first amplifier, the first mixed signal output by the first mixer; and
reflecting, using the first reflector, at least some RF energy generated by the first mixer back into the first mixer.

13. The method of claim 12, wherein:
the RF signal has a center frequency, and
the at least some RF energy comprises a voltage and/or current wave having the center frequency of the RF signal.

14. The method of claim 13, wherein:
the first amplifier comprises a transimpedance amplifier (TIA);
the first reflector comprises a current reflector;
mixing the RF signal with the reference RF signal comprises outputting, using the first mixer, the first mixed signal as a current signal,
amplifying the first mixed signal comprises converting, using the TIA, the current signal into a voltage signal;
the at least some RF energy comprises a current wave having the center frequency of the RF signal, and
reflecting the at least some RF energy comprises reflecting, using the current reflector, the current wave back into the first mixer.

15. The method of claim 13, wherein the center frequency of the RF signal is between 300 GHz and 320 GHz.

16. The method of claim 13, wherein:
the first reflector comprises a current reflector; and
the first reflector comprises a transmission line stub having a length of one quarter of a wavelength at the center frequency of the RF signal.

17. The method of claim 13, wherein:
the reference RF signal comprises a second harmonic having the center frequency of the RF signal, and
mixing the RF signal with the reference RF signal comprises mixing, using the first mixer, the RF signal with the second harmonic of the reference RF signal.

18. The method of claim 12, wherein:
the RF signal is defined by a first differential component and a second differential component;
the plurality of mixers further comprises a second mixer coupled to the first RF antenna;
mixing the RF signal with the reference RF signal comprises mixing, using the first mixer, the first differential component of the RF signal with the reference RF signal to output the first mixed signal;
the method further comprises mixing, using the second mixer, the second differential component of the RF signal with the reference RF signal to output a second mixed signal;
the first receive circuitry further comprises a second amplifier coupled to the second mixer and a second reflector coupled between the second mixer and the second amplifier; and
the method further comprises:
amplifying, using the second amplifier, the second mixed signal output by the second mixer; and
reflecting, using the second reflector, at least some RF energy generated by the second mixer back into the second mixer.

19. The method of claim 12, wherein:
the first mixer comprises a first differential mixer; and
mixing the RF signal with the reference RF signal comprises:
mixing, using the first differential mixer, the RF signal with a first differential component of the reference RF signal to generate a first mixed signal component;
mixing, using the first differential mixer, the RF signal with a second differential component of the reference RF signal to generate a second mixed signal component; and
combining, using the first differential mixer, the first and second mixed signal components to generate the first mixed signal.

20. A device, comprising:
a substrate; and
a receiver mounted on the substrate, the receiver comprising:
a first receive semiconductor die having integrated thereon:
a first RF antenna configured to receive RF signals; and
first receive circuitry comprising:
a first mixer coupled to the first RF antenna and configured to mix an RF signal obtained using the first RF antenna with a reference RF signal to output a first mixed signal;
a first amplifier coupled to the first mixer and configured to amplify the first mixed signal output by the first mixer; and
a first reflector coupled between the first mixer and the first amplifier.
